(19) United States
(12) Patent Application Publication
(10) Pub. No.: US 2026/0347379 A1
(43) Pub. Date: Nov. 5, 2026

(54) POLYCYCLIC COMPOUND CONTAINING TRIPHENYLSILYL AND MULTIPLE ALKYL SUBSTITUENTS AND ORGANIC ELECTROLUMINESCENT DEVICE COMPRISING SAME

(71) Applicant: SHIJIAZHUANG CHENGZHI YONGHUA DISPLAY MATERIAL CO., LTD., Shijiazhuang (CN)

(72) Inventors: Tianyu WEI, Shijiazhuang (CN); Zhe SHAO, Shijiazhuang (CN); Zelin WU, Shijiazhuang (CN); Feng LIANG, Shijiazhuang (CN)

(73) Assignee: SHIJIAZHUANG CHENGZHI YONGHUA DISPLAY MATERIAL CO., LTD., Shijiazhuang (CN)

(21) Appl. No.: 19/556,937

(22) Filed: Mar. 4, 2026

(30) Foreign Application Priority Data
Sep. 25, 2025 (CN) 202511385660.0

(51) Int. Cl. C07F 7/08; H10K 50/12; H10K 85/40; H10K 85/60

(52) U.S. Cl. CPC C07F 7/0812; H10K 50/12; H10K 85/40; H10K 85/626; H10K 85/633; H10K 85/654; H10K 85/656; H10K 85/6572; H10K 85/6574; C07B 2200/05

(57) ABSTRACT

The present invention belongs to the technical field of OLEDs. The present invention provides a polycyclic compound containing triphenylsilyl and multiple alkyl substituents and an organic electroluminescent device comprising the polycyclic compound. The general structural formula of the polycyclic compound is as represented by Formula I. By the introduction of benzofuranyl having stronger electronegativity into a cyclic structure composed of a nitrogen atom and a boron atom and further the introduction of triphenylsilyl into the para position relative to the boron, a synergistic effect between the benzofuranyl and triphenylsilyl can significantly enhance the multiple resonance of a luminescent core and reduce vibrational relaxation. Therefore, the use of both benzofuranyl and triphenylsilyl significantly ameliorates issues such as increased vibrational relaxation and spectral broadening caused by the introduction of multiple alkyl substituents, significantly improves the luminous efficiency of the material, and improves the color purity, thereby meeting the luminescence spectrum requirements of the BT.2020 wide color gamut display standard.

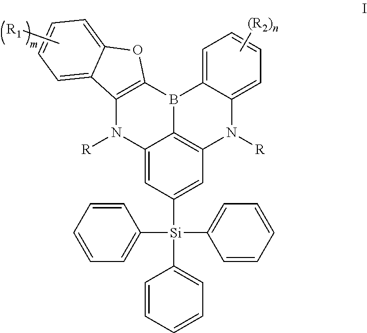

### TECHNICAL FIELD

The present invention belongs to the technical field of OLEDs and in particular comprises a polycyclic compound containing triphenylsilyl and multiple alkyl substituents and an organic electroluminescent device comprising the polycyclic compound.

### BACKGROUND ART

In the current OLED display field, low efficiency and short lifetime issues existing in blue light-emitting devices are still the key bottleneck restricting the development of this field. Current mainstream OLED blue-light technology still relies on fluorescent luminescent materials as host materials (BH) and dopant materials (BD). During luminescence, the dopant material requires a host-guest energy transfer mechanism to acquire energy from the host material. This process mainly relies on two forms: Förster energy transfer and Dexter energy transfer, wherein Dexter energy transfer easily results in the generation of triplet excitons having a relatively long lifetime in the dopant material during working. Being in the excited state for a long time can induce material decomposition. Therefore, the occurrence of this energy transfer process should be suppressed as much as possible.

Since the rate constant of Dexter energy transfer is closely related to the intermolecular spacing between the host material and the dopant material, increasing the intermolecular spacing between the two materials can significantly reduce the probability of occurrence thereof. To this end, a certain number of alkyl structures are introduced into existing dopant materials to increase the intermolecular spacing. However, excessive alkyl structures can significantly enhance the vibrational relaxation of the material in the excited state, leading to an increase in the peak width at half height of the spectrum and a reduction in luminous efficiency. Furthermore, the emission peak width at half height of currently developed blue luminescent materials inherently struggles to fully meet the requirements of the BT.2020 wide color gamut standard. The introduction of excessive alkyl structures exacerbates this issue.

Therefore, while Dexter energy transfer is suppressed as much as possible, how to reduce vibrational relaxation in order to maintain relatively high luminous efficiency has become a core issue to be urgently solved during the development of dopant materials.

### SUMMARY OF THE INVENTION

In view of this, the present invention provides a polycyclic compound containing triphenylsilyl and multiple alkyl substituents and an organic electroluminescent device comprising the polycyclic compound.

In order to achieve the object of the present invention, the following technical solution is used in the present invention:

In a first aspect, the present invention provides a polycyclic compound containing triphenylsilyl and multiple alkyl substituents. The general structural formula of the polycyclic compound is as shown in Formula I;

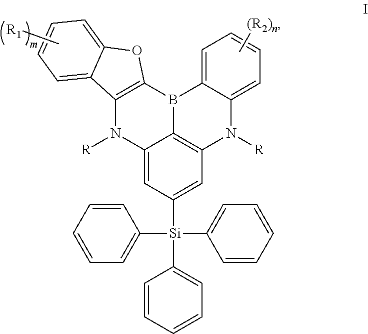

wherein R₁ and R₂ are the same or different and each independently represent any one of hydrogen, deuterium, halogen, a substituted or unsubstituted alkyl group having a carbon atom number of C1-C30, a substituted or unsubstituted cycloalkyl group having a carbon atom number of C3-C30, a substituted or unsubstituted aryl group having a carbon atom number of C6-C60, a substituted or unsubstituted heteroaryl group having a carbon atom number of C5-C60, a substituted or unsubstituted fused aryl group having a carbon atom number of C6-C60, and a substituted or unsubstituted heterocyclic fused aryl group having a carbon atom number of C5-C60, wherein two or more R₁ can be connected to each other to form an aliphatic ring, an aromatic ring, or a fused ring, and two or more R₂ can be connected to each other to form an aliphatic ring, an aromatic ring, or a fused ring;
each occurrence of R independently represents any one of a substituted or unsubstituted aryl group having a carbon atom number of C6-C60, a substituted or unsubstituted heteroaryl group having a carbon atom number of C5-C60, a substituted or unsubstituted fused aryl group having a carbon atom number of C6-C60, and a substituted or unsubstituted heterocyclic fused aryl group having a carbon atom number of C5-C60;
m and n each independently represent 0, 1, 2, 3, or 4, preferably 0, 1, or 2;
when R₁, R₂, and R contain substituents, the substituents are selected from an alkyl group having a carbon atom number of C1-C10 or an aryl group having a carbon atom number of C6-C20; and two or more of the substituents can be connected to each other to form an aliphatic ring;
the polycyclic compound comprises at least:
five tert-butyl groups; or
three tert-butyl groups and one ring structure formed by connecting any two tert-butyl groups at adjacent positions to each other; and
any hydrogen in Formula I can be replaced by deuterium or alkyl.

It needs to be first noted that the following provides an explanation regarding the replacement of hydrogen in the structure by tert-butyl and the ring formation.

The at least any one hydrogen being replaced by tert-butyl means that the hydrogen in the structure can be replaced by one or more tert-butyl groups in the following manner. When more than one tert-butyl group is replaced and two adjacent tert-butyl groups are present, these two tert-butyl groups can lose two hydrogen atoms and be connected to form a ring structure.

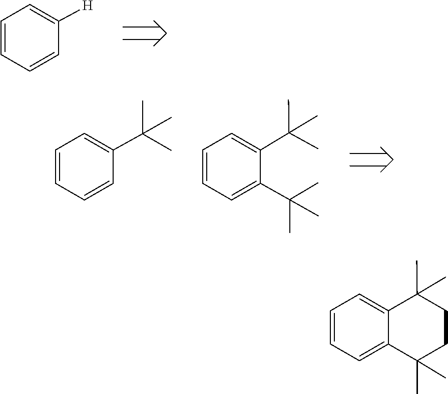

Furthermore, R₁ and R₂ each independently represent any one of a substituted or unsubstituted alkyl group having a carbon atom number of C1-C10 and a substituted or unsubstituted aryl group having a carbon atom number of C6-C30, wherein two or more R₁ can be connected to each other to form an aliphatic ring, and two or more R₂ can be connected to each other to form an aliphatic ring.

Furthermore, each occurrence of R independently represents a substituted or unsubstituted aryl group having a carbon atom number of C6-C20.

Furthermore, each occurrence of R independently represents any one of a substituted or unsubstituted phenyl group, a substituted or unsubstituted biphenylyl group, and a substituted or unsubstituted terphenylyl group.

Furthermore, each occurrence of R independently represents any one of

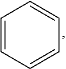

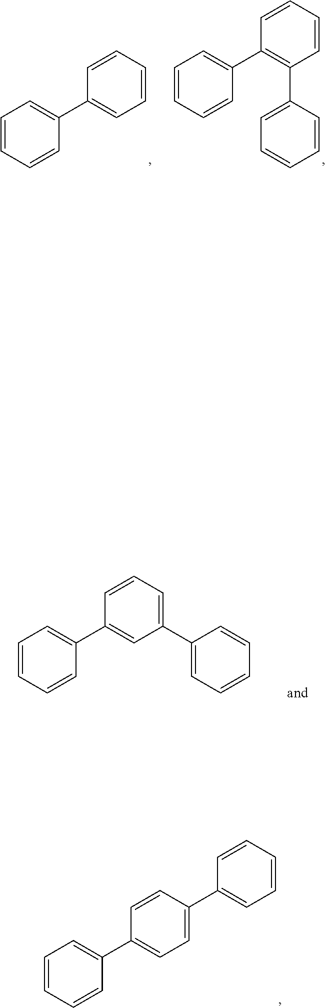

and any hydrogen in the above groups can be replaced by deuterium or alkyl.

Furthermore, the general structural formula of the polycyclic compound is as represented by one of:

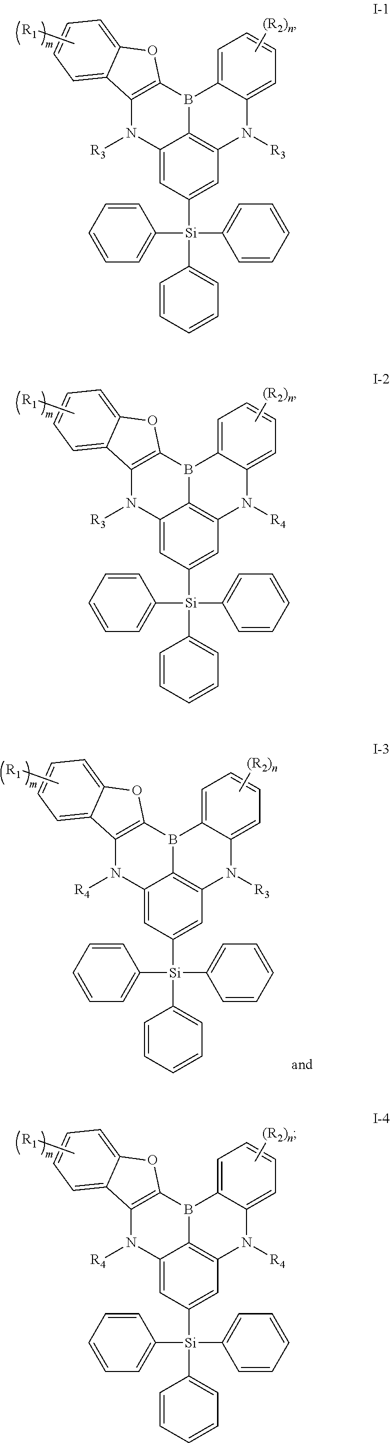

R₃ represents one of the following structures:

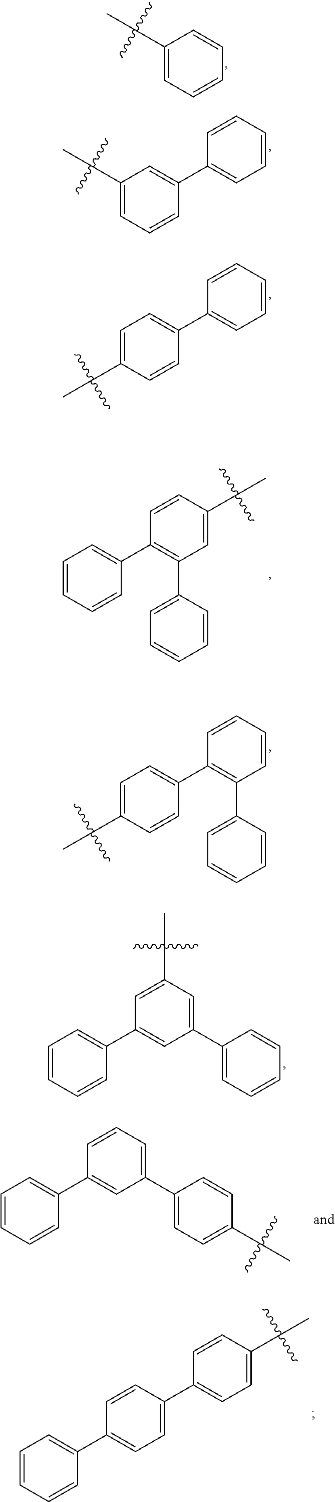

R₄ represents one of the following structures:

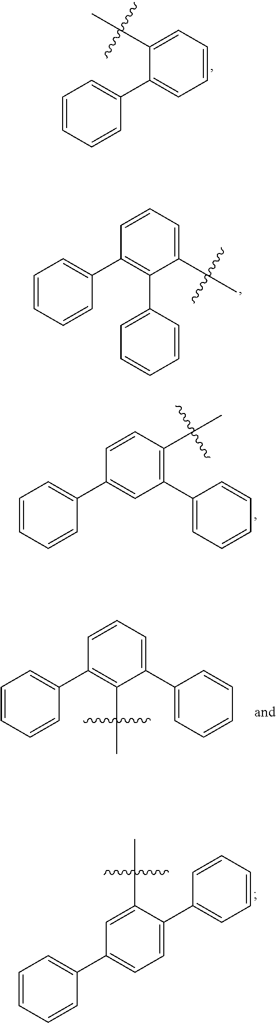 [SMILES: *c1ccccc1-c1ccccc1 ; *c1cccc(-c2ccccc2)c1-c1ccccc1 ; *c1ccc(-c2ccccc2)cc1-c1ccccc1 ; *c1c(-c2ccccc2)cccc1-c1ccccc1 ; *c1cc(-c2ccccc2)ccc1-c1ccccc1]

any hydrogen in the above groups defined for R₃ and R₄ can be replaced by deuterium or tert-butyl, at least one hydrogen in the above groups defined for R₃ and R₄ is replaced by tert-butyl, and when more than one hydrogen is replaced, two tert-butyl groups at adjacent positions can be connected to form a ring structure; and

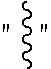

represents a bonding linkage.

Furthermore, R₃ represents one of the following structures:

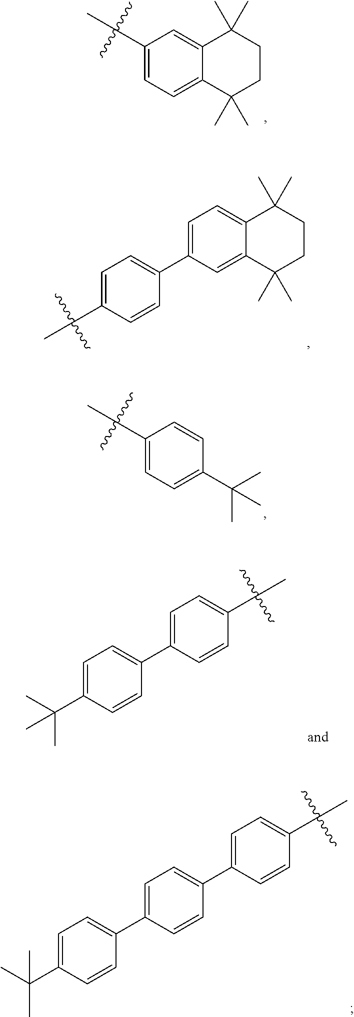 [SMILES: *c1ccc2c(c1)C(C)(C)CCC2(C)C ; *c1ccc(-c2ccc3c(c2)C(C)(C)CCC3(C)C)cc1 ; *c1ccc(C(C)(C)C)cc1 ; *c1ccc(-c2ccc(C(C)(C)C)cc2)cc1 ; *c1ccc(-c2ccc(-c3ccc(C(C)(C)C)cc3)cc2)cc1]

and/or
R₄ represents one of the following structures:

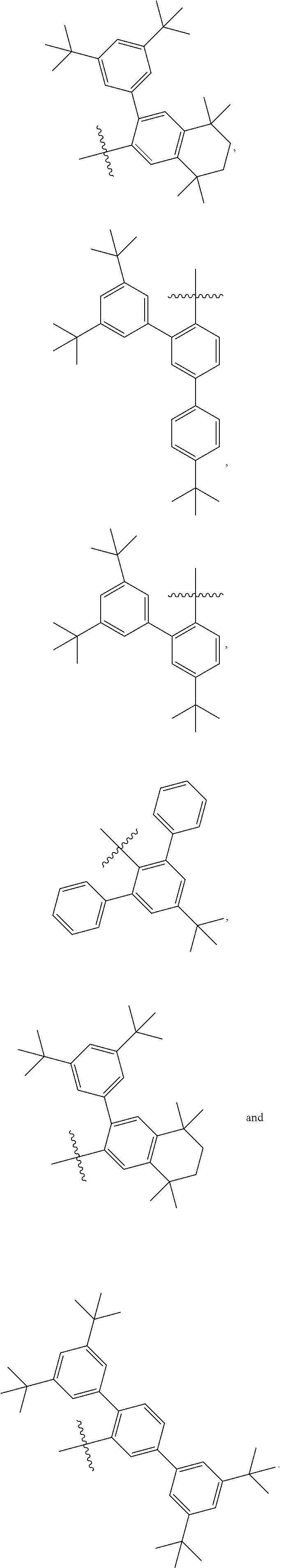

Furthermore, R₁ and R₂ each independently represent one of

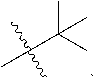 [SMILES: *C(C)(C)C]

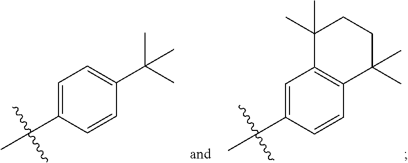

when R₁ represents tert-butyl, two R₁ at adjacent positions can be connected to each other to form a ring structure; and
when R₂ represents tert-butyl, two R₂ at adjacent positions can be connected to each other to form a ring structure.

Furthermore, the polycyclic compound is selected from the following structures:

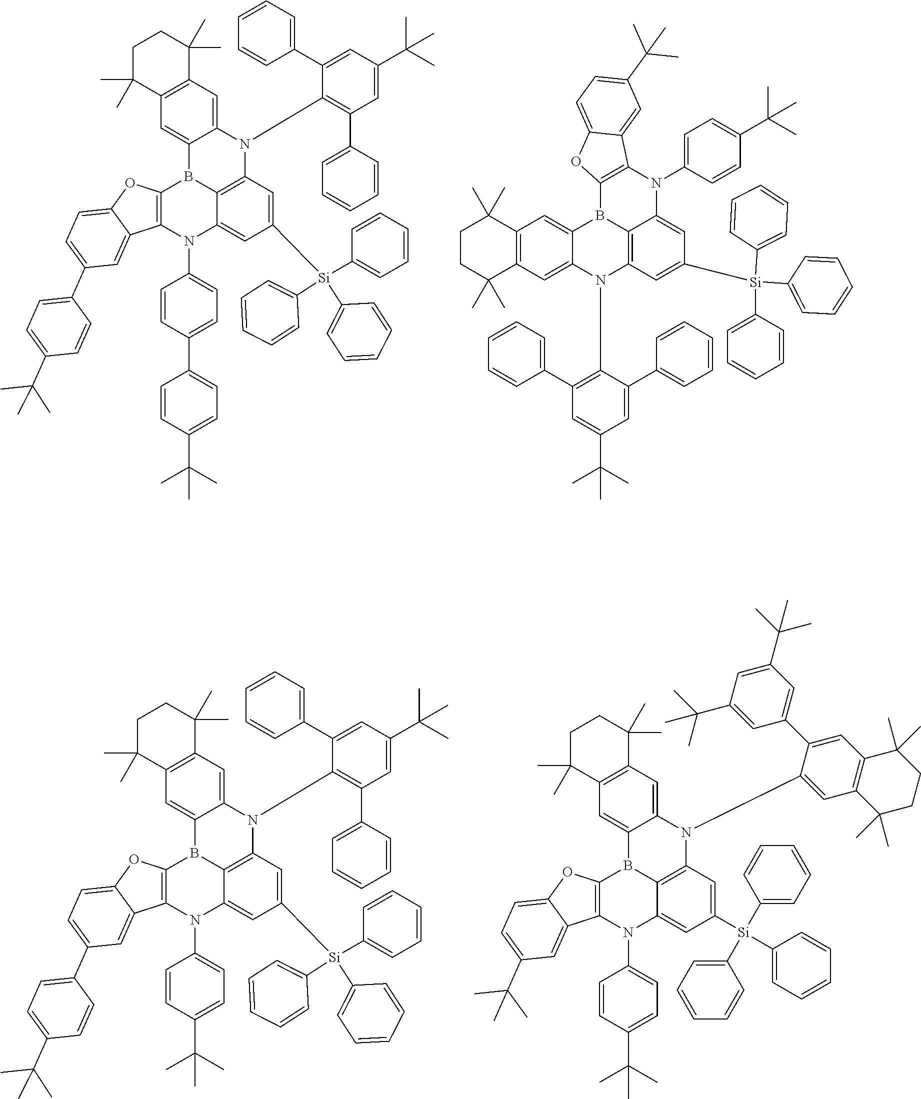

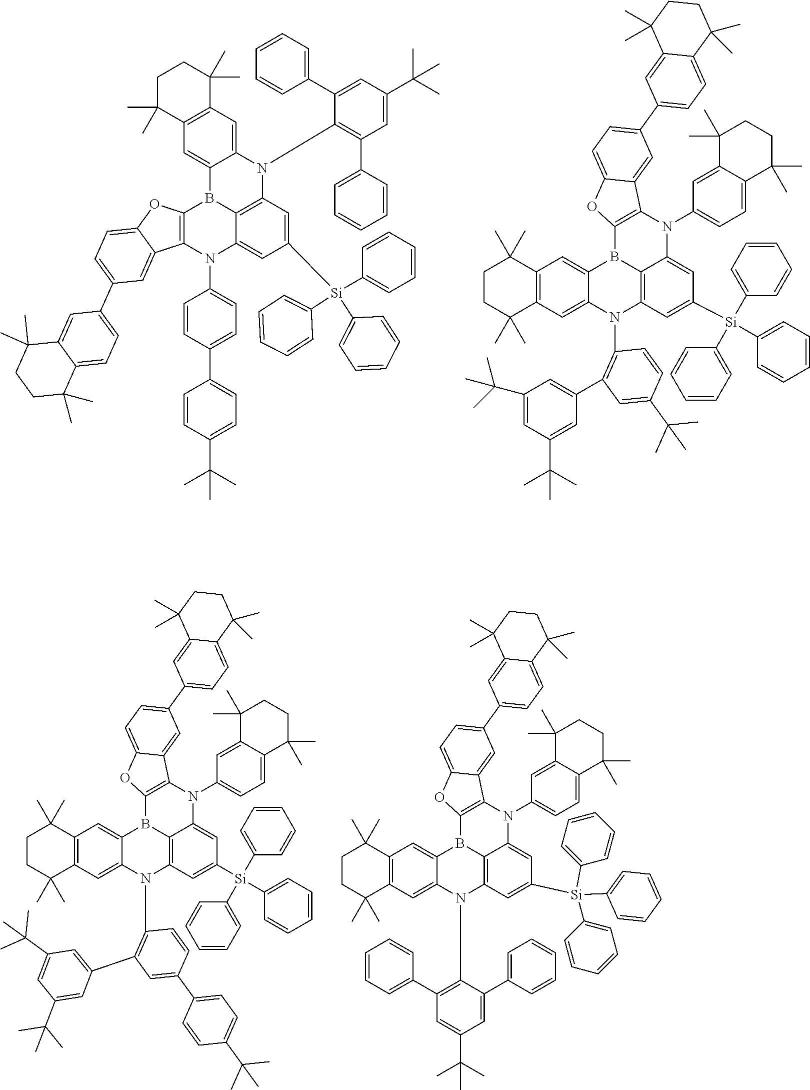

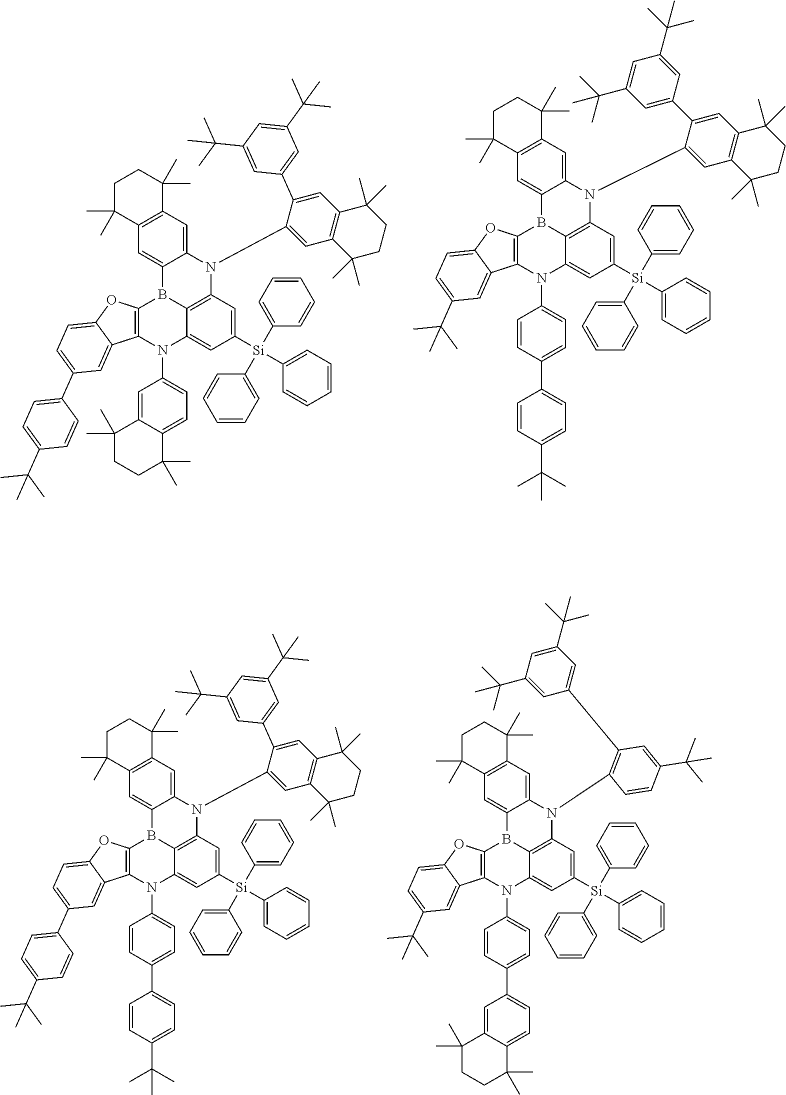

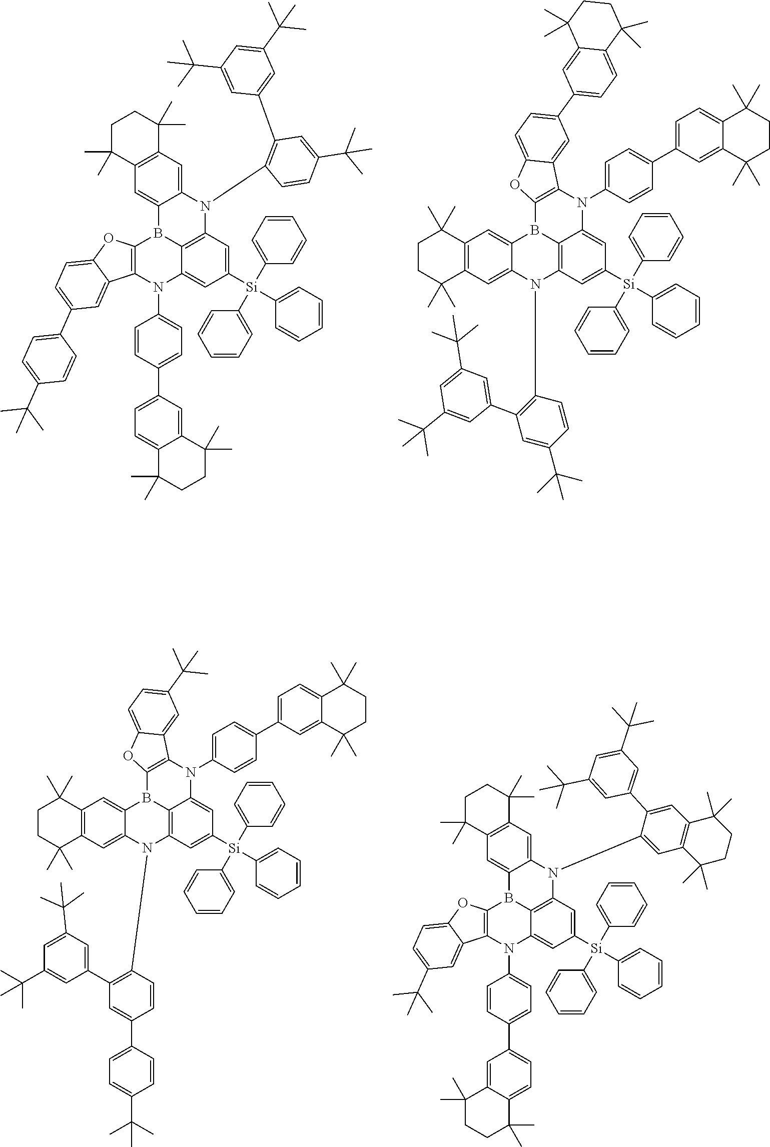

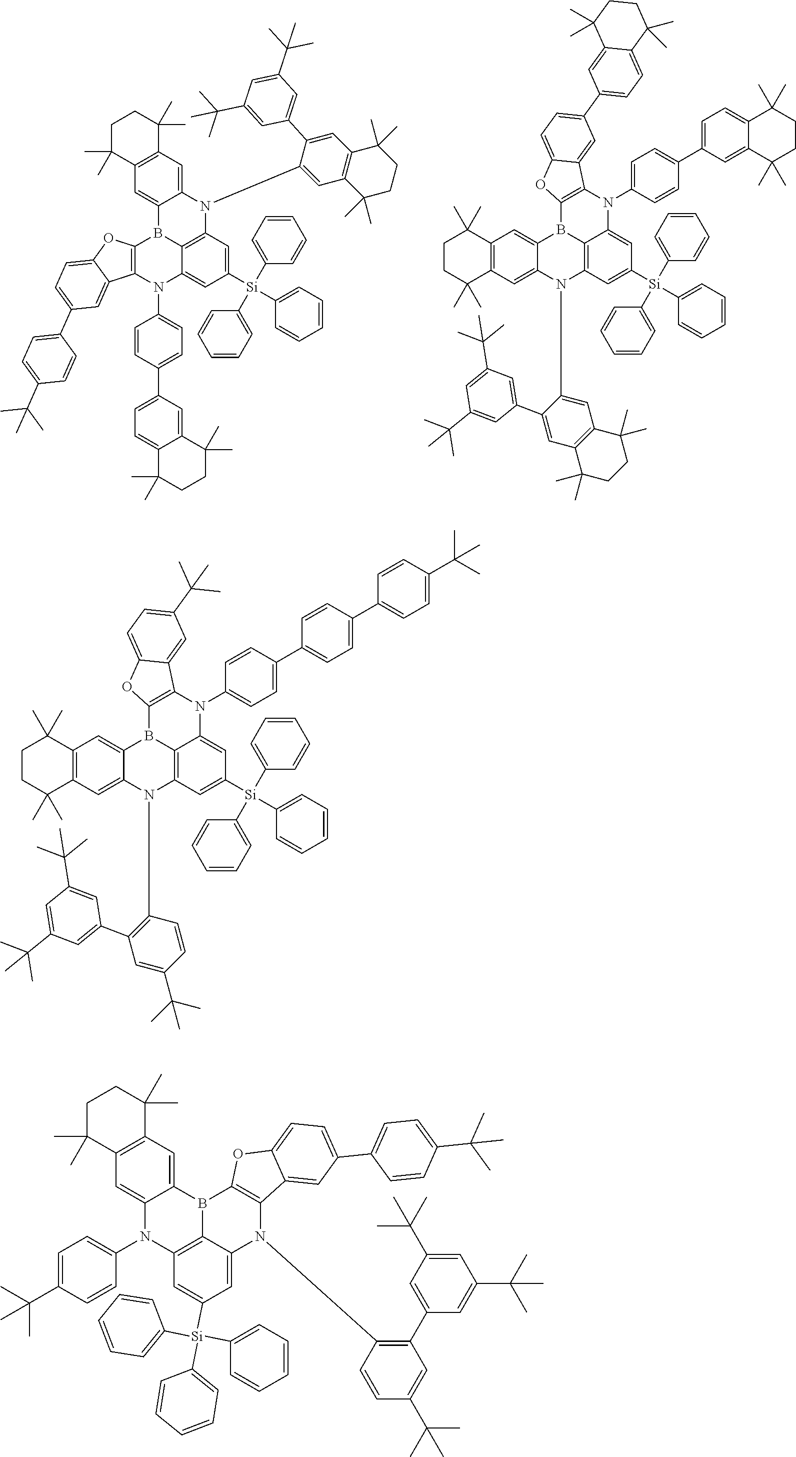

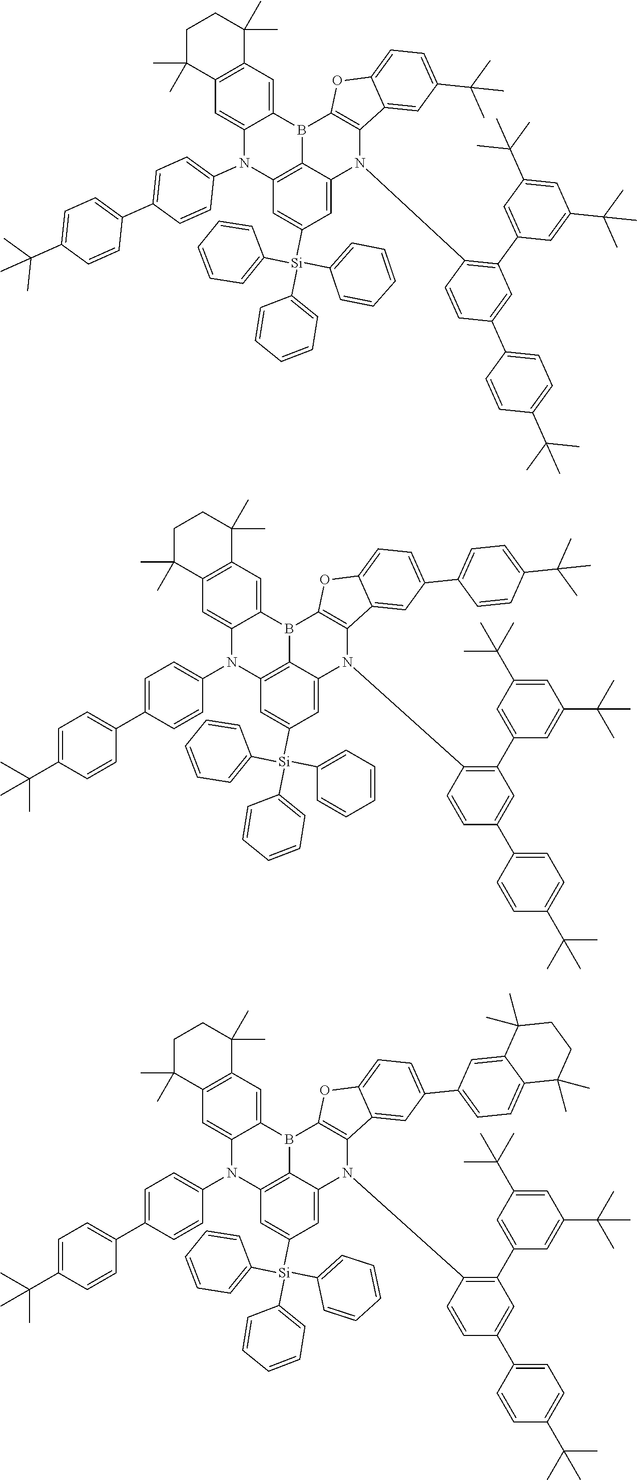

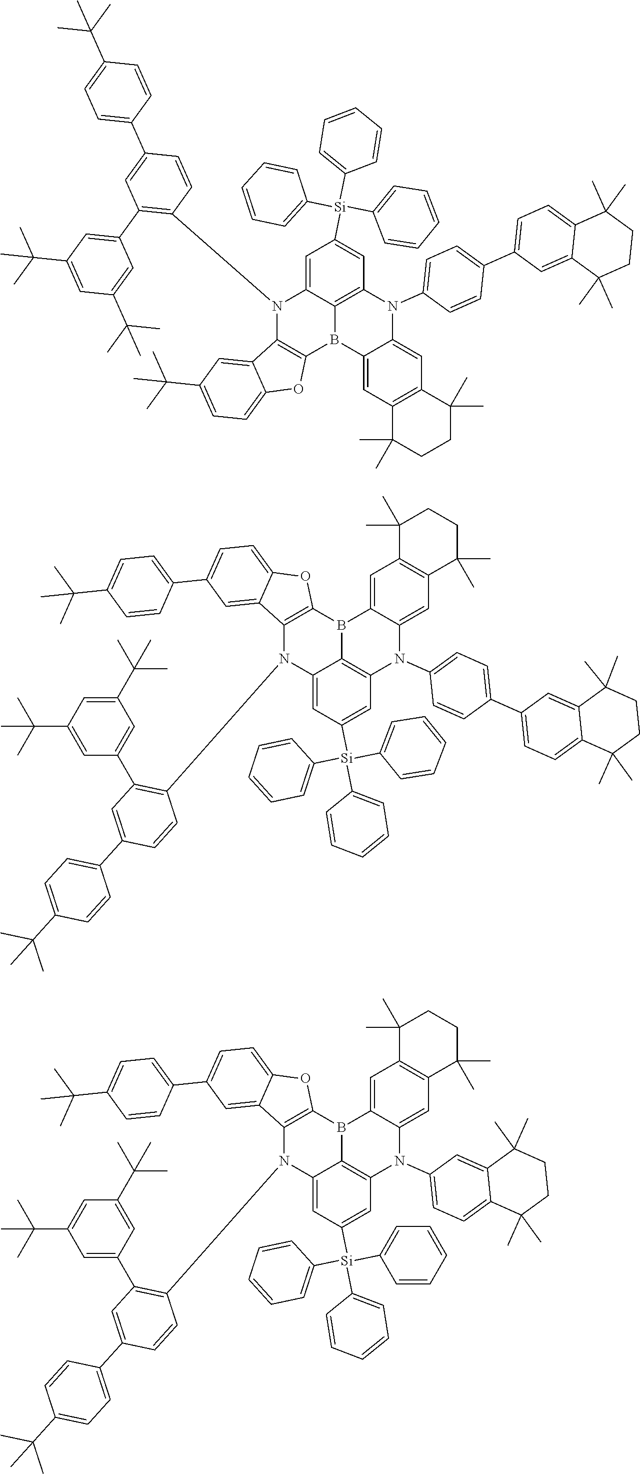

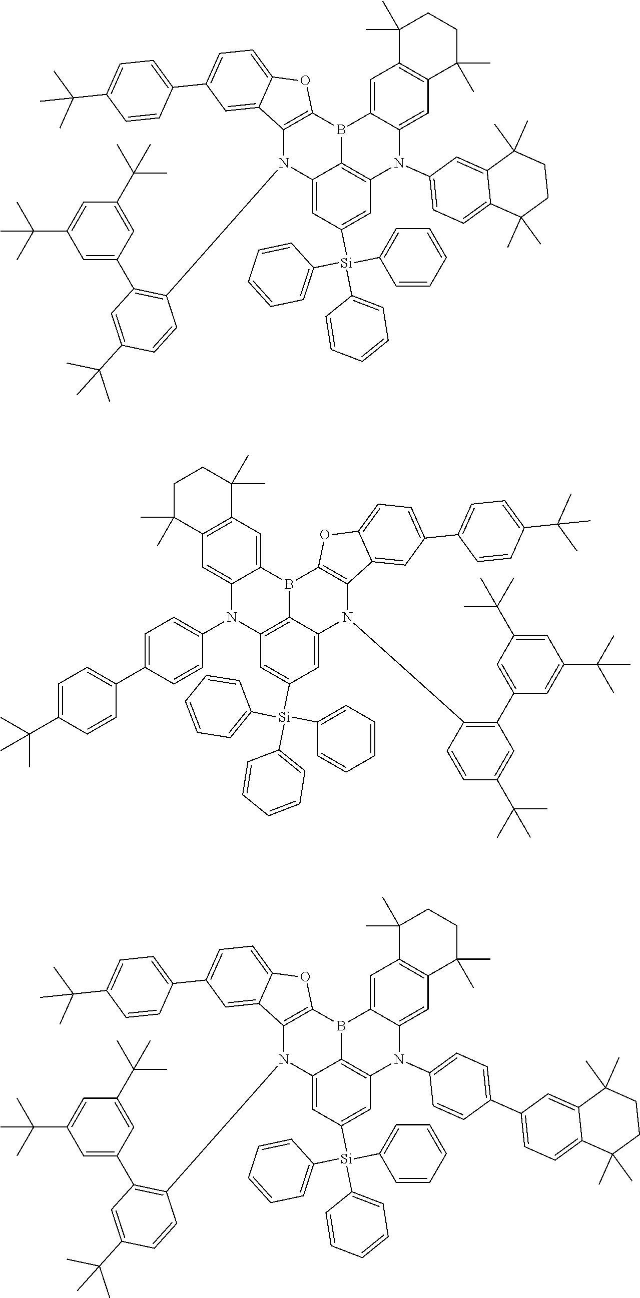

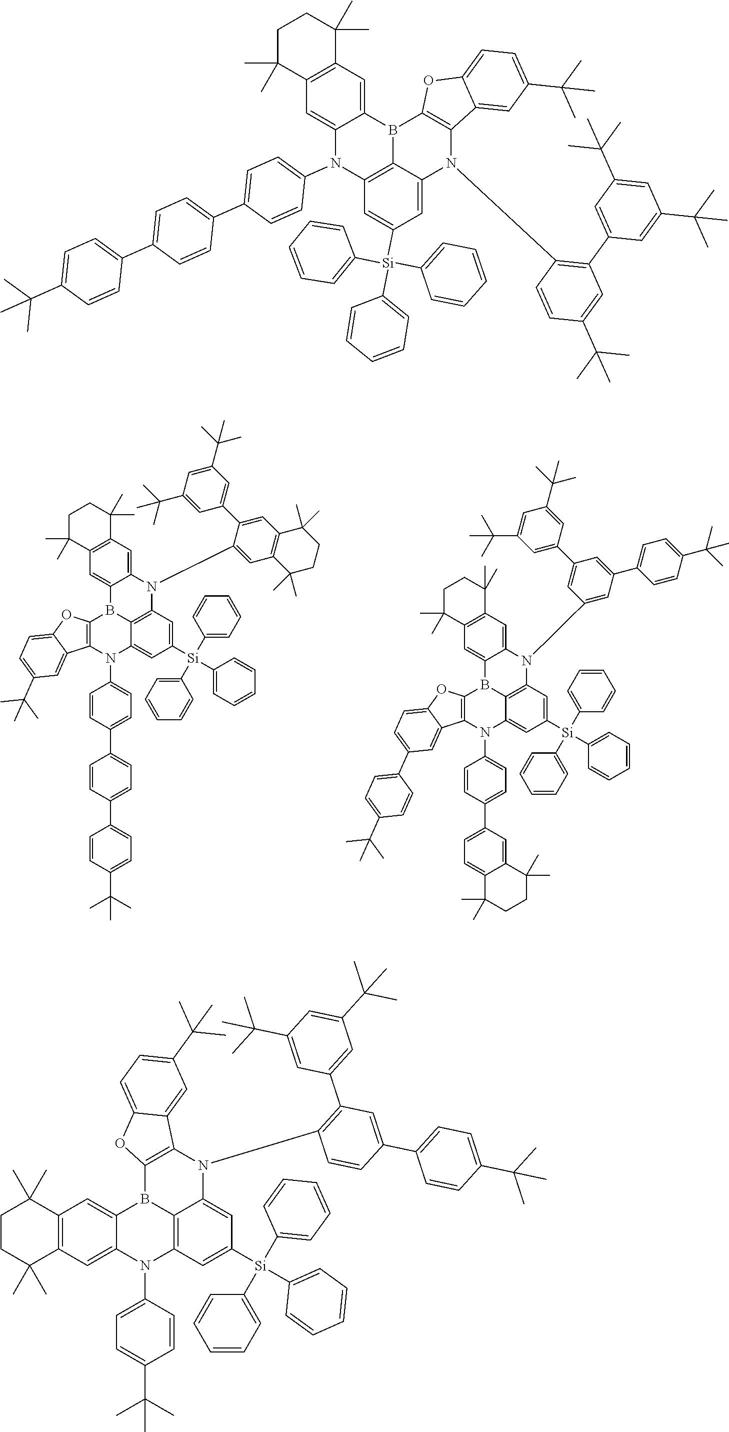

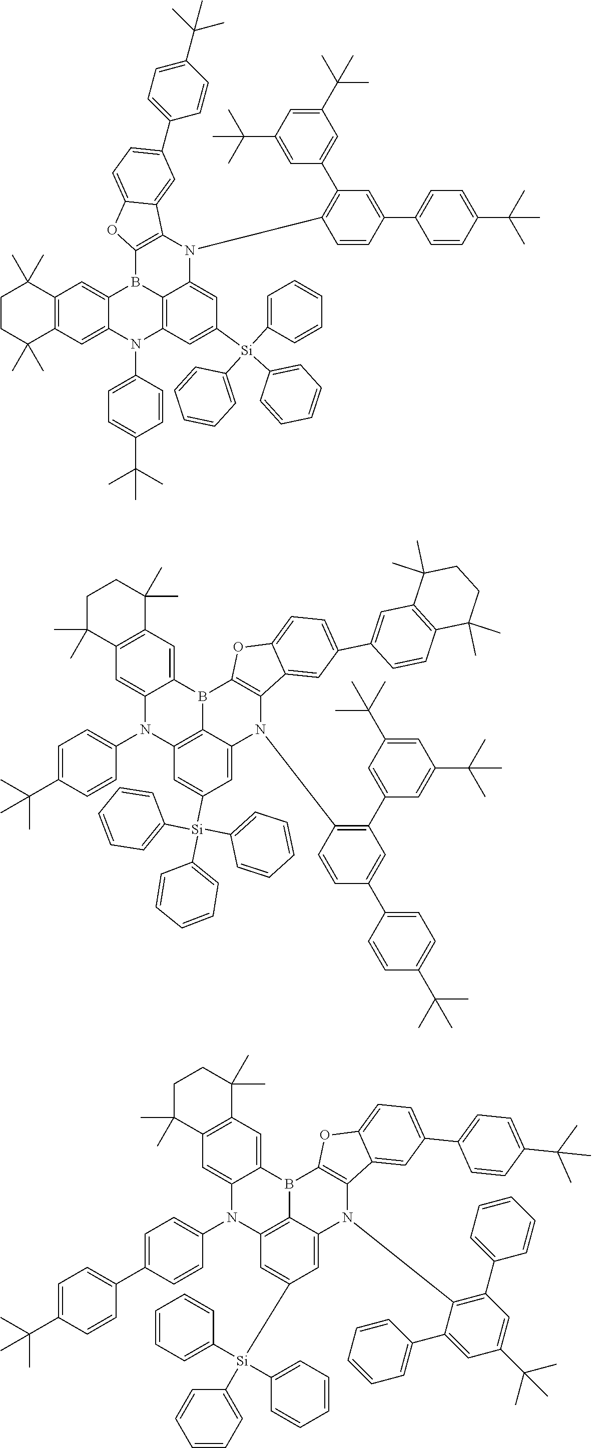

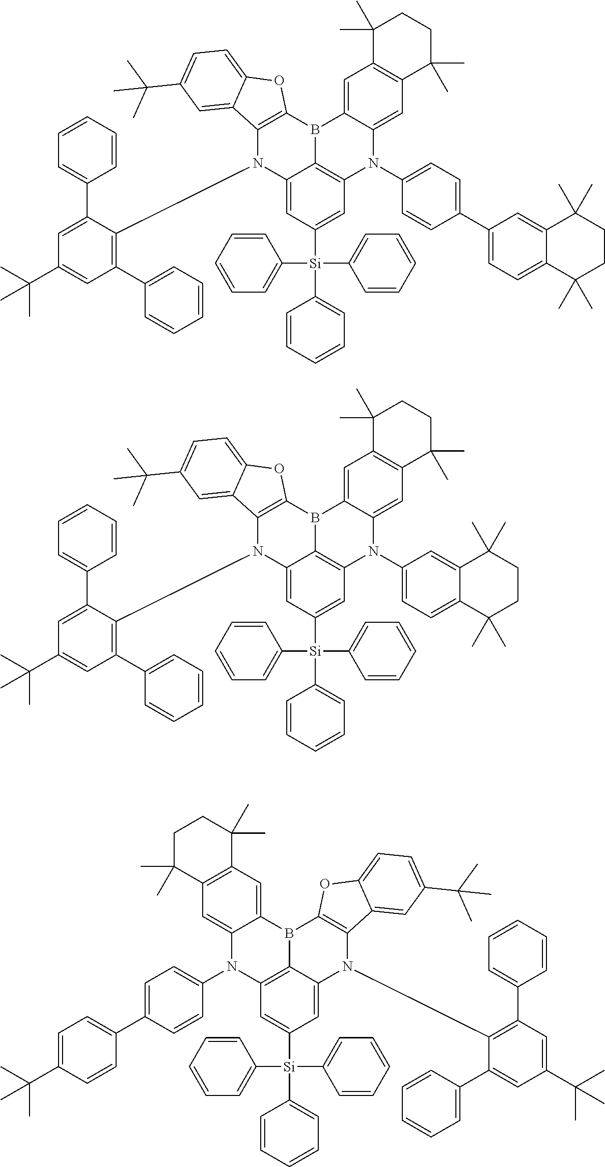

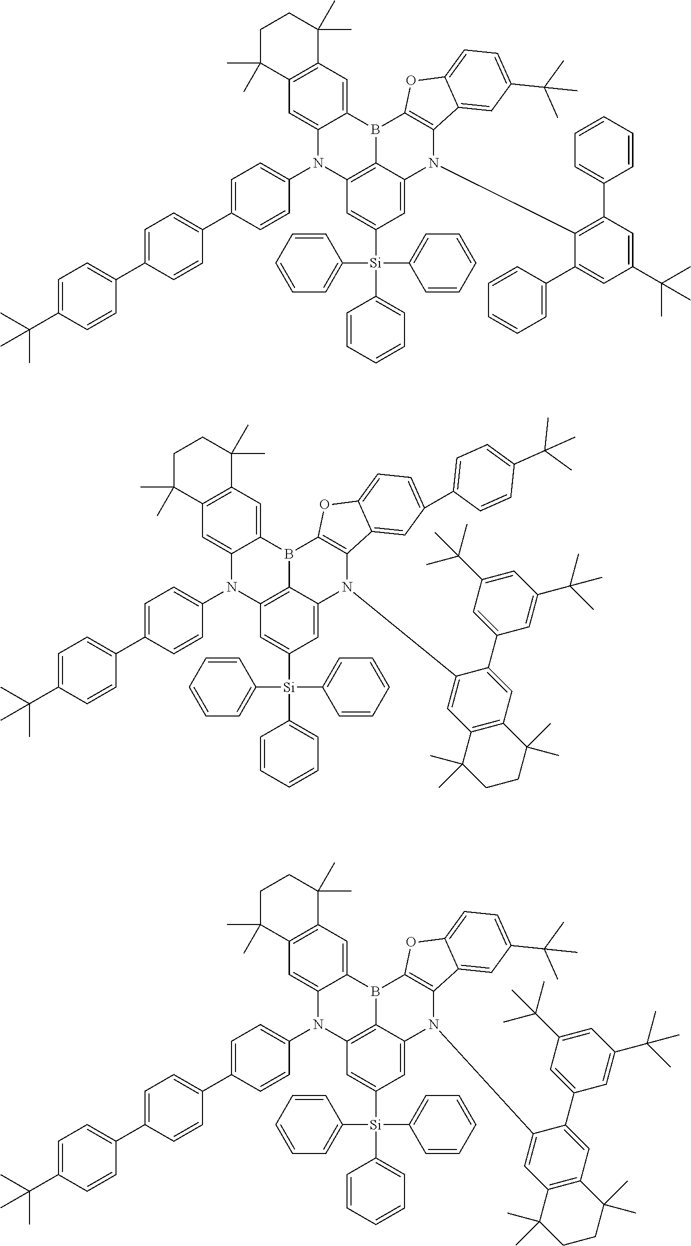

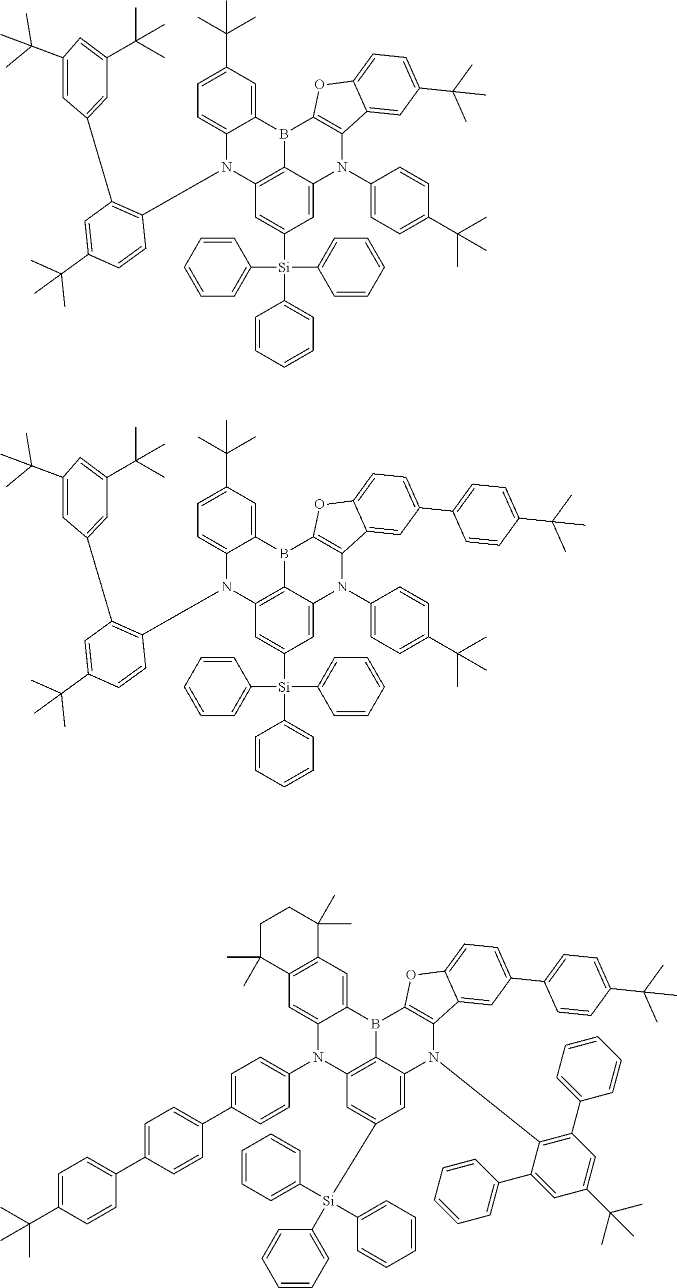

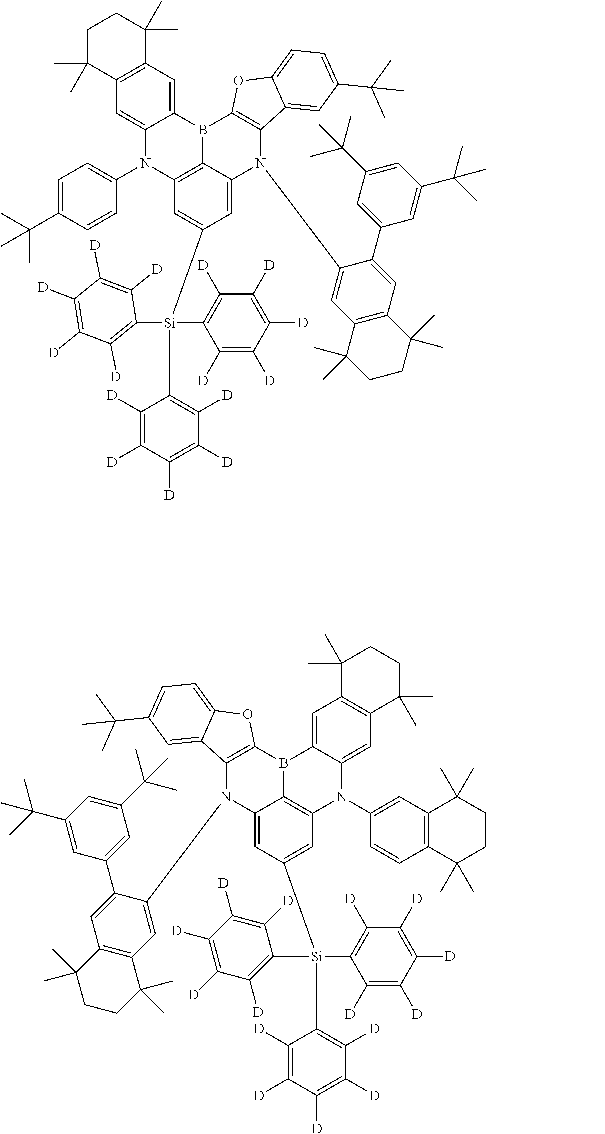

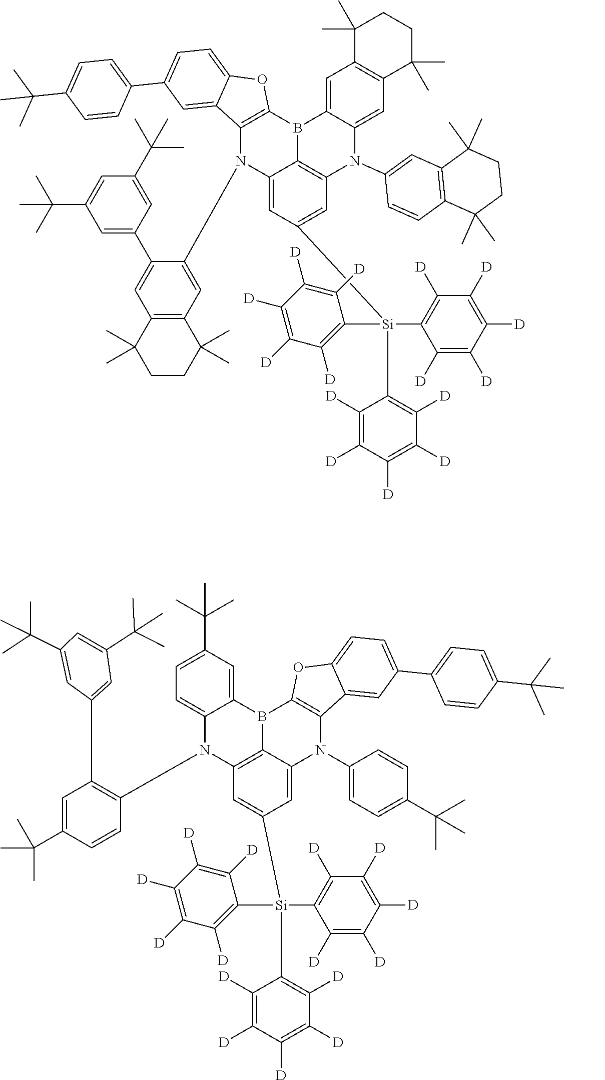

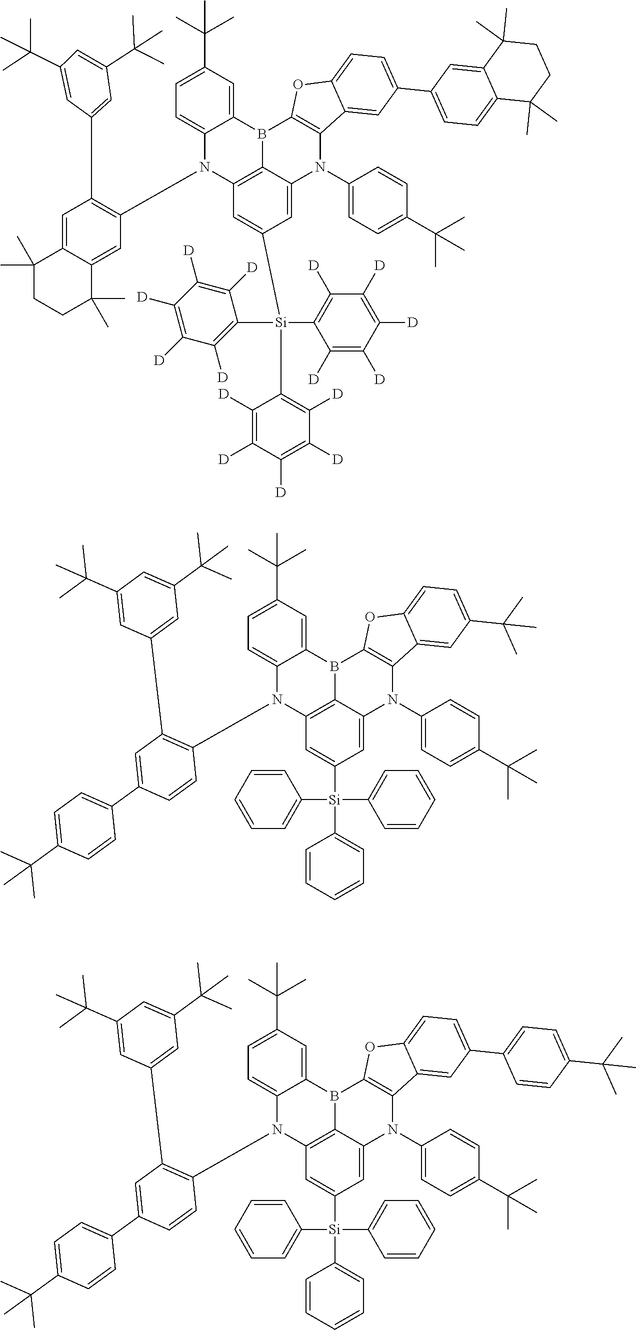

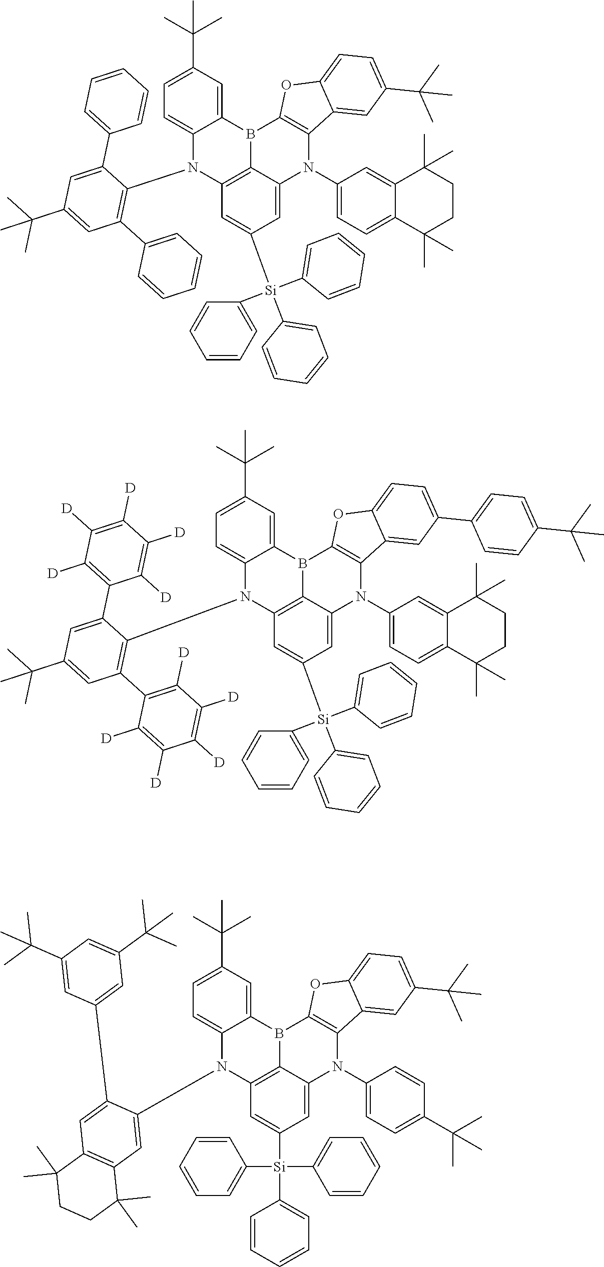

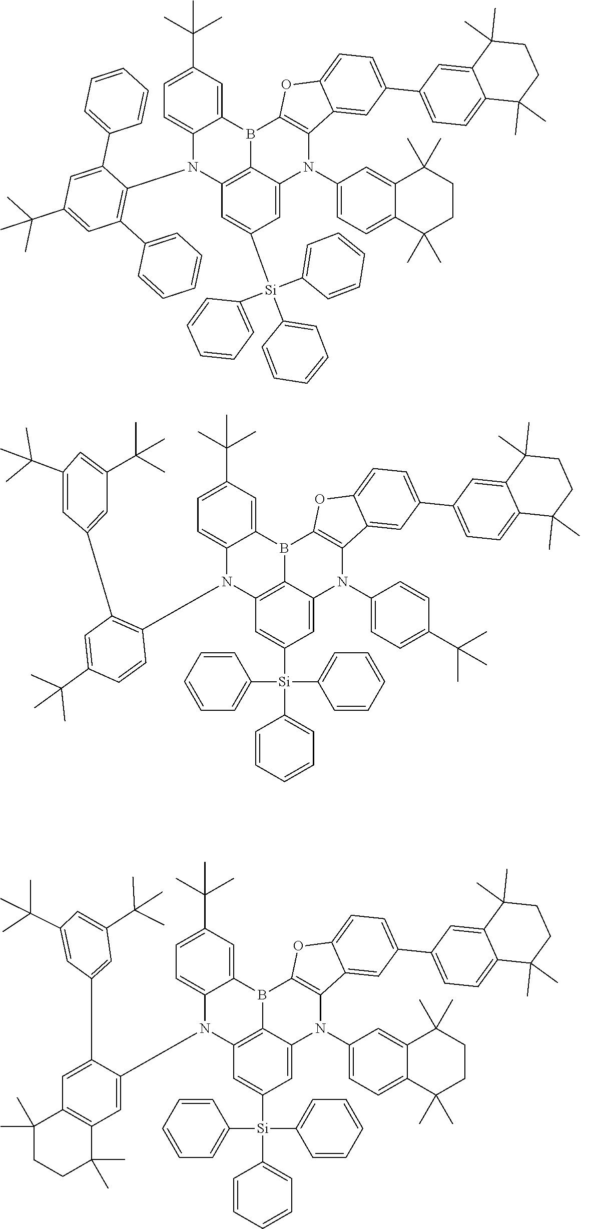

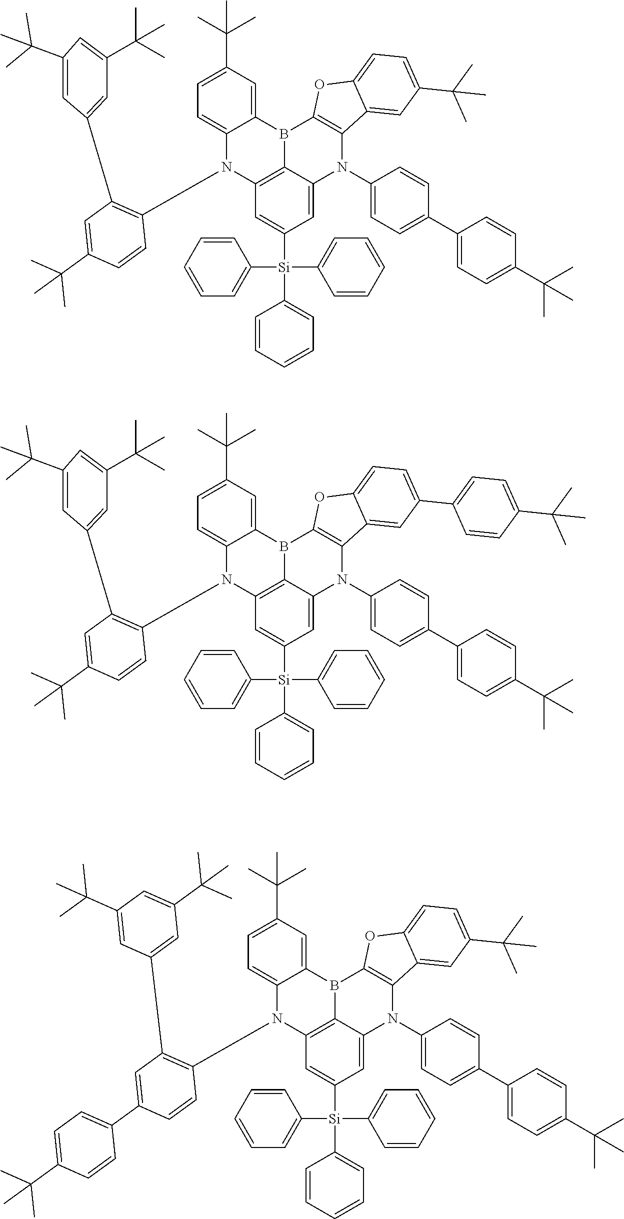

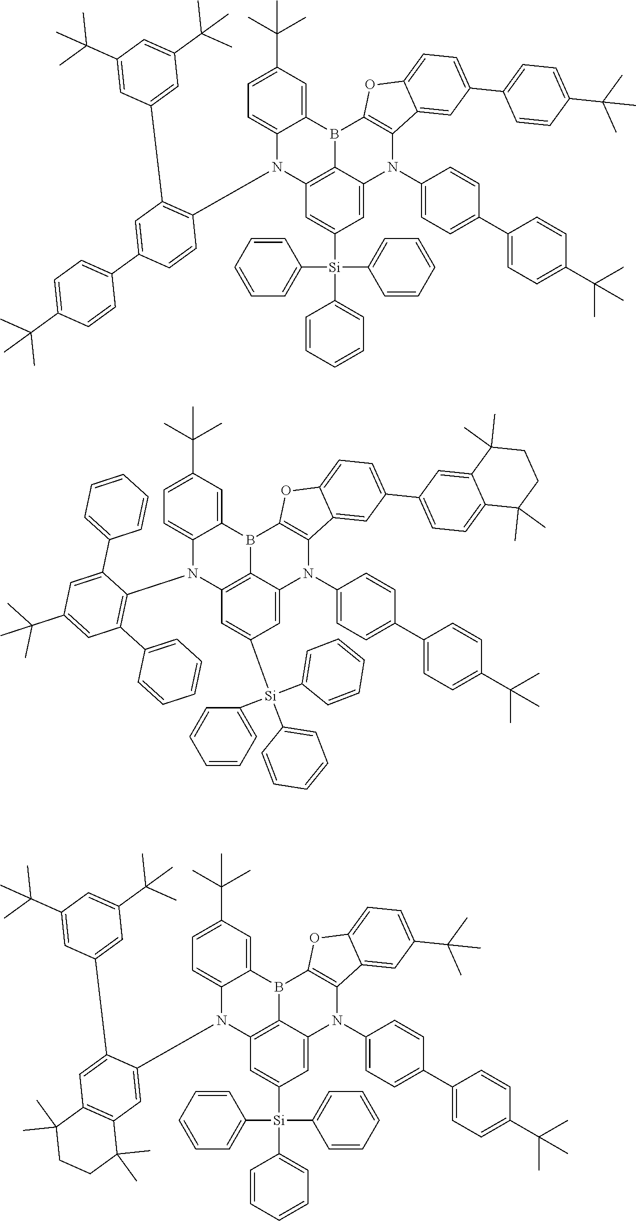

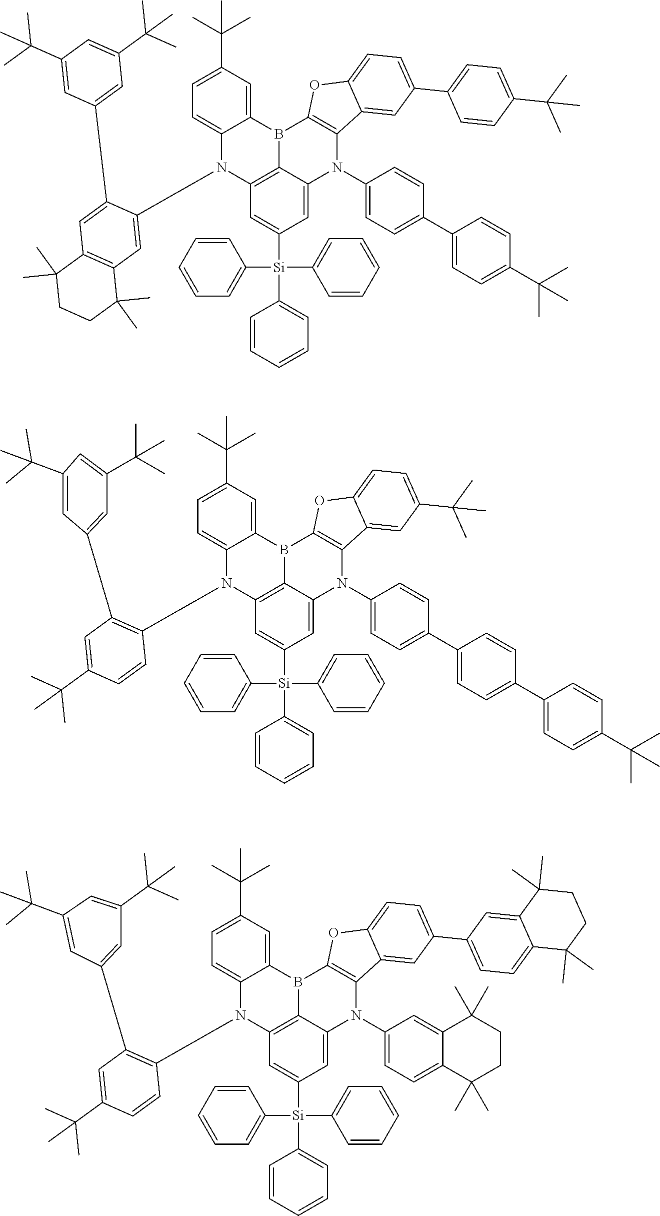

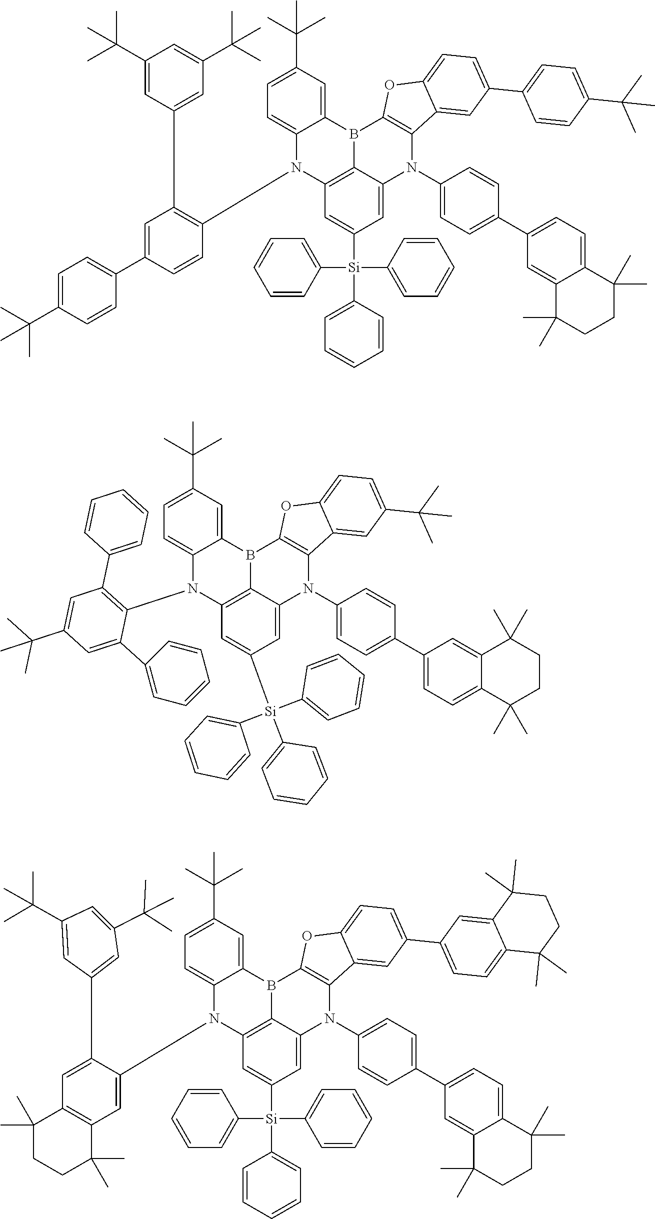

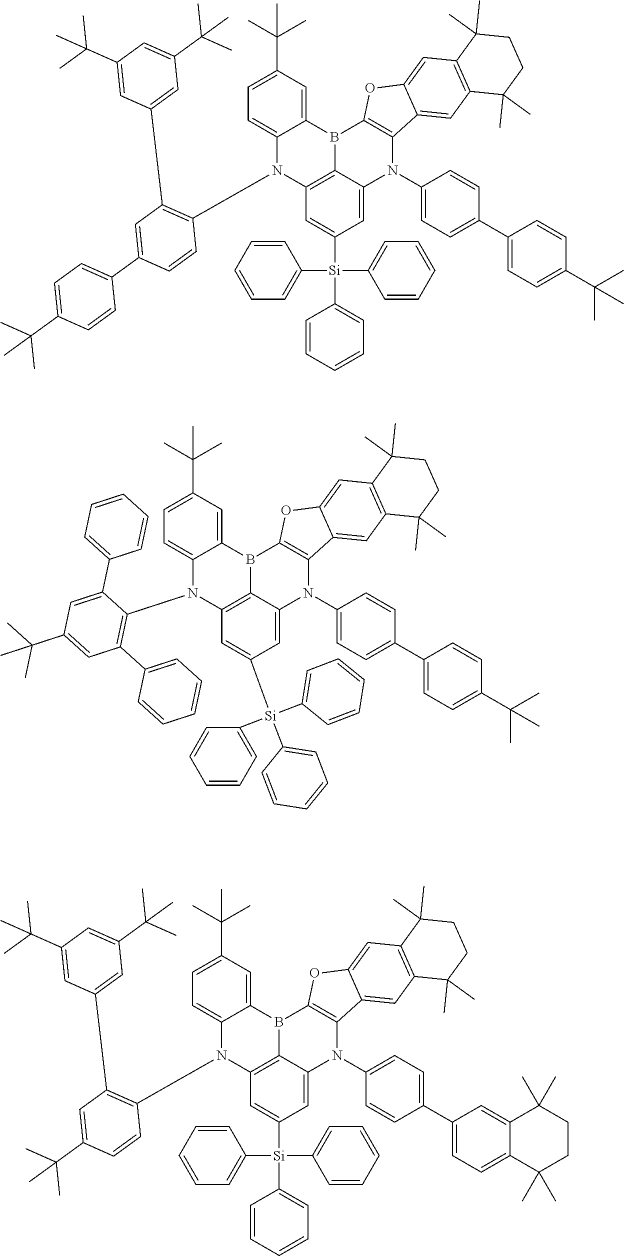

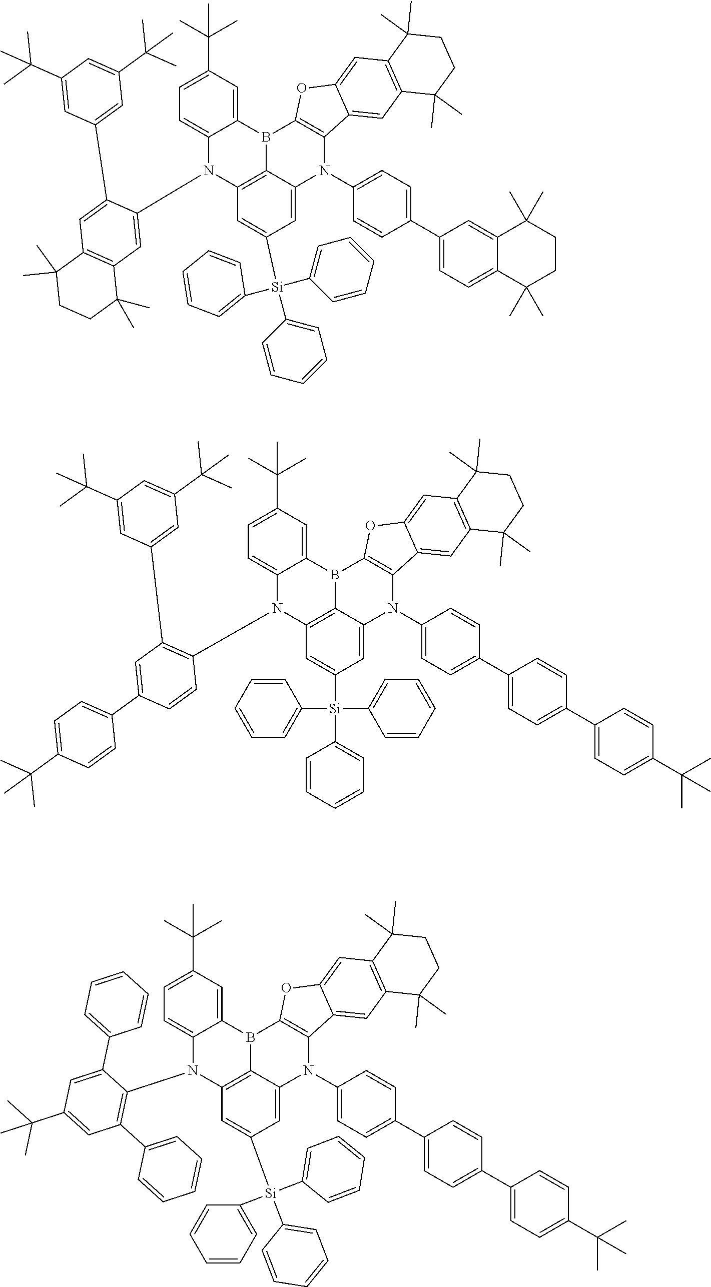

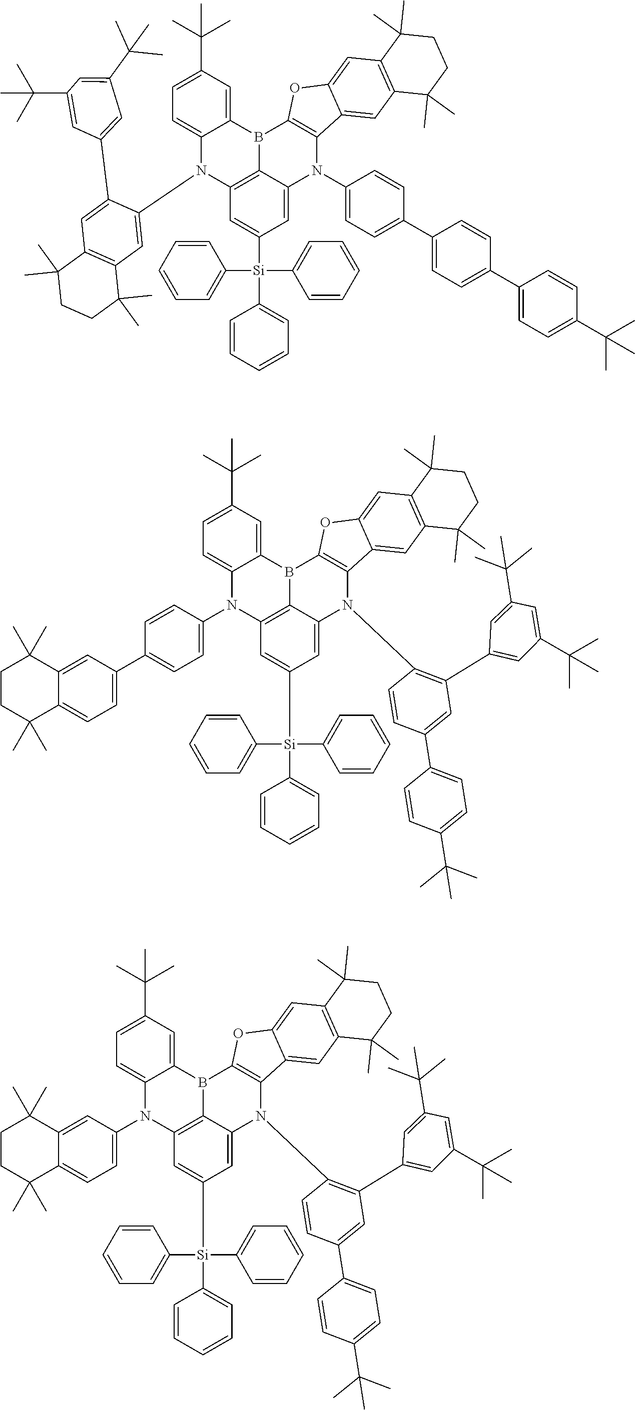

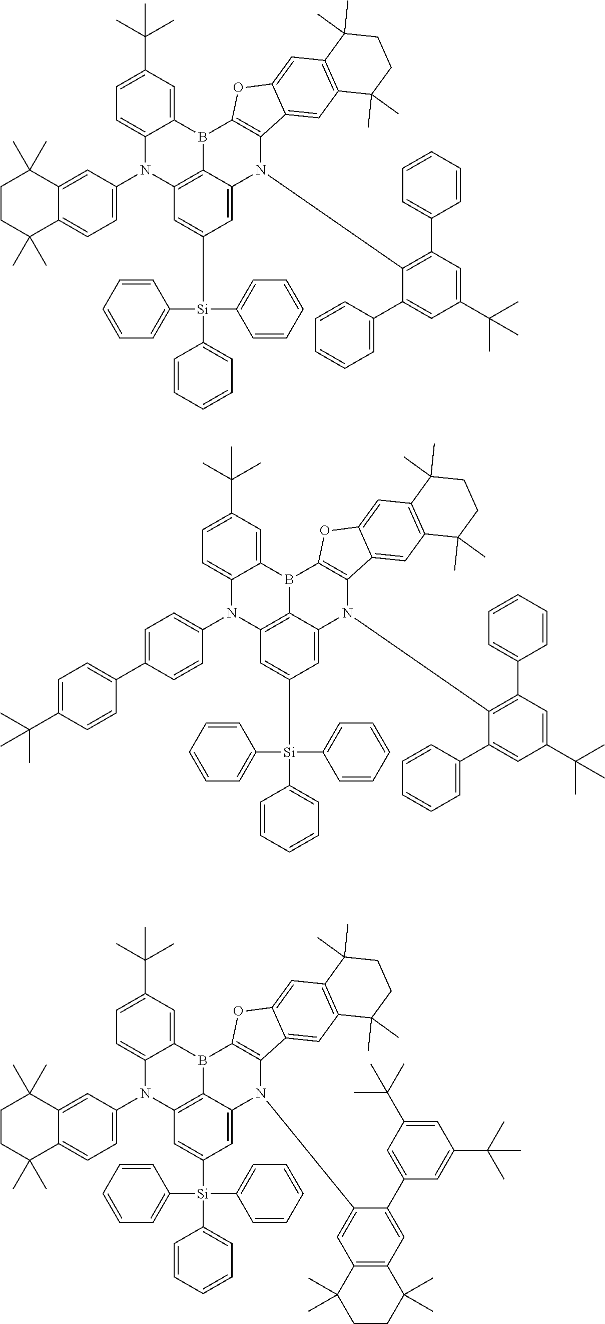

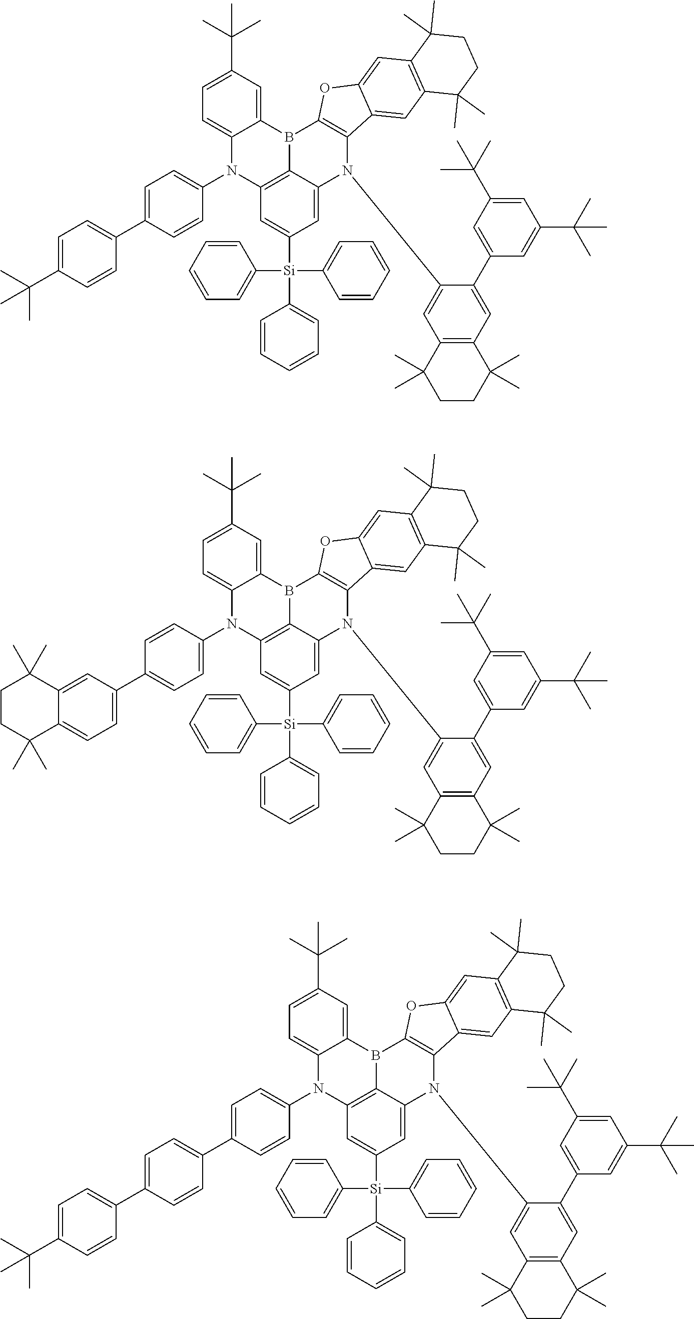

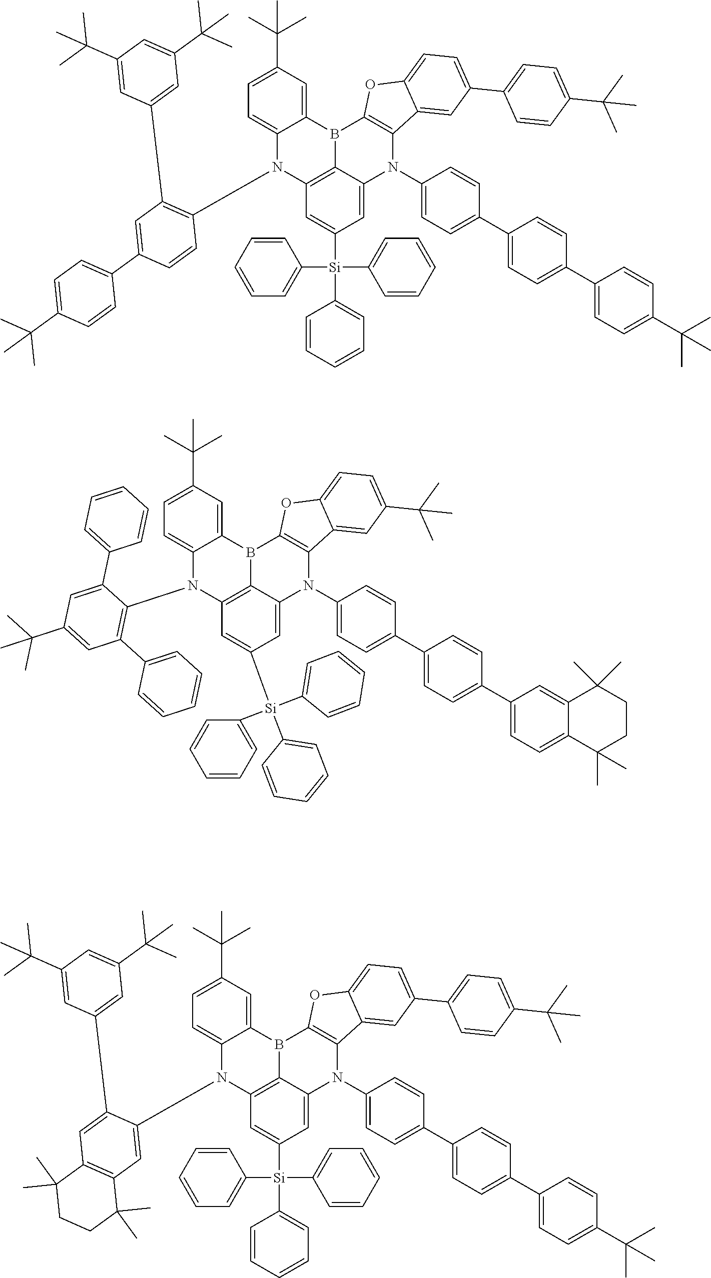

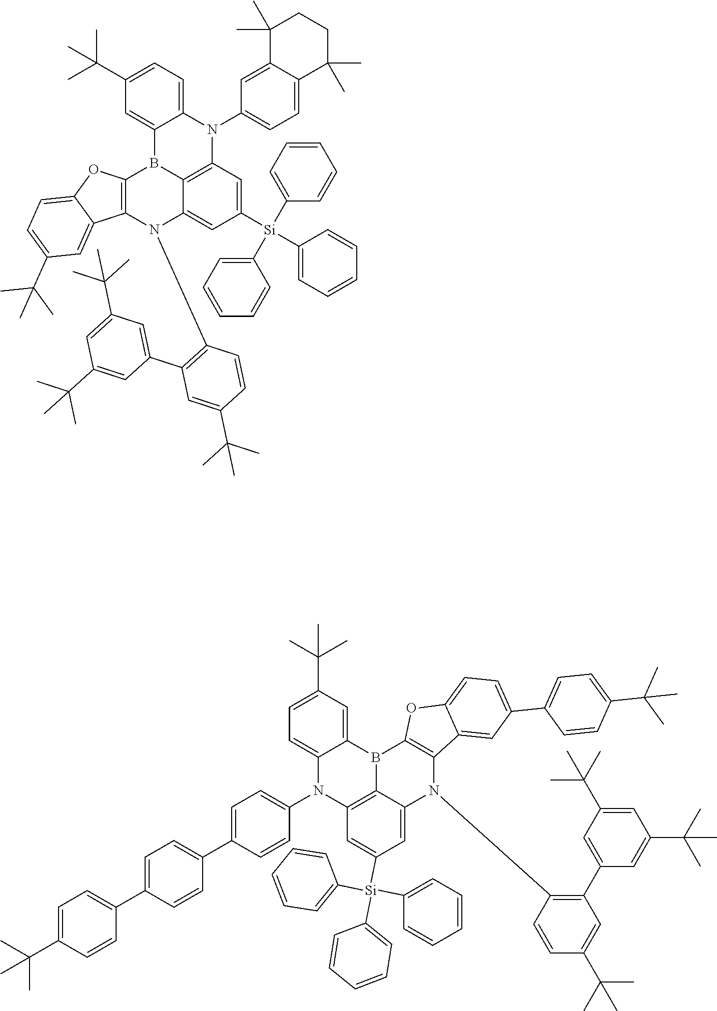 [SMILES: CC(C)(C)c1cc(-c2cc(C(C)(C)C)ccc2N2c3cc([Si](c4ccccc4)(c4ccccc4)c4ccccc4)cc4c3B(c3cc(C(C)(C)C)ccc3N4c3ccc4c(c3)C(C)(C)CCC4(C)C)c3oc4ccc(C(C)(C)C)cc4c32)cc(C(C)(C)C)c1 ; CC(C)(C)c1ccc(-c2ccc(-c3ccc(N4c5ccc(C(C)(C)C)cc5B5c6oc7ccc(-c8ccc(C(C)(C)C)cc8)cc7c6N(c6ccc(C(C)(C)C)cc6-c6cc(C(C)(C)C)cc(C(C)(C)C)c6)c6cc([Si](c7ccccc7)(c7ccccc7)c7ccccc7)cc4c65)cc3)cc2)cc1]

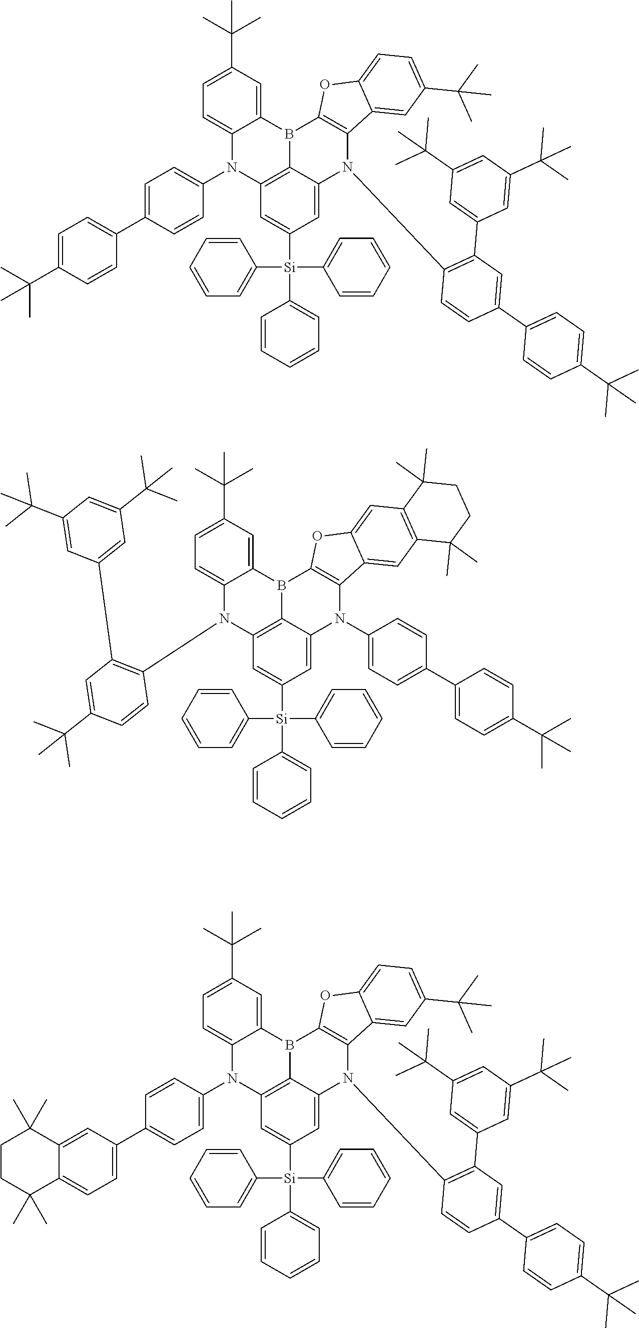

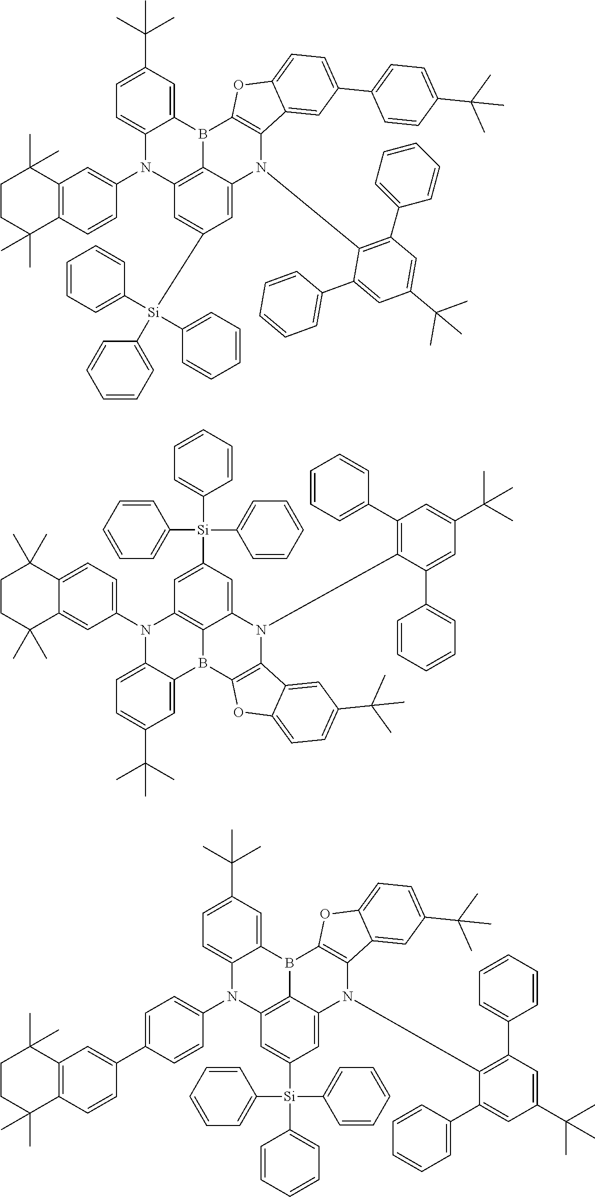 [SMILES: CC(C)(C)c1ccc(-c2ccc3oc4c(c3c2)N(c2c(-c3ccccc3)cc(C(C)(C)C)cc2-c2ccccc2)c2cc([Si](c3ccccc3)(c3ccccc3)c3ccccc3)cc3c2B4c2cc(C(C)(C)C)ccc2N3c2ccc3c(c2)C(C)(C)CCC3(C)C)cc1 ; CC(C)(C)c1ccc2c(c1)B1c3oc4ccc(C(C)(C)C)cc4c3N(c3c(-c4ccccc4)cc(C(C)(C)C)cc3-c3ccccc3)c3cc([Si](c4ccccc4)(c4ccccc4)c4ccccc4)cc(c31)N2c1ccc2c(c1)C(C)(C)CCC2(C)C ; CC(C)(C)c1ccc2c(c1)B1c3oc4ccc(C(C)(C)C)cc4c3N(c3c(-c4ccccc4)cc(C(C)(C)C)cc3-c3ccccc3)c3cc([Si](c4ccccc4)(c4ccccc4)c4ccccc4)cc(c31)N2c1ccc(-c2ccc3c(c2)C(C)(C)CCC3(C)C)cc1]

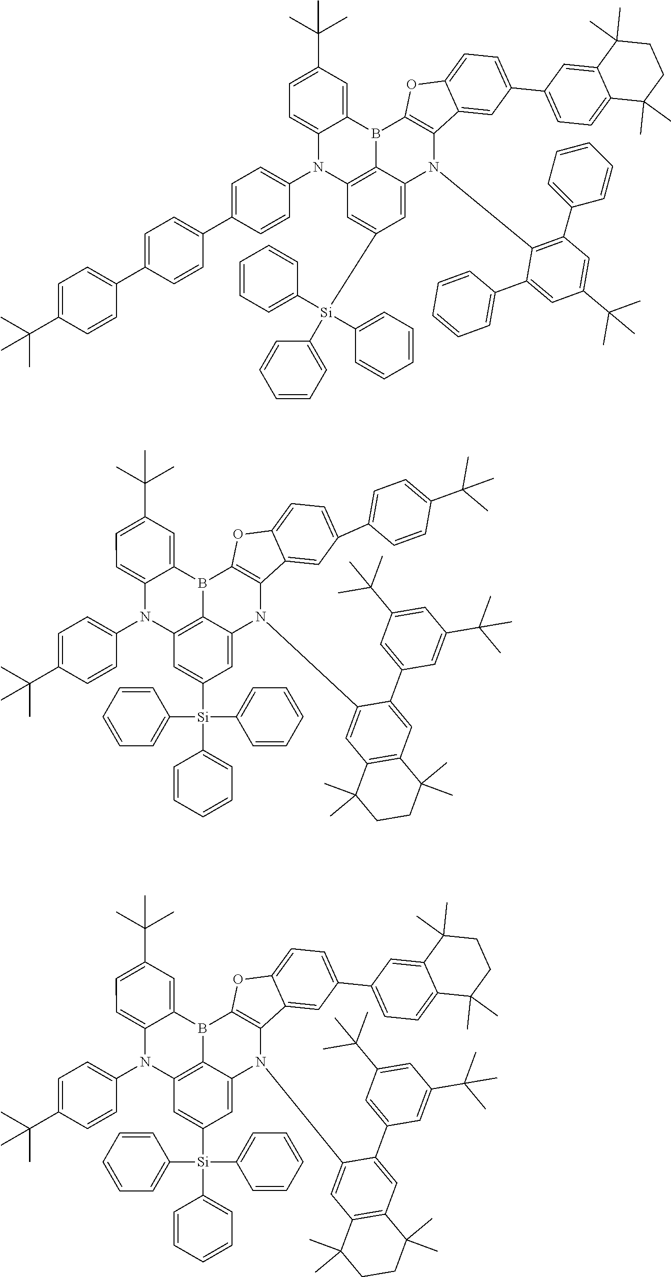

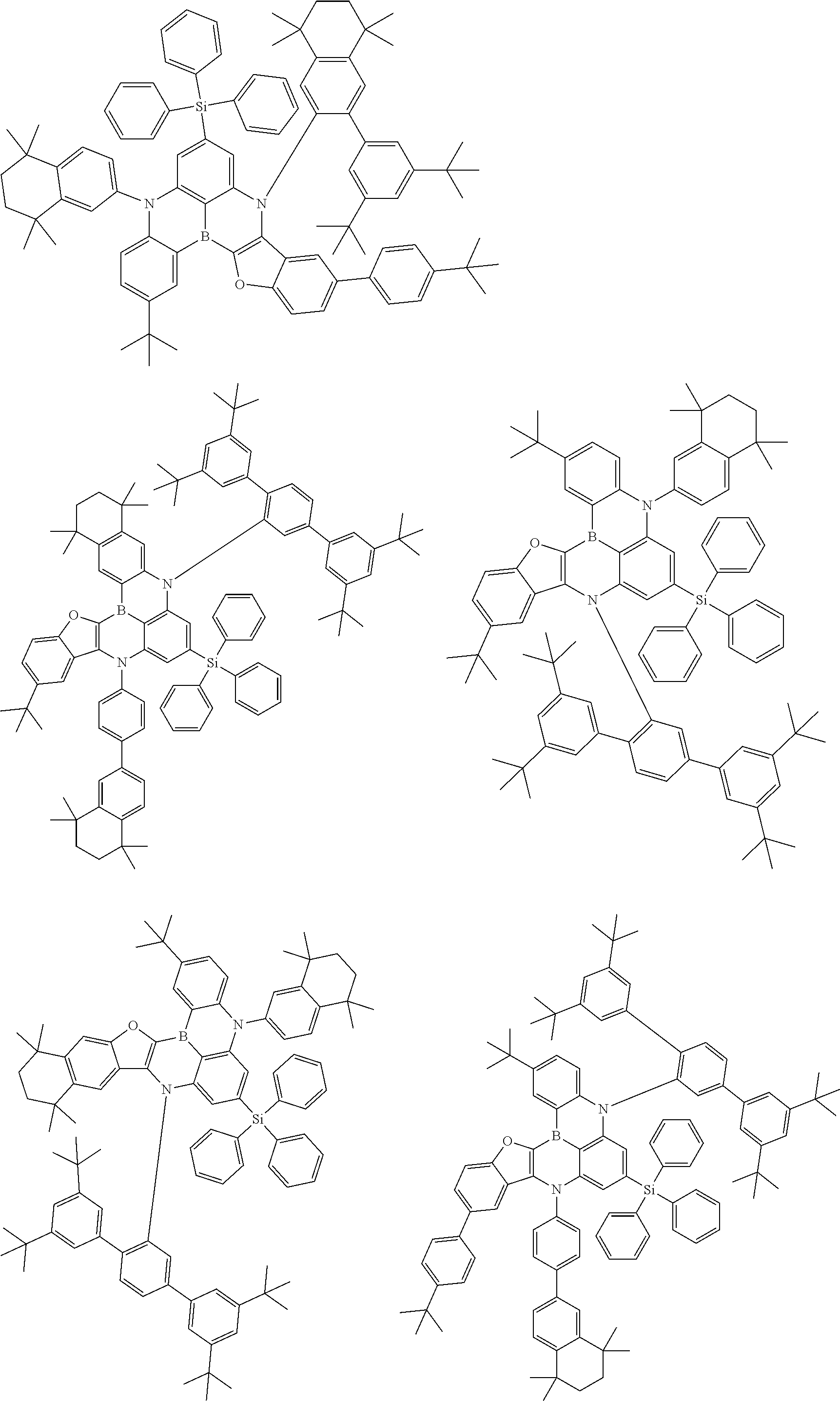

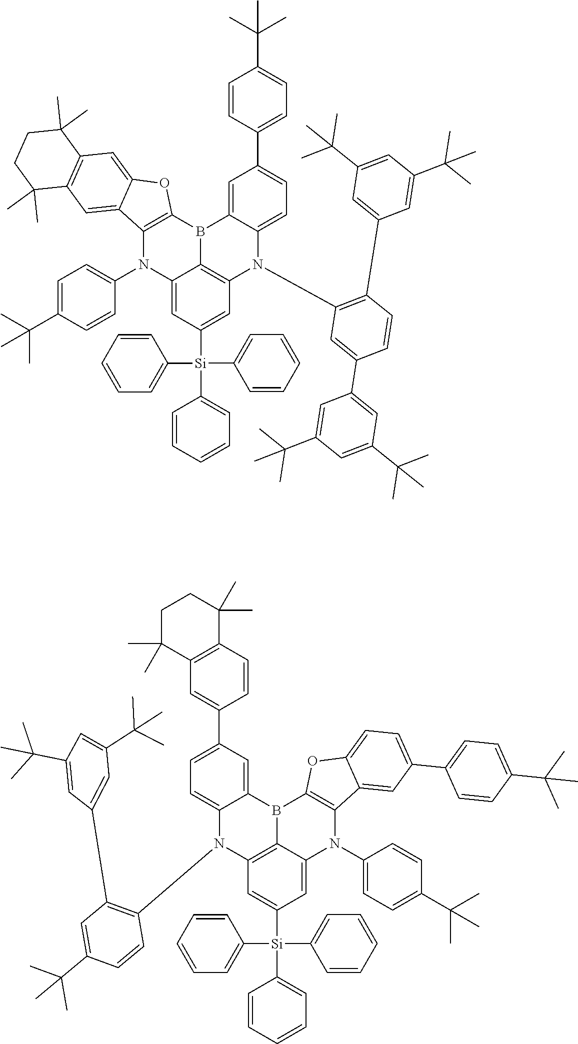

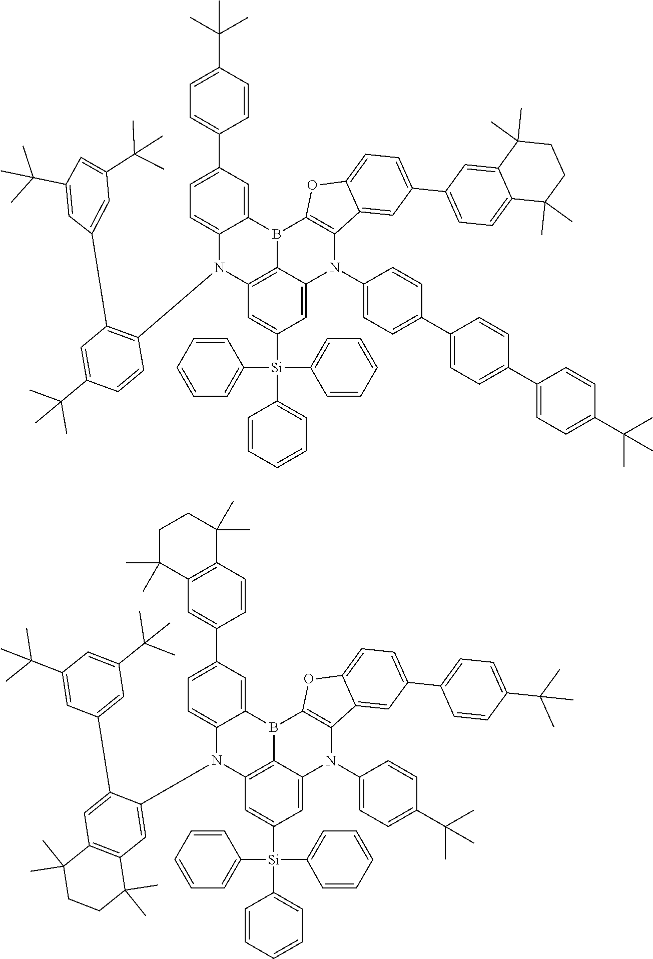

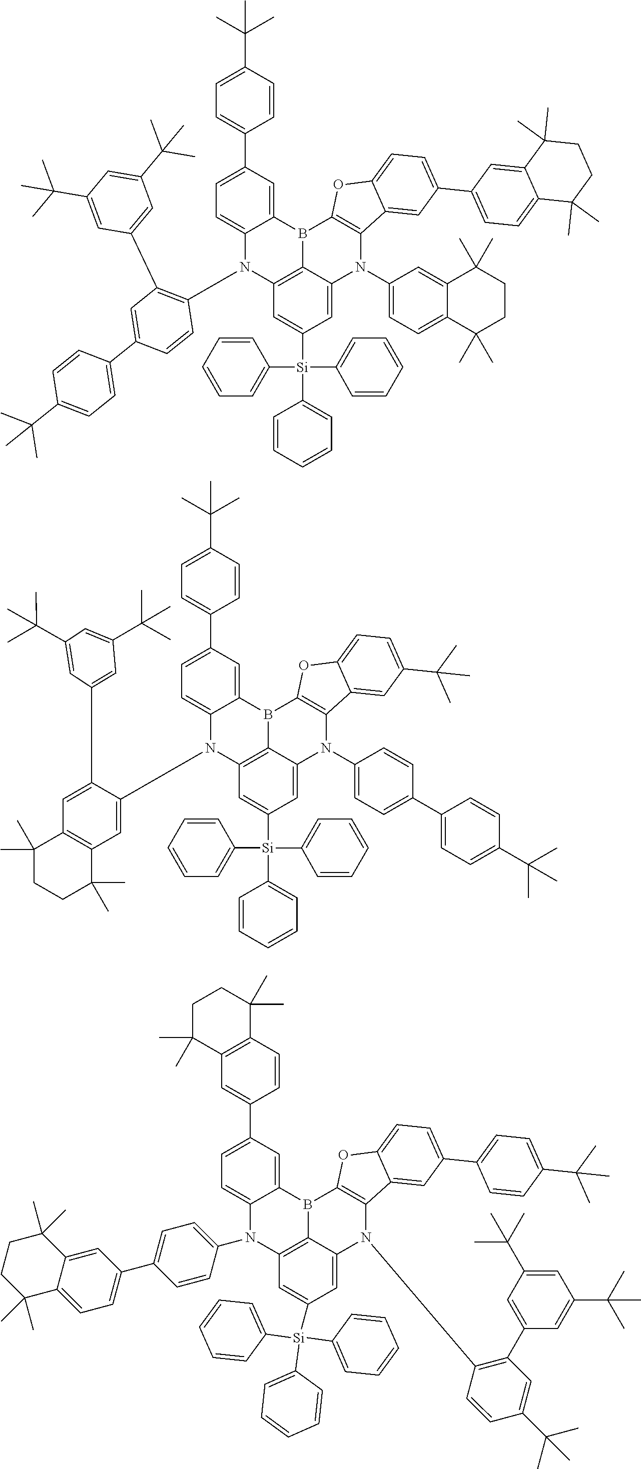

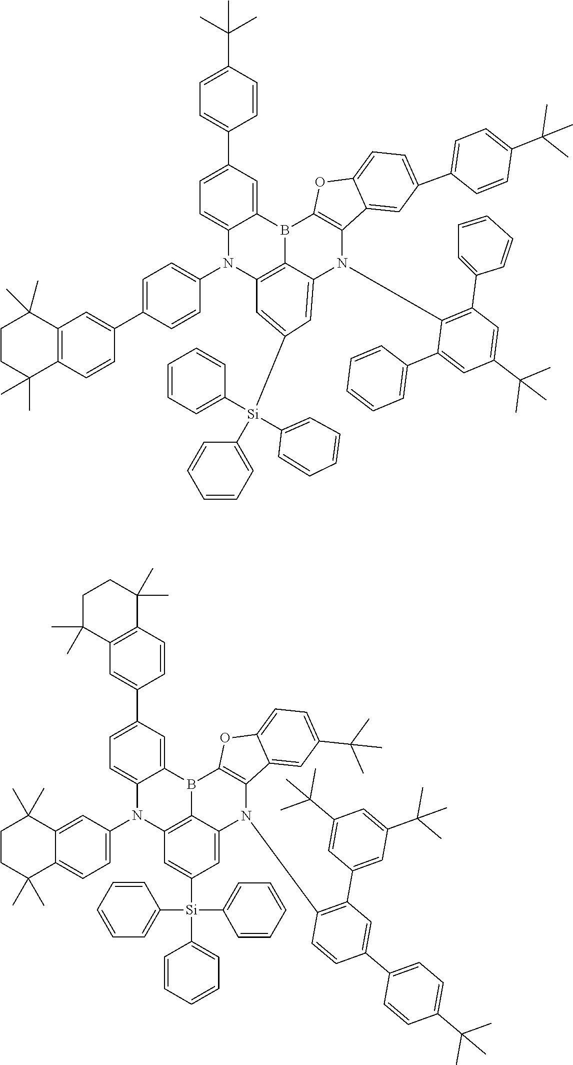 [SMILES: CC(C)(C)c1ccc(-c2ccc3c(c2)B2c4oc5ccc(-c6ccc(C(C)(C)C)cc6)cc5c4N(c4c(-c5ccccc5)cc(C(C)(C)C)cc4-c4ccccc4)c4cc([Si](c5ccccc5)(c5ccccc5)c5ccccc5)cc(c42)N3c2ccc(-c3ccc4c(c3)C(C)(C)CCC4(C)C)cc2)cc1 ; CC(C)(C)c1ccc(-c2ccc(N3c4cc([Si](c5ccccc5)(c5ccccc5)c5ccccc5)cc5c4B(c4cc(-c6ccc7c(c6)C(C)(C)CCC7(C)C)ccc4N5c4ccc5c(c4)C(C)(C)CCC5(C)C)c4oc5ccc(C(C)(C)C)cc5c43)c(-c3cc(C(C)(C)C)cc(C(C)(C)C)c3)c2)cc1]

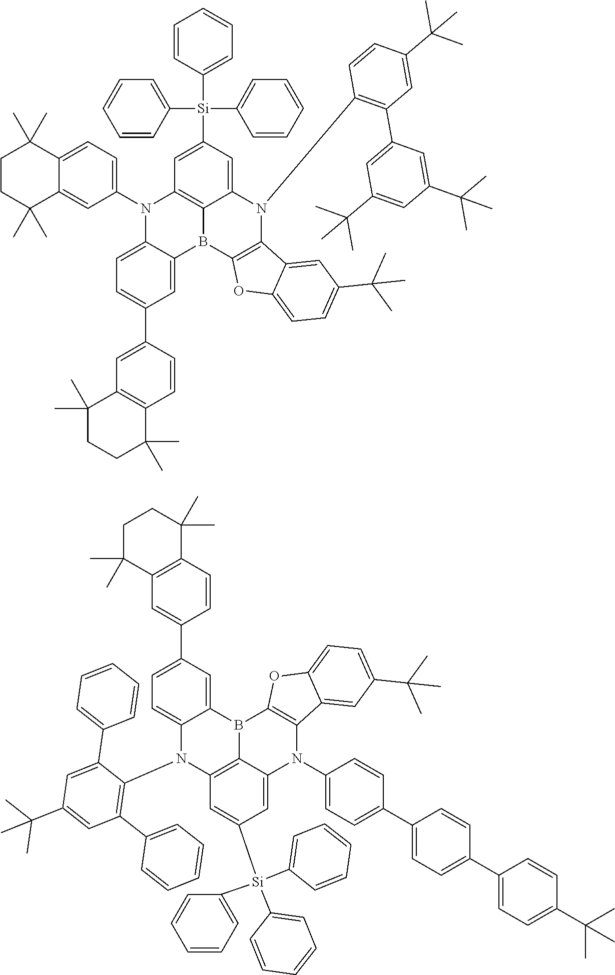

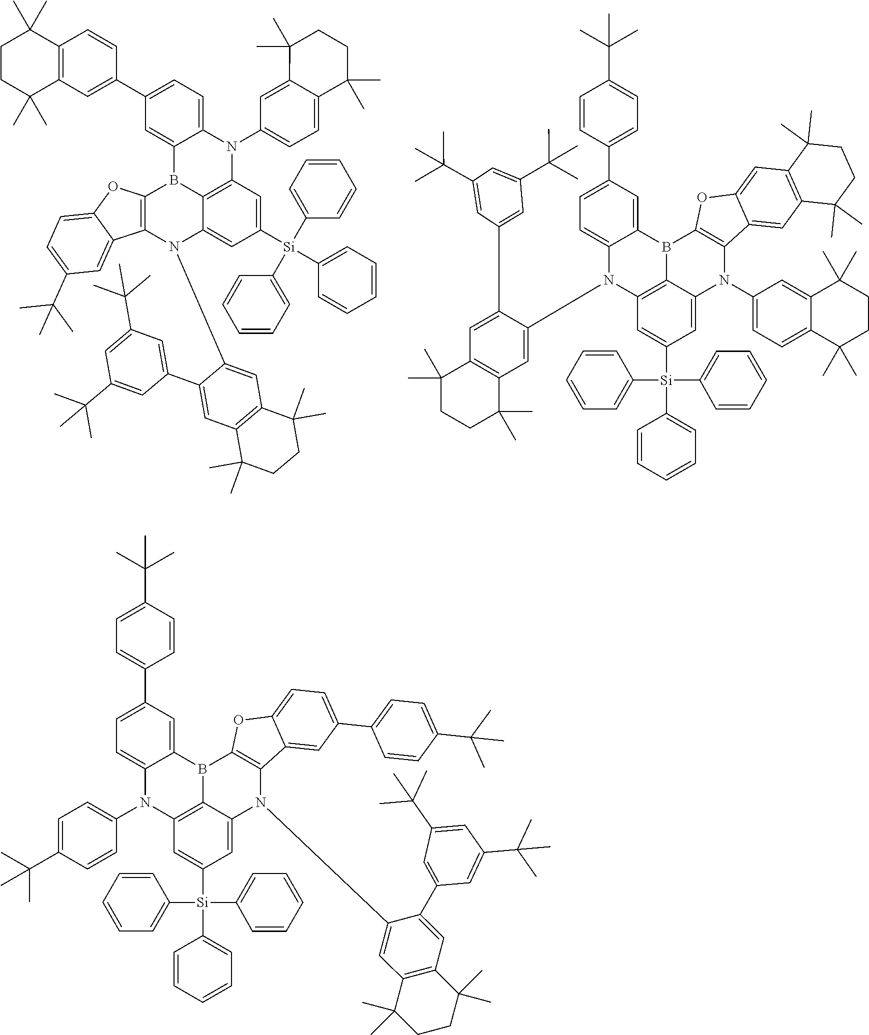

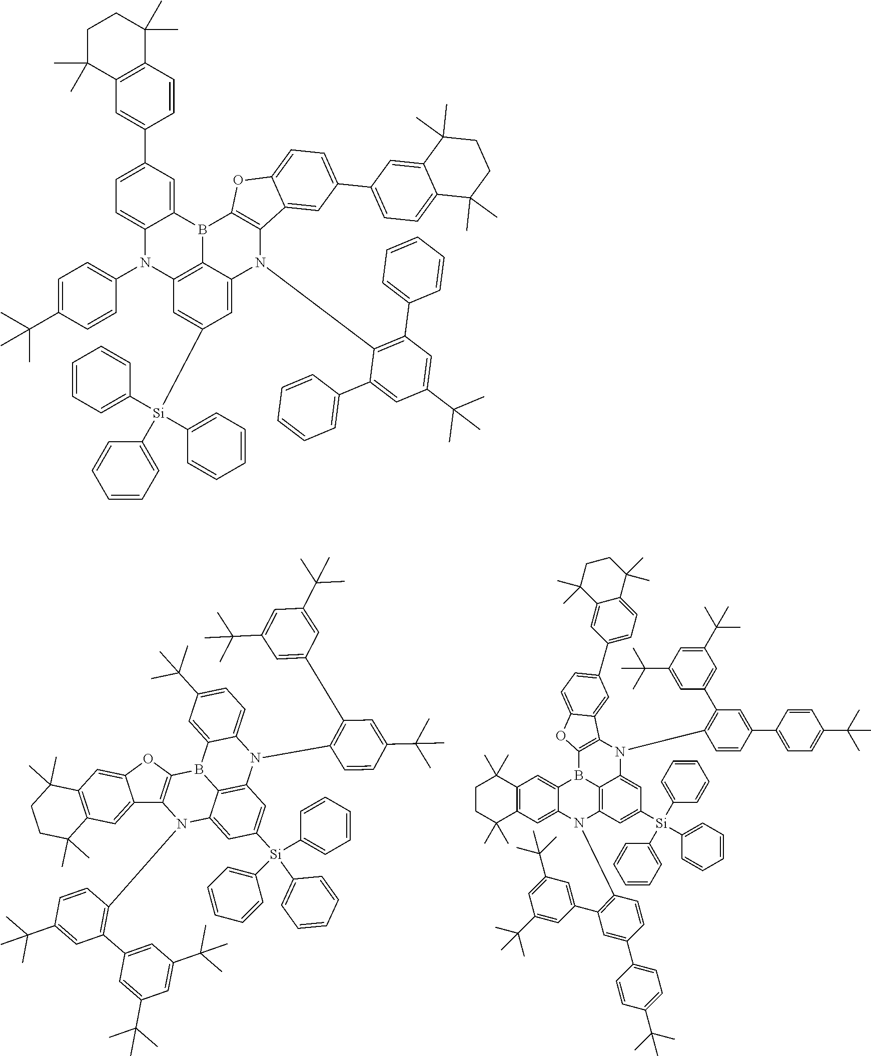

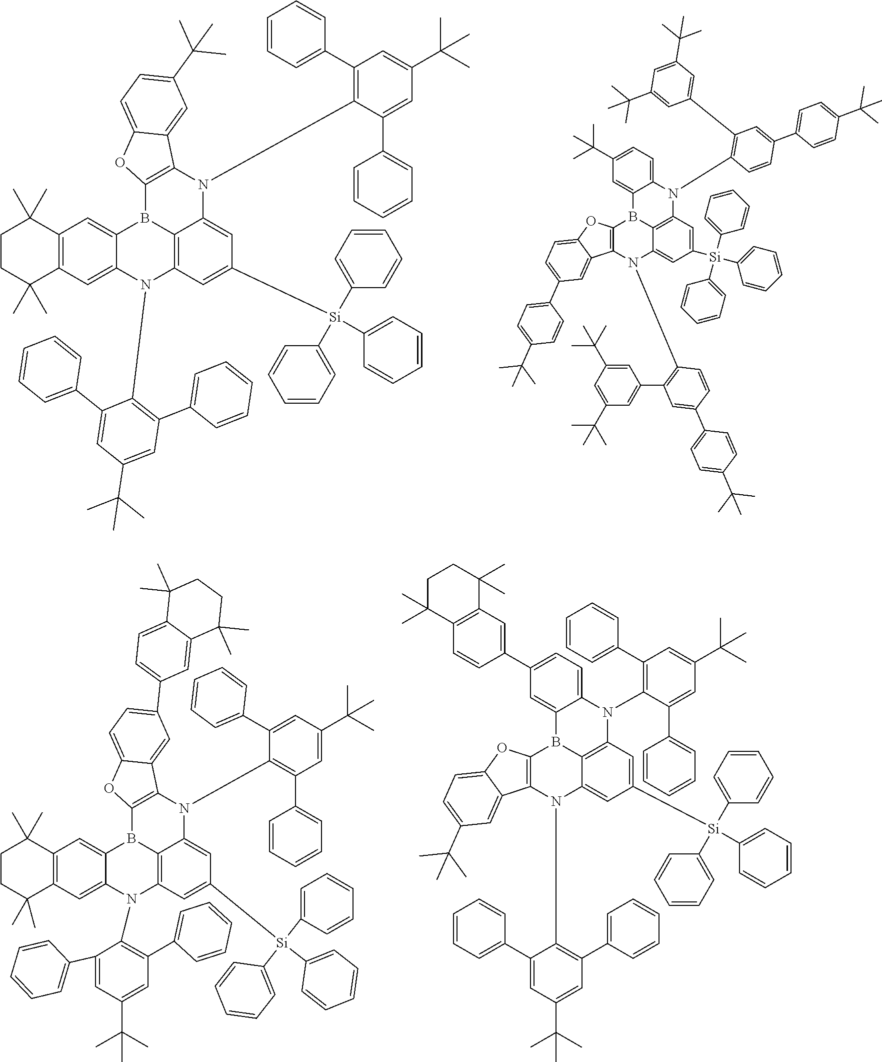

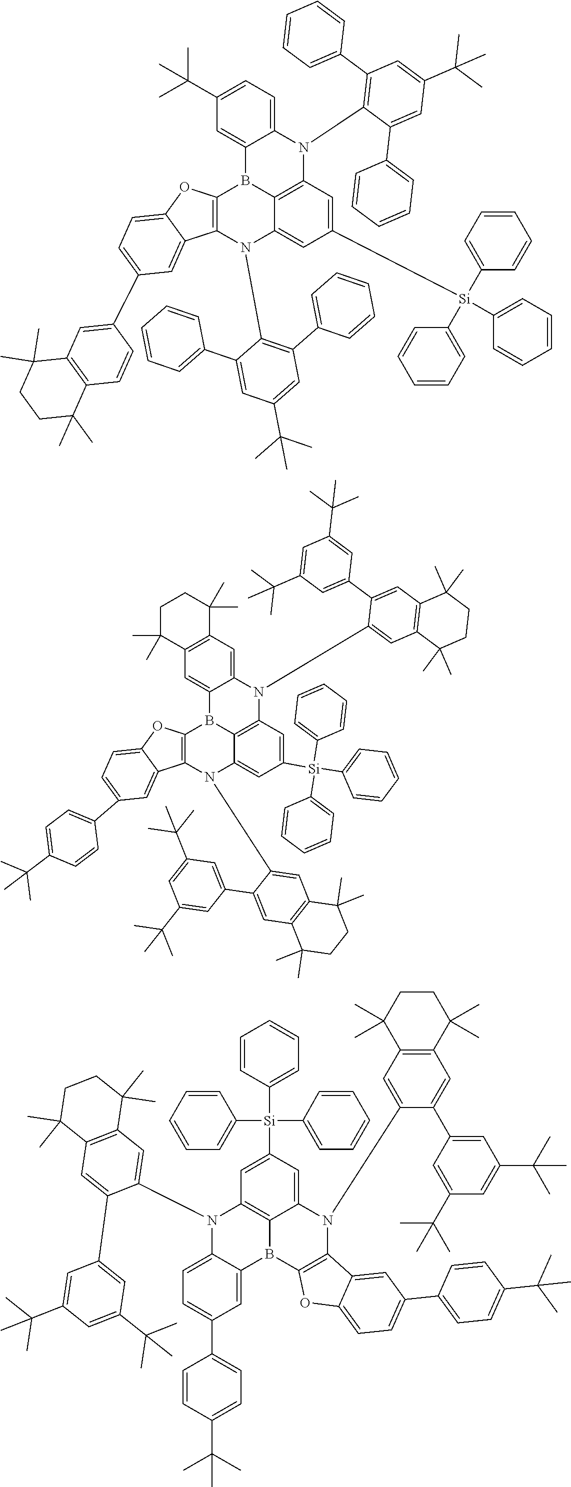

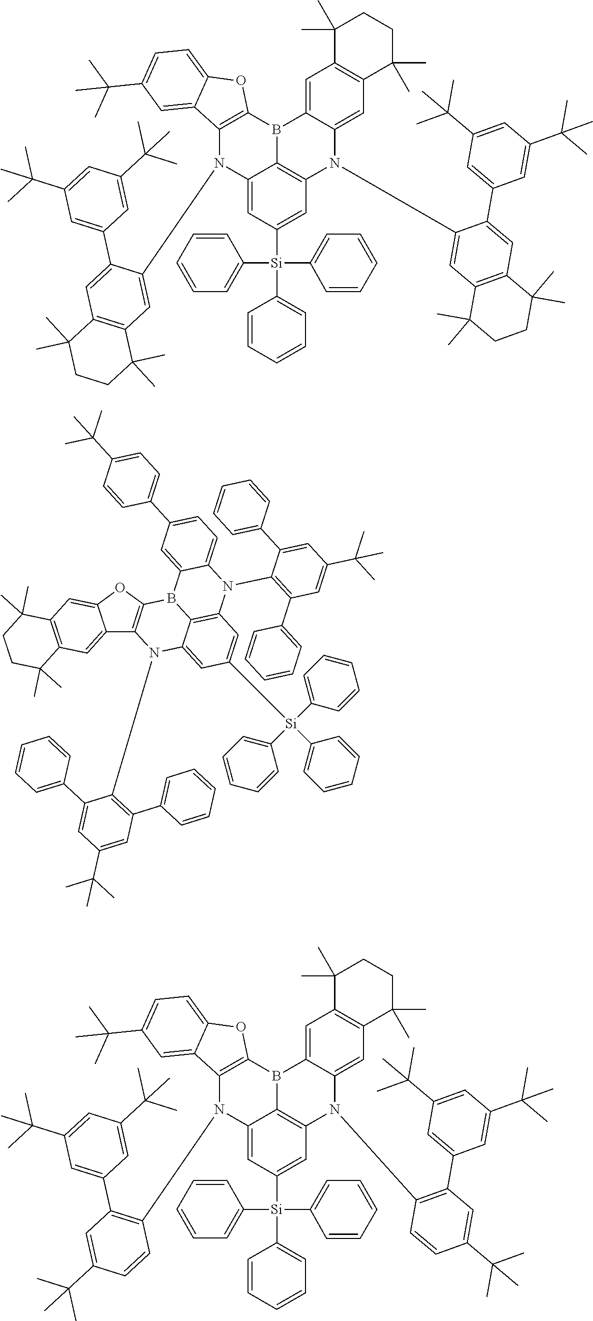

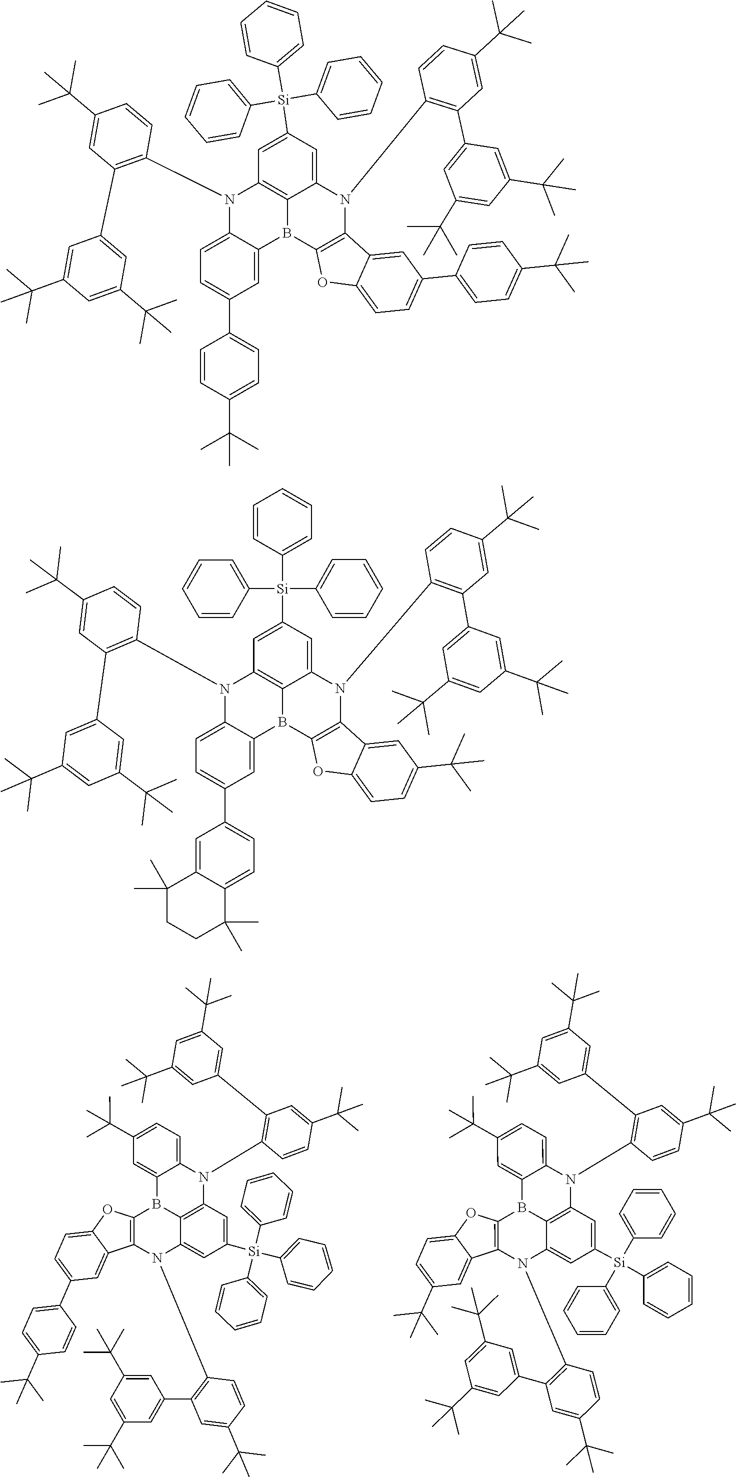

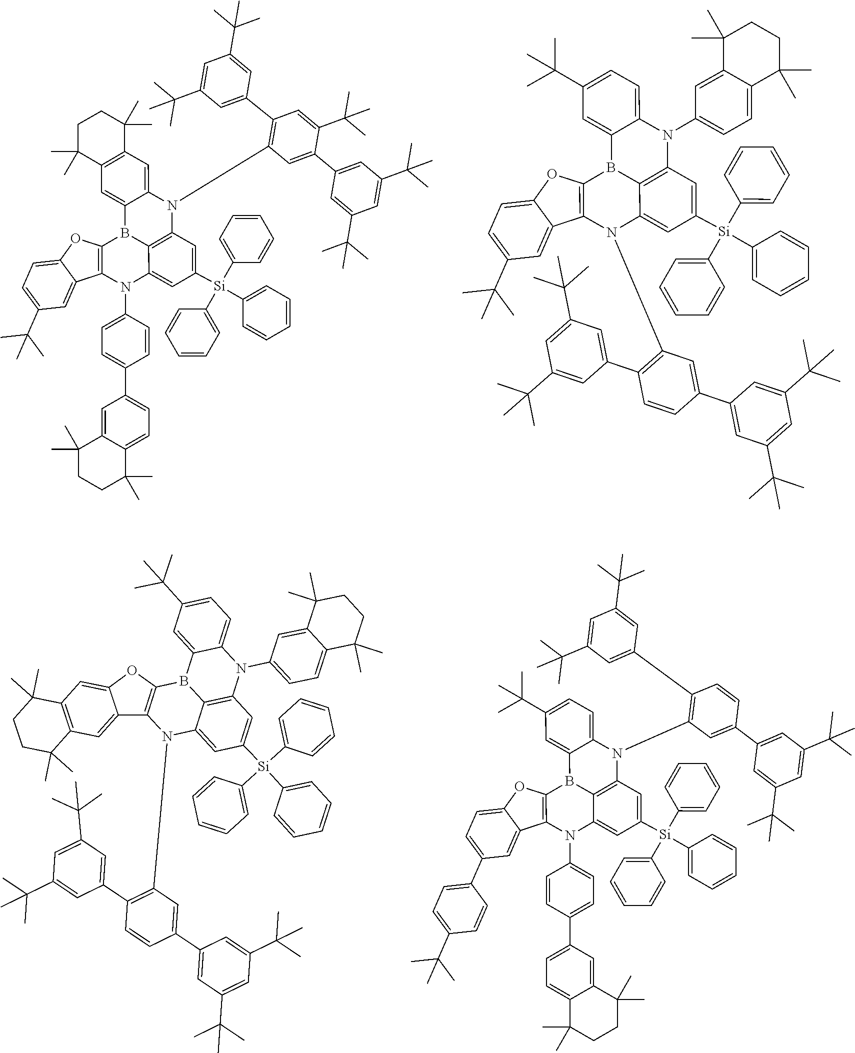

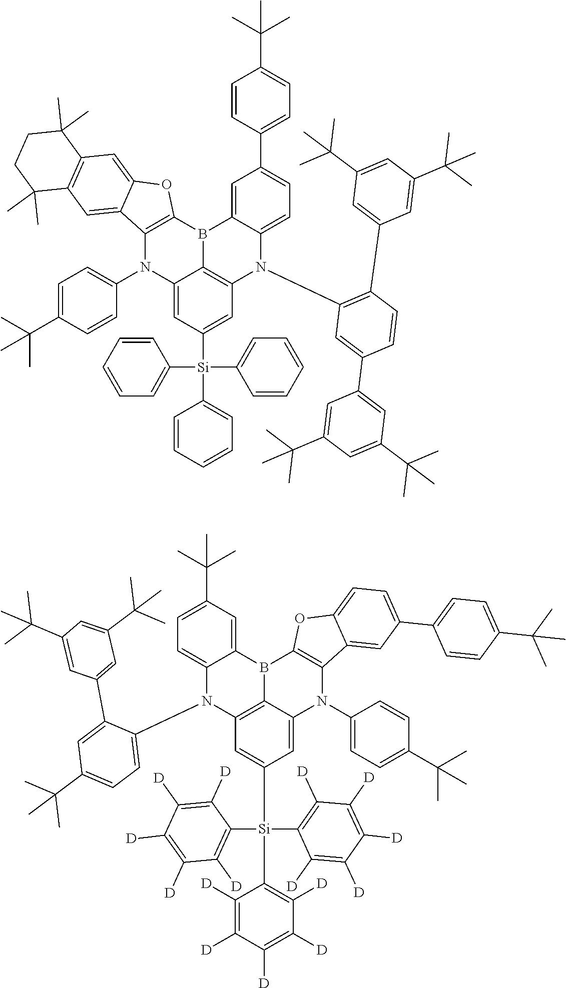

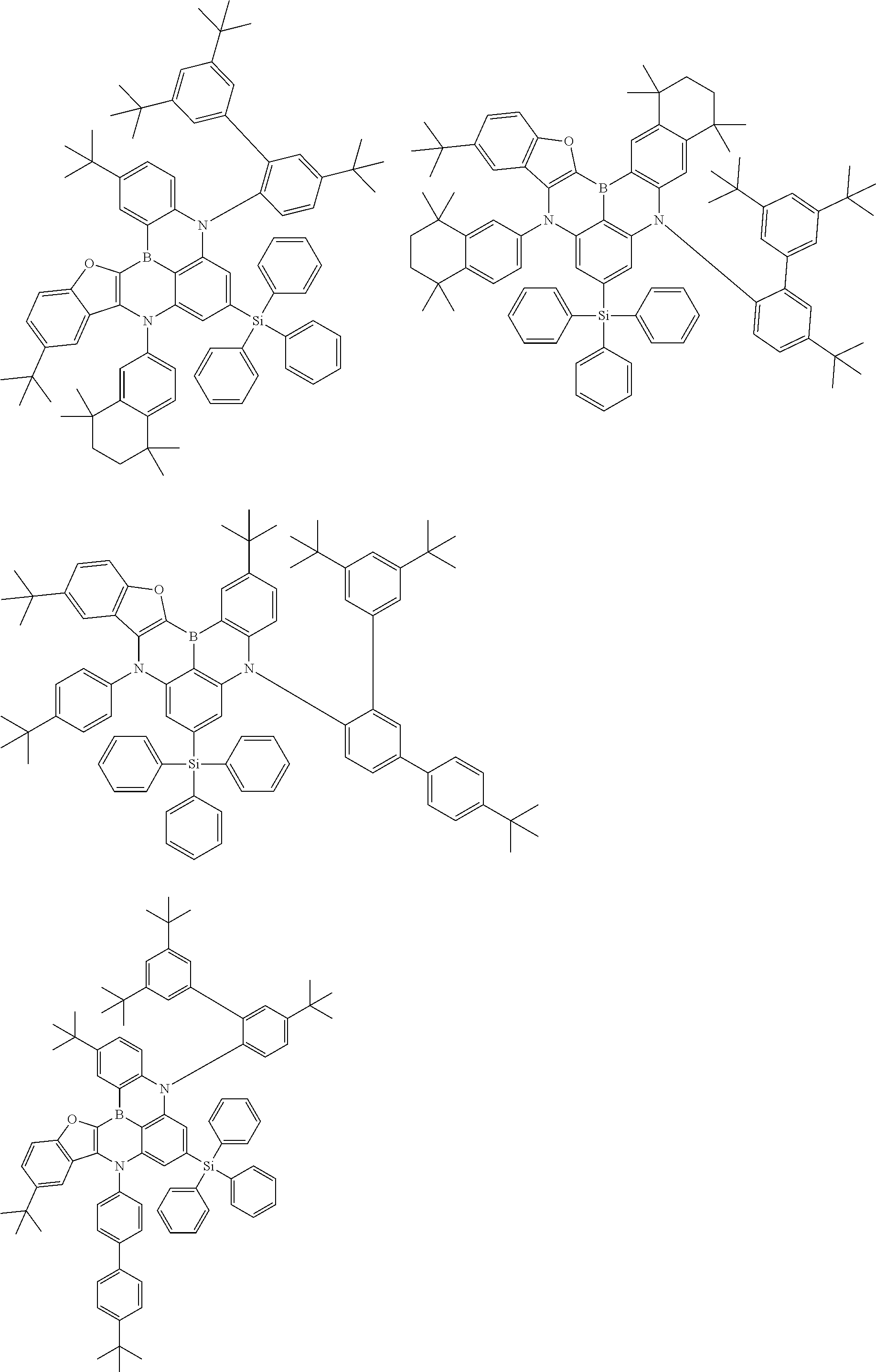

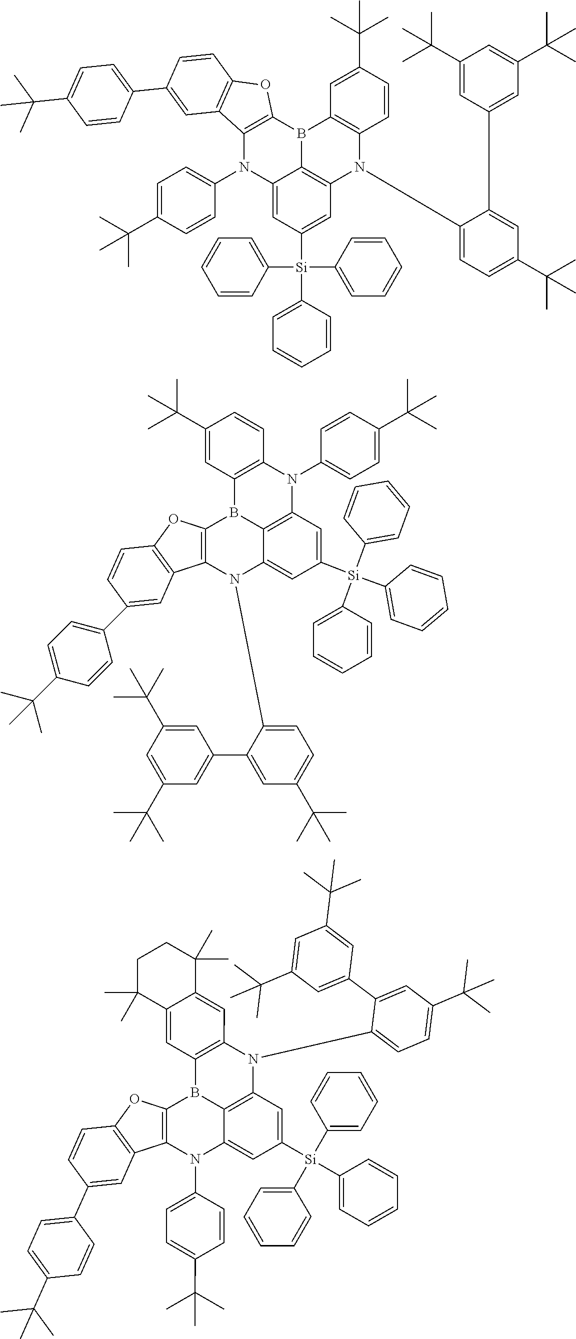

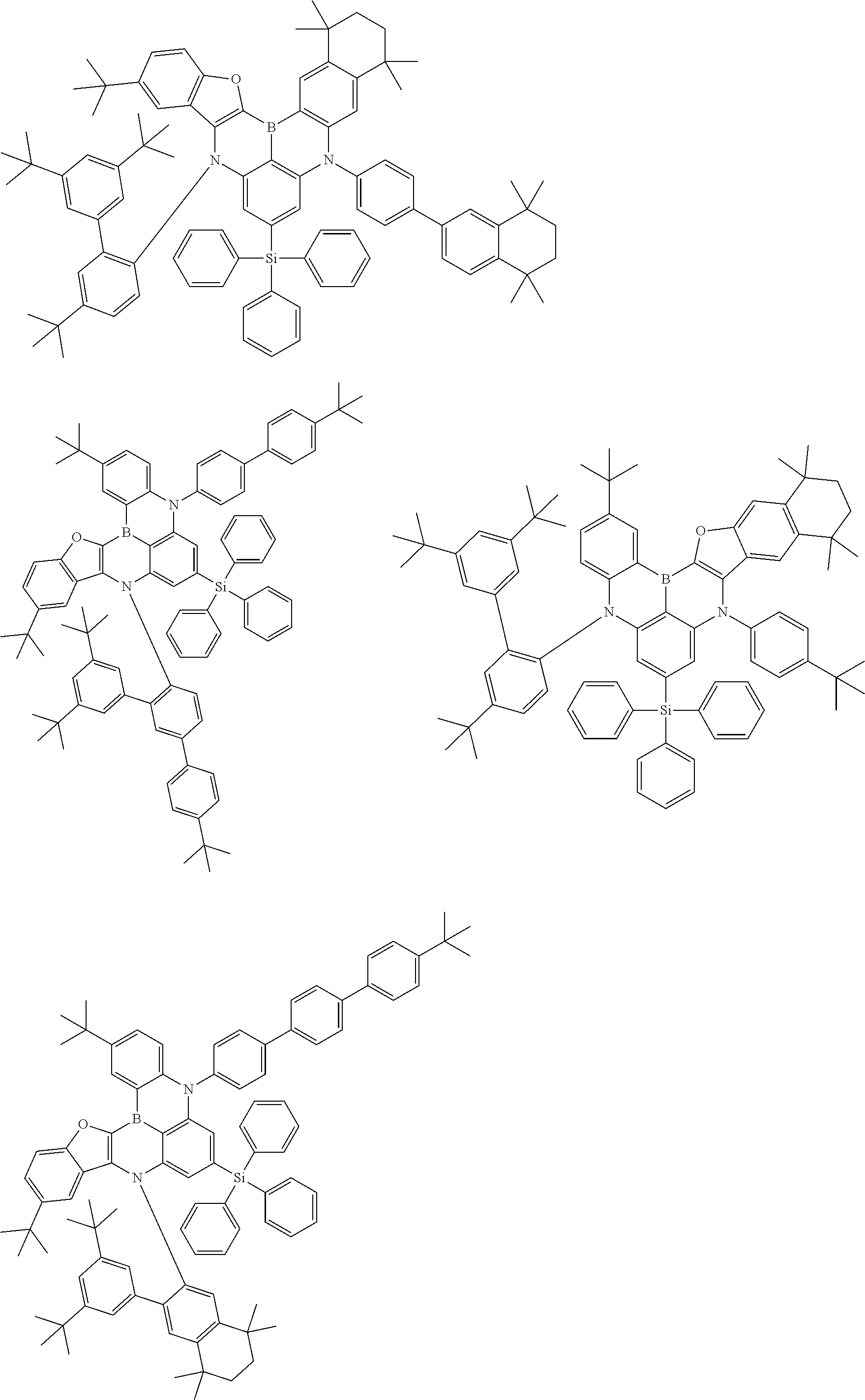

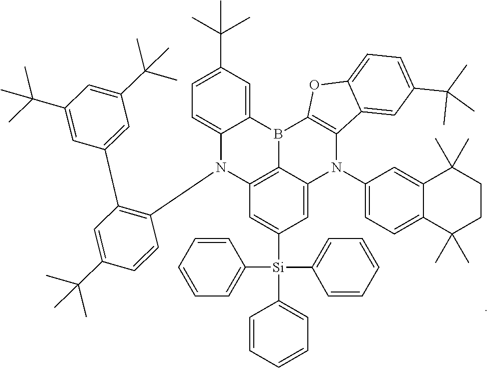 [SMILES: CC(C)(C)c1cc(-c2cc(C(C)(C)C)ccc2N2c3ccc(C(C)(C)C)cc3B3c4oc5ccc(C(C)(C)C)cc5c4N(c4ccc5c(c4)C(C)(C)CCC5(C)C)c4cc([Si](c5ccccc5)(c5ccccc5)c5ccccc5)cc2c43)cc(C(C)(C)C)c1]

In a second aspect, the present invention provides an organic electroluminescent device. The organic electroluminescent device comprises an anode, a hole transport region, a luminescent layer, an electron transport region, and a cathode, which are sequentially arranged on a substrate plate, wherein the luminescent layer comprises a host material and a dopant material, and the dopant material comprises one or more polycyclic compounds as described above.

Furthermore, the host material is selected from structures represented by the following general formula:

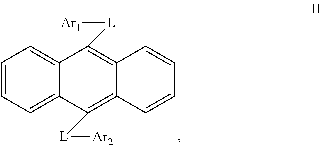

wherein
L is selected from a single bond or phenylene;
Ar₁ is selected from phenyl or naphthyl;
Ar₂ represents one of the following groups:

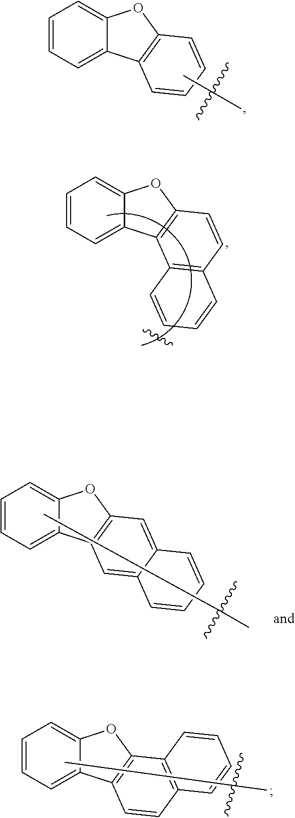

any hydrogen in Formula II can be replaced by deuterium, alkyl, or aryl; and
“|” represents a bonding linkage.

Furthermore, the host material is selected from the following structures:

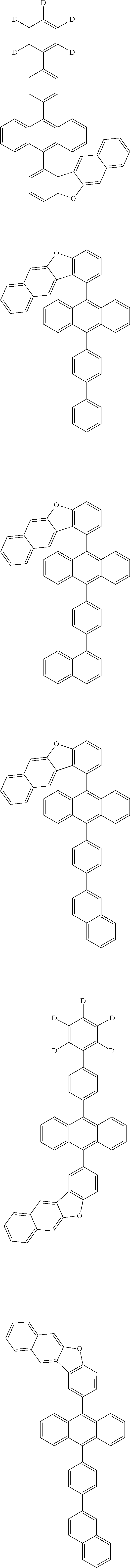

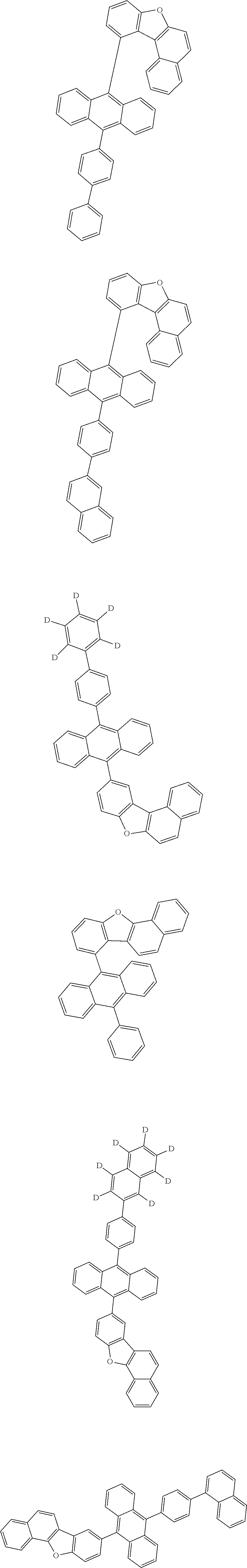

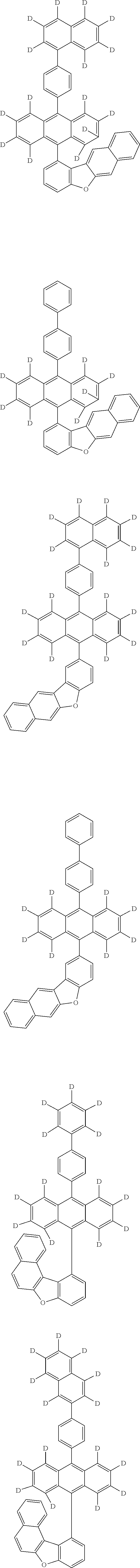

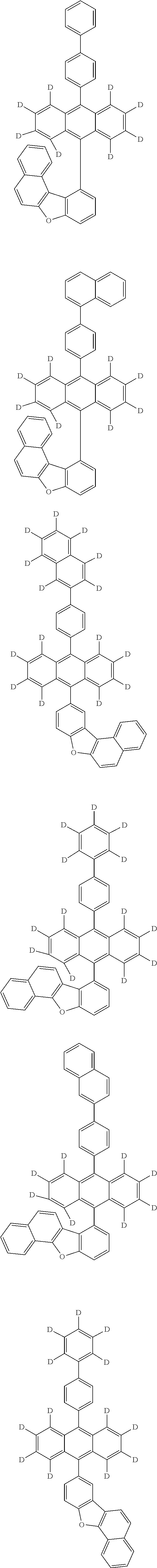

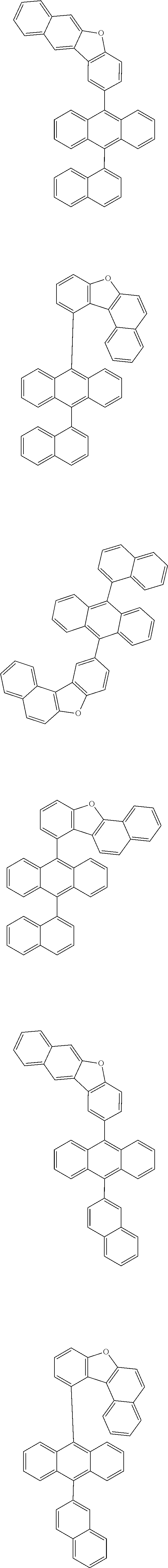 [SMILES: c1ccc2cc3c(cc2c1)oc1ccc(-c2c4ccccc4c(-c4cccc5ccccc45)c4ccccc24)cc13 ; c1ccc2c(-c3c4ccccc4c(-c4cccc5oc6ccc7ccccc7c6c45)c4ccccc34)cccc2c1 ; c1ccc2c(-c3c4ccccc4c(-c4ccc5oc6ccc7ccccc7c6c5c4)c4ccccc34)cccc2c1 ; c1ccc2c(-c3c4ccccc4c(-c4cccc5oc6c7ccccc7ccc6c45)c4ccccc34)cccc2c1 ; c1ccc2cc(-c3c4ccccc4c(-c4ccc5oc6cc7ccccc7cc6c5c4)c4ccccc34)ccc2c1 ; c1ccc2cc(-c3c4ccccc4c(-c4cccc5oc6ccc7ccccc7c6c45)c4ccccc34)ccc2c1]

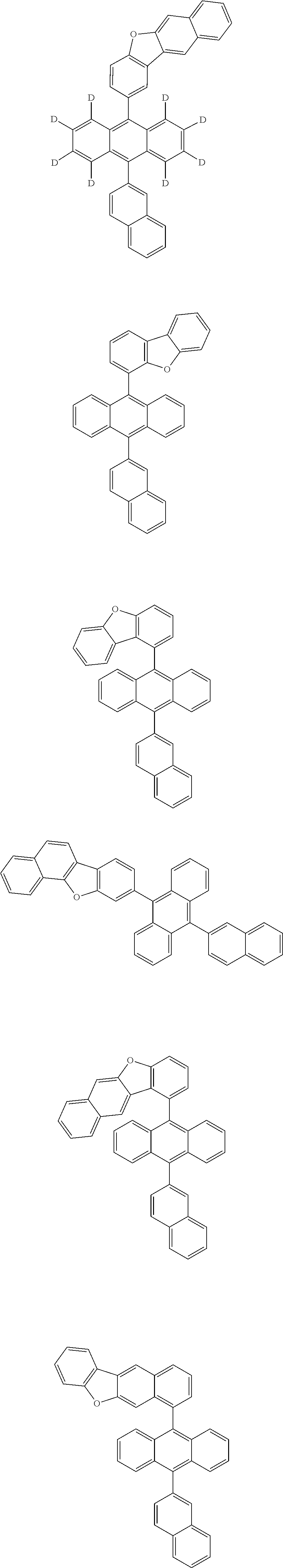 [SMILES: [2H]c1c([2H])c([2H])c2c(-c3ccc4oc5cc6ccccc6cc5c4c3)c3c([2H])c([2H])c([2H])c([2H])c3c(-c3ccc4ccccc4c3)c2c1[2H] ; c1ccc2cc(-c3c4ccccc4c(-c4cccc5c4oc4ccccc45)c4ccccc34)ccc2c1 ; c1ccc2cc(-c3c4ccccc4c(-c4cccc5oc6ccccc6c45)c4ccccc34)ccc2c1 ; c1ccc2cc(-c3c4ccccc4c(-c4ccc5c(c4)oc4c6ccccc6ccc54)c4ccccc34)ccc2c1 ; c1ccc2cc(-c3c4ccccc4c(-c4cccc5oc6cc7ccccc7cc6c45)c4ccccc34)ccc2c1 ; c1ccc2cc(-c3c4ccccc4c(-c4cccc5cc6c(cc45)oc4ccccc46)c4ccccc34)ccc2c1]

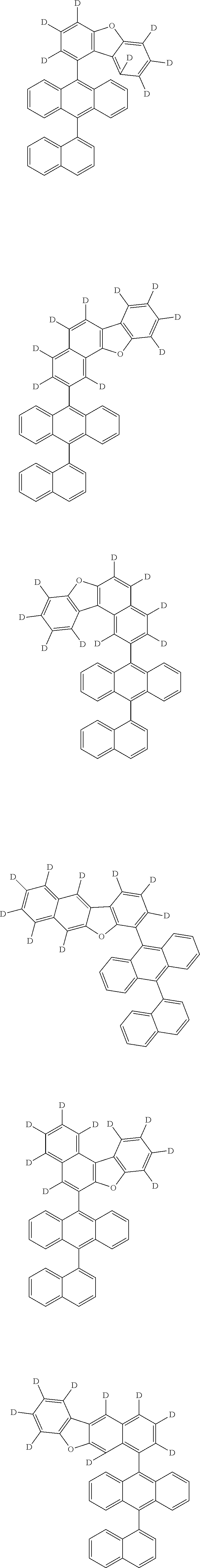

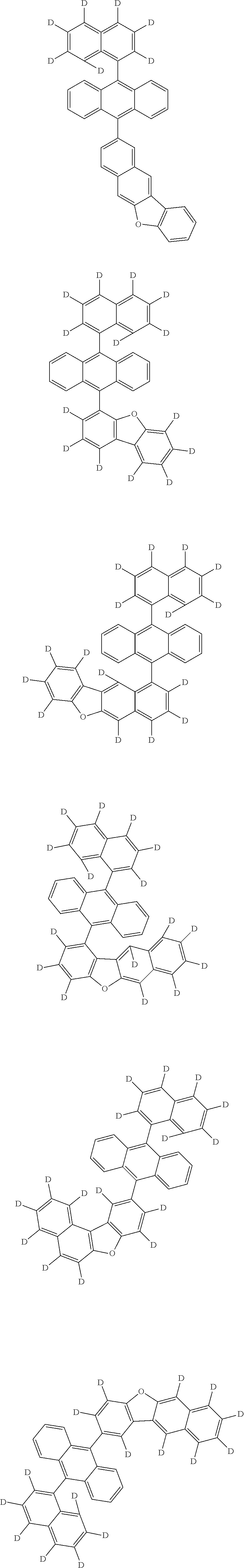

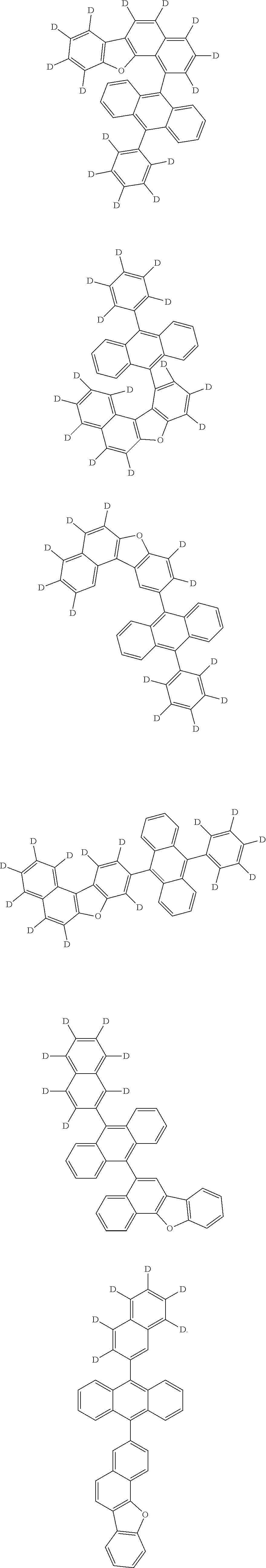

Furthermore, the content of the host material in the luminescent layer should be more than 50 wt %, preferably more than 90 wt %.

Furthermore, the content of the dopant material in the luminescent layer should be less than 20 wt %, preferably less than 5 wt %.

Furthermore, the hole transport region comprises at least one functional layer for transporting holes, such as a hole transport layer and a luminescent auxiliary layer, and the materials used for the hole transport layer and the luminescent auxiliary layer are selected from structures represented by the following general formula:

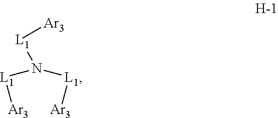

wherein each L₁ independently represents a single bond, phenylene, or biphenylene;
each Ar₃ independently represents the following group:

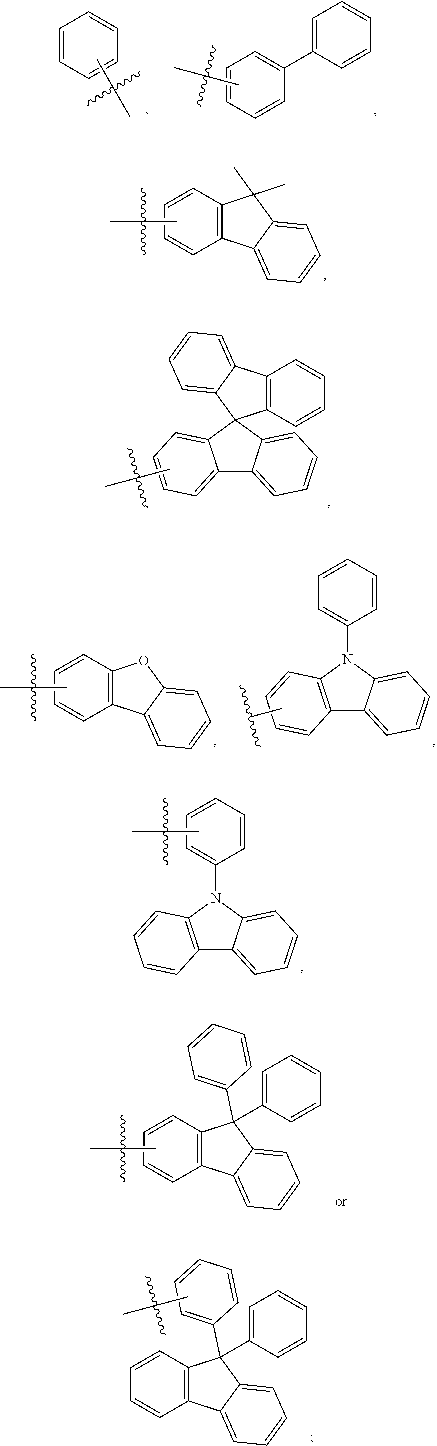

any hydrogen in Formula H-1 can be replaced by deuterium, alkyl, or aryl; and

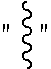

represents a bonding linkage.

Furthermore, the material used for the hole transport layer is selected from the following structures:

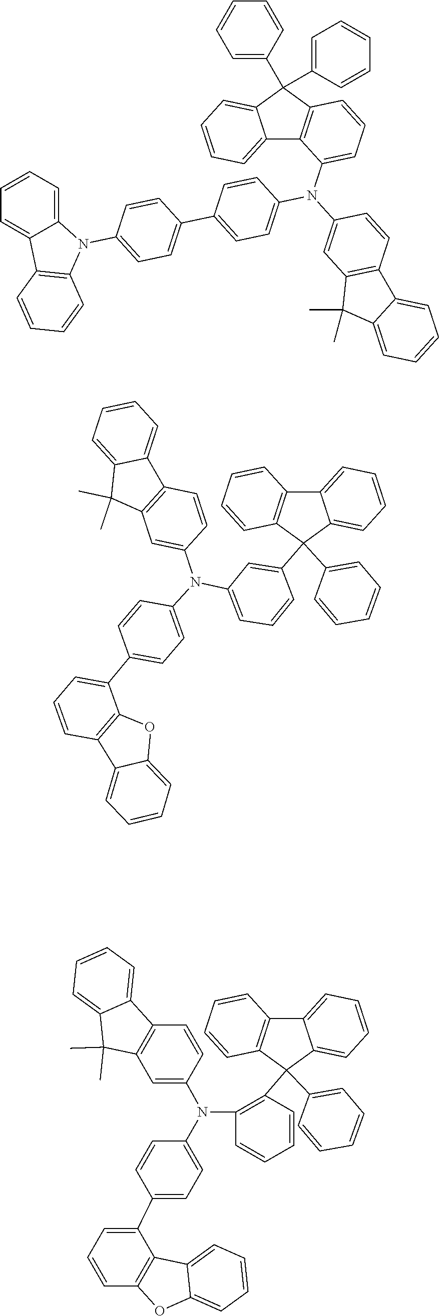 [SMILES: CC1(C)c2ccccc2-c2ccc(N(c3ccc(-c4ccc(-n5c6ccccc6c6ccccc65)cc4)cc3)c3cccc4c3-c3ccccc3C4(c3ccccc3)c3ccccc3)cc21 ; CC1(C)c2ccccc2-c2ccc(N(c3ccc(-c4cccc5c4oc4ccccc45)cc3)c3cccc(C4(c5ccccc5)c5ccccc5-c5ccccc54)c3)cc21 ; CC1(C)c2ccccc2-c2ccc(N(c3ccc(-c4cccc5oc6ccccc6c45)cc3)c3ccccc3C3(c4ccccc4)c4ccccc4-c4ccccc43)cc21]

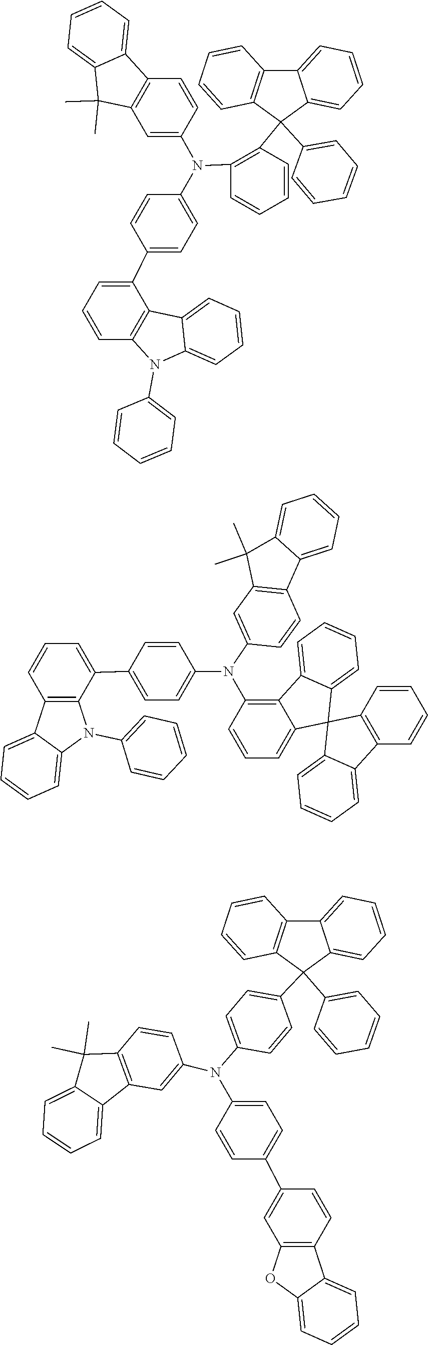 [SMILES: CC1(C)c2ccccc2-c2ccc(N(c3ccc(-c4cccc5c4c4ccccc4n5-c4ccccc4)cc3)c3ccccc3C3(c4ccccc4)c4ccccc4-c4ccccc43)cc21 ; CC1(C)c2ccccc2-c2ccc(N(c3ccc(-c4cccc5c6ccccc6n(-c6ccccc6)c45)cc3)c3cccc4c3-c3ccccc3C43c4ccccc4-c4ccccc43)cc21 ; CC1(C)c2ccccc2-c2cc(N(c3ccc(-c4ccc5c(c4)oc4ccccc45)cc3)c3ccc(C4(c5ccccc5)c5ccccc5-c5ccccc54)cc3)ccc21]

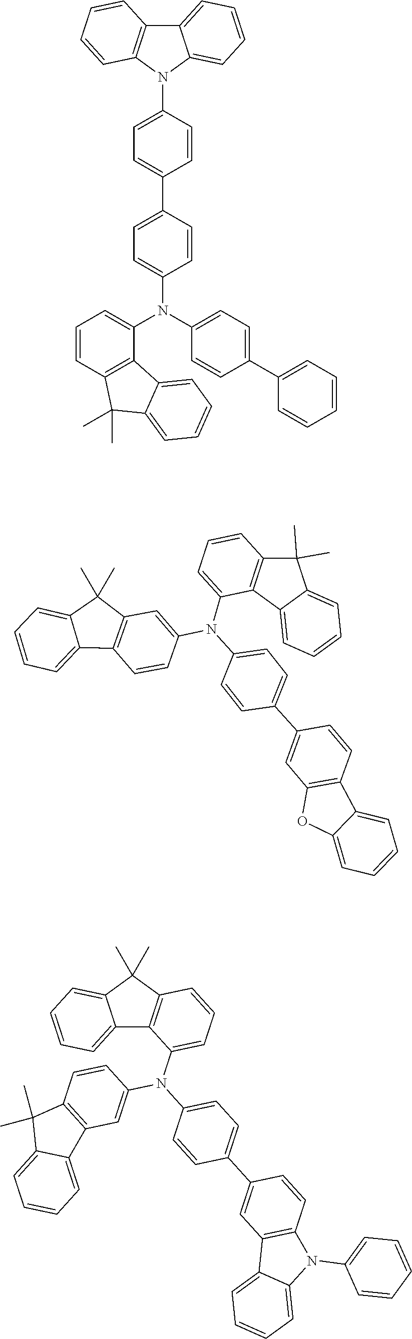 [SMILES: CC1(C)c2ccccc2-c2c(N(c3ccc(-c4ccccc4)cc3)c3ccc(-c4ccc(-n5c6ccccc6c6ccccc65)cc4)cc3)cccc21 ; CC1(C)c2ccccc2-c2ccc(N(c3ccc(-c4ccc5c(c4)oc4ccccc45)cc3)c3cccc4c3-c3ccccc3C4(C)C)cc21 ; CC1(C)c2ccccc2-c2cc(N(c3ccc(-c4ccc5c(c4)c4ccccc4n5-c4ccccc4)cc3)c3cccc4c3-c3ccccc3C4(C)C)ccc21]

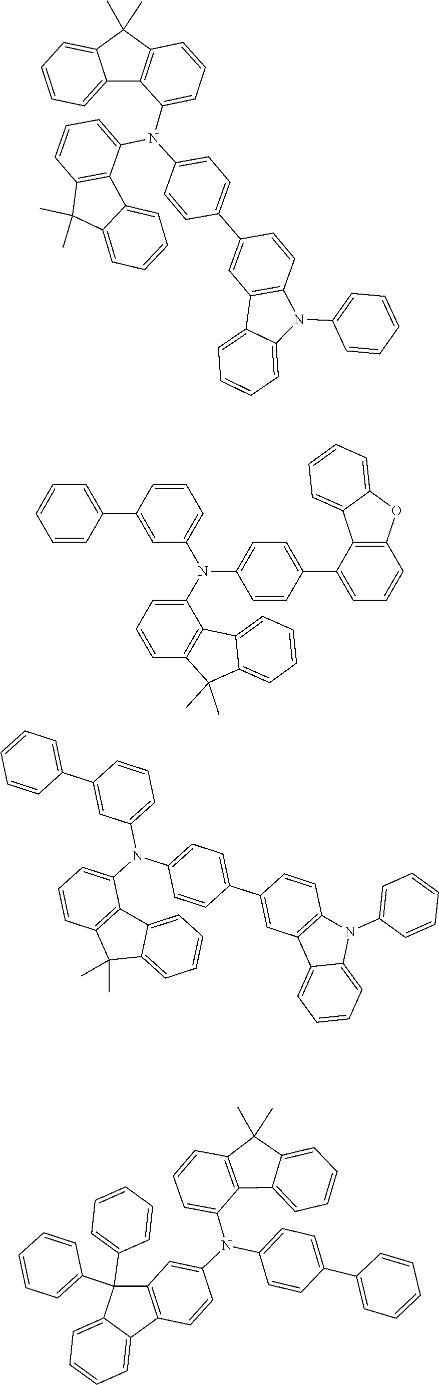 [SMILES: CC1(C)c2ccccc2-c2c(N(c3ccc(-c4ccc5c(c4)c4ccccc4n5-c4ccccc4)cc3)c3cccc4c3-c3ccccc3C4(C)C)cccc21 ; CC1(C)c2ccccc2-c2c(N(c3ccc(-c4cccc5oc6ccccc6c45)cc3)c3cccc(-c4ccccc4)c3)cccc21 ; CC1(C)c2ccccc2-c2c(N(c3ccc(-c4ccc5c(c4)c4ccccc4n5-c4ccccc4)cc3)c3cccc(-c4ccccc4)c3)cccc21 ; CC1(C)c2ccccc2-c2c(N(c3ccc(-c4ccccc4)cc3)c3ccc4c(c3)C(c3ccccc3)(c3ccccc3)c3ccccc3-4)cccc21]

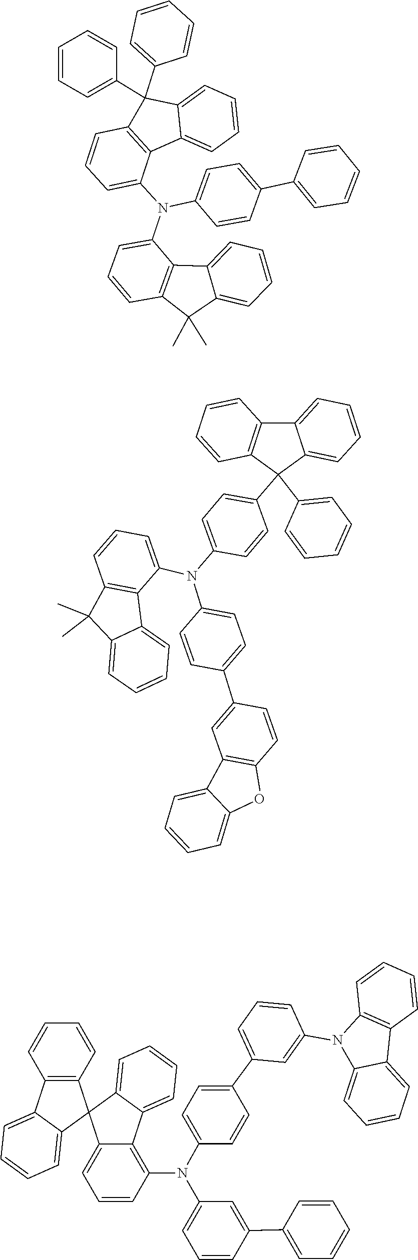 [SMILES: CC1(C)c2ccccc2-c2c(N(c3ccc(-c4ccccc4)cc3)c3cccc4c3-c3ccccc3C4(c3ccccc3)c3ccccc3)cccc21 ; CC1(C)c2ccccc2-c2c(N(c3ccc(-c4ccc5oc6ccccc6c5c4)cc3)c3ccc(C4(c5ccccc5)c5ccccc5-c5ccccc54)cc3)cccc21 ; c1ccc(-c2cccc(N(c3ccc(-c4cccc(-n5c6ccccc6c6ccccc65)c4)cc3)c3cccc4c3-c3ccccc3C43c4ccccc4-c4ccccc43)c2)cc1]

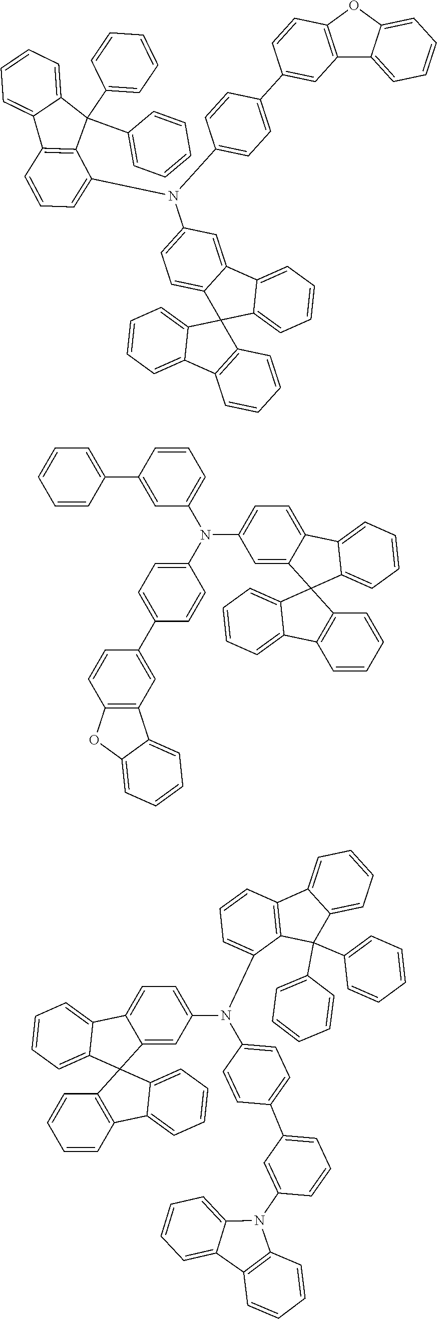 [SMILES: c1ccc(C2(c3ccccc3)c3ccccc3-c3cccc(N(c4ccc(-c5ccc6oc7ccccc7c6c5)cc4)c4ccc5c(c4)-c4ccccc4C54c5ccccc5-c5ccccc54)c32)cc1 ; c1ccc(-c2cccc(N(c3ccc(-c4ccc5oc6ccccc6c5c4)cc3)c3ccc4c(c3)C3(c5ccccc5-c5ccccc53)c3ccccc3-4)c2)cc1 ; c1ccc(C2(c3ccccc3)c3ccccc3-c3cccc(N(c4ccc(-c5cccc(-n6c7ccccc7c7ccccc76)c5)cc4)c4ccc5c(c4)C4(c6ccccc6-c6ccccc64)c4ccccc4-5)c32)cc1]

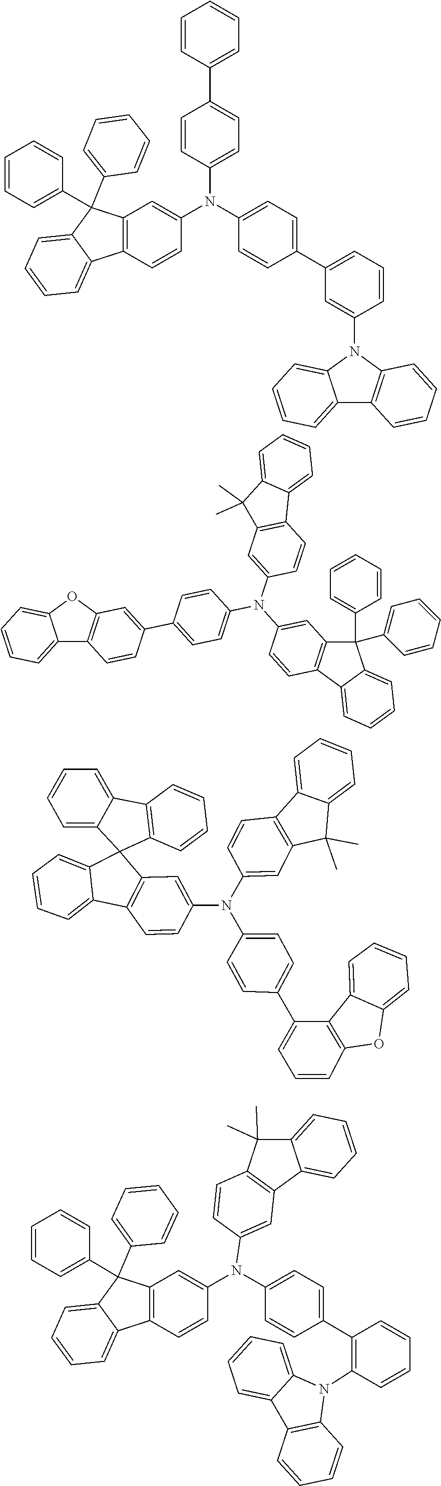

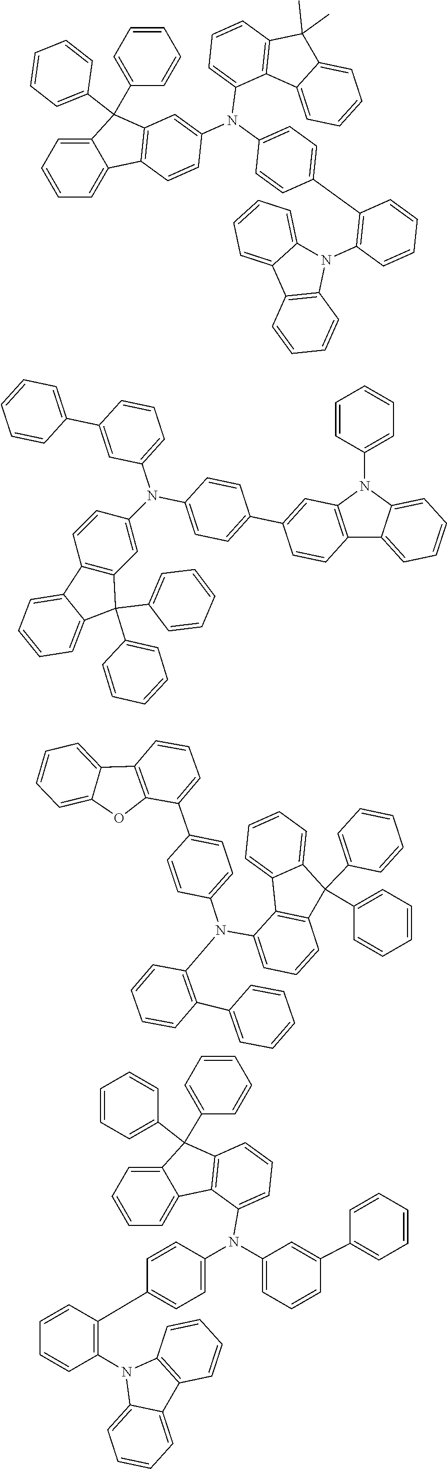

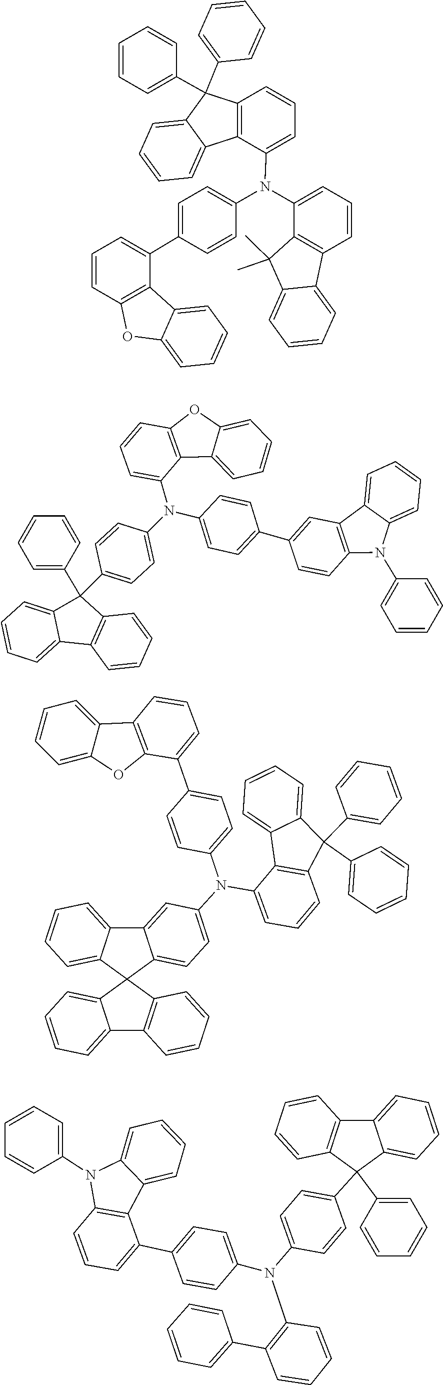

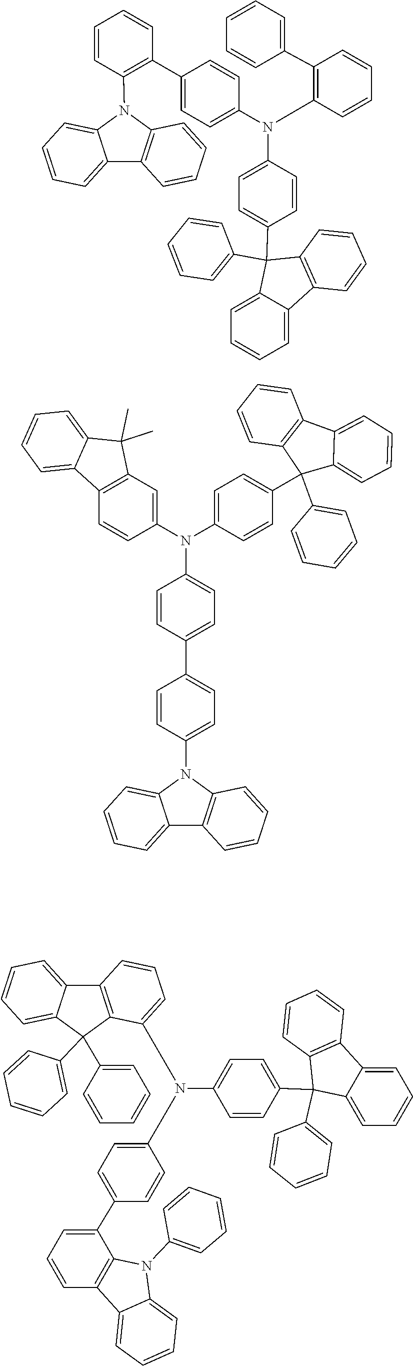

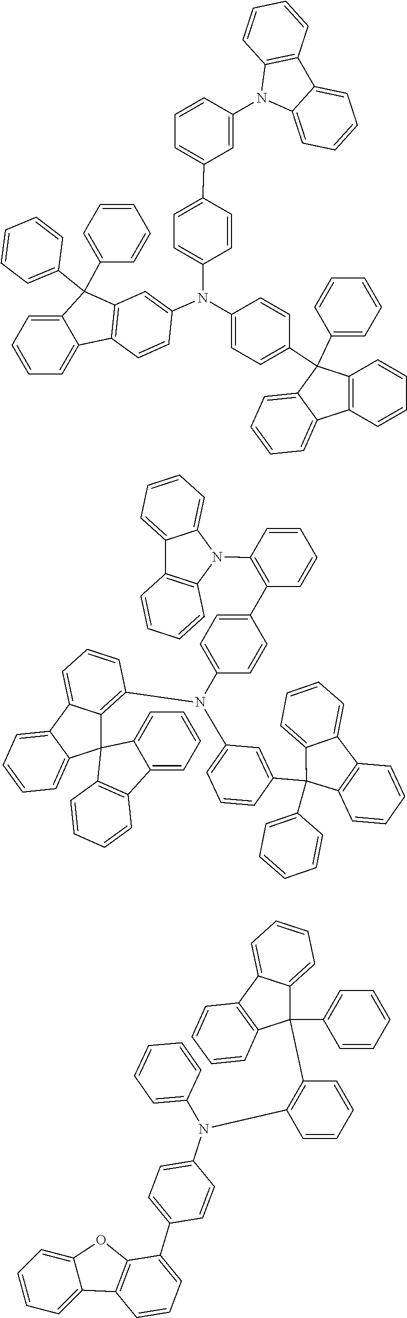

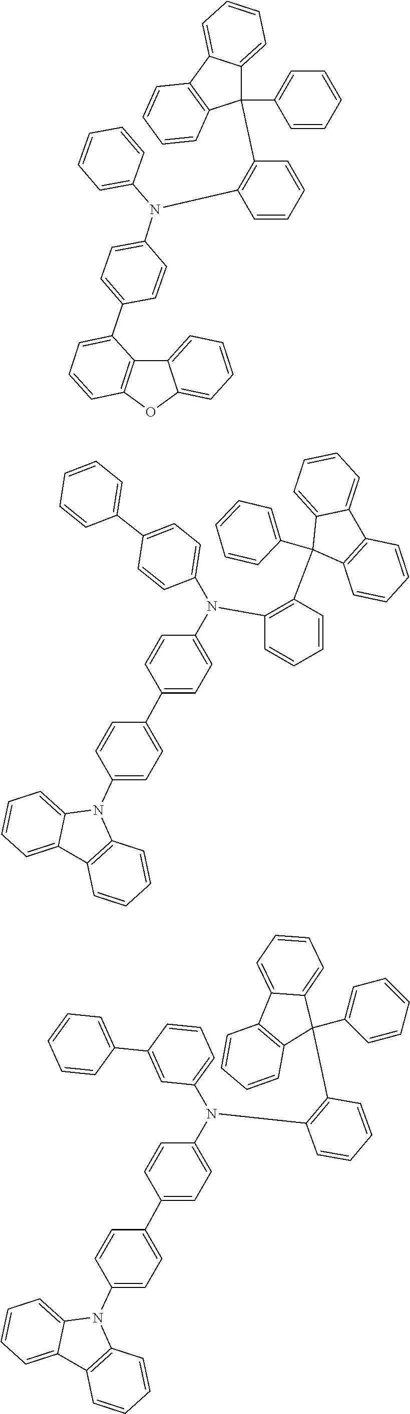 [SMILES: c1ccc(N(c2ccc(-c3cccc4oc5ccccc5c34)cc2)c2ccccc2C2(c3ccccc3)c3ccccc3-c3ccccc32)cc1 ; c1ccc(-c2ccc(N(c3ccc(-c4ccc(-n5c6ccccc6c6ccccc65)cc4)cc3)c3ccccc3C3(c4ccccc4)c4ccccc4-c4ccccc43)cc2)cc1 ; c1ccc(-c2cccc(N(c3ccc(-c4ccc(-n5c6ccccc6c6ccccc65)cc4)cc3)c3ccccc3C3(c4ccccc4)c4ccccc4-c4ccccc43)c2)cc1]

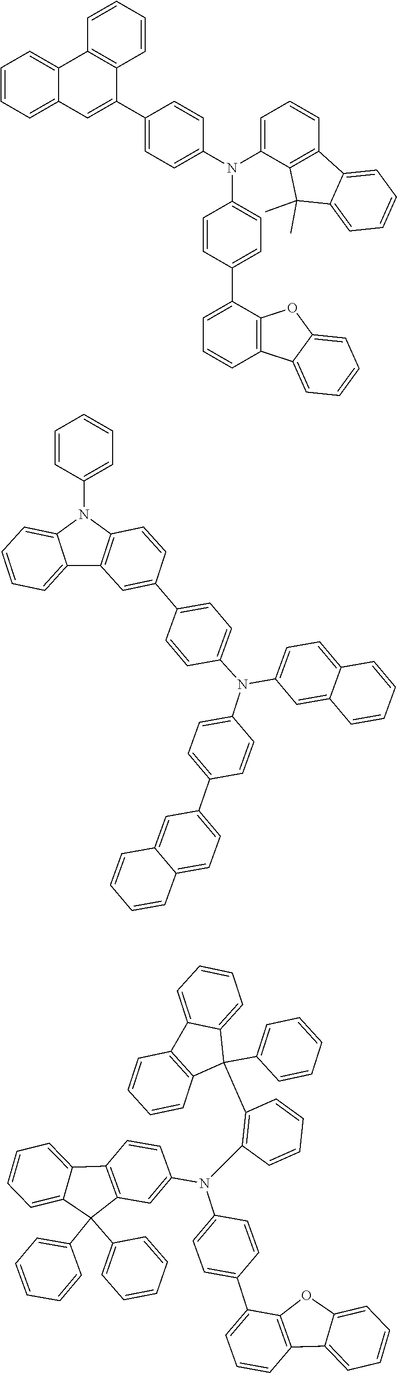 [SMILES: CC1(C)c2ccccc2-c2cccc(N(c3ccc(-c4cc5ccccc5c5ccccc45)cc3)c3ccc(-c4cccc5c4oc4ccccc45)cc3)c21 ; c1ccc(-n2c3ccccc3c3cc(-c4ccc(N(c5ccc(-c6ccc7ccccc7c6)cc5)c5ccc6ccccc6c5)cc4)ccc32)cc1 ; c1ccc(C2(c3ccccc3)c3ccccc3-c3ccc(N(c4ccc(-c5cccc6c5oc5ccccc56)cc4)c4ccccc4C4(c5ccccc5)c5ccccc5-c5ccccc54)cc32)cc1]

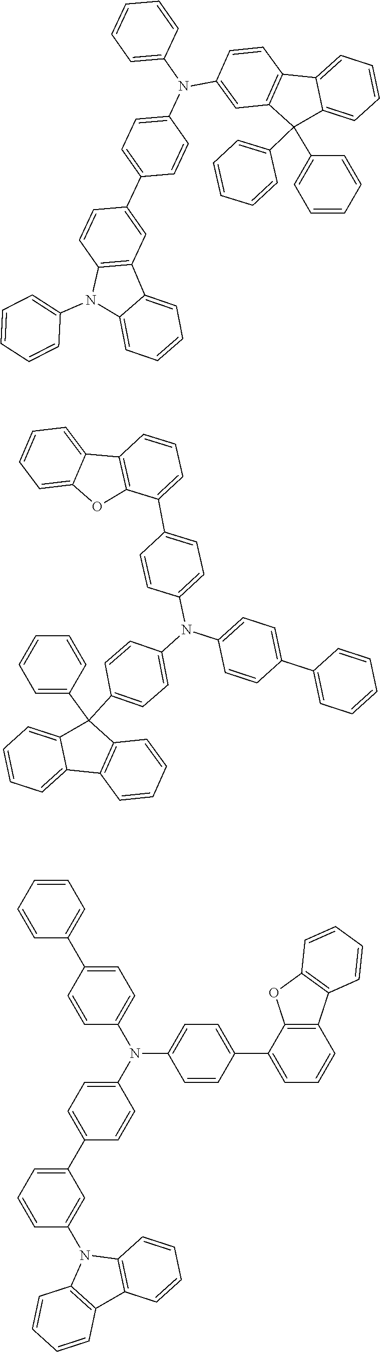 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4cccc5c4oc4ccccc45)cc3)c3ccc(C4(c5ccccc5)c5ccccc5-c5ccccc54)cc3)cc2)cc1 ; c1ccc(-c2ccc(N(c3ccc(-c4cccc(-n5c6ccccc6c6ccccc65)c4)cc3)c3ccc(-c4cccc5c4oc4ccccc45)cc3)cc2)cc1]

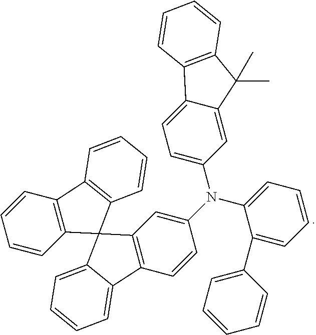 [SMILES: CC1(C)c2ccccc2-c2ccc(N(c3ccc4c(c3)C3(c5ccccc5-c5ccccc53)c3ccccc3-4)c3ccccc3-c3ccccc3)cc21]

Furthermore, the electron transport region comprises at least one functional layer for transporting electrons, such as an electron transport layer and a hole barrier layer, and the materials used for the electron transport layer and the hole barrier layer are selected from structures represented by the following general formula:

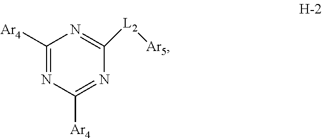

wherein L₂ is selected from a single bond, phenylene, or biphenylene;
each Ar₄ independently represents the following group:

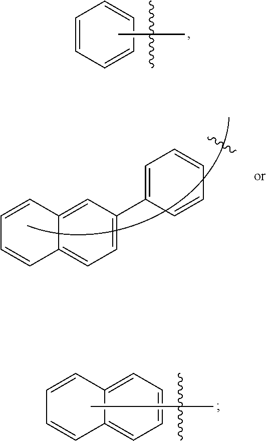

Ar₅ represents the following group:

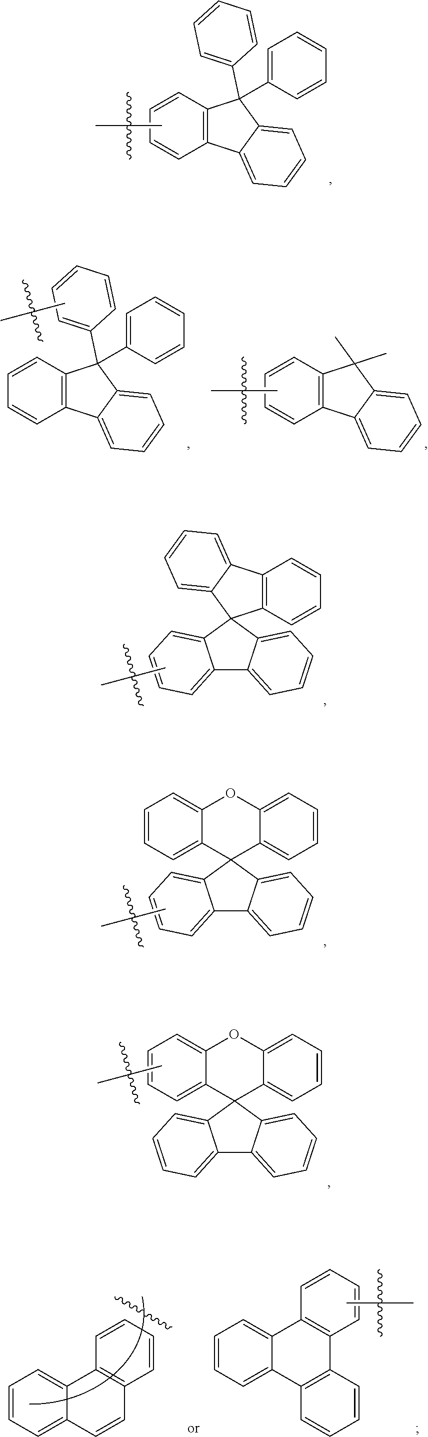

any hydrogen in Formula H-2 can be replaced by deuterium, alkyl, or aryl; and
“|” represents a bonding linkage.

Furthermore, the material used for the electron transport layer is selected from the following structures:

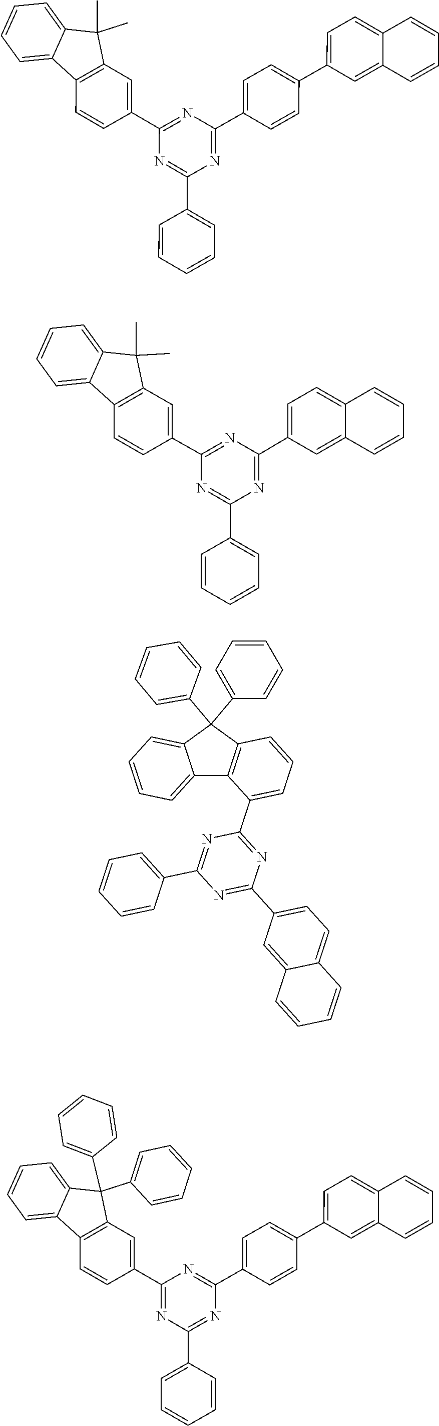

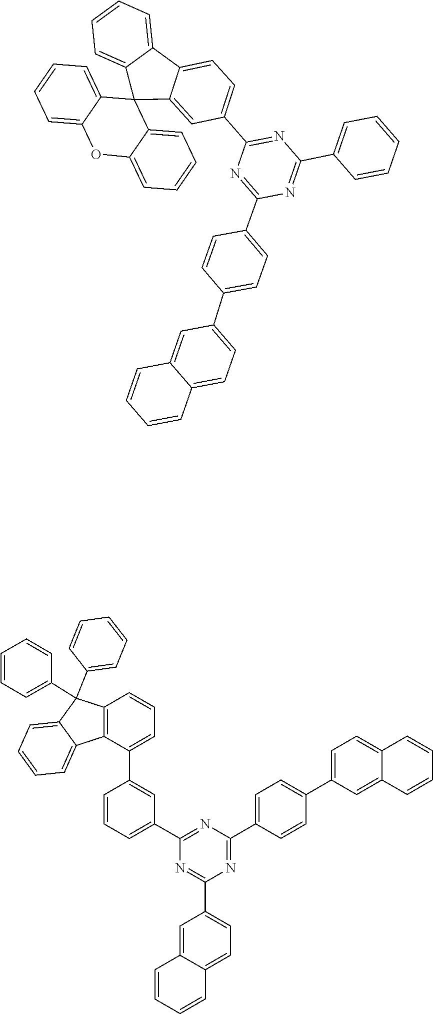 [SMILES: c1ccc(-c2nc(-c3ccc(-c4ccc5ccccc5c4)cc3)nc(-c3ccc4c(c3)C3(c5ccccc5Oc5ccccc53)c3ccccc3-4)n2)cc1 ; c1ccc(C2(c3ccccc3)c3ccccc3-c3c(-c4cccc(-c5nc(-c6ccc(-c7ccc8ccccc8c7)cc6)nc(-c6ccc7ccccc7c6)n5)c4)cccc32)cc1]

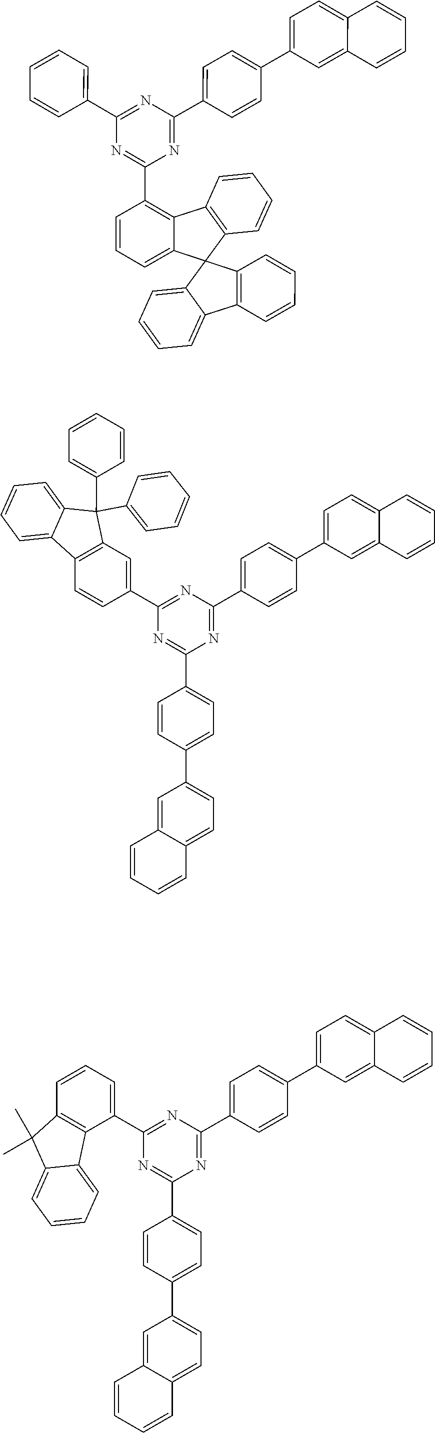 [SMILES: c1ccc(-c2nc(-c3ccc(-c4ccc5ccccc5c4)cc3)nc(-c3cccc4c3-c3ccccc3C43c4ccccc4-c4ccccc43)n2)cc1 ; c1ccc(C2(c3ccccc3)c3ccccc3-c3ccc(-c4nc(-c5ccc(-c6ccc7ccccc7c6)cc5)nc(-c5ccc(-c6ccc7ccccc7c6)cc5)n4)cc32)cc1 ; CC1(C)c2ccccc2-c2c(-c3nc(-c4ccc(-c5ccc6ccccc6c5)cc4)nc(-c4ccc(-c5ccc6ccccc6c5)cc4)n3)cccc21]

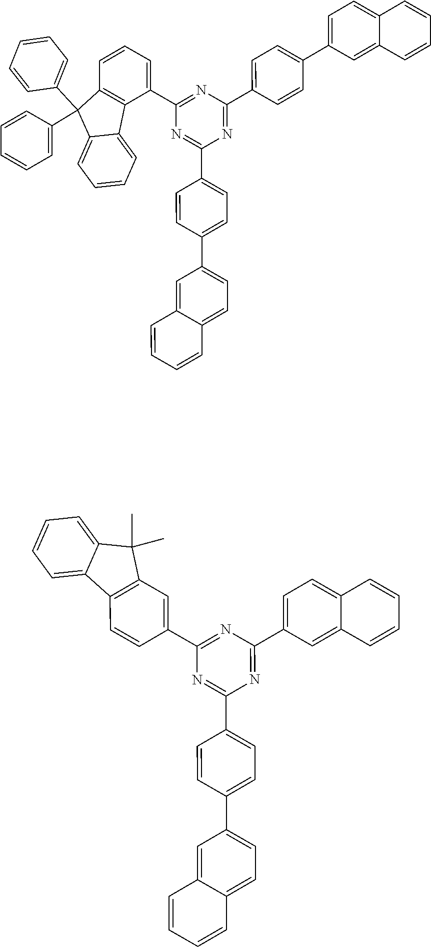 [SMILES: c1ccc(C2(c3ccccc3)c3ccccc3-c3c(-c4nc(-c5ccc(-c6ccc7ccccc7c6)cc5)nc(-c5ccc(-c6ccc7ccccc7c6)cc5)n4)cccc32)cc1 ; CC1(C)c2ccccc2-c2ccc(-c3nc(-c4ccc(-c5ccc6ccccc6c5)cc4)nc(-c4ccc5ccccc5c4)n3)cc21]

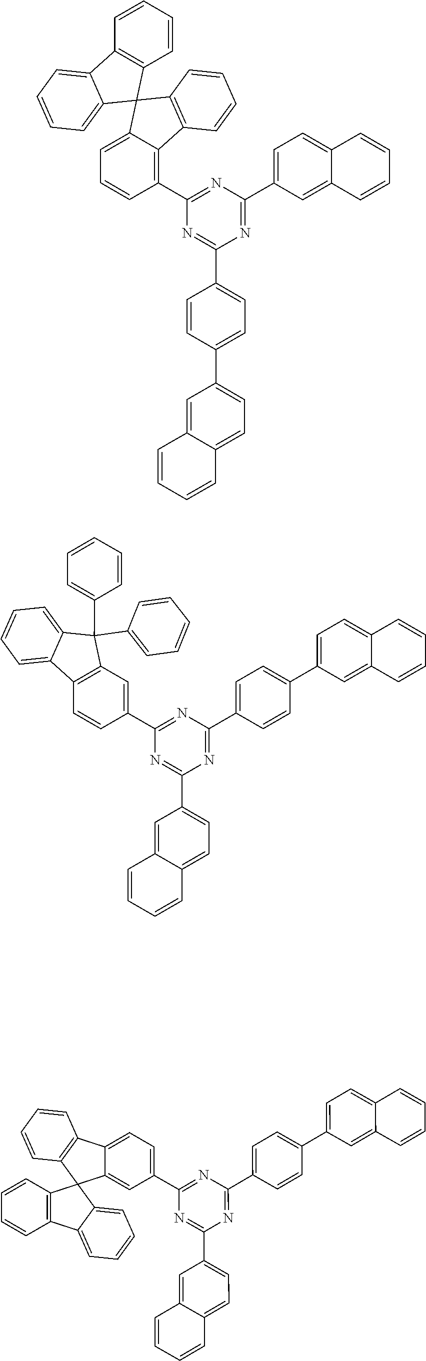 [SMILES: c1ccc2c(c1)-c1ccccc1C21c2ccccc2-c2c(-c3nc(-c4ccc(-c5ccc6ccccc6c5)cc4)nc(-c4ccc5ccccc5c4)n3)cccc21 ; c1ccc(C2(c3ccccc3)c3ccccc3-c3ccc(-c4nc(-c5ccc(-c6ccc7ccccc7c6)cc5)nc(-c5ccc6ccccc6c5)n4)cc32)cc1 ; c1ccc2c(c1)-c1ccccc1C21c2ccccc2-c2ccc(-c3nc(-c4ccc(-c5ccc6ccccc6c5)cc4)nc(-c4ccc5ccccc5c4)n3)cc21]

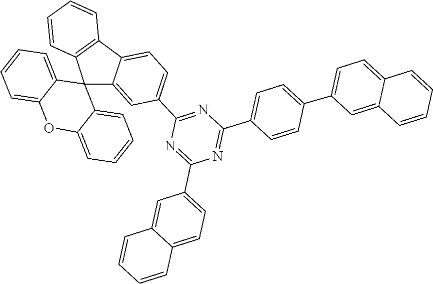 [SMILES: c1ccc2c(c1)Oc1ccccc1C21c2ccccc2-c2ccc(-c3nc(-c4ccc(-c5ccc6ccccc6c5)cc4)nc(-c4ccc5ccccc5c4)n3)cc21]

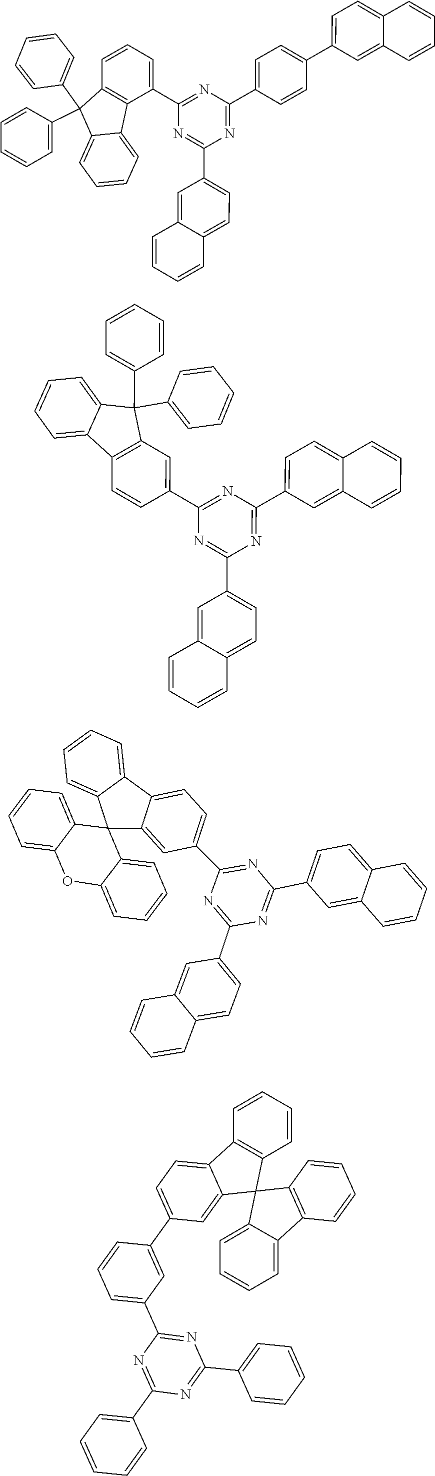

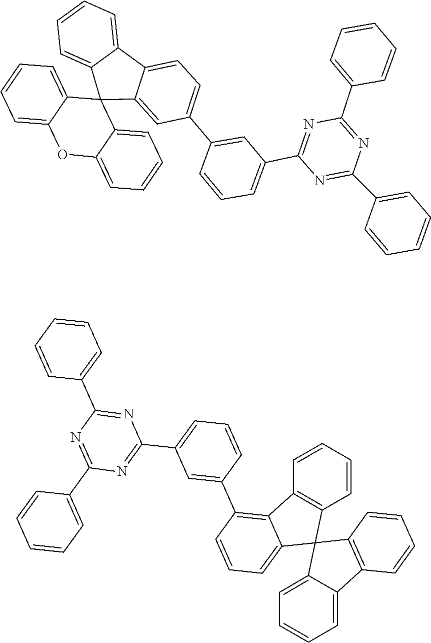 [SMILES: c1ccc(-c2nc(-c3ccccc3)nc(-c3cccc(-c4ccc5c(c4)C4(c6ccccc6Oc6ccccc64)c4ccccc4-5)c3)n2)cc1 ; c1ccc(-c2nc(-c3ccccc3)nc(-c3cccc(-c4cccc5c4-c4ccccc4C54c5ccccc5-c5ccccc54)c3)n2)cc1]

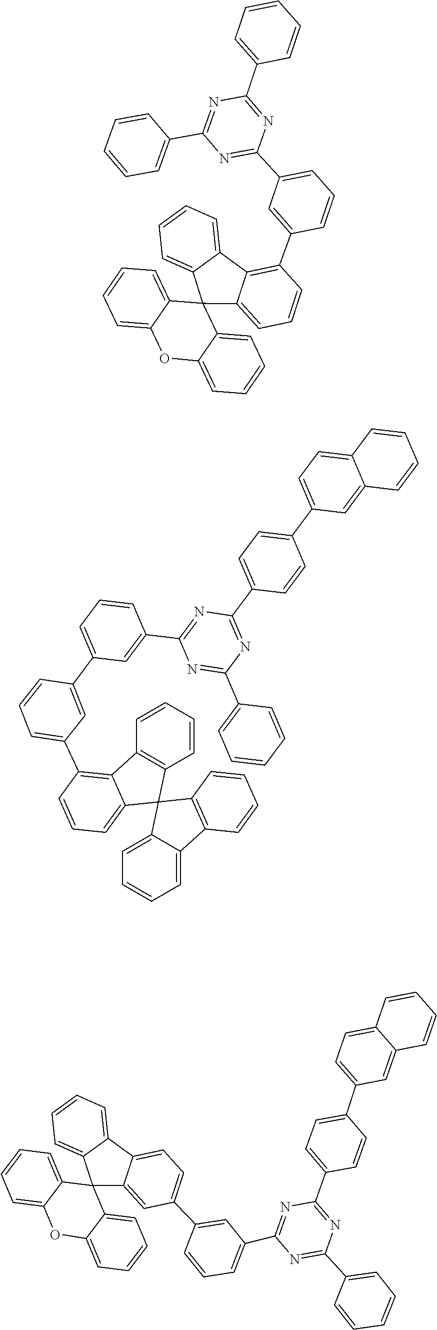 [SMILES: c1ccc(-c2nc(-c3ccccc3)nc(-c3cccc(-c4cccc5c4-c4ccccc4C54c5ccccc5Oc5ccccc54)c3)n2)cc1 ; c1ccc(-c2nc(-c3ccc(-c4ccc5ccccc5c4)cc3)nc(-c3cccc(-c4cccc(-c5cccc6c5-c5ccccc5C65c6ccccc6-c6ccccc65)c4)c3)n2)cc1 ; c1ccc(-c2nc(-c3ccc(-c4ccc5ccccc5c4)cc3)nc(-c3cccc(-c4ccc5c(c4)C4(c6ccccc6Oc6ccccc64)c4ccccc4-5)c3)n2)cc1]

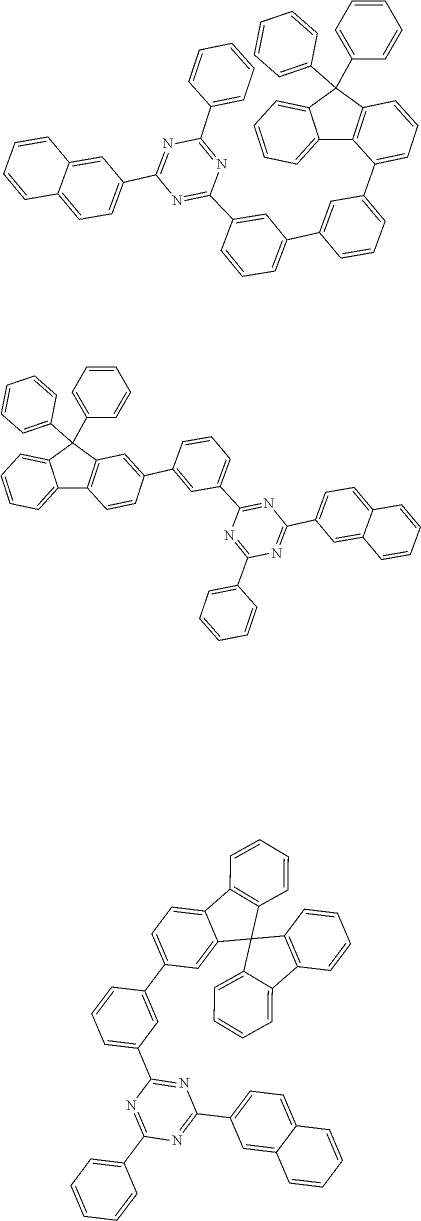 [SMILES: c1ccc(-c2nc(-c3cccc(-c4cccc(-c5cccc6c5-c5ccccc5C6(c5ccccc5)c5ccccc5)c4)c3)nc(-c3ccc4ccccc4c3)n2)cc1 ; c1ccc(-c2nc(-c3cccc(-c4ccc5c(c4)C(c4ccccc4)(c4ccccc4)c4ccccc4-5)c3)nc(-c3ccc4ccccc4c3)n2)cc1 ; c1ccc(-c2nc(-c3cccc(-c4ccc5c(c4)C4(c6ccccc6-c6ccccc64)c4ccccc4-5)c3)nc(-c3ccc4ccccc4c3)n2)cc1]

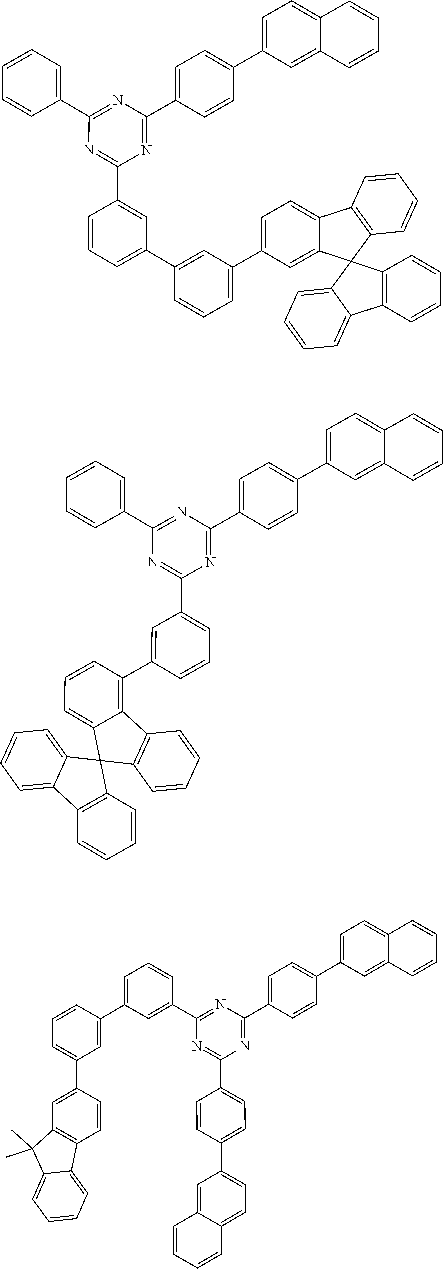 [SMILES: c1ccc(-c2nc(-c3ccc(-c4ccc5ccccc5c4)cc3)nc(-c3cccc(-c4cccc(-c5ccc6c(c5)C5(c7ccccc7-c7ccccc75)c5ccccc5-6)c4)c3)n2)cc1 ; c1ccc(-c2nc(-c3ccc(-c4ccc5ccccc5c4)cc3)nc(-c3cccc(-c4cccc5c4-c4ccccc4C54c5ccccc5-c5ccccc54)c3)n2)cc1 ; CC1(C)c2ccccc2-c2ccc(-c3cccc(-c4cccc(-c5nc(-c6ccc(-c7ccc8ccccc8c7)cc6)nc(-c6ccc(-c7ccc8ccccc8c7)cc6)n5)c4)c3)cc21]

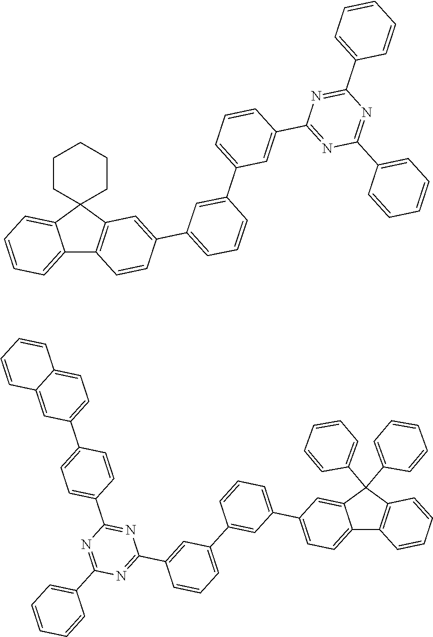 [SMILES: c1ccc(-c2nc(-c3ccccc3)nc(-c3cccc(-c4cccc(-c5ccc6c(c5)C5(CCCCC5)c5ccccc5-6)c4)c3)n2)cc1 ; c1ccc(-c2nc(-c3ccc(-c4ccc5ccccc5c4)cc3)nc(-c3cccc(-c4cccc(-c5ccc6c(c5)C(c5ccccc5)(c5ccccc5)c5ccccc5-6)c4)c3)n2)cc1]

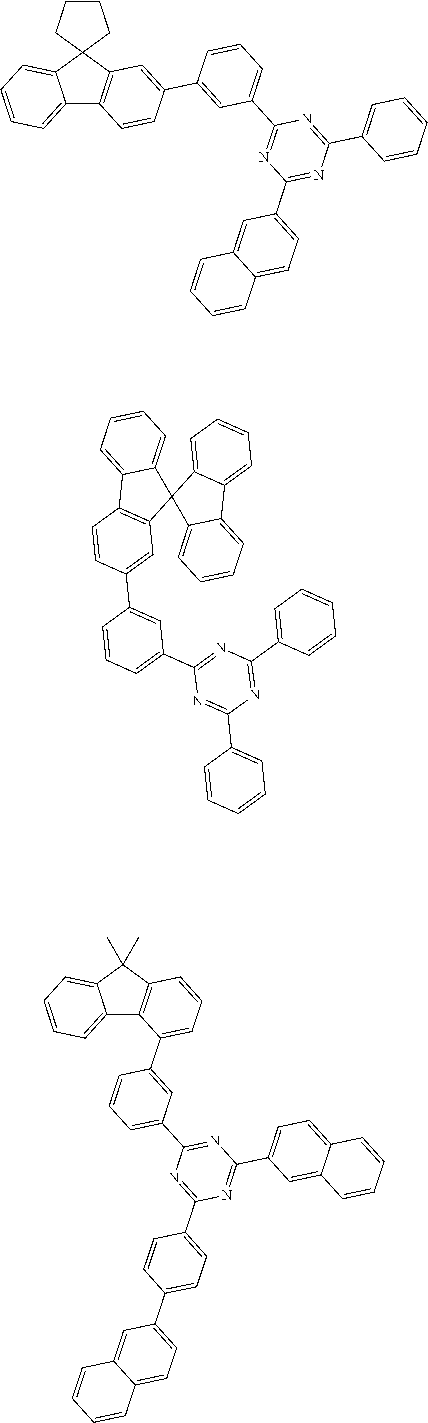 [SMILES: c1ccc(-c2nc(-c3cccc(-c4ccc5c(c4)C4(CCCC4)c4ccccc4-5)c3)nc(-c3ccc4ccccc4c3)n2)cc1 ; c1ccc(-c2nc(-c3ccccc3)nc(-c3cccc(-c4ccc5c(c4)C4(c6ccccc6-c6ccccc64)c4ccccc4-5)c3)n2)cc1 ; CC1(C)c2ccccc2-c2c(-c3cccc(-c4nc(-c5ccc(-c6ccc7ccccc7c6)cc5)nc(-c5ccc6ccccc6c5)n4)c3)cccc21]

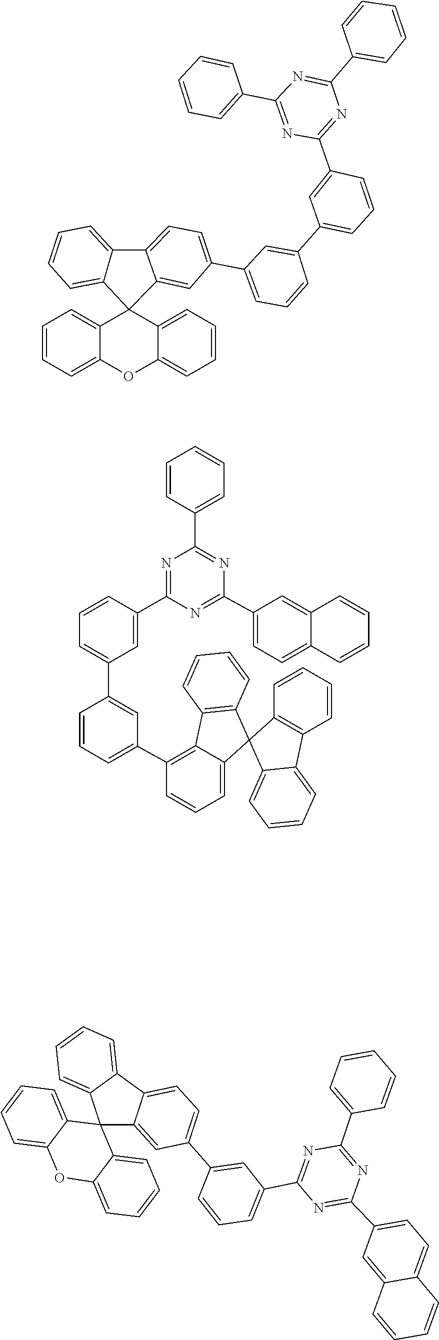 [SMILES: c1ccc(-c2nc(-c3ccccc3)nc(-c3cccc(-c4cccc(-c5ccc6c(c5)C5(c7ccccc7Oc7ccccc75)c5ccccc5-6)c4)c3)n2)cc1 ; c1ccc(-c2nc(-c3cccc(-c4cccc(-c5cccc6c5-c5ccccc5C65c6ccccc6-c6ccccc65)c4)c3)nc(-c3ccc4ccccc4c3)n2)cc1 ; c1ccc(-c2nc(-c3cccc(-c4ccc5c(c4)C4(c6ccccc6Oc6ccccc64)c4ccccc4-5)c3)nc(-c3ccc4ccccc4c3)n2)cc1]

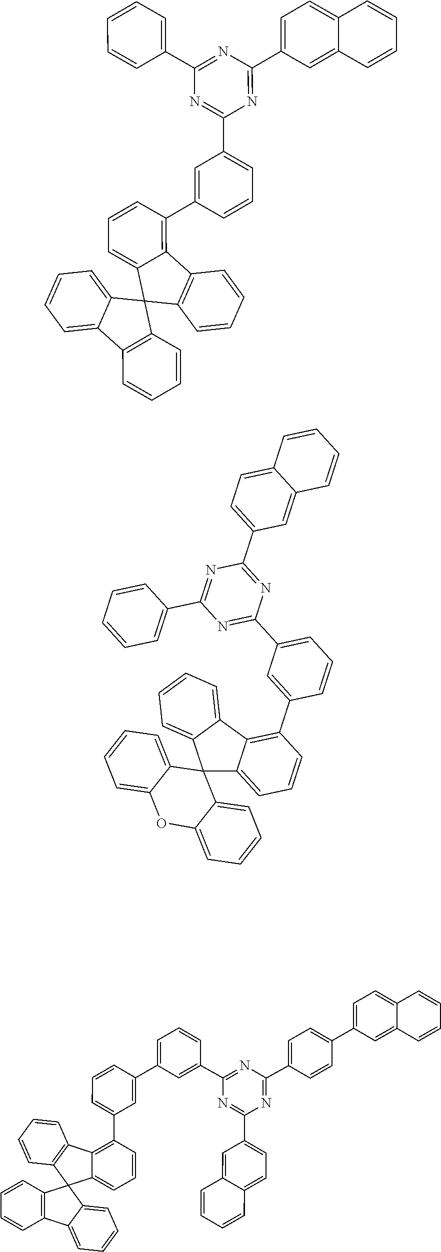 [SMILES: c1ccc(-c2nc(-c3cccc(-c4cccc5c4-c4ccccc4C54c5ccccc5-c5ccccc54)c3)nc(-c3ccc4ccccc4c3)n2)cc1 ; c1ccc(-c2nc(-c3cccc(-c4cccc5c4-c4ccccc4C54c5ccccc5Oc5ccccc54)c3)nc(-c3ccc4ccccc4c3)n2)cc1 ; c1cc(-c2cccc(-c3cccc4c3-c3ccccc3C43c4ccccc4-c4ccccc43)c2)cc(-c2nc(-c3ccc(-c4ccc5ccccc5c4)cc3)nc(-c3ccc4ccccc4c3)n2)c1]

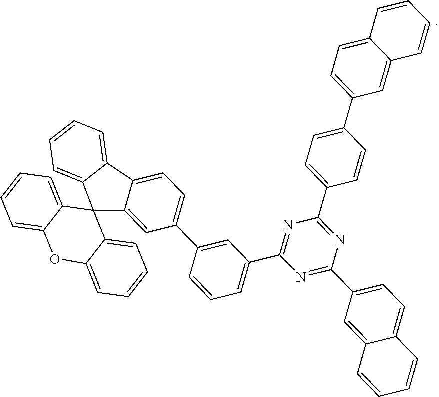 [SMILES: c1cc(-c2ccc3c(c2)C2(c4ccccc4Oc4ccccc42)c2ccccc2-3)cc(-c2nc(-c3ccc(-c4ccc5ccccc5c4)cc3)nc(-c3ccc4ccccc4c3)n2)c1]

### Beneficial Effects of the Invention

The present invention provides a polycyclic compound containing triphenylsilyl and multiple alkyl substituents. By the introduction of benzofuranyl having stronger electronegativity into a cyclic structure composed of a nitrogen atom and a boron atom and further the introduction of triphenylsilyl into the para position relative to the boron, a synergistic effect between the benzofuranyl and triphenylsilyl can significantly enhance the multiple resonance of a luminescent core and reduce vibrational relaxation. Therefore, the use of both benzofuranyl and triphenylsilyl significantly ameliorates issues such as increased vibrational relaxation and spectral broadening caused by the introduction of multiple alkyl substituents, significantly improves the luminous efficiency of the material, and improves the color purity, thereby meeting the luminescence spectrum requirements of the BT.2020 wide color gamut display standard.

### BRIEF DESCRIPTION OF THE DRAWINGS

The specific embodiments of the present invention will be described in further detail with reference to the accompanying drawings.

FIG. 1 is a schematic structural view of an organic electroluminescent device comprising the compound of the present invention, in which 1—substrate, 2—anode, 3—hole injection layer, 4—hole transport layer, 5—luminescent auxiliary layer, 6—luminescent layer, 7—hole barrier layer, 8—electron transport layer, 9—electron injection layer, 10—cathode, and 11—cover layer.

### DETAILED DESCRIPTION OF EMBODIMENTS

In order to explain the present invention more clearly, the present invention will be further explained below in conjunction with preferred examples and the accompanying drawings. In the drawings, like parts are denoted by like reference signs. A person skilled in the art should understand that the following detailed description is illustrative rather than restrictive and should not limit the scope of protection of the present invention. The examples and comparative examples in the present description are provided to explain the present description more completely to those skilled in the art. The examples and comparative examples according to the present description can be transformed into various forms, and the scope of protection of the present invention should not be limited to the examples and comparative examples detailed below.

The compound of the present invention is suitable for light-emitting elements, display panels, and electronic devices, especially for organic electroluminescent devices. The electronic device of the present invention is a device comprising a layer of at least one organic compound, and the device may also comprise an inorganic material or a layer formed entirely of an inorganic material. The electronic device is preferably an organic electroluminescent device (OLED), an organic integrated circuit (O-IC), an organic field effect transistor (O-FET), an organic thin film transistor (O-TFT), an organic light-emitting transistor (O-LET), an organic solar cell (O-SC), an organic dye-sensitized solar cell (O-DSSC), an organic optical detector, an organic photosensor, an organic field-quenching device (O-FQD), a luminescent electrochemical cell (LEC), an organic laser diode (O-laser), and an organic plasma emitting device. The electronic device is preferably an organic electroluminescent device (OLED).

In order to understand the content of the present invention more clearly, the polycyclic compound containing a triarylamine structure, the preparation method for the compound, and the luminescent characteristics of the device comprising the compound will be explained in detail with reference to examples. Various chemical reactions can be applied to the synthesis method for a compound according to one embodiment of the present invention. However, it should be noted that the synthesis method for the compound according to one embodiment of the present invention is not limited to the synthesis method described below. Unless otherwise specified, the subsequent synthesis is carried out in an anhydrous solvent in a protective gas atmosphere. Solvents and reagents can be purchased from conventional reagent suppliers. The compound of the present invention is prepared by means of Buchwald-Hartwig coupling reaction, Suzuki coupling reaction, or Heck coupling reaction as representative reactions.

### Synthesis of Intermediates

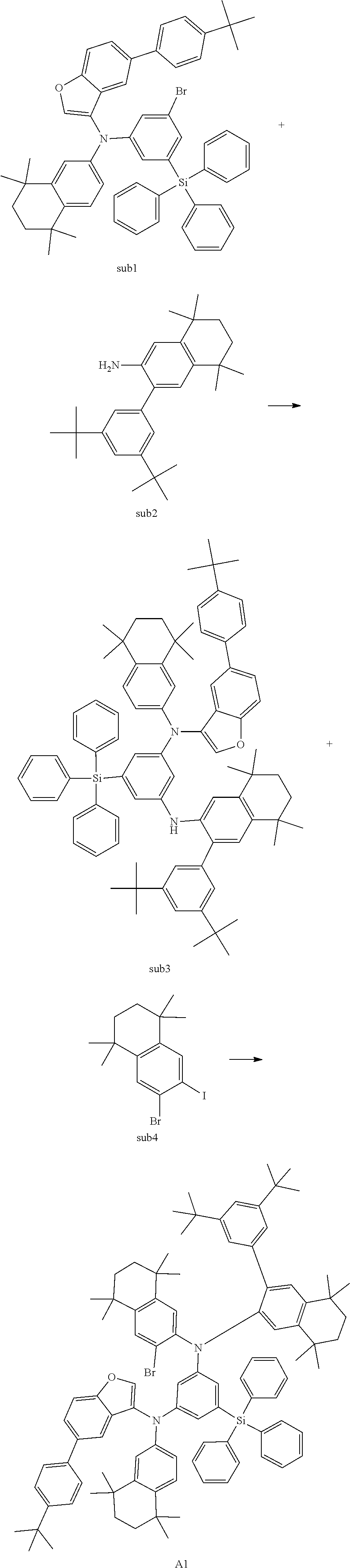

sub1 (86.5 g), sub2 (39.2 g), and sodium tert-butoxide (10.5 g) were added to toluene (500 ml). Under nitrogen protection, bis(dibenzylideneacetone)palladium (2.7 g) and XantPhos (3.4 g) were then added. Subsequently, the reaction system was heated to reflux, maintained for 10 hours, and cooled to room temperature. The reaction mixture was then quenched by adding water and subjected to liquid separation. After the organic phase was filtered, the resulting material was dried over anhydrous sodium sulfate, followed by rotary evaporation to remove the solvent. The crude product was purified by column chromatography to finally obtain 85.8 g of the product sub3, MS (m/z) (M+): 962.

sub3 (85.8 g), sub4 (28.7 g), and sodium tert-butoxide (7.7 g) were added to toluene (500 ml). Under nitrogen protection, bis(dibenzylideneacetone)palladium (2.0 g) and tri-tert-butylphosphine (0.9 g) were then added. Subsequently, the reaction system was heated to reflux, maintained for 10 hours, and cooled to room temperature. The reaction mixture was then quenched by adding water and subjected to liquid separation. The organic phase was filtered, then dried over anhydrous sodium sulfate, and subjected to rotary evaporation to remove the solvent. The crude product was purified by column chromatography to finally obtain 79.3 g of the product A1, MS (m/z) (M+): 1438.

Intermediates A2-A26 were prepared following the above preparation process. No more details will be repeated here.

### Synthesis Example 1

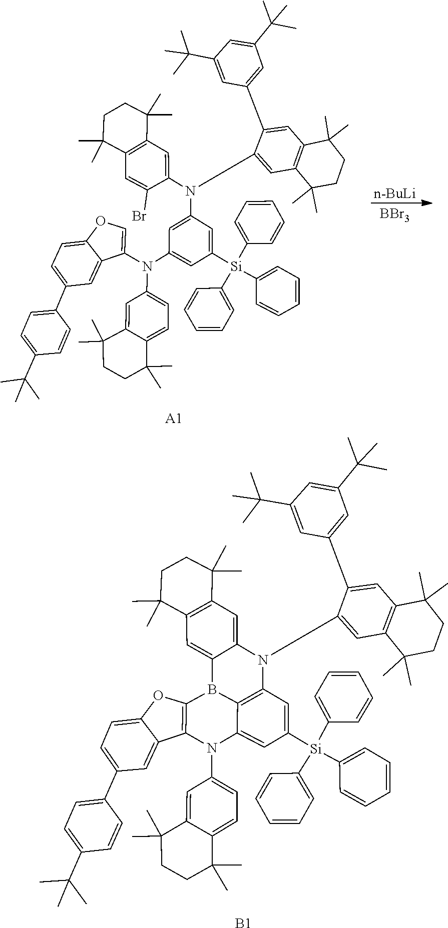

Under nitrogen protection, the system was maintained between −30° C. and −40° C. A n-butyl lithium solution (15.40 mL) was slowly dropwise added to a solution containing Compound A1 (14.38 g) in tert-butyl benzene (100 mL), followed by stirring at 60° C. for 6 hours. Then, after boron tribromide (1.91 mL) was dropwise added at −30° C., the reaction system was stirred at 60° C. for 6 hours. Finally, N,N-diisopropylethylamine (2.78 mL) was added at 0° C., and the reaction system was stirred at room temperature for 2 hours. 150 mL of deionized water was added to the reaction system to quench the residual boron tribromide. The mixture was extracted three times with 200 mL of dichloromethane. The organic layers were combined, concentrated in vacuo, and purified by column chromatography using a mixed eluent of dichloromethane/petroleum ether (1:20). The crude product was recrystallized from n-heptane, acetone, and toluene to finally obtain 0.87 g of the final product B1, MS (m/z) (M+): 1380.

¹H NMR (400 MHz, CDCl₃) δ 8.16 (d, 1H), 7.60-7.52 (m, 4H), 7.49-7.43 (m, 6H), 7.41-7.33 (m, 12H), 7.32 (d, 1H), 7.30 (s, 1H), 7.27 (d, 3H), 7.14 (d, 1H), 7.08 (d, 2H), 7.01-6.95 (m, 3H), 1.54-1.49 (m, 12H), 1.35-1.30 (m, 9H), 1.29-1.25 (m, 18H), 0.91-0.87 (m, 36H).

### Synthesis Example 2

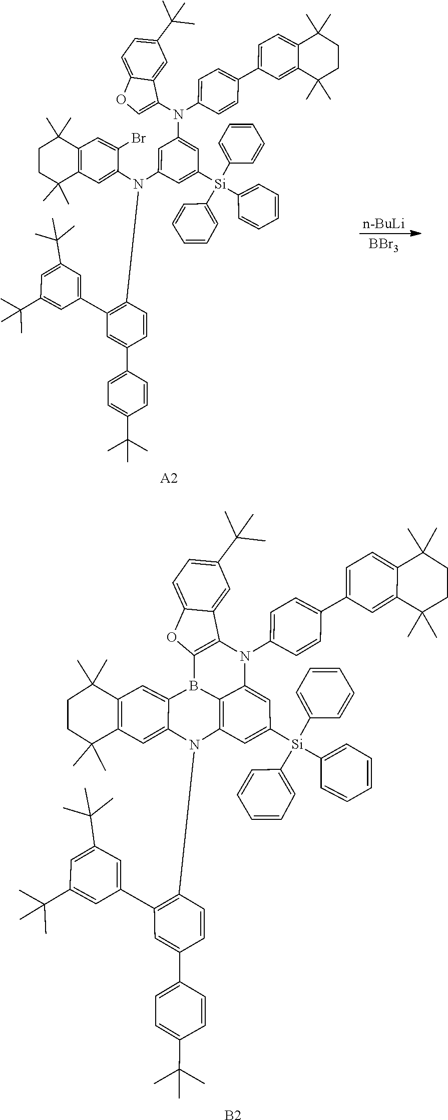

The preparation method was the same as in Synthesis Example 1, except that Compound A1 was replaced by Compound A2 (11.38 g) to finally obtain 0.74 g of the product B2, MS (m/z) (M+): 1413.

¹H NMR (400 MHz, CDCl₃) δ 8.60 (d, 1H), 7.64 (dd, 1H), 7.59-7.52 (m, 5H), 7.52-7.43 (m, 9H), 7.41-7.33 (m, 13H), 7.31 (d, 4H), 7.27 (d, 2H), 7.22 (dd, 1H), 7.08 (s, 1H), 7.00 (d, 2H), 1.74 (t, 8H), 1.32 (s, 9H), 1.20 (s, 9H), 1.16-1.10 (m, 18H), 0.99-0.94 (m, 24H).

### Synthesis Example 3

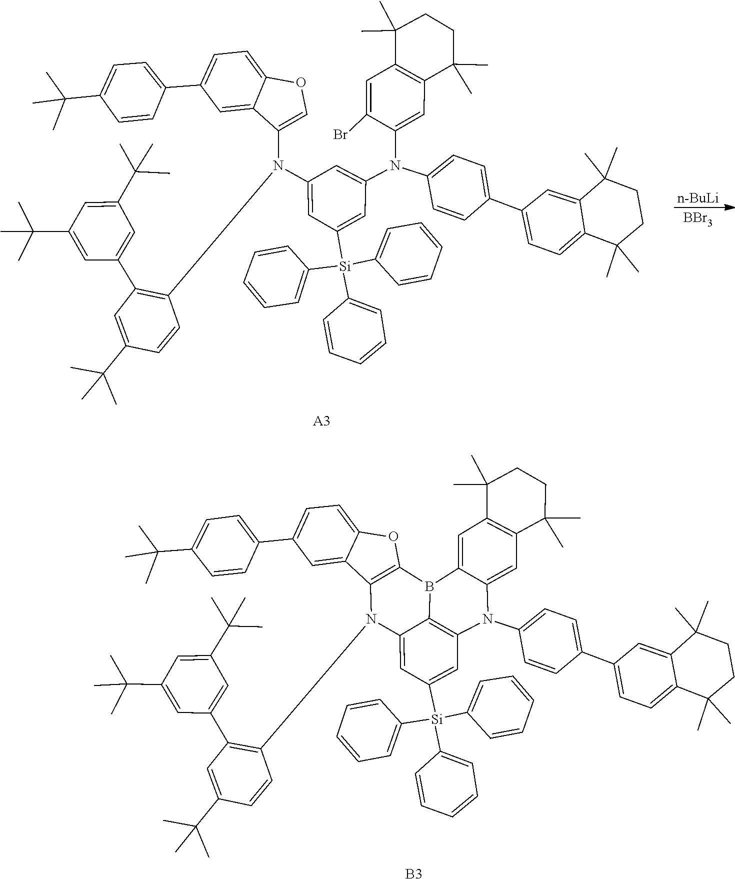

The preparation method was the same as in Synthesis Example 1, except that Compound A1 was replaced by Compound A3 (14.62 g) to finally obtain 0.67 g of the product B3, MS (m/z) (M+): 1391.

¹H NMR (400 MHz, CDCl₃) δ 8.16 (d, 1H), 7.59-7.51 (m, 6H), 7.45 (ddd, 7H), 7.41-7.33 (m, 13H), 7.31 (d, 4H), 7.27 (s, 2H), 7.25-7.16 (m, 2H), 7.08 (s, 1H), 7.00 (d, 2H), 6.67 (dd, 1H), 1.61-1.58 (m, 8H), 1.39-1.33 (m, 9H), 1.29 (s, 9H), 1.20-1.16 (m, 18H), 0.92-0.86 (m, 24H).

### Synthesis Example 4

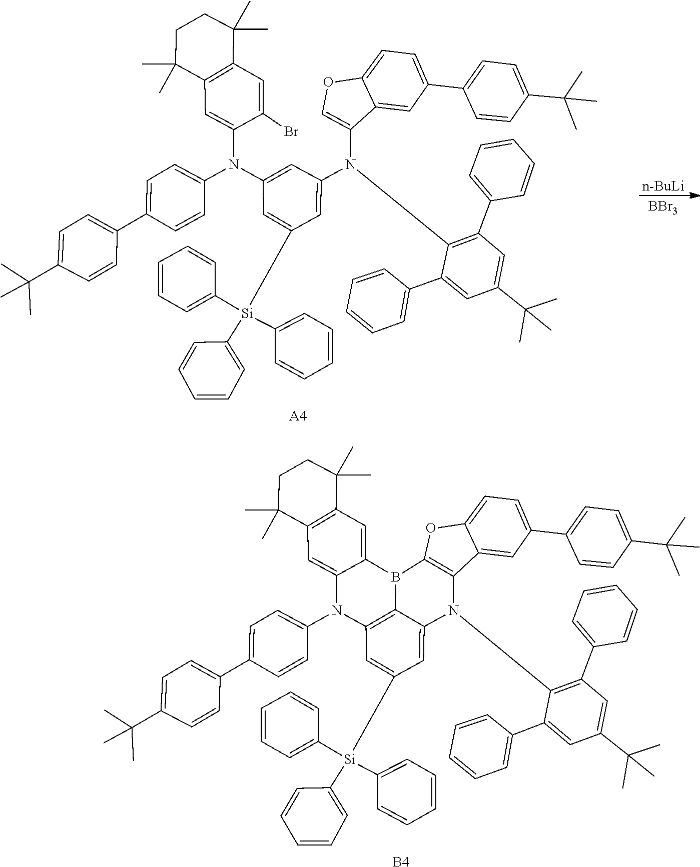

The preparation method was the same as in Synthesis Example 1, except that Compound A1 was replaced by Compound A4 (13.72 g) to finally obtain 0.80 g of the product B4, MS (m/z) (M+): 1344.

¹H NMR (400 MHz, CDCl₃) δ 8.16 (d, 1H), 7.60-7.51 (m, 9H), 7.49-7.40 (m, 10H), 7.40-7.28 (m, 20H), 7.11-7.04 (m, 5H), 7.00 (s, 1H), 1.55-1.50 (m, 4H), 1.26-1.18 (m, 27H), 0.90-0.86 (m, 12H).

### Synthesis Example 5

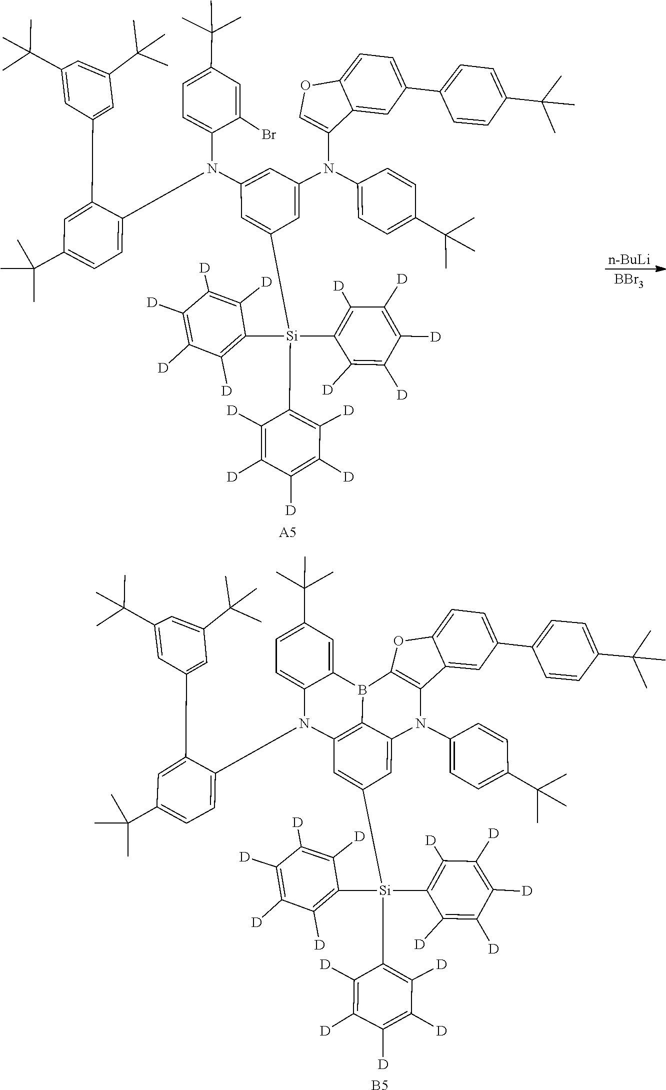

The preparation method was the same as in Synthesis Example 1, except that Compound A1 was replaced by Compound A5 (11.30 g) to finally obtain 0.55 g of the product B5, MS (m/z) (M+): 1222.

¹H NMR (400 MHz, CDCl₃) δ 8.71 (s, 1H), 7.65 (s, 1H), 7.57 (dd, 4H), 7.46 (d, 1H), 7.40 (d, 1H), 7.33 (d, 3H), 7.25-7.17 (m, 4H), 6.91 (s, 1H), 6.72 (d, 2H), 6.64 (d, 2H), 6.57 (d, 1H), 6.11 (s, 1H), 1.46-1.39 (m, 27H), 1.34 (s, 9H), 0.88-0.80 (m, 18H).

### Synthesis Example 6

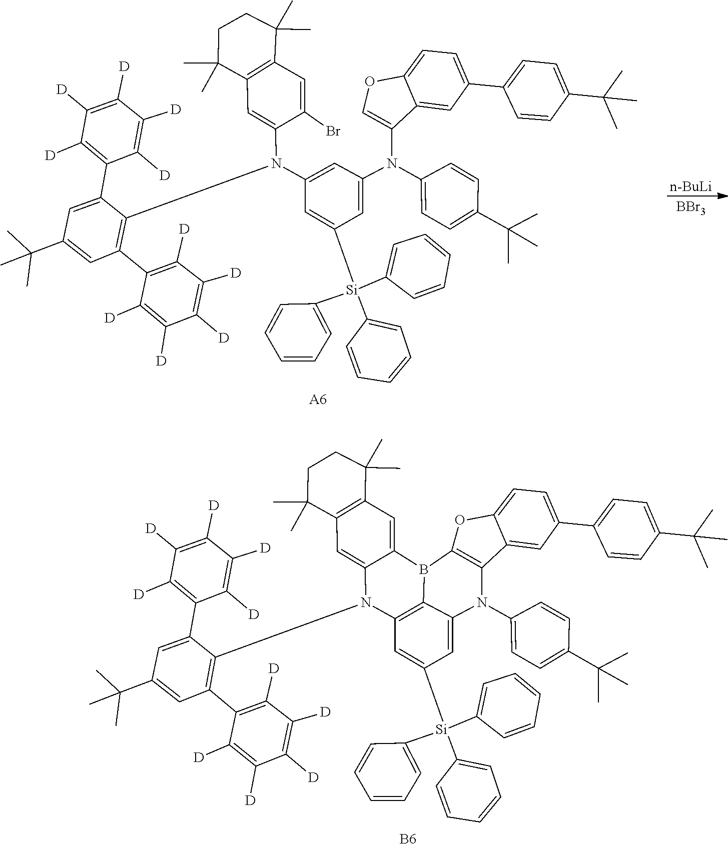

The preparation method was the same as in Synthesis Example 1, except that Compound A1 was replaced by Compound A6 (13.07 g) to finally obtain 0.60 g of the product B6, MS (m/z) (M+): 1234.

¹H NMR (400 MHz, CDCl₃) δ=8.22 (dd, 1H), 7.64-7.56 (m, 8H), 7.52-7.48 (m, 2H), 7.46 (s, 1H), 7.44 (s, 2H), 7.40 (d, 1H), 7.38-7.33 (m, 10H), 7.27 (d, 1H), 7.26-7.23 (m, 3H), 7.11 (s, 1H), 7.04 (d, 1H), 7.02 (d, 1H), 1.84-1.74 (m, 2H), 1.68-1.58 (m, 2H), 1.08-1.02 (m, 27H), 0.95-0.89 (m, 12H).

### Synthesis Example 7

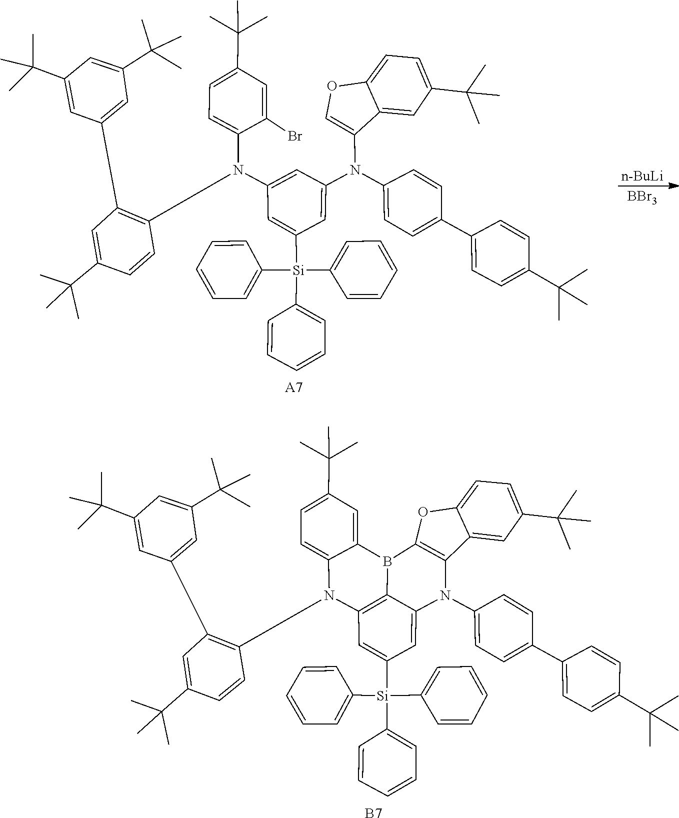

The preparation method was the same as in Synthesis Example 1, except that Compound A1 was replaced by Compound A7 (12.78 g) to finally obtain 0.65 g of the product B7, MS (m/z) (M+): 1207.

¹H NMR (400 MHz, CDCl₃) δ 7.60-7.49 (m, 6H), 7.49-7.41 (m, 7H), 7.41-7.33 (m, 12H), 7.32 (s, 4H), 7.27 (d, 2H), 7.25-7.17 (m, 4H), 7.10 (dd, 1H), 7.04 (d, 1H), 0.94-0.84 (m, 54H).

### Synthesis Example 8

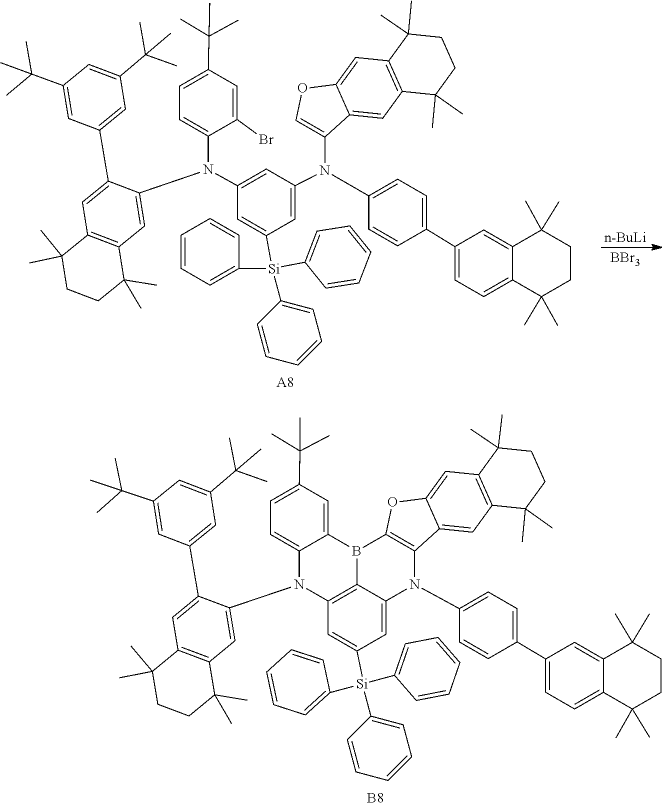

The preparation method was the same as in Synthesis Example 1, except that Compound A1 was replaced by Compound A8 (14.40 g) to finally obtain 0.74 g of the product B8, MS (m/z) (M+): 1456.

¹H NMR (400 MHz, CDCl₃) δ 7.57-7.51 (m, 3H), 7.45 (td, 7H), 7.37 (q, 10H), 7.35-7.29 (m, 5H), 7.27 (s, 3H), 7.20 (d, 1H), 7.10 (dd, 1H), 7.04 (d, 1H), 7.00 (d, 1H), 6.96 (s, 1H), 6.67 (dd, 1H), 1.56-1.51 (m, 12H), 1.35 (s, 9H), 1.27-1.21 (m, 18H), 0.95-0.82 (m, 36H).

### Synthesis Example 9

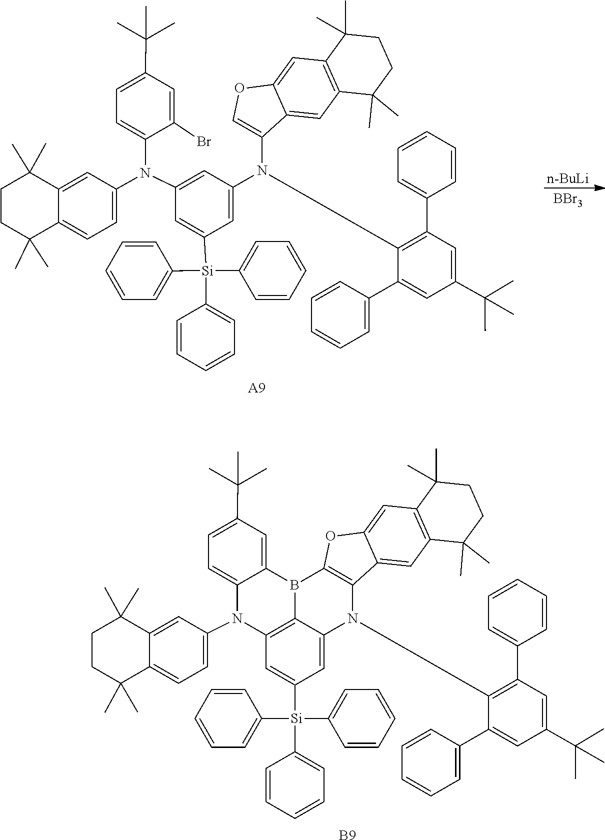

The preparation method was the same as in Synthesis Example 1, except that Compound A1 was replaced by Compound A9 (12.74 g) to finally obtain 0.75 g of the product B9, MS (m/z) (M+): 1203.

¹H NMR (400 MHz, CDCl₃) δ 7.53 (s, 2H), 7.50-7.40 (m, 11H), 7.40-7.29 (m, 14H), 7.20 (d, 1H), 7.14 (d, 1H), 7.12-7.06 (m, 6H), 7.04 (d, 1H), 6.97 (dd, 1H), 1.43-1.40 (m, 8H), 1.37-1.34 (m, 18H), 0.89-0.81 (m, 24H).

### Synthesis Example 10

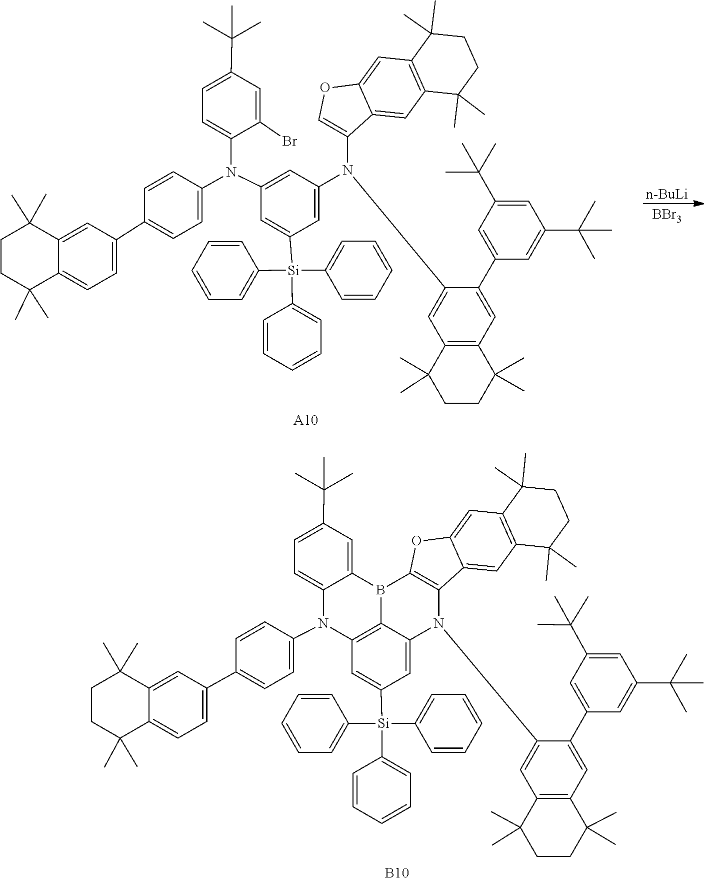

The preparation method was the same as in Synthesis Example 1, except that Compound A1 was replaced by Compound A10 (14.40 g) to finally obtain 0.81 g of the product B10, MS (m/z) (M+): 1477.

¹H NMR (400 MHz, CDCl₃) δ 7.57-7.51 (m, 3H), 7.50-7.42 (m, 7H), 7.41-7.35 (m, 10H), 7.35-7.29 (m, 5H), 7.27 (s, 3H), 7.20 (d, 1H), 7.10 (dd, 1H), 7.04 (d, 1H), 7.00 (d, 1H), 6.96 (s, 1H), 6.67 (dd, 1H), 1.44-1.40 (m, 12H), 1.25 (s, 9H), 1.11-1.06 (m, 18H), 0.91-0.86 (m, 36H).

### Synthesis Example 11

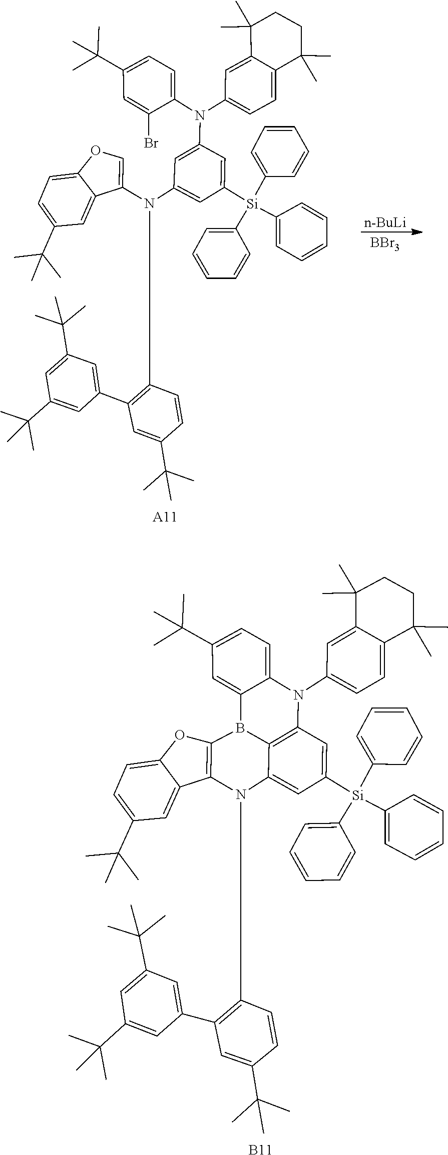

The preparation method was the same as in Synthesis Example 1, except that Compound A1 was replaced by Compound A11 (12.56 g) to finally obtain 0.58 g of the product B11, MS (m/z) (M+): 1185.

¹H NMR (400 MHz, CDCl₃) δ 7.54 (t, 1H), 7.51 (d, 1H), 7.45 (ddd, 7H), 7.41-7.33 (m, 12H), 7.27 (d, 2H), 7.25-7.17 (m, 4H), 7.14 (d, 1H), 7.12-7.06 (m, 2H), 7.04 (d, 1H), 6.97 (dd, 1H), 1.54-1.50 (s, 4H), 1.27-1.22 (m, 18H), 1.18 (s, 9H), 1.15-1.10 (m, 18H), 0.98-0.92 (m, 12H).

### Synthesis Example 12

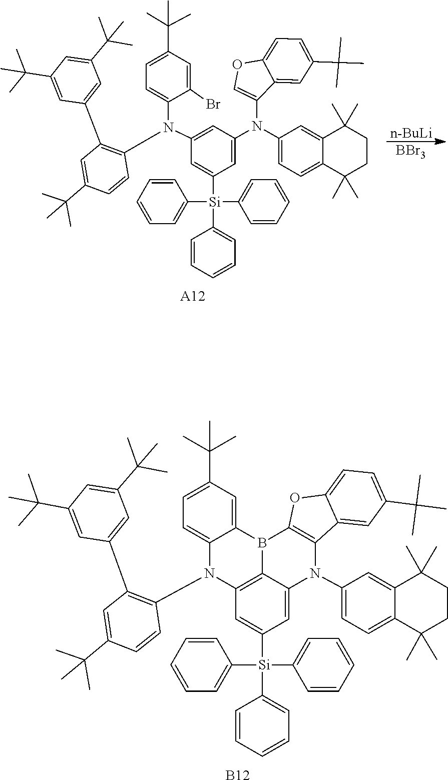

The preparation method was the same as in Synthesis Example 1, except that Compound A1 was replaced by Compound A12 (12.56 g) to finally obtain 0.56 g of the product B12, MS (m/z) (M+): 1185.

¹H NMR (400 MHz, CDCl₃) δ 8.70 (s, 1H), 7.53 (d, 2H), 7.36 (d, 9H), 7.30 (d, 4H), 7.20 (t, 9H), 7.07 (d, 1H), 6.91 (d, 1H), 6.72 (d, 2H), 6.59 (br, 2H), 6.03 (s, 1H), 1.73 (dd, 4H), 1.42 (dd, 18H), 1.37 (d, 6H), 1.12 (s, 12H), 0.84-0.80 (m, 21H).

### Synthesis Example 13

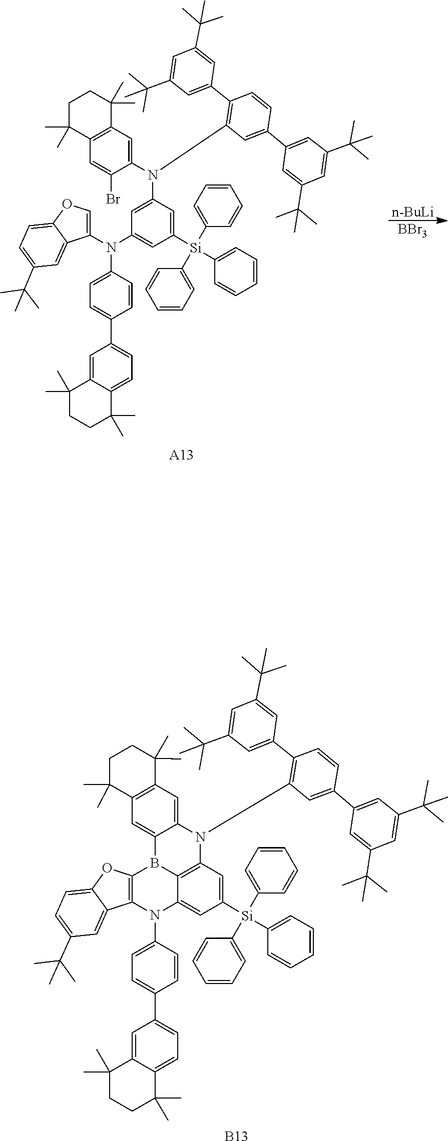

The preparation method was the same as in Synthesis Example 1, except that Compound A1 was replaced by Compound A13 (15.19 g) to finally obtain 0.85 g of the product B13, MS (m/z) (M+): 1448.

¹H NMR (400 MHz, CDCl₃) δ 7.71 (d, 1H), 7.54 (dd, 4H), 7.51 (d, 1H), 7.49-7.42 (m, 6H), 7.41-7.29 (m, 15H), 7.29-7.18 (m, 7H), 7.08 (s, 1H), 7.00 (s, 2H), 6.67 (dd, 1H), 1.44-1.40 (m, 8H), 1.27 (s, 9H), 1.02-0.88 (m, 60H).

### Synthesis Example 14

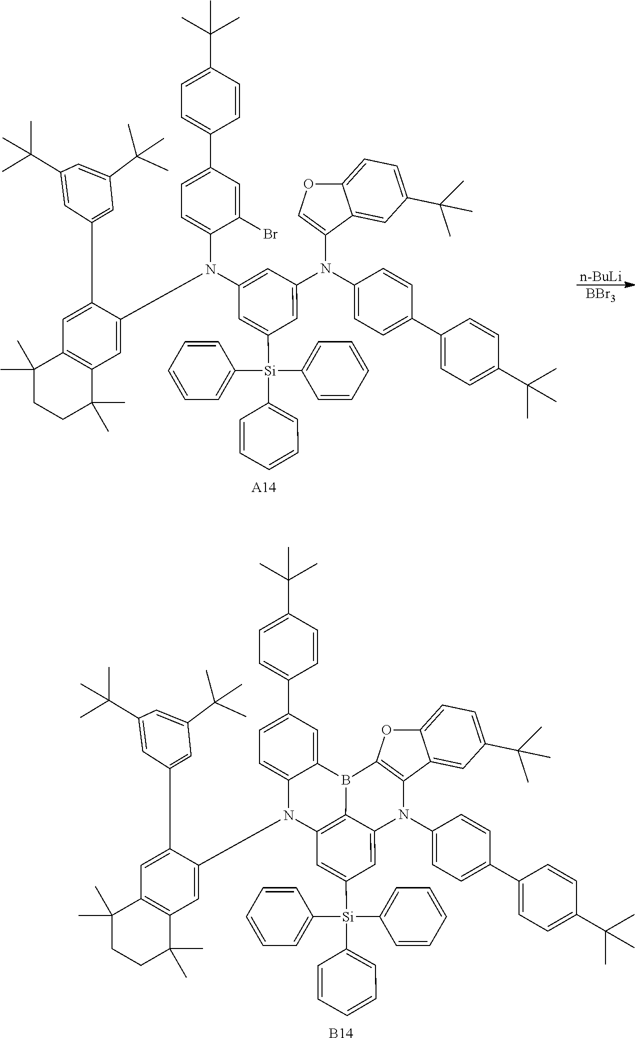

The preparation method was the same as in Synthesis Example 1, except that Compound A1 was replaced by Compound A14 (14.08 g) to finally obtain 0.74 g of the product B14, MS (m/z) (M+): 1337.

¹H NMR (400 MHz, CDCl₃) δ 7.60 (d, 1H), 7.59-7.50 (m, 10H), 7.49-7.42 (m, 6H), 7.41-7.33 (m, 12H), 7.31 (d, 7H), 7.27 (s, 3H), 7.22 (dd, 1H), 1.64-1.60 (m, 4H), 1.37 (s, 9H), 1.25-1.17 (m, 36H), 0.89-0.82 (m, 12H).

### Synthesis Example 15

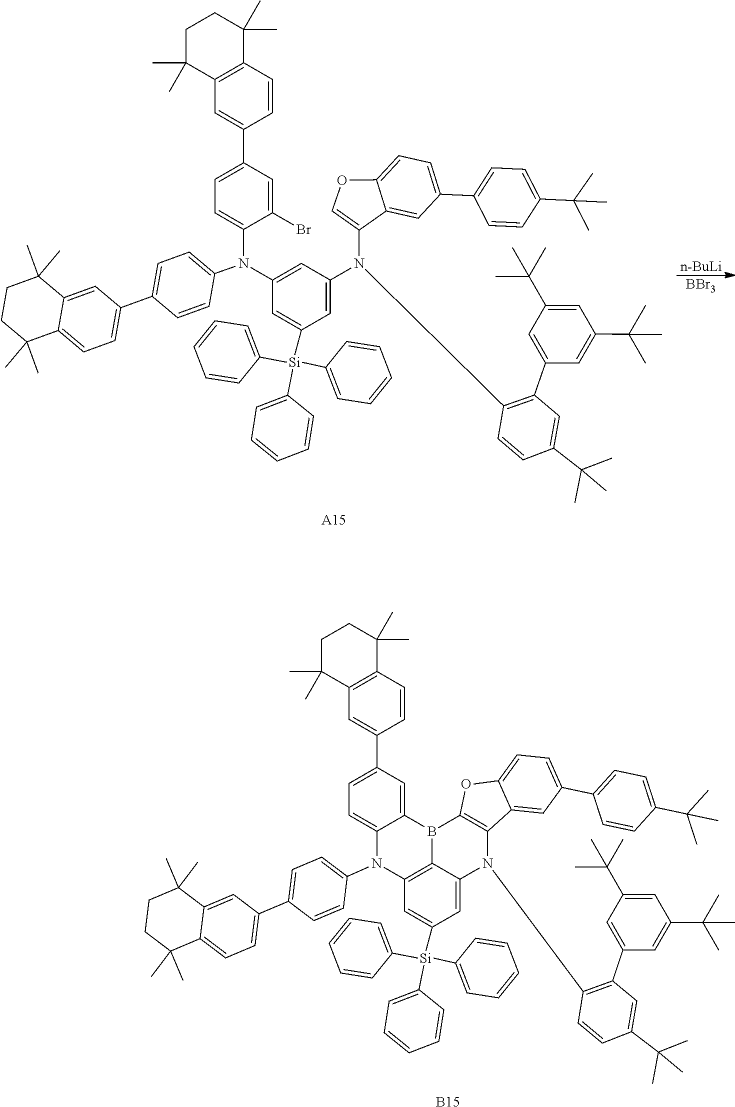

The preparation method was the same as in Synthesis Example 1, except that Compound A1 was replaced by Compound A15 (15.39 g) to finally obtain 0.75 g of the product B15, MS (m/z) (M+): 1467.

¹H NMR (400 MHz, CDCl₃) δ 8.16 (d, 1H), 7.62-7.51 (m, 8H), 7.50-7.41 (m, 7H), 7.41-7.33 (m, 14H), 7.31 (d, 5H), 7.27 (d, 2H), 7.25-7.17 (m, 2H), 7.00 (d, 2H), 6.67 (dd, 2H), 1.45-1.40 (t, 8H), 1.30 (s, 9H), 1.22 (s, 9H), 1.15-1.10 (m, 18H), 0.92-0.84 (m, 24H).

### Synthesis Example 16

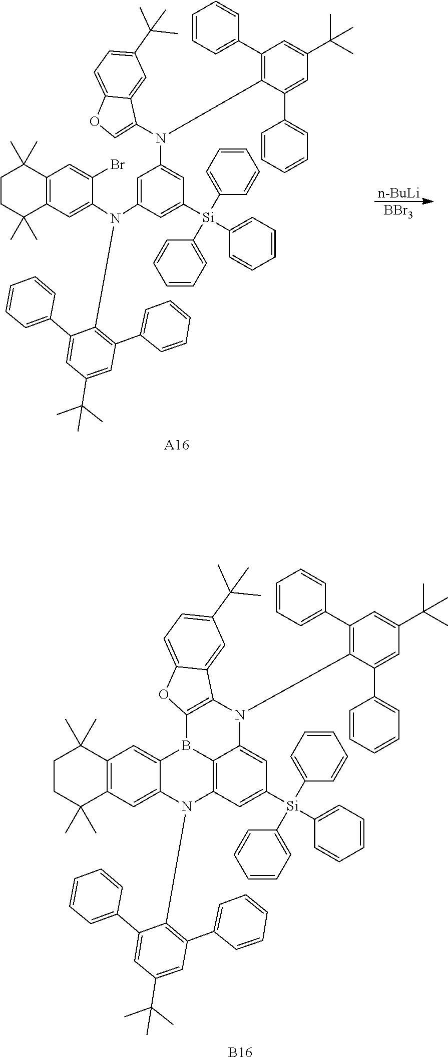

The preparation method was the same as in Synthesis Example 1, except that Compound A1 was replaced by Compound A16 (13.71 g) to finally obtain 0.64 g of the product B16, MS (m/z) (M+): 1301.

¹H NMR (400 MHz, CDCl₃) δ 7.55-7.49 (m, 5H), 7.49-7.40 (m, 14H), 7.40-7.31 (m, 16H), 7.22 (dd, 1H), 7.11-7.04 (m, 9H), 7.00 (s, 1H), 1.44-1.40 (m, 4H), 1.16-1.08 (m, 27H), 1.00-0.94 (m, 12H).

### Synthesis Example 17

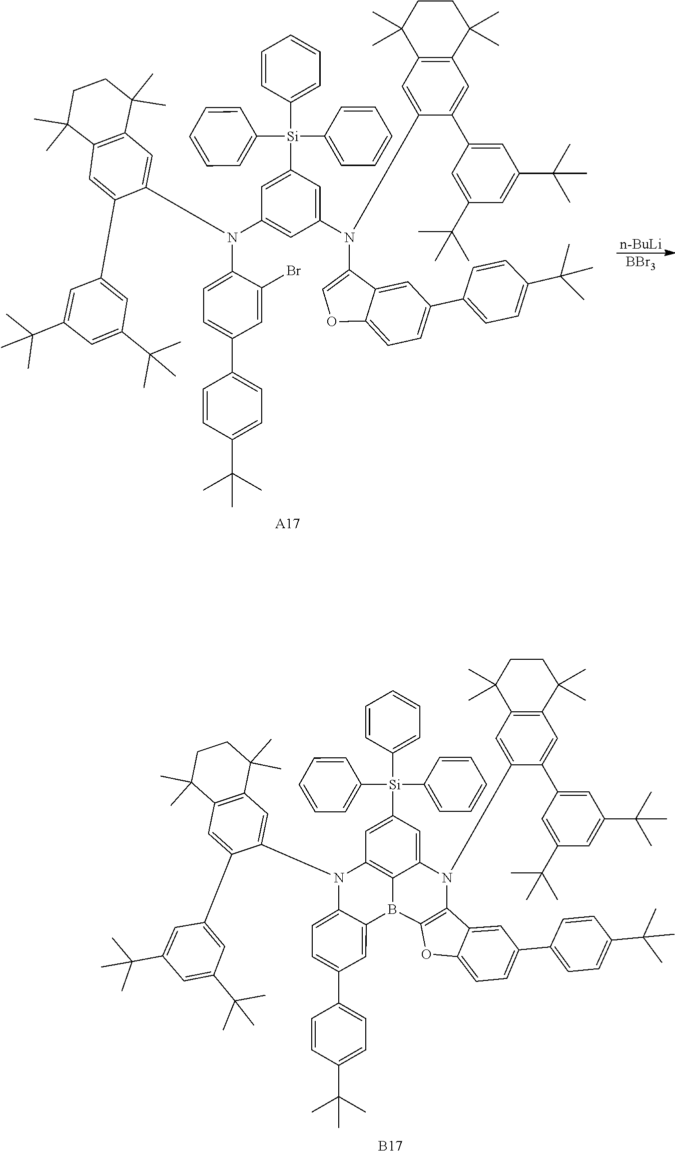

The preparation method was the same as in Synthesis Example 1, except that Compound A1 was replaced by Compound A17 (16.51 g) to finally obtain 0.66 g of the product B17, MS (m/z) (M+): 1579.

¹H NMR (400 MHz, CDCl₃) δ 8.16 (d, 1H), 7.61-7.52 (m, 9H), 7.49-7.43 (m, 6H), 7.41-7.33 (m, 12H), 7.33-7.24 (m, 11H), 6.96 (s, 2H), 1.42-1.39 (m, 8H), 1.23-1.19 (m, 18H), 1.15-1.02 (m, 36H), 0.98-0.90 (m, 24H).

### Synthesis Example 18

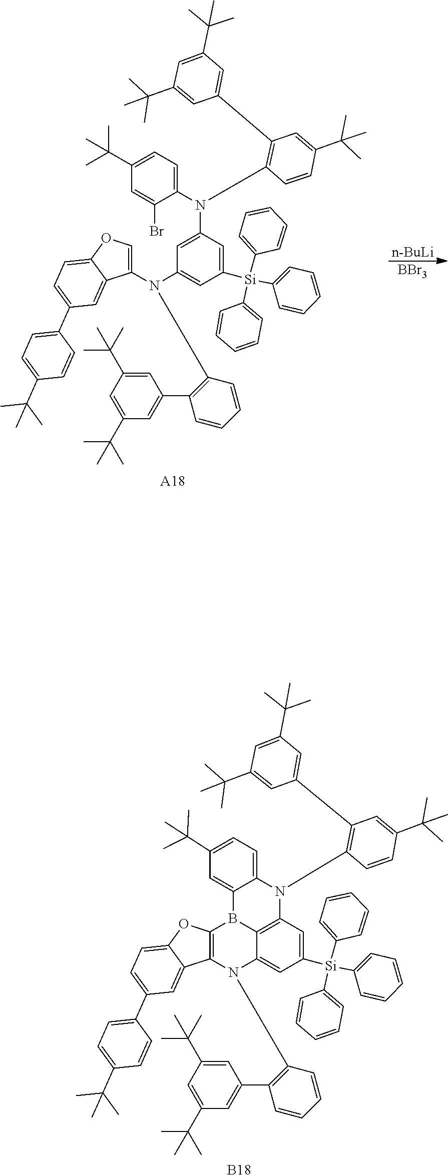

The preparation method was the same as in Synthesis Example 1, except that Compound A1 was replaced by Compound A18 (14.67 g) to finally obtain 0.92 g of the product B18, MS (m/z) (M+): 1395.

¹H NMR (400 MHz, CDCl₃) δ 8.16 (d, 1H), 7.59-7.52 (m, 5H), 7.45 (ddd, 8H), 7.41-7.33 (m, 12H), 7.32 (s, 2H), 7.27 (d, 4H), 7.25-7.16 (m, 5H), 7.13-7.01 (m, 2H), 1.27-1.20 (m, 18H), 1.15 (s, 9H), 1.10 (s, 9H), 0.95-0.87 (m, 36H).

### Synthesis Example 19

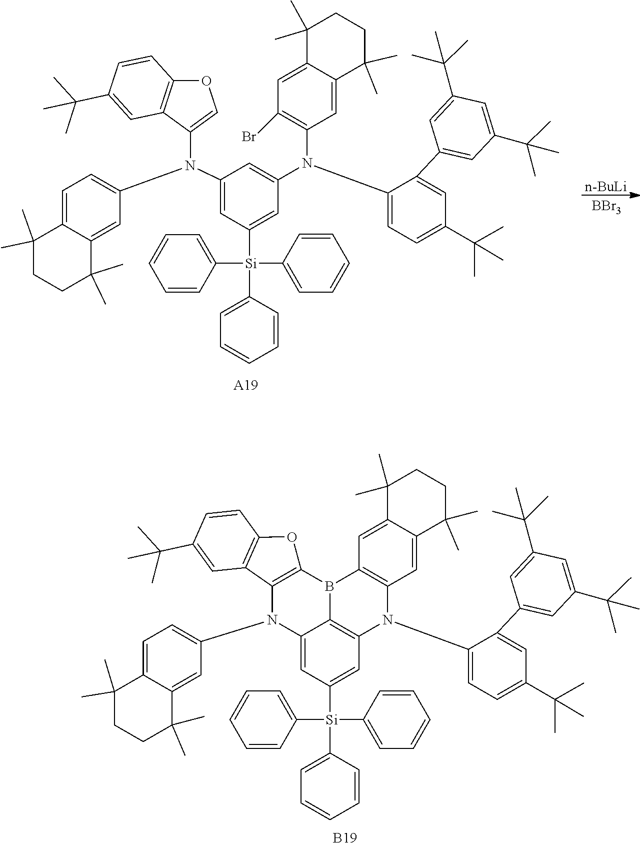

The preparation method was the same as in Synthesis Example 1, except that Compound A1 was replaced by Compound A19 (13.11 g) to finally obtain 0.63 g of the product B19, MS (m/z) (M+): 1239.

¹H NMR (400 MHz, CDCl₃) δ 8.50 (br, 1H), 7.54 (d, 2H), 7.34 (d, 9H), 7.28 (d, 4H), 7.18 (t, 9H), 6.95 (d, 1H), 6.76 (d, 2H), 6.56 (br, 2H), 6.04 (s, 1H), 1.70 (dd, 9H), 1.56 (s, 4H), 1.44 (d, 12H), 1.11 (s, 18H), 0.86-0.80 (m, 27H).

### Synthesis Example 20

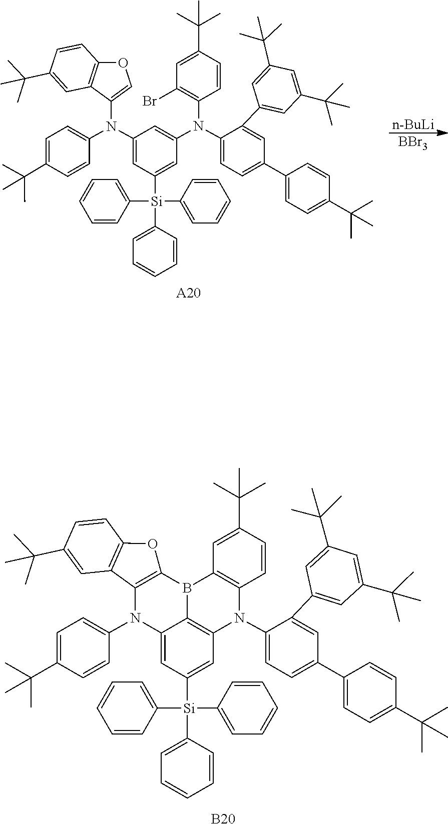

The preparation method was the same as in Synthesis Example 1, except that Compound A1 was replaced by Compound A20 (12.79 g) to finally obtain 0.74 g of the product B20, MS (m/z) (M+): 1207.

¹H NMR (400 MHz, CDCl₃) δ 8.72 (d, 1H), 7.74 (d, 1H), 7.70 (s, 1H), 7.68 (d, 2H), 7.57 (s, 2H), 7.55 (d, 2H), 7.40-7.34 (m, 11H), 7.28 (s, 1H), 7.26 (s, 1H), 7.25 (d, 2H), 7.18 (t, 6H), 6.91 (s, 1H), 6.72 (d, 2H), 6.64 (s, 2H), 6.57 (s, 1H), 6.04 (d, 1H), 1.42 (d, 27H), 1.10 (s, 9H), 0.84 (s, 18H).

### Synthesis Example 21

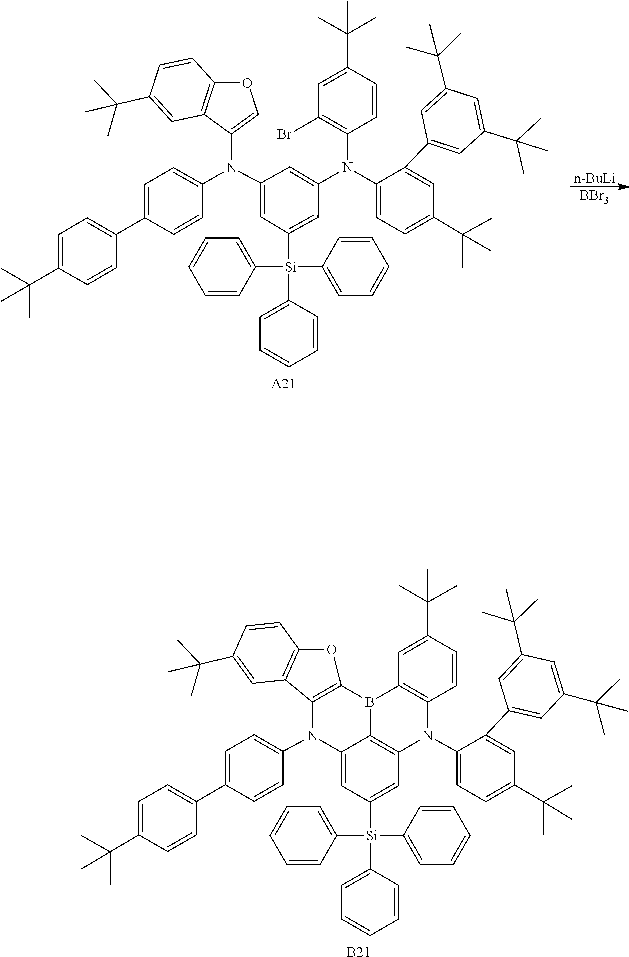

The preparation method was the same as in Synthesis Example 1, except that Compound A1 was replaced by Compound A21 (12.78 g) to finally obtain 0.71 g of the product B21, MS (m/z) (M+): 1207.

¹H NMR (400 MHz, CDCl₃) δ 8.71 (s, 1H), 7.73 (t, 2H), 7.59 (d, 4H), 7.56 (d, 2H), 7.46 (t, 2H), 7.40 (dd, 9H), 7.33 (br, 2H), 7.31 (s, 1H), 7.30-7.27 (m, 2H), 7.23 (s, 2H), 7.21 (s, 3H), 7.19 (s, 1H), 6.92 (s, 1H), 6.75 (d, 2H), 6.62 (br, 2H), 6.12 (s, 1H), 1.45 (s, 9H), 1.43 (d, 18H), 1.10 (s, 9H), 0.86 (s, 18H).

### Synthesis Example 22

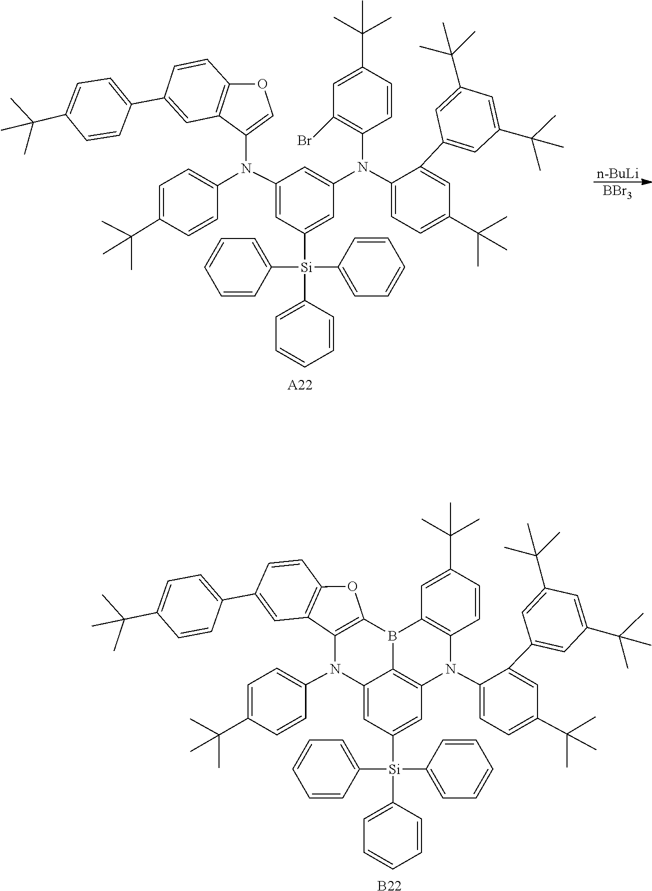

The preparation method was the same as in Synthesis Example 1, except that Compound A1 was replaced by Compound A22 (12.78 g) to finally obtain 0.69 g of the product B22, MS (m/z) (M+): 1207.

¹H NMR (400 MHz, CDCl₃) δ 8.74 (s, 1H), 7.69 (s, 1H), 7.63 (d, 1H), 7.59 (d, 3H), 7.50 (d, 1H), 7.44-7.40 (m, 8H), 7.34-7.29 (m, 6H), 7.24-7.18 (m, 9H), 6.94 (s, 1H), 6.76 (d, 2H), 6.68 (br, 2H), 6.60 (br, 1H), 6.15 (s, 1H), 1.48 (s, 9H), 1.46 (d, 18H), 1.36 (s, 9H), 0.89 (s, 18H).

### Synthesis Example 23

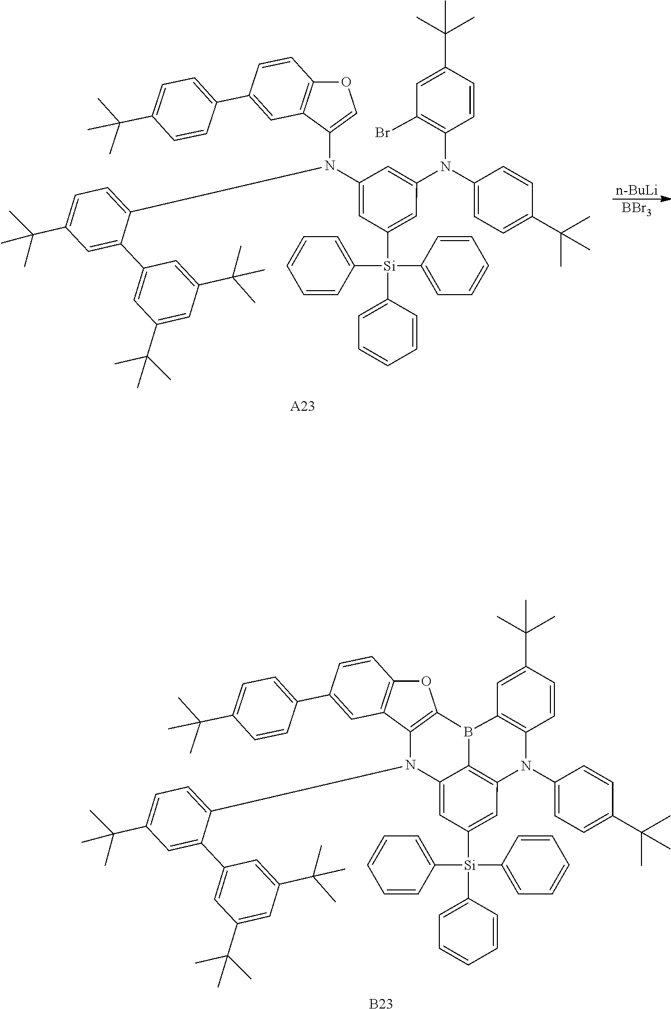

The preparation method was the same as in Synthesis Example 1, except that Compound A1 was replaced by Compound A23 (12.78 g) to finally obtain 0.62 g of the product B23, MS (m/z) (M+): 1207.

¹H NMR (400 MHz, CDCl₃) δ 8.78 (d, 1H), 7.63 (d, 1H), 7.57 (d, 2H), 7.54-7.47 (m, 3H), 7.43 (d, 1H), 7.42-7.36 (m, 10H), 7.32 (dt, 5H), 7.21 (t, 7H), 6.96 (s, 1H), 6.89 (s, 1H), 6.63 (d, 2H), 6.58 (d, 1H), 6.32 (s, 1H), 6.23 (s, 1H), 1.50 (s, 9H), 1.45 (s, 9H), 1.35 (d, 18H), 0.75 (s, 18H).

### Synthesis Example 24

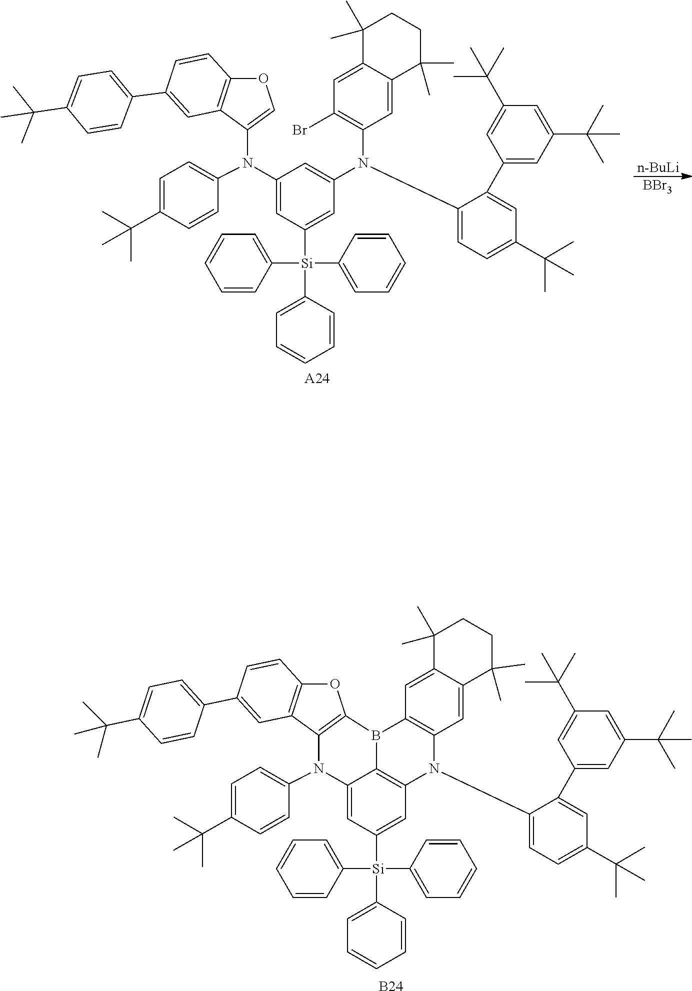

The preparation method was the same as in Synthesis Example 1, except that Compound A1 was replaced by Compound A24 (13.33 g) to finally obtain 0.58 g of the product B24, MS (m/z) (M+): 1261.

¹H NMR (400 MHz, CDCl₃) δ 8.78 (d, 1H), 7.63 (d, 1H), 7.57 (d, 2H), 7.54-7.47 (m, 3H), 7.43 (d, 1H), 7.42-7.36 (m, 10H), 7.32 (dt, 5H), 7.21 (t, 7H), 6.96 (s, 1H), 6.89 (s, 1H), 6.63 (d, 2H), 6.58 (d, 1H), 6.32 (s, 1H), 6.23 (s, 1H), 1.50 (s, 9H), 1.45 (s, 9H), 1.35 (d, 18H), 0.75 (s, 18H).

### Synthesis Example 25

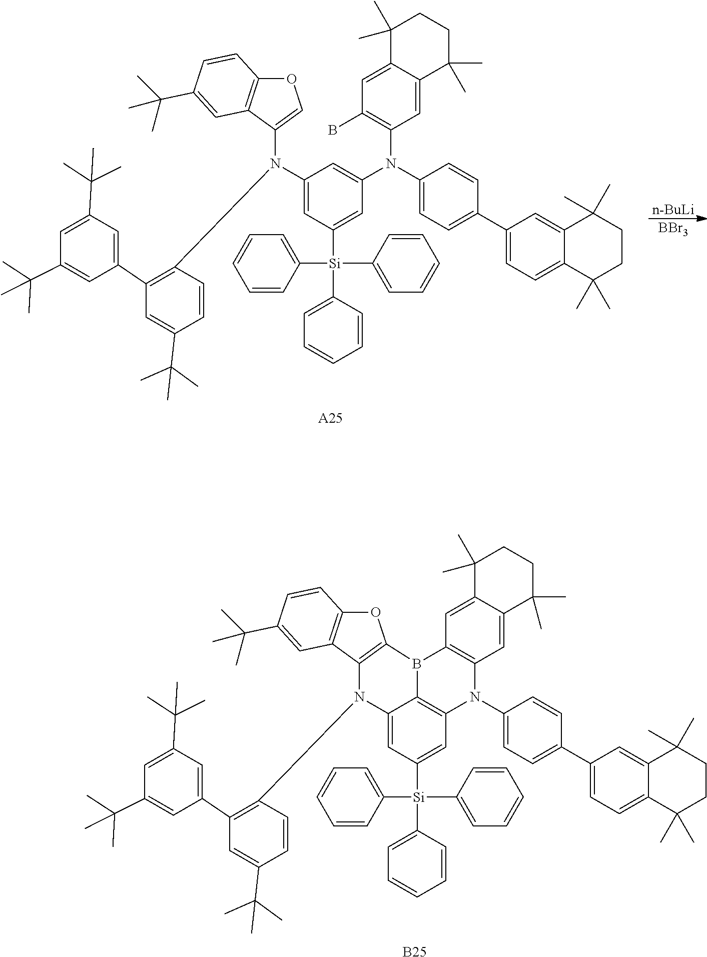

The preparation method was the same as in Synthesis Example 1, except that Compound A1 was replaced by Compound A25 (13.85 g) to finally obtain 0.60 g of the product B25, MS (m/z) (M+): 1315.

¹H NMR (400 MHz, CDCl₃) δ 8.70 (s, 1H), 7.74 (d, 2H), 7.64 (s, 1H), 7.61 (d, 1H), 7.56 (d, 1H), 7.48 (t, 3H), 7.44 (s, 1H), 7.42 (d, 3H), 7.39 (d, 4H), 7.37 (d, 1H), 7.32 (s, 1H), 7.30 (s, 2H), 7.28 (s, 1H), 7.21 (t, 7H), 6.91 (d, 2H), 6.64 (d, 2H), 6.55 (s, 1H), 6.37 (s, 1H), 6.15 (d, 1H), 1.79 (s, 4H), 1.71 (d, 4H), 1.50 (d, 12H), 1.46 (d, 9H), 1.38 (s, 6H), 1.21 (s, 9H), 1.08 (d, 6H), 0.79 (s, 18H).

### Synthesis Example 26

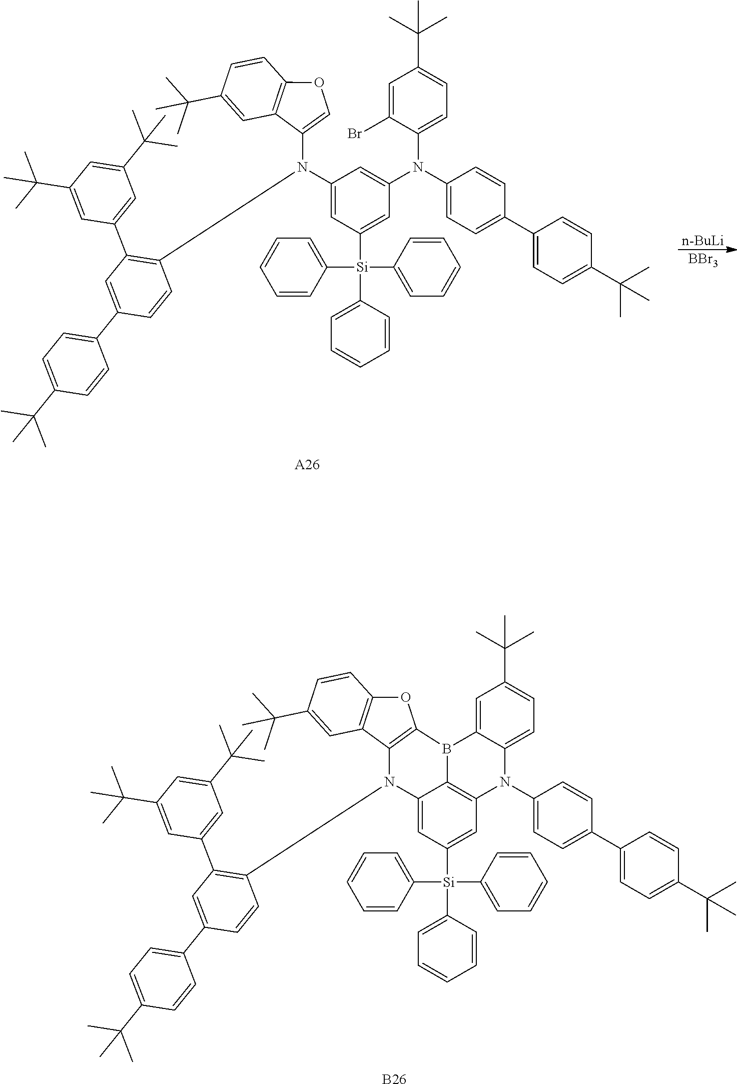

The preparation method was the same as in Synthesis Example 1, except that Compound A1 was replaced by Compound A26 (13.55 g) to finally obtain 0.58 g of the product B26, MS (m/z) (M+): 1283.

¹H NMR (400 MHz, CDCl₃) δ 8.78 (d, 1H), 7.79 (d, 1H), 7.71 (d, 3H), 7.65 (s, 3H), 7.59 (d, 5H), 7.53 (d, 4H), 7.45 (d, 3H), 7.41 (s, 3H), 7.39 (d, 3H), 7.24 (s, 2H), 7.20 (s, 2H), 7.18 (s, 3H), 7.16 (s, 1H), 6.96 (s, 1H), 6.91 (s, 1H), 6.65 (d, 2H), 6.38 (s, 1H), 6.25 (d, 1H), 1.45 (s, 9H), 1.44 (s, 9H), 1.41 (s, 9H), 1.17 (s, 9H), 0.77 (s, 18H).

### Comparative Examples

The following provided some compounds that had been experimented during research, and the specific structural formulas thereof were:

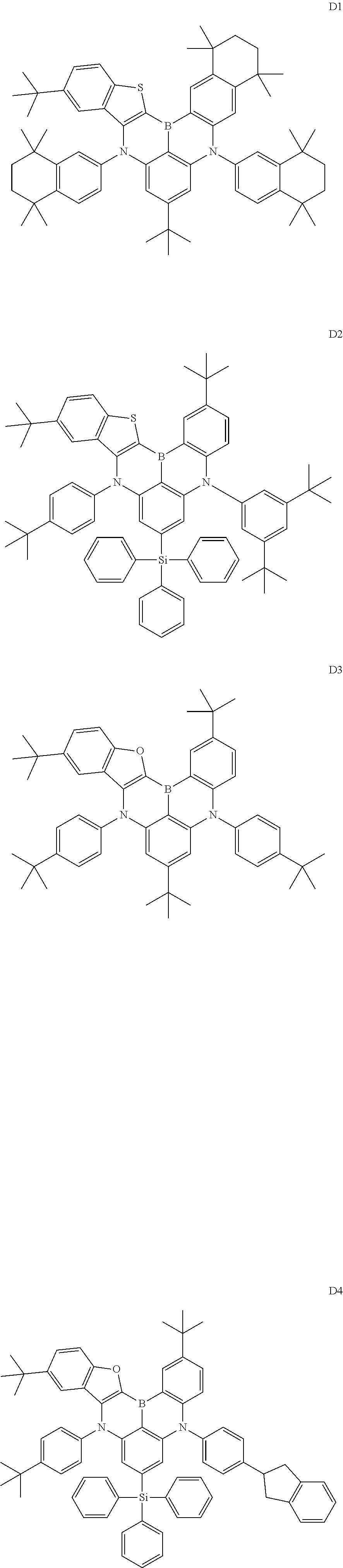

### Evaluation of Performance of Compounds

From the calculation of the vibrational relaxation energy generated during molecular excitation and emission processes (reorganization energy λ of the excited state, in kJ/mol), the impact of the introduction of the triphenylsilyl and benzofuranyl groups into the compound provided in the present invention on the vibrational relaxation of the compound can be seen. The smaller the reorganization energy of the excited state, the smaller the vibrational relaxation during the excitation process, and the narrower the luminescence spectrum thereof. The acquisition method was as follows: Using ORCA 6.0.1 software, based on a density functional theory (DFT) calculation method (the basis set level was set as: b3lyp-d3/6-31G(d), the charge number was 0), geometry optimization and vibration analysis (Opt+freq) of the ground-state structure of the molecule were performed; based on a time-dependent density functional theory (TD-DFT) calculation method (the basis set level was set as: b3lyp-d3/6-31G(d), the charge number was 0), geometry optimization and vibration analysis (Opt+freq) of the first singlet excited-state (S1) structure of the molecule are performed; none of the calculated structures had an imaginary frequency; subsequently, using dushin software, energy decomposition was performed based on the molecular vibrational modes under the ground state of the molecule and the first singlet excited state of the molecule; and based on the Huang-Rhys factors and wavenumbers obtained from the energy decomposition, the contributions of these vibrational states to the reorganization energy were summed, and the excited-state reorganization energy λ (kJ/mol) of the compound provided by the present invention during the fluorescence emission process was calculated.

On the other hand, since Dexter energy transfer can lead to a decrease in device efficiency, the number of alkyl substituents was increased to increase the intermolecular spacing, thereby reducing the probability of Dexter energy transfer. The acquisition method was as follows: the intermolecular spacing was measured by single-crystal diffraction XRD.

Table 1 lists excited-state reorganization energy and intermolecular spacing data of various compounds.

TABLE 1

| Compound | λ (kJ/mol) | Intermolecular spacing (Å) |
|---|---|---|
| B1 | 14.77 | 13.2 |
| B2 | 14.61 | 12.86 |
| B3 | 13.04 | 11.41 |
| B4 | 13.49 | 10.26 |
| B5 | 14.92 | 11.76 |
| B6 | 14.42 | 11.4 |
| B7 | 14.95 | 11.87 |
| B8 | 14.92 | 13.37 |
| B9 | 13.80 | 10.82 |
| B10 | 13.57 | 12.32 |
| B11 | 13.70 | 11.39 |
| B12 | 14.90 | 12.29 |
| B13 | 15.47 | 13.41 |
| B14 | 15.19 | 12.15 |
| B15 | 14.06 | 11.71 |
| B16 | 14.26 | 10.31 |
| B17 | 15.96 | 12.78 |
| B18 | 15.90 | 11.73 |
| B19 | 14.70 | 12.96 |
| B20 | 14.84 | 11.77 |
| B21 | 14.86 | 11.91 |
| B22 | 14.76 | 11.68 |
| B23 | 13.76 | 10.72 |
| B24 | 15.49 | 13.41 |
| B25 | 13.74 | 11.85 |
| B26 | 13.05 | 10.69 |
| D1 | 21.82 | 11.34 |
| D2 | 20.46 | 10.26 |
| D3 | 20.04 | 10.39 |
| D4 | 17.39 | 9.31 |

As can be seen from the data in the above table, the introduction of both benzofuranyl and triphenylsilyl substituents into the molecule could significantly reduce the energy loss caused by vibrational relaxation during the excitation process of the molecule. In addition, while the multiple tert-butyl groups resulted in increased intermolecular spacing, the three phenyl groups on the triphenylsilyl group also contributed to the effect of increasing the intermolecular spacing. This was beneficial to improving the dispersion of the material during the device preparation process and reducing the probability of Dexter energy transfer.

Compared with Comparative Example Compound D1, the introduction of the benzofuranyl and triphenylsilyl groups could significantly reduce the energy loss caused by vibrational relaxation during the excitation process. As can be seen from Comparative Example Compounds D2 and D3, the use of the benzofuranyl and the triphenylsilyl alone could not significantly influence the excited-state reorganization energy or the intermolecular spacing. As can be seen from Comparative Example Compound D4, a reduced number of tert-butyl groups could lead to a significant reduction in intermolecular spacing, thereby increasing the probability of Dexter energy transfer.

### Device Examples

For the anodes of the following examples, anode materials commonly used in the art, such as ITO, Ag or multilayer structures thereof, were used. For the hole injection unit, hole injection materials commonly used in the art were used, and at the same time F4TCNQ, HATCN, NDP-9, etc. were added for doping. For the hole transport unit, hole transport materials commonly used in the art were used. For a light-emitting unit, a luminescent material commonly used in the art was used, for example, it could be composed of a host material doped with an emissive guest material, wherein the emissive guest material could be an organic material such as a pyrene compound or could also be a metal complex (such as the metal Ir or Pt). For the electron transport unit, an electron transport material commonly used in the art was used. For the electron injection layer, an electron injection material commonly used in the art, such as LiQ, LiF or Yb, was used. For the cathode, materials commonly used in the art, such as the metals Al and Ag or metal mixtures (Ag-doped Mg, Ag-doped Ca, etc.), were used.

The electrode preparation method and the deposition method for each functional layer in the following examples were both conventional methods in the art, e.g., vacuum thermal evaporation or ink-jet printing. No more details will be repeated here, but only some process details and test methods in the preparation process were supplemented as follows:

### Device Example 1

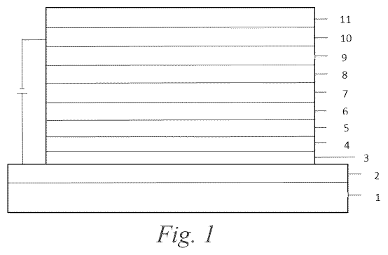

This example provided a blue-light organic electroluminescent device. The preparation method therefor was as follows: an ITO substrate was patterned to achieve a light-emitting area of 3 mm×3 mm in size, followed by ultrasonic treatment separately with water/isopropanol, UV/ozone irradiation, and then drying at 100° C.; subsequently, the ITO substrate was mounted on a substrate holder of a vacuum deposition device, and the pressure was adjusted to achieve a vacuum level of 1×10⁻⁷ torr. Subsequently, the following operations were carried out: firstly, on an ITO layer (anode) formed on a substrate, Compound HT01 and Compound PD01 (the mass ratio of Compound HT01 to Compound PD01 being 97:3) were deposited in vacuo to a thickness of 10 nm to form a hole injection layer; secondly, on the above hole injection layer, Compound HT01 was deposited in vacuo to a thickness of 100 nm to form a hole transport layer; thirdly, on the above hole transport layer, Compound BP01 was deposited in vacuo to a thickness of 5 nm to form a luminescent auxiliary layer; fourthly, on the above luminescent auxiliary layer, a mixture of Compound B1 and Compound BH01 provided by the present invention was deposited in vacuo to a thickness of 20 nm to form a luminescent layer, wherein BH01 was used as a host material, Compound B1 used as was a guest material, and the mass ratio of Compound BH01 to Compound B1 was 98:2; next, on the above luminescent layer, Compound BH01 was deposited in vacuo to a thickness of 5 nm to form a hole barrier layer; then, on the above hole barrier layer, Compound ET01 and Compound LiQ (the mass ratio of Compound ET01 to Compound LiQ being 1:1) were deposited in vacuo to a thickness of 30 nm to form an electron transport layer; then, on the above electron transport layer, Yb was deposited in vacuo to a thickness of 1 nm to form an electron injection layer; then, on the above electron injection layer, Mg and Ag (the mass ratio of Mg to Ag being 1:9) were deposited to a thickness of 15 nm to form a cathode; then, on the above cathode, Compound CP01 was deposited to a thickness of 50 nm to form a cover layer; and finally, the evaporated substrate was packaged and the cleaned cover plate was subjected to a coating process using a UV adhesive by a coating apparatus. The coated cover plate was then moved to a pressure bonding work stage. The evaporated substrate was placed on top of the cover plate. Finally, the substrate and the cover plate were laminated under the action of a lamination apparatus while the UV adhesive was simultaneously photocured, thereby preparing a top-emitting organic electroluminescent device. The structure of the device was shown in FIG. 1.

The molecular structural formulas of the materials of the layers other than the blue-light dopant material were as follows:

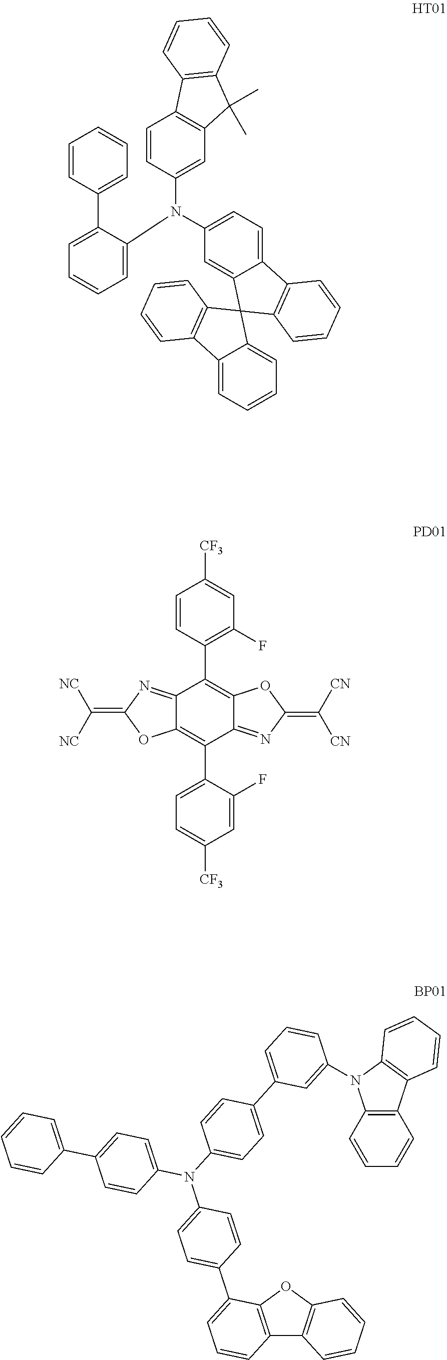 [SMILES: CC1(C)c2ccccc2-c2ccc(N(c3ccc4c(c3)C3(c5ccccc5-c5ccccc53)c3ccccc3-4)c3ccccc3-c3ccccc3)cc21 ; N#CC(C#N)=c1nc2c(-c3ccc(C(F)(F)F)cc3F)c3oc(=C(C#N)C#N)nc3c(-c3ccc(C(F)(F)F)cc3F)c2o1 ; c1ccc(-c2ccc(N(c3ccc(-c4cccc(-n5c6ccccc6c6ccccc65)c4)cc3)c3ccc(-c4cccc5c4oc4ccccc45)cc3)cc2)cc1]

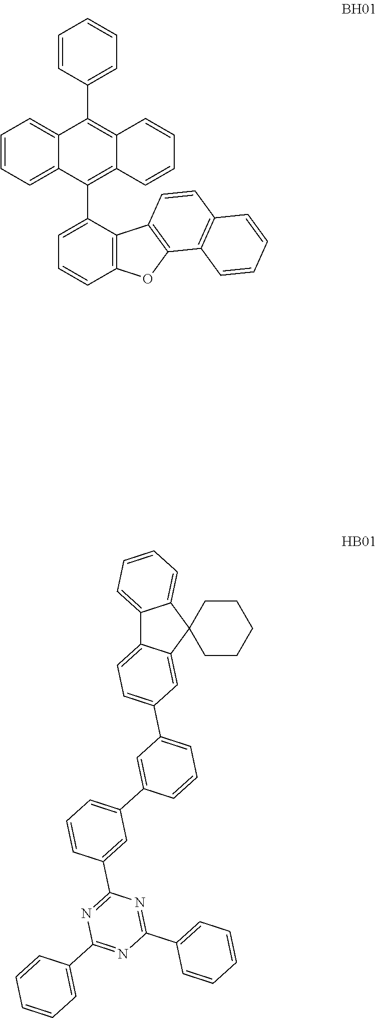 [SMILES: c1ccc(-c2c3ccccc3c(-c3cccc4oc5c6ccccc6ccc5c34)c3ccccc23)cc1 ; c1ccc(-c2nc(-c3ccccc3)nc(-c3cccc(-c4cccc(-c5ccc6c(c5)C5(CCCCC5)c5ccccc5-6)c4)c3)n2)cc1]

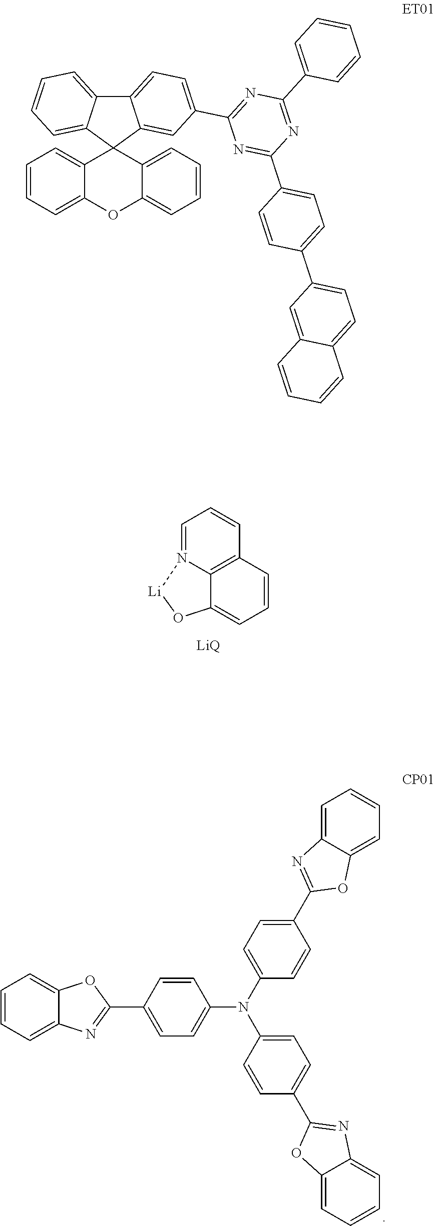

### Device Examples 2-26

This comparative example provided a blue-light organic electroluminescent device. The preparation method therefor was as follows. Compound B1 in Device Example 1 was replaced separately by Compounds B2 to B26 provided by Compound Examples 2 to 26 to form luminescent layers, while the other preparation steps were the same as in Device Example 1, so as to separately prepare blue-light organic electroluminescent devices.

### Comparative Device Examples 1-4

The method was the same as in Device Example 1, except that Compound B1 in Device Example 1 was replaced separately by Compounds D1 to D5 to form luminescent layers, while the other preparation steps were the same as in Device Example 1, so as to separately prepare blue-light organic electroluminescent devices.

### Evaluation of Performance of Organic Electroluminescent Devices

The OLED devices described above were tested by means of a standard method. In this regard, the organic electroluminescent devices were measured at a current density of J=10 mA/cm² for the driving voltage, brightness, electroluminescent current efficiency (measured as cd/A), and external quantum efficiency (EQE, measured by percentage). The luminescence spectrum was calculated, as a function of luminous density, from the current/voltage/luminous density characteristic curves (IVL characteristic curves) showing Lambertian emission characteristics. The lifetime LT was defined as the time for the brightness to decrease from the initial luminous brightness L₀ to a specific proportion L₁, during working at a constant current J; The expression of J=20 mA/cm² and L₁=97% means that during working at J=20 mA/cm², the luminous brightness decreases to 97% of its initial value L₀ after the time LT. The lifetime (LT97) of the organic electroluminescent device was determined at a current density of J=20 mA/cm².

The data of these OLED devices were summarized in Table 2. A comparison in various parameters was made between the device examples and the comparative device examples, and the performance data of various OLED devices were demonstrated.

The test instruments and methods for testing the performance of the OLED devices of the above examples and comparative examples were as follows:
the quantum efficiency C.E (cd/A), color coordinates (CIEy), and luminescence peak width at half height were tested by spectrum scanner PhotoResearch PR-655;
the current density and turn-on voltage were tested by digital SourceMeter Keithley 2400;
the Blue index was derived by dividing the quantum efficiency C.E (cd/A) by the coordinate (CIEy); and
the lifetime test was obtained using LT-96ch lifetime test device.

TABLE 2
Performance test results of blue-light devices

| | Driving | | | Luminescence peak |
|---|---|---|---|---|
| | voltage | Luminescence | Blue index | width at half height |
| No. | (V) | lifetime L97 (h) | (cd/A/CIEy) | (nm) |
| B1 | 3.27 | 237 | 265.47 | 18.5 |
| B2 | 3.3 | 226 | 266.11 | 18.4 |
| B3 | 3.28 | 212 | 264.20 | 18.1 |
| B4 | 3.27 | 221 | 255.77 | 18.9 |
| B5 | 3.25 | 217 | 260.77 | 19.0 |
| B6 | 3.27 | 230 | 257.55 | 19.0 |
| B7 | 3.26 | 237 | 260.64 | 19.0 |
| B8 | 3.27 | 218 | 265.87 | 18.5 |
| B9 | 3.28 | 224 | 254.81 | 19.0 |
| B10 | 3.28 | 237 | 264.96 | 18.0 |
| B11 | 3.25 | 223 | 260.76 | 18.5 |
| B12 | 3.27 | 228 | 262.34 | 18.8 |
| B13 | 3.29 | 219 | 265.03 | 18.8 |
| B14 | 3.29 | 225 | 261.27 | 19.0 |
| B15 | 3.29 | 229 | 261.38 | 18.5 |
| B16 | 3.26 | 214 | 253.88 | 19.5 |
| B17 | 3.28 | 230 | 259.52 | 19.5 |
| B18 | 3.29 | 217 | 257.94 | 19.8 |
| B19 | 3.26 | 228 | 264.67 | 18.5 |
| B20 | 3.28 | 236 | 260.81 | 19.0 |
| B21 | 3.28 | 236 | 261.55 | 19.0 |
| B22 | 3.28 | 235 | 260.92 | 18.9 |
| B23 | 3.26 | 232 | 259.03 | 18.7 |
| B24 | 3.27 | 231 | 264.69 | 18.8 |
| B25 | 3.26 | 226 | 263.20 | 18.3 |
| B26 | 3.28 | 223 | 264.79 | 18.1 |
| D1 | 3.3 | 212 | 245.84 | 22.5 |
| D2 | 3.29 | 214 | 242.31 | 23.1 |
| D3 | 3.26 | 234 | 242.25 | 23.0 |
| D4 | 3.39 | 224 | 240.34 | 22.8 |

As can be seen from the verification results of the device examples, compared with the similar multi-tert-butyl structure, the introduction of both benzofuranyl and triphenylsilyl substituents into the molecule led to a significant improvement in the working efficiency of the device due to the reduction of energy loss during the excitation process of the molecule. In addition, the suppression of vibrational relaxation also led to a reduction in the luminescence peak width at half height, an improved color purity effect, and narrow-spectrum characteristics, thus meeting the spectral requirements of the BT.2020 wide color gamut standard.

The above description is only preferred embodiments of the present invention, and the scope of protection of the present invention is not limited thereto. Any changes, substitutions, etc. readily conceivable to any of those familiar with the technical field within the technical scope of the disclosure of the present invention should be included in the scope of protection of the present invention. Therefore, for the scope of protection of the present invention, the scope of protection of the claims shall prevail.

1. A polycyclic compound containing triphenylsilyl and multiple alkyl substituents, characterized in that the general structural formula of the polycyclic compound is as represented by one of: 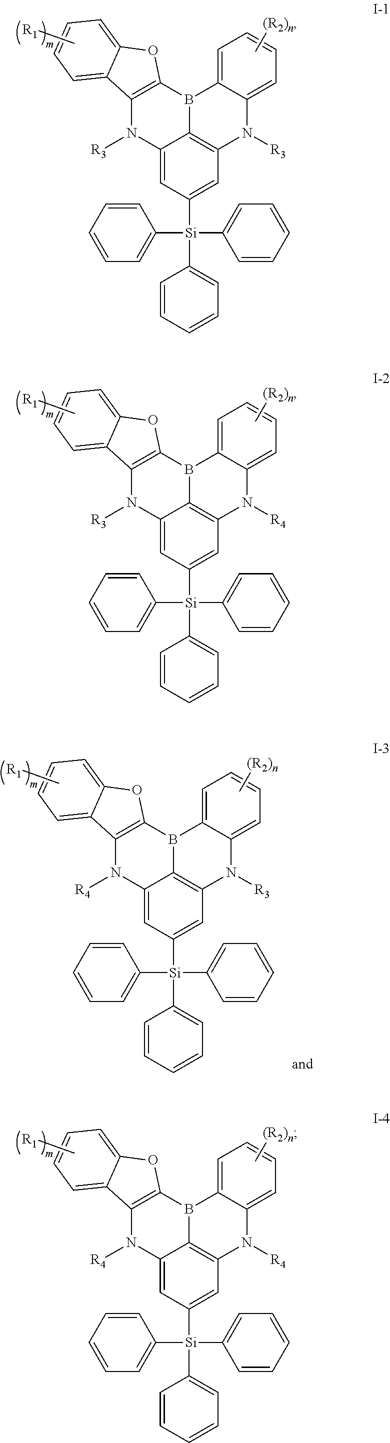
characterized in that R₁ and R₂ each independently represent one of 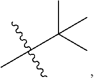 [SMILES: *C(C)(C)C] 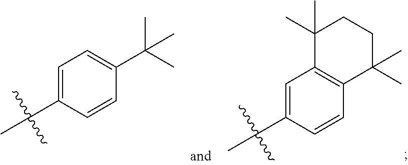
when R₁ represents tert-butyl, two R₁ at adjacent positions can be connected to each other to form a ring structure; and
when R₂ represents tert-butyl, two R₂ at adjacent positions can be connected to each other to form a ring structure;
R₃ represents one of the following structures: 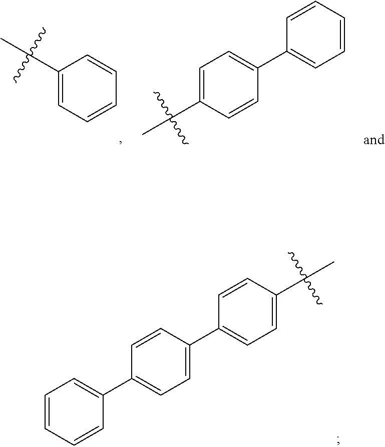 [SMILES: *c1ccccc1 ; *c1ccc(-c2ccccc2)cc1 ; *c1ccc(-c2ccc(-c3ccccc3)cc2)cc1]
R₄ represents one of the following structures: 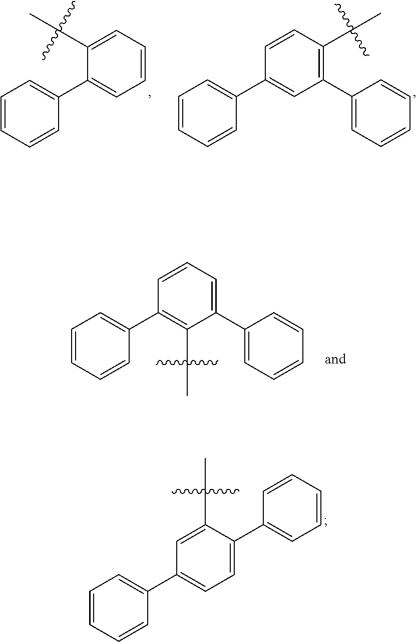
n represent 0, 1, 2, 3, or 4;
m represent 1 or 2;
the polycyclic compound comprises at least:
five tert-butyl groups; or
three tert-butyl groups and one ring structure formed by connecting any two tert-butyl groups at adjacent positions to each other;
any hydrogen in the above groups defined for R3 and R4 can be replaced by deuterium or tert-butyl, at least one hydrogen in the above groups defined for R3 and R4 is replaced by tert-butyl, and when more than one hydrogen is replaced, two tert-butyl groups at adjacent positions can be connected to form a ring structure.

2. (canceled)

3. (canceled)

4. (canceled)

5. (canceled)

6. The polycyclic compound according to claim 1, characterized in that R₃ represents one of the following structures: 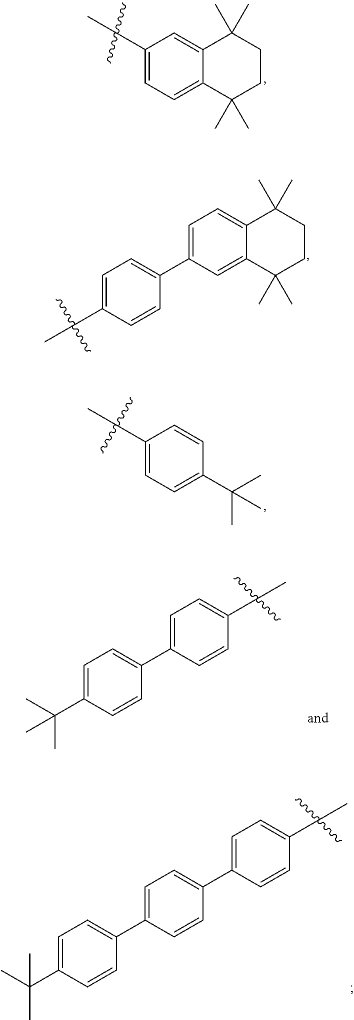 [SMILES: *c1ccc2c(c1)C(C)(C)CCC2(C)C ; *c1ccc(-c2ccc3c(c2)C(C)(C)CCC3(C)C)cc1 ; *c1ccc(C(C)(C)C)cc1 ; *c1ccc(-c2ccc(C(C)(C)C)cc2)cc1 ; *c1ccc(-c2ccc(-c3ccc(C(C)(C)C)cc3)cc2)cc1]
and/or
R₄ represents one of the following structures:

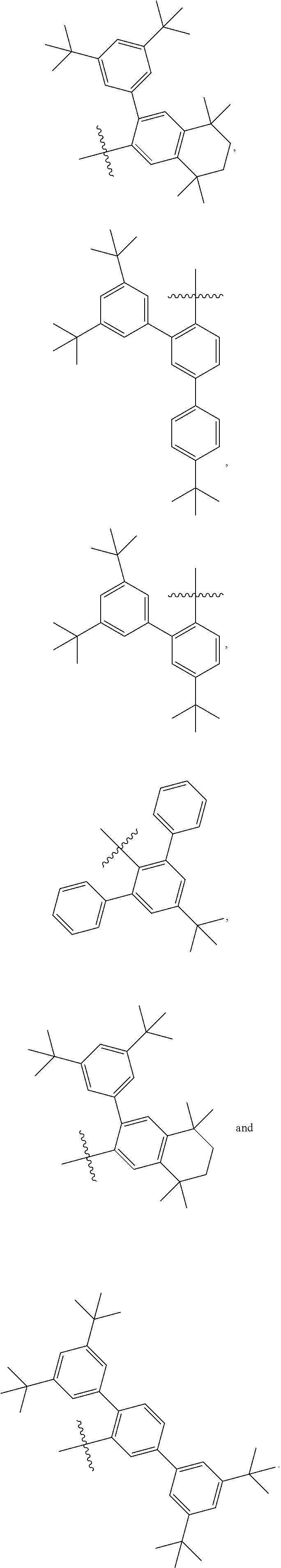

7. (canceled)

8. The polycyclic compound according to claim 1, characterized in that the polycyclic compound is selected from the following structures:

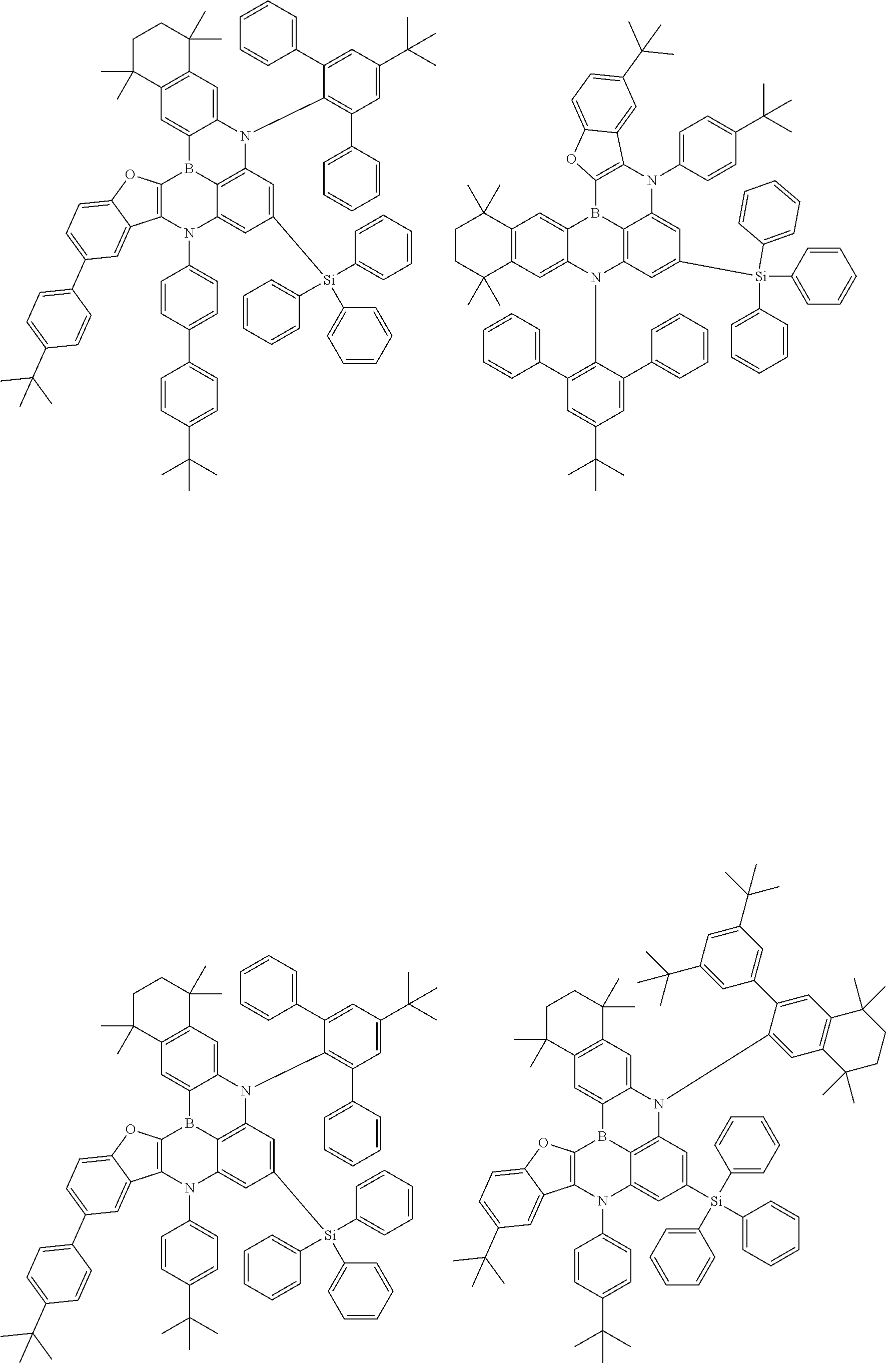

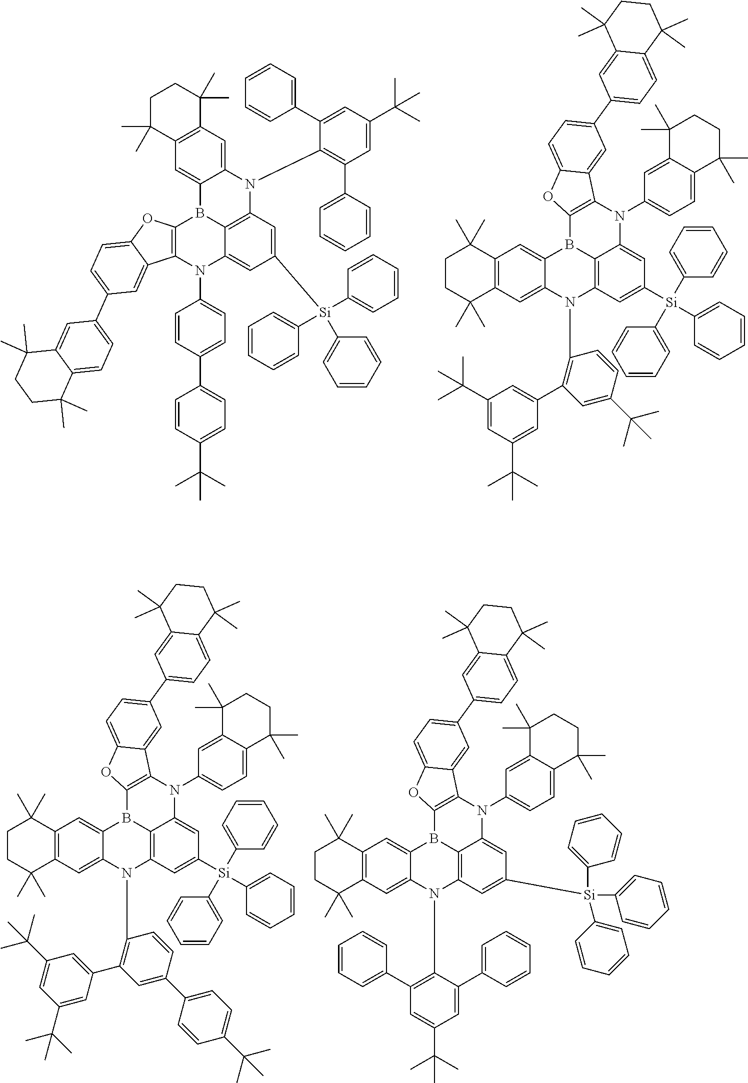

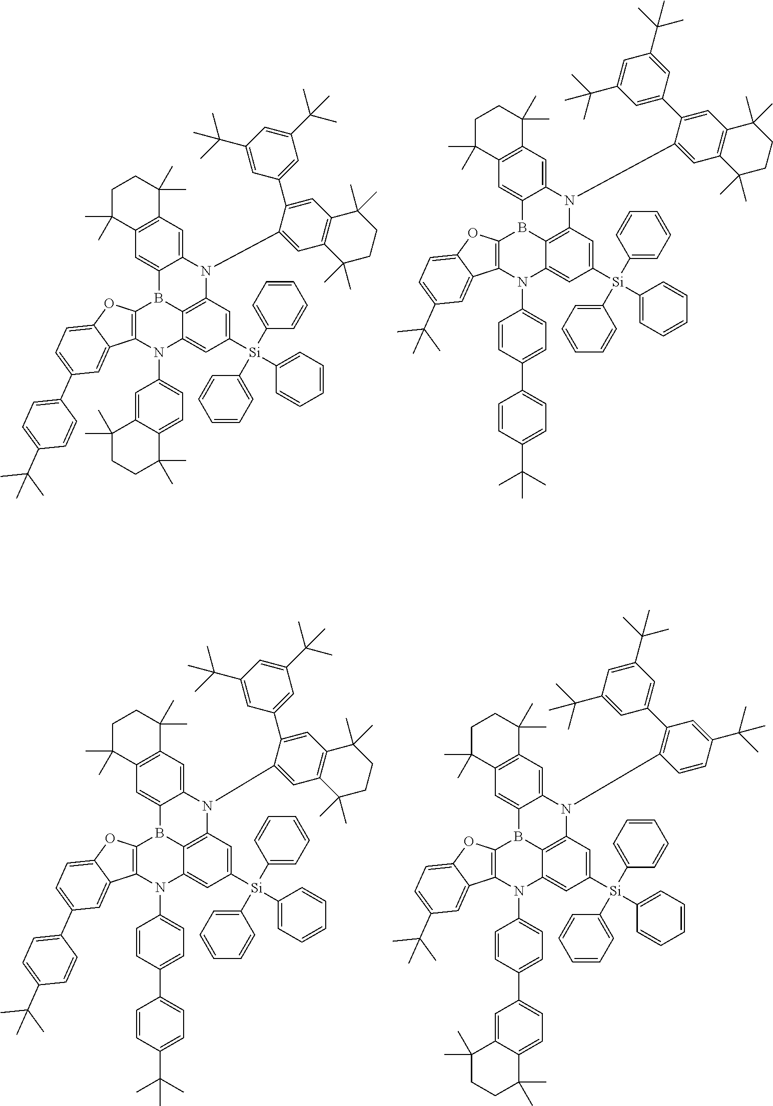

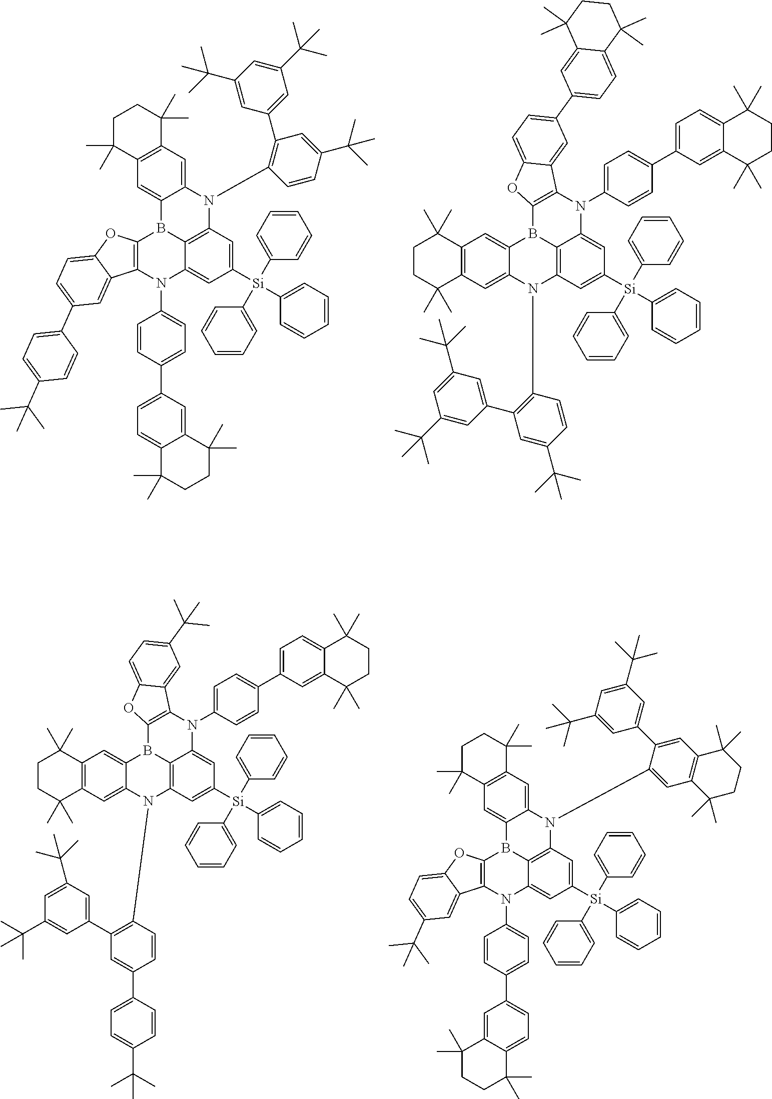

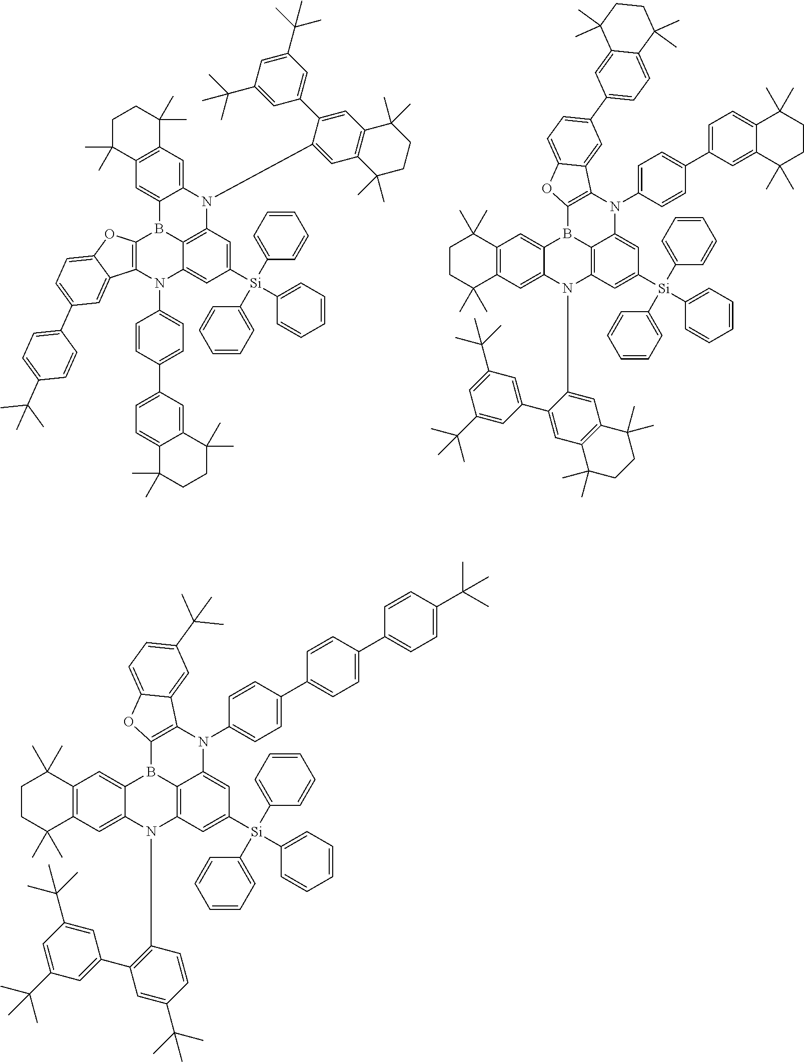

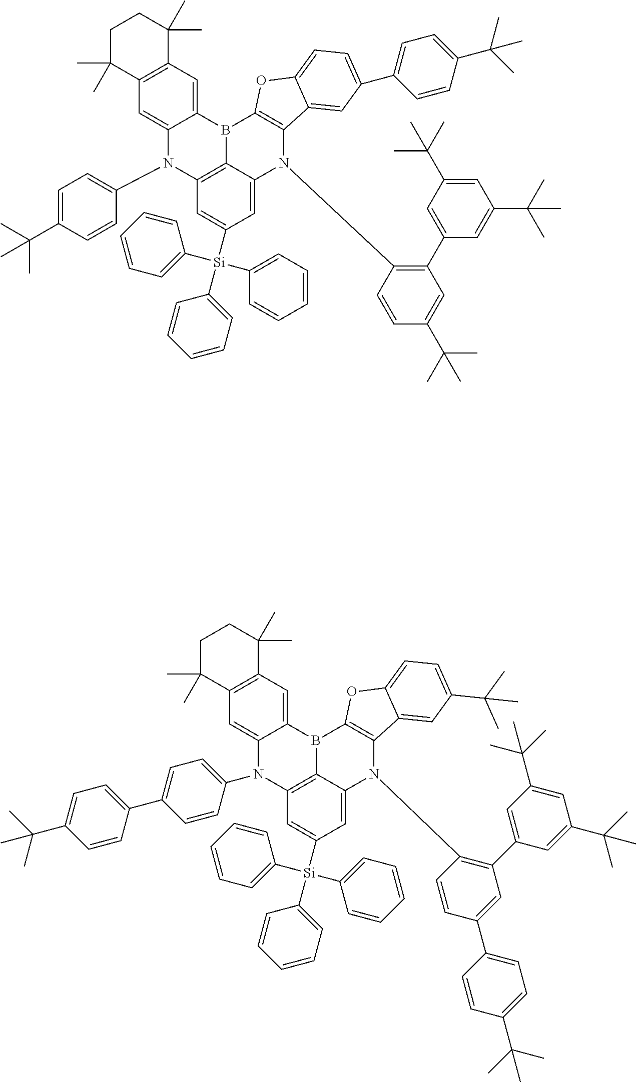

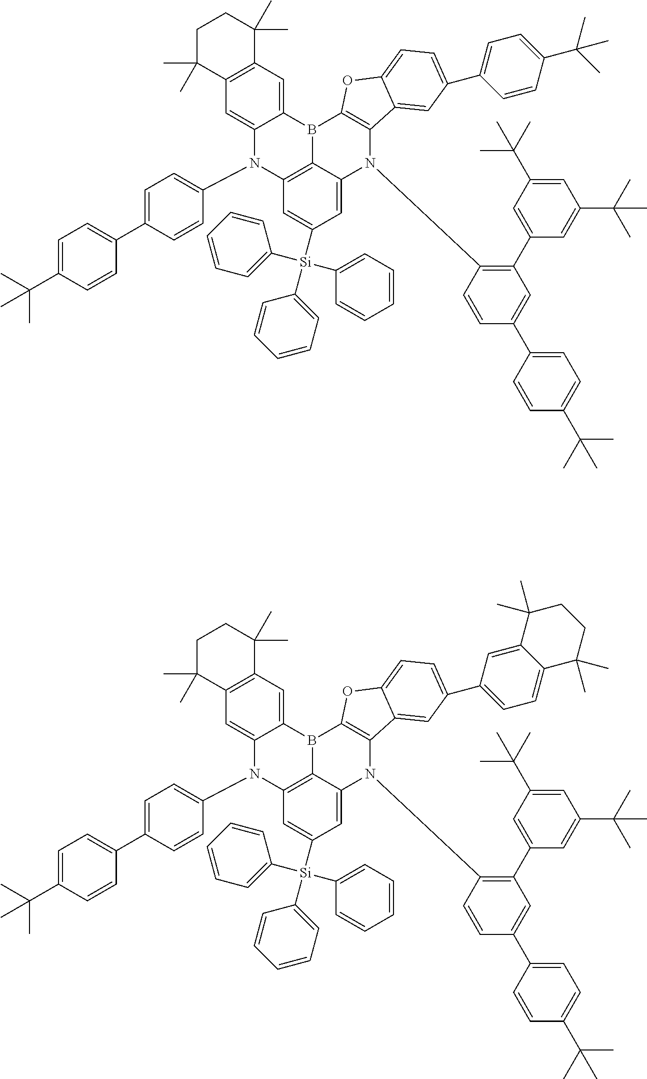

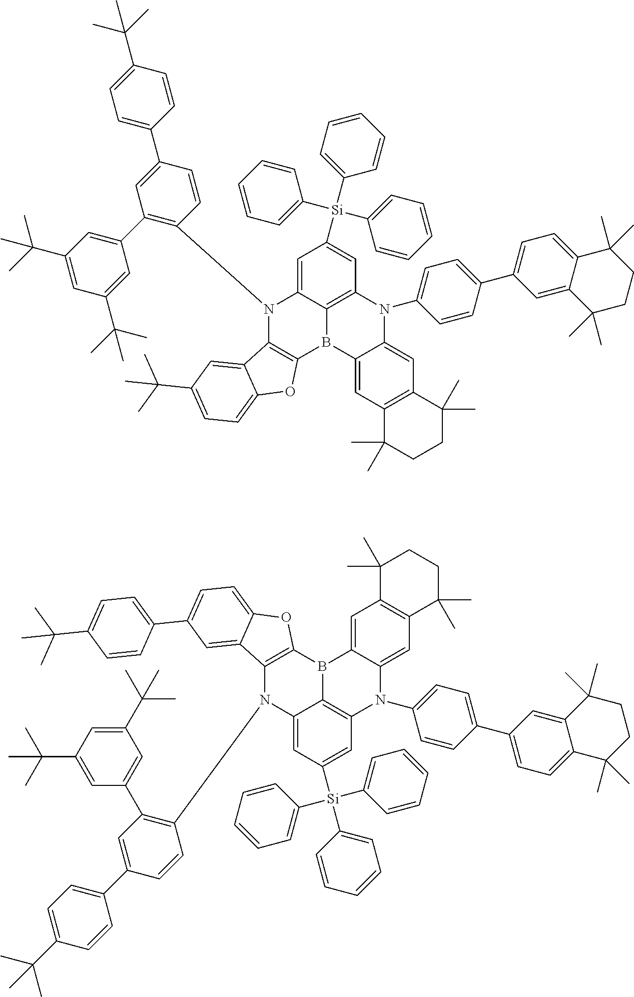

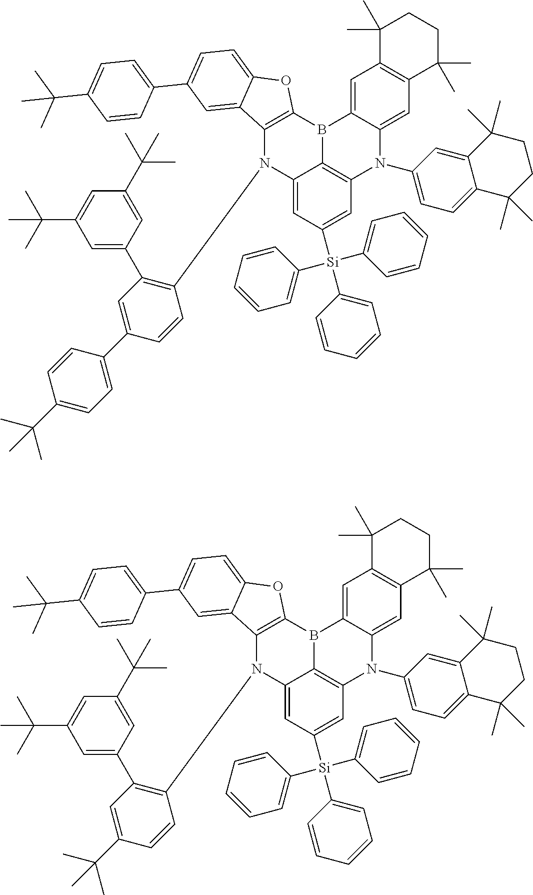

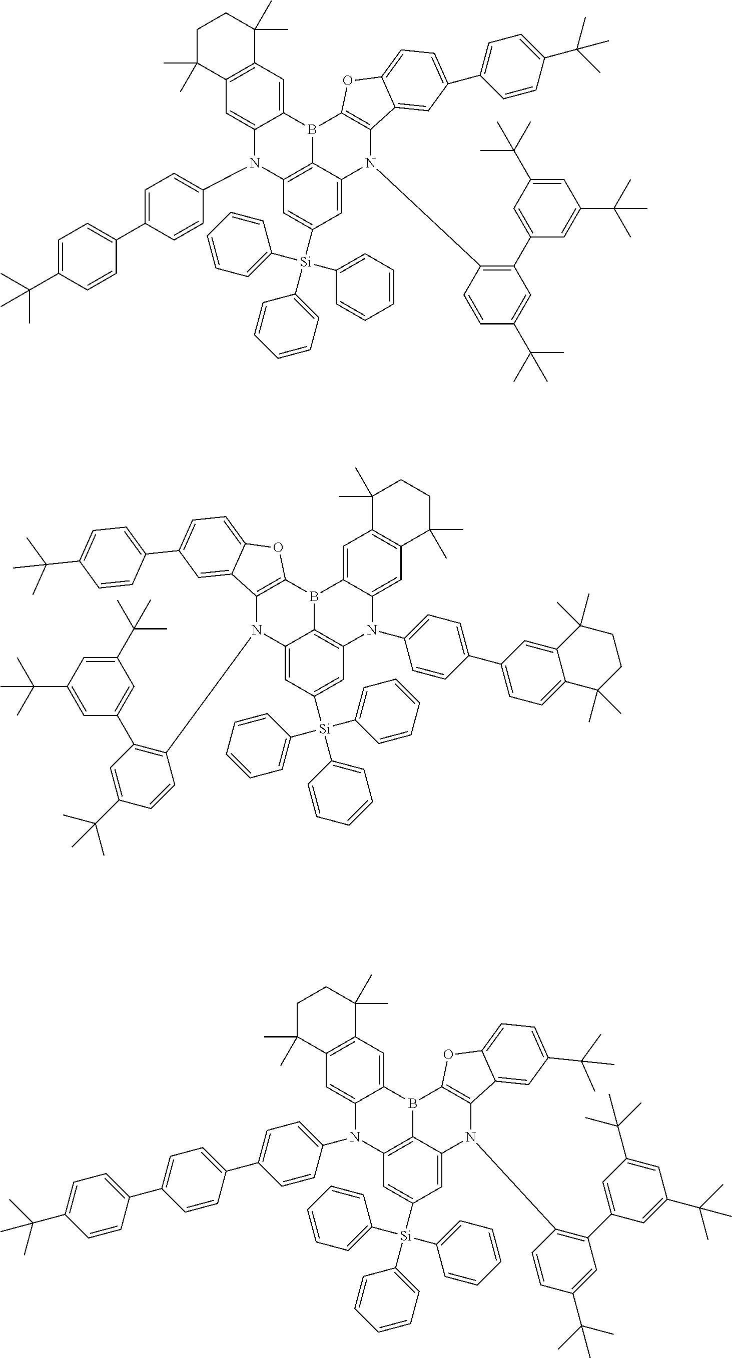

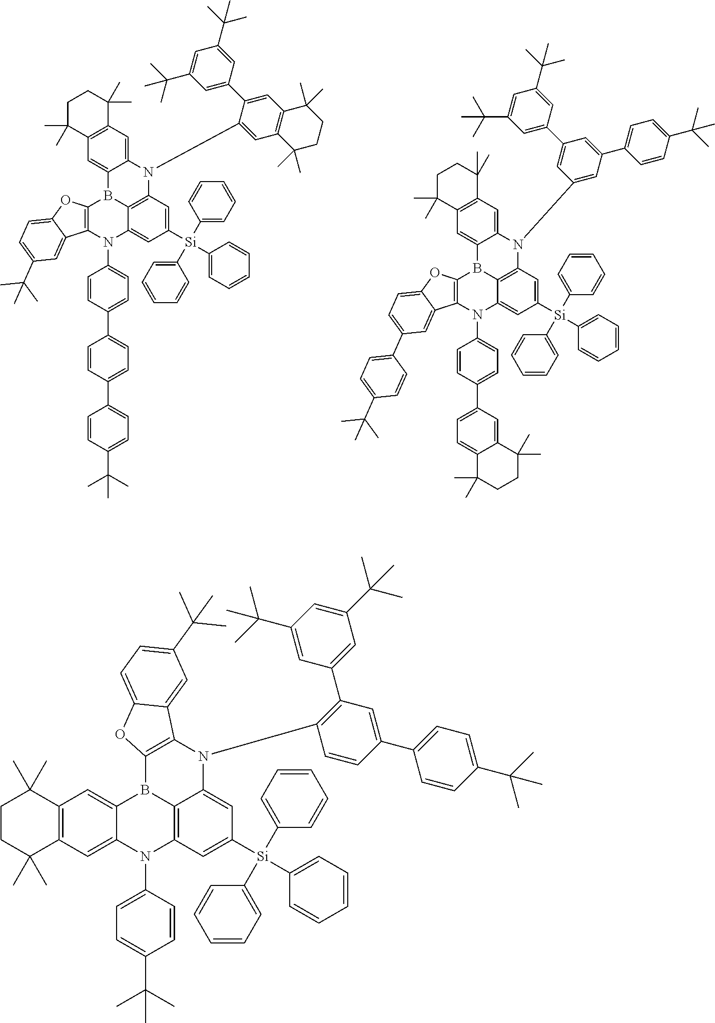

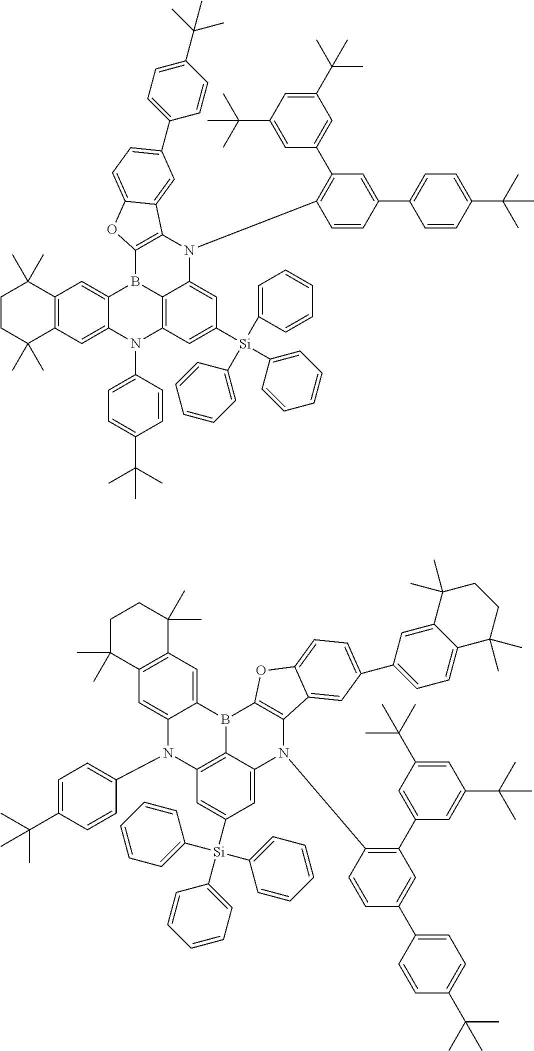

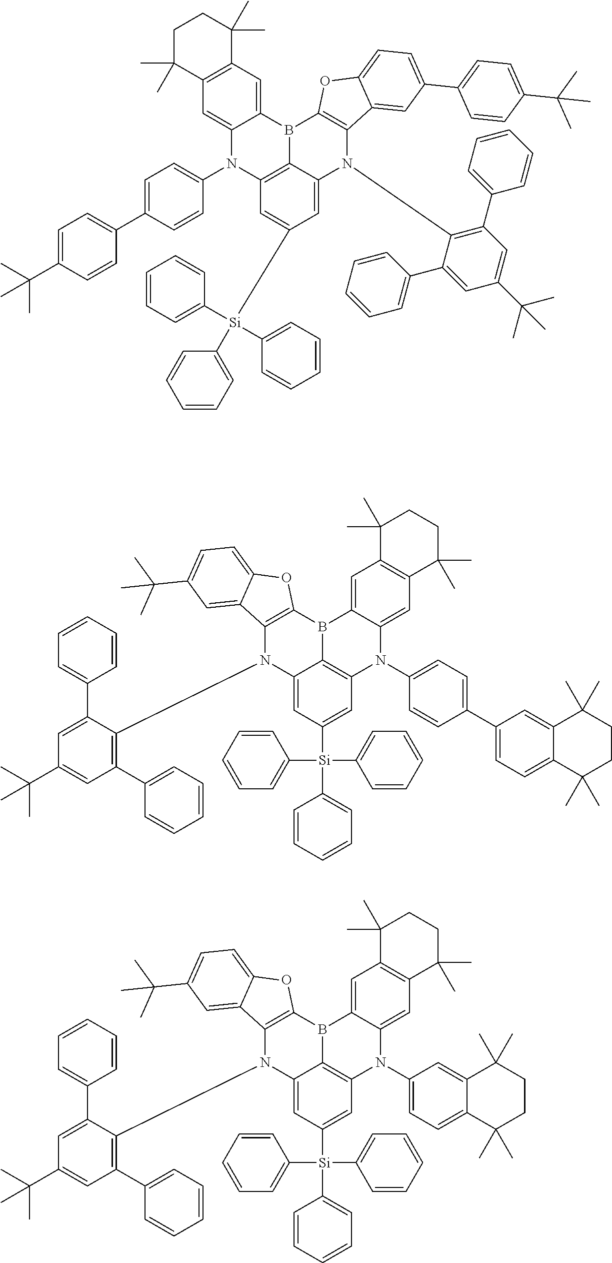

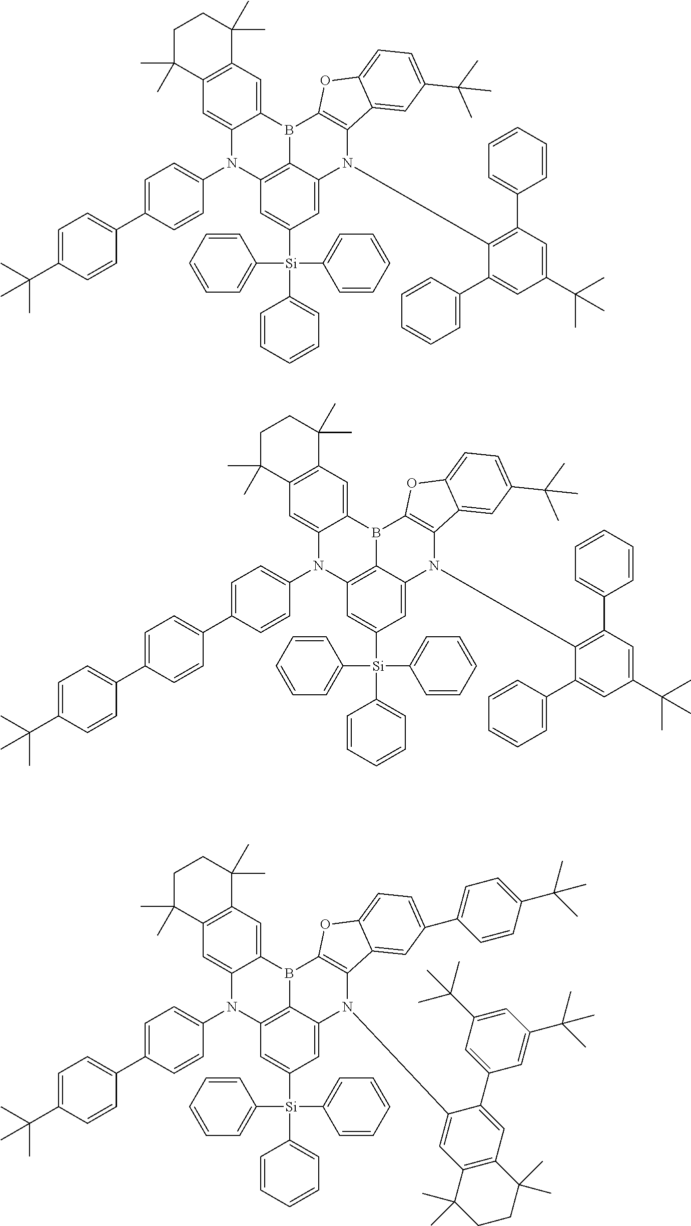

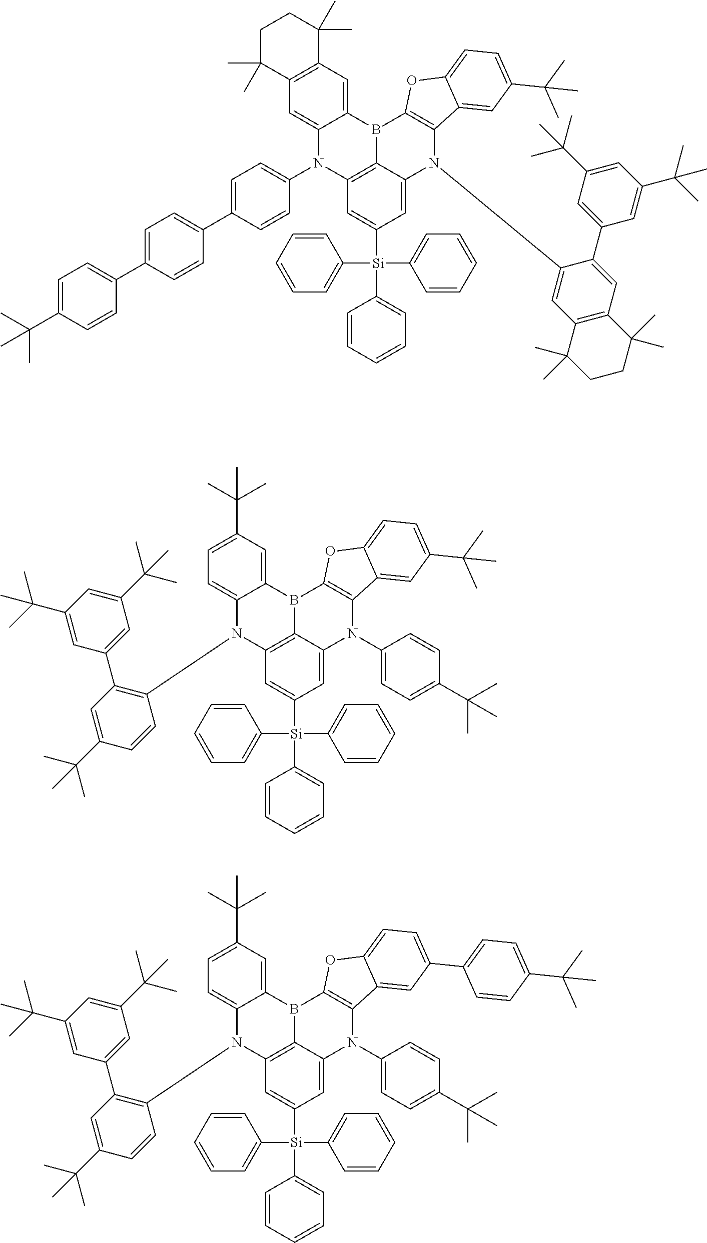

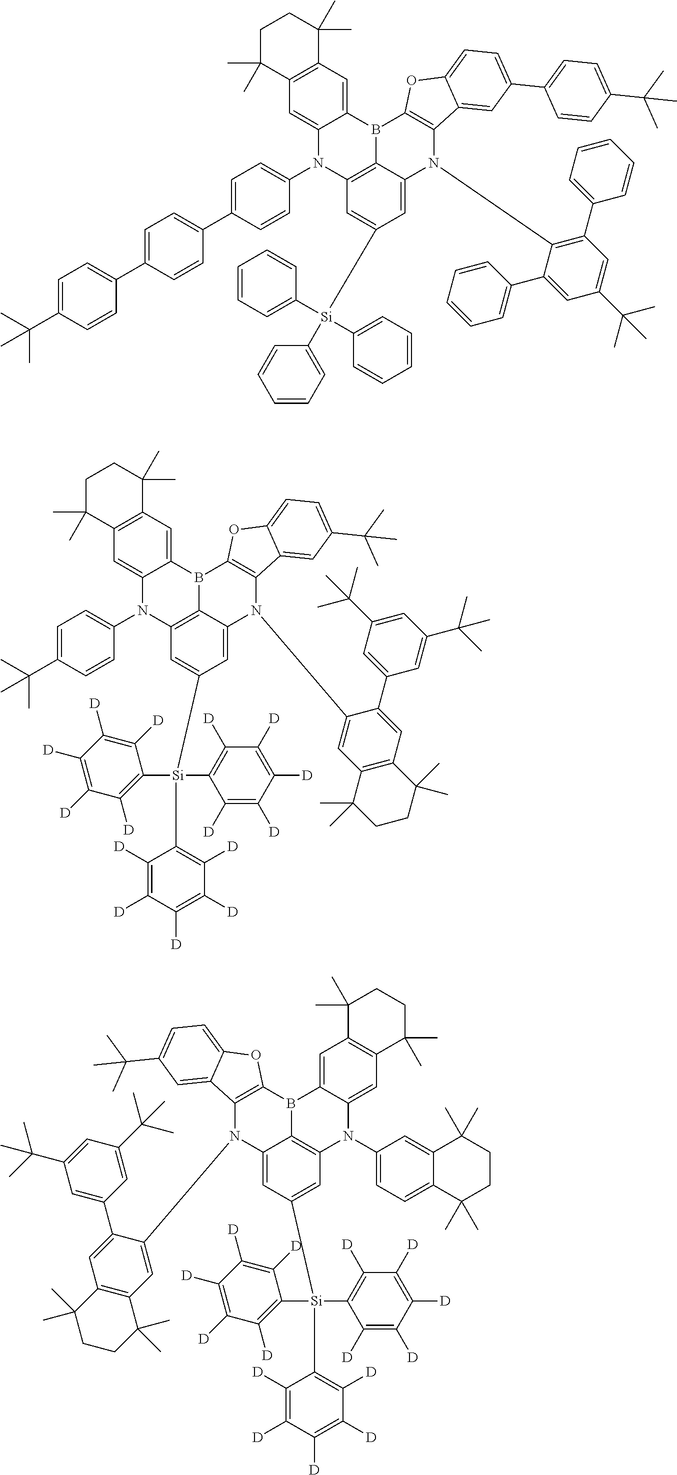

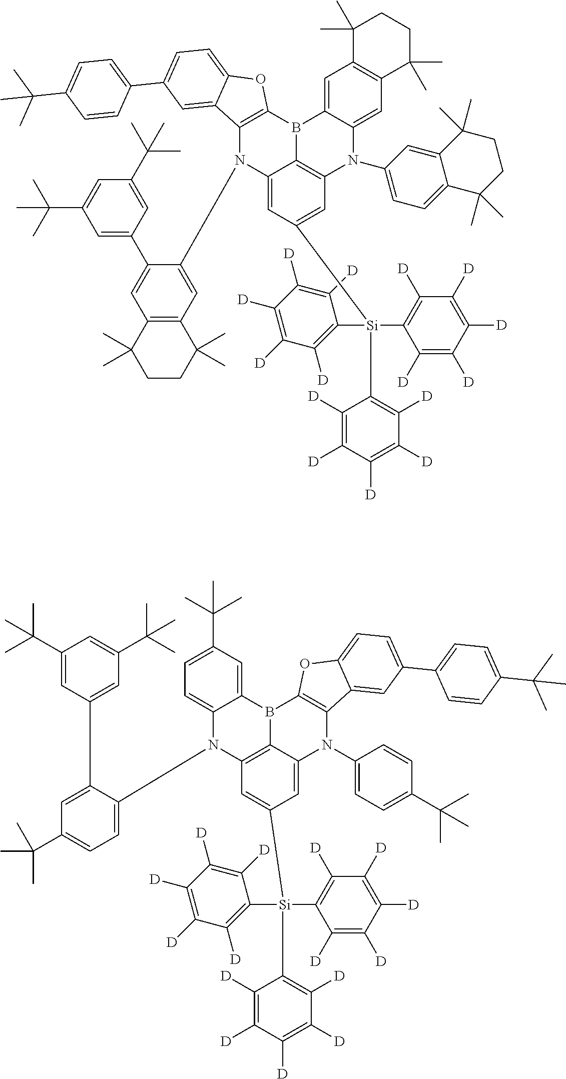

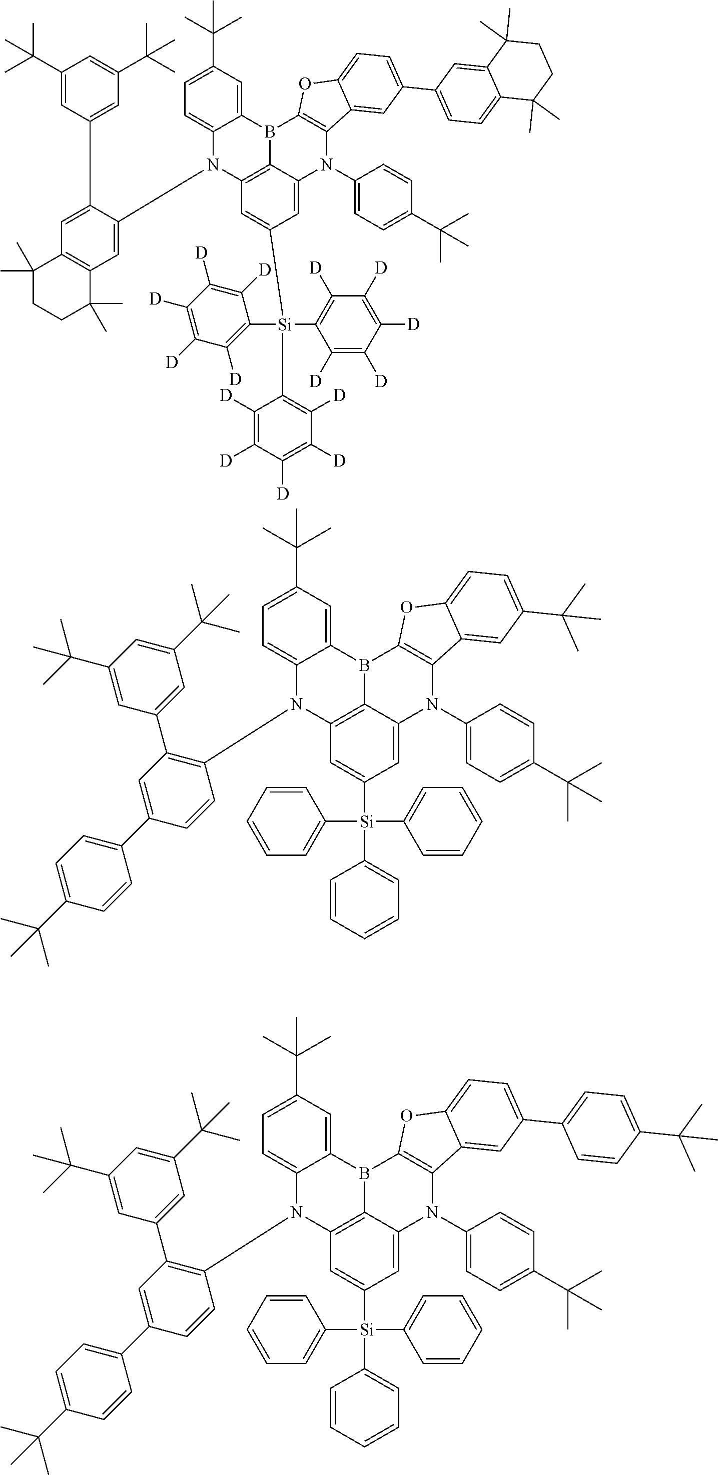

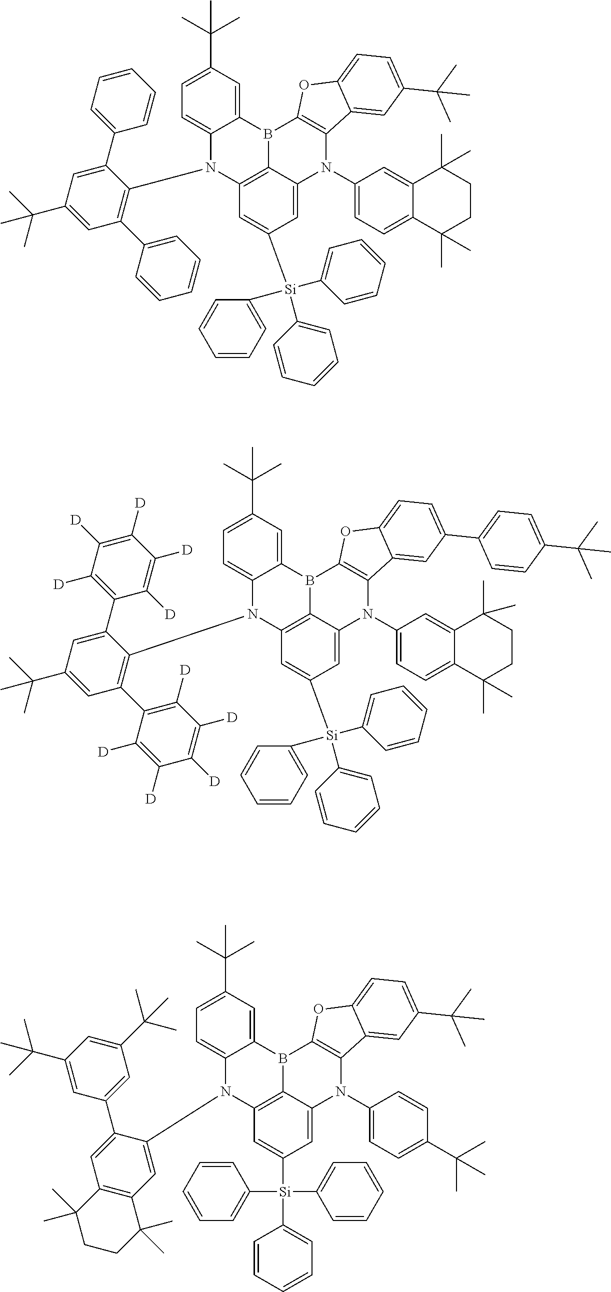

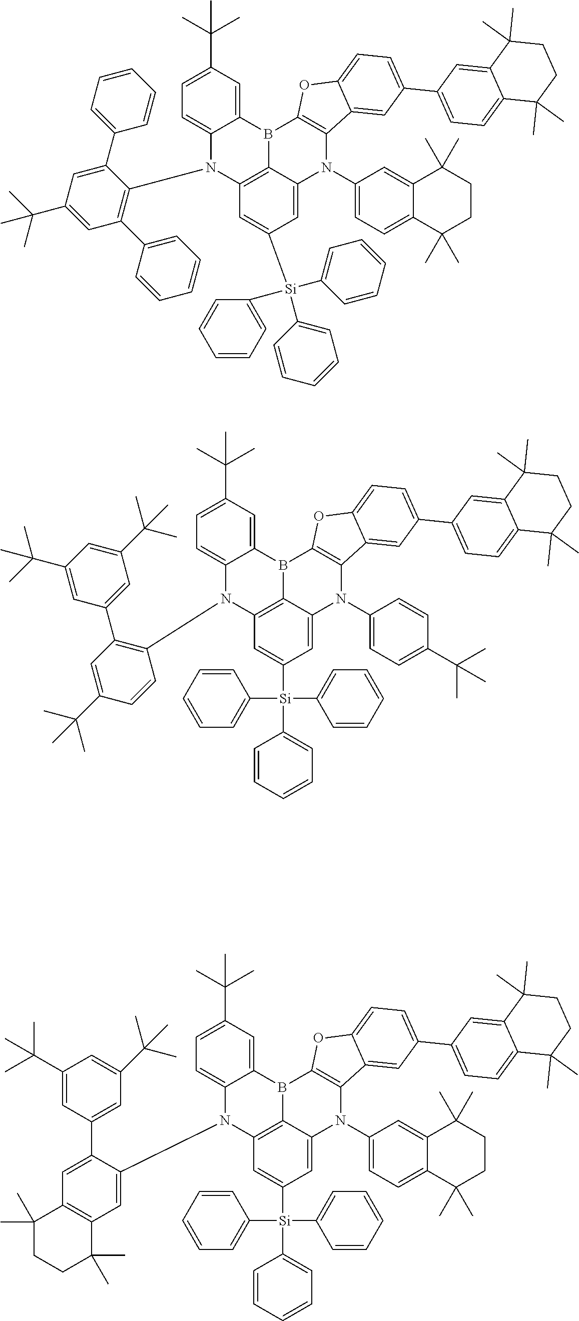

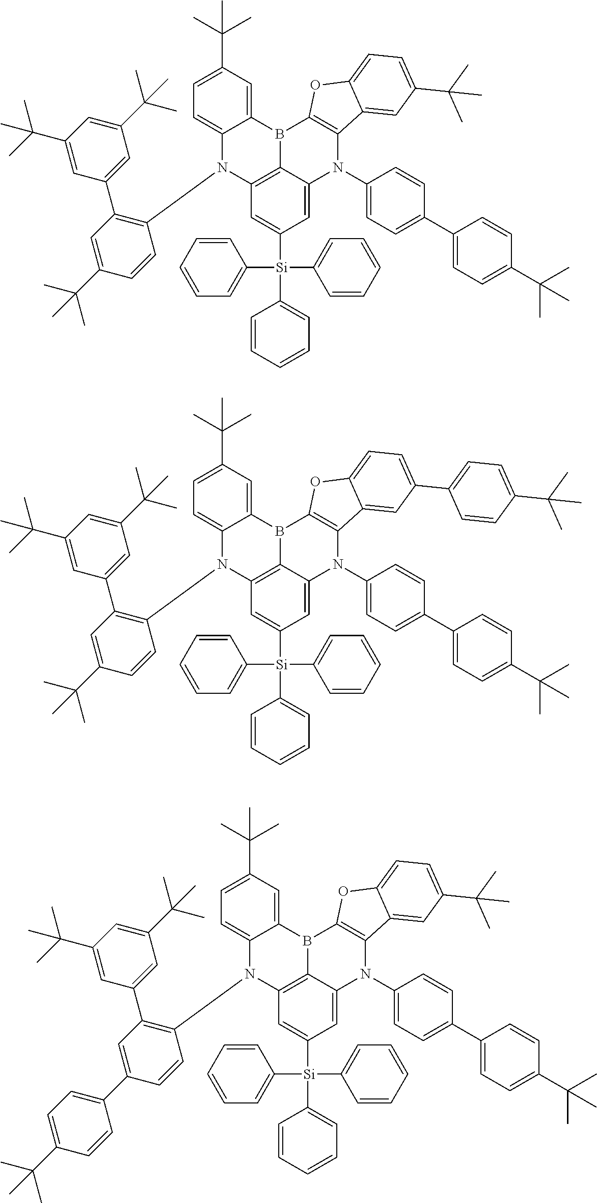

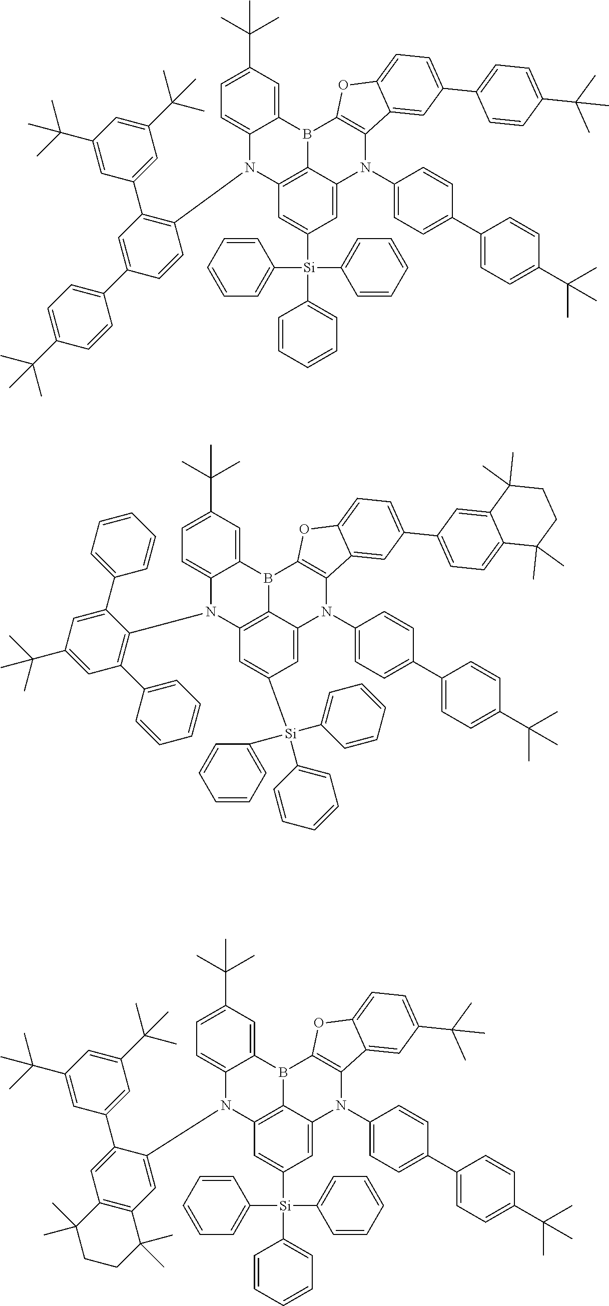

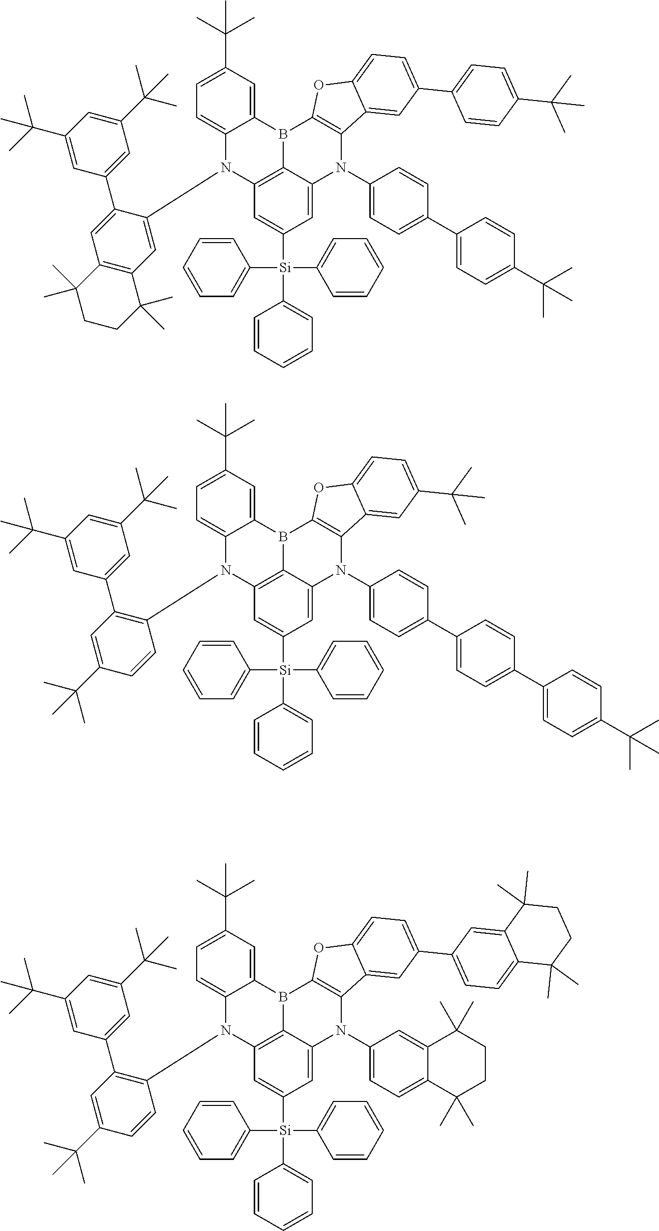

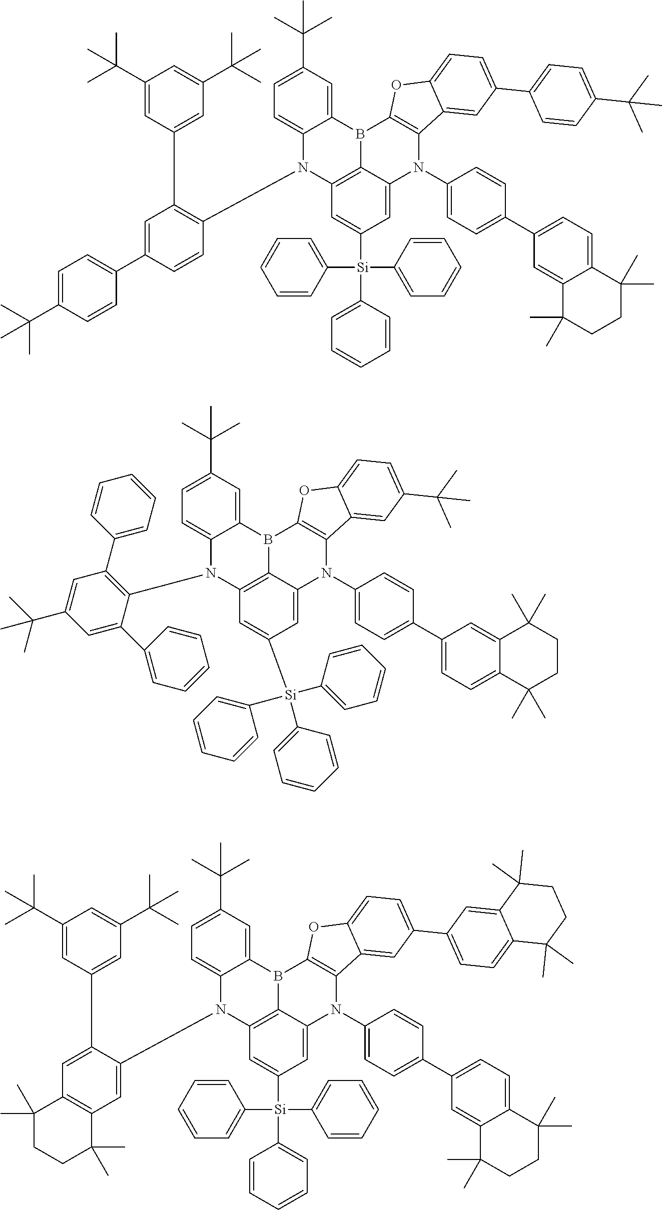

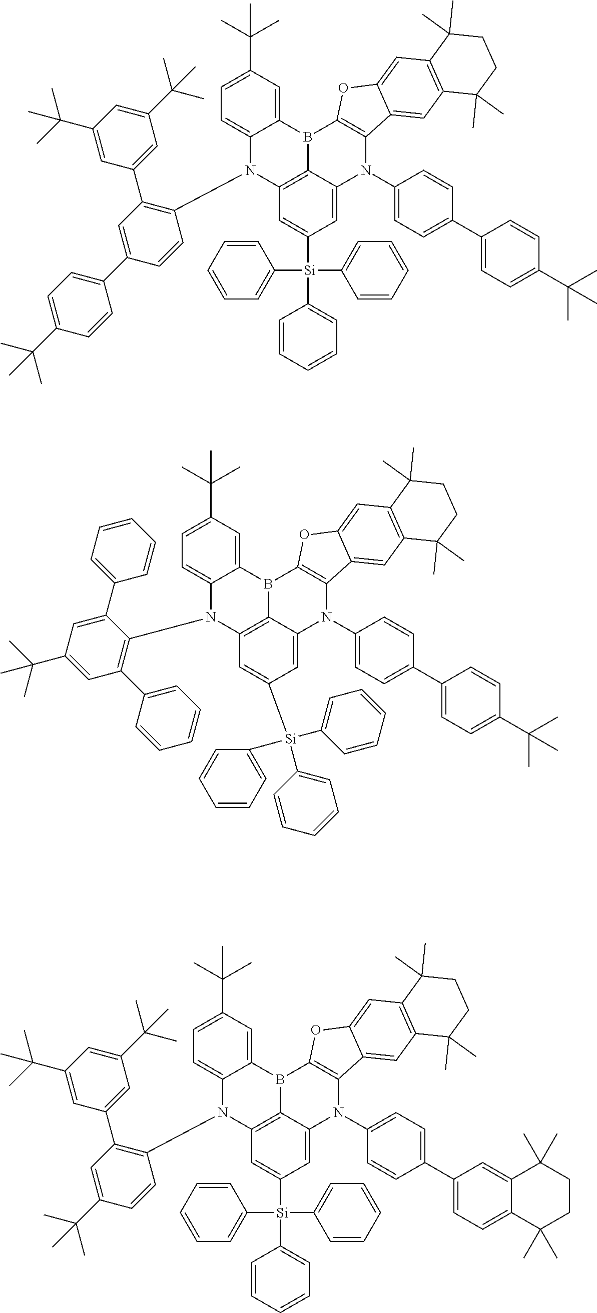

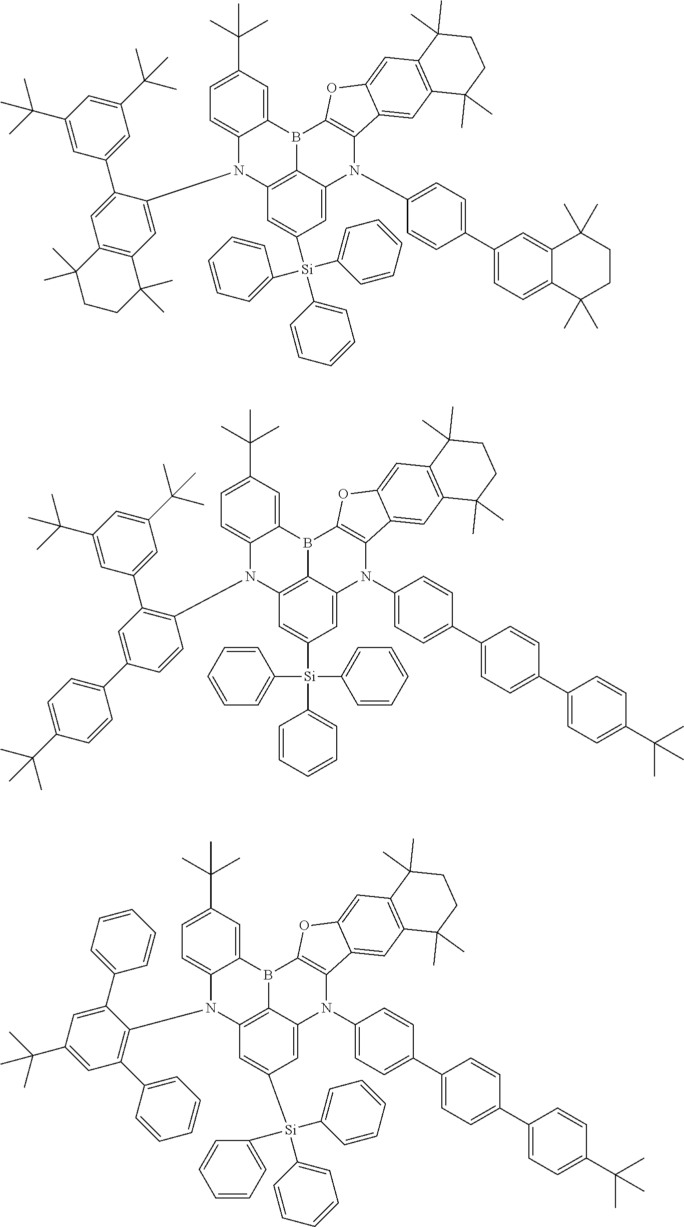

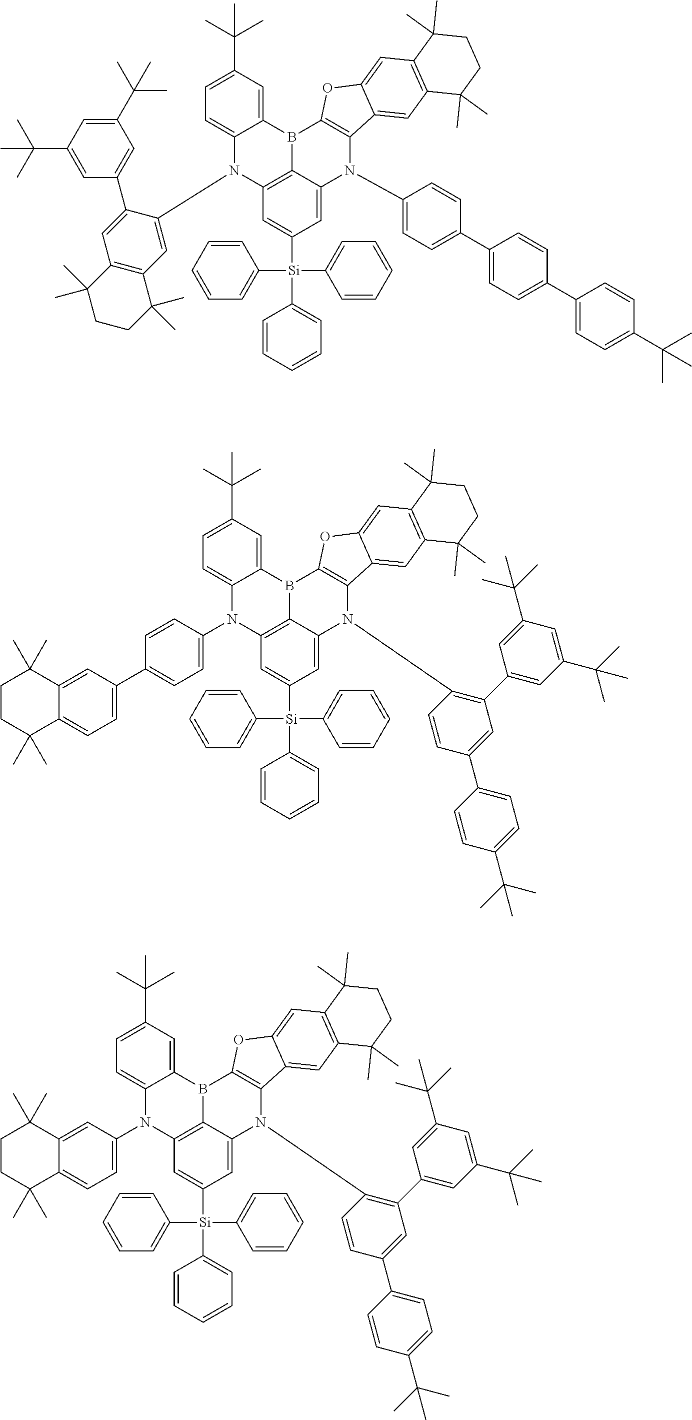

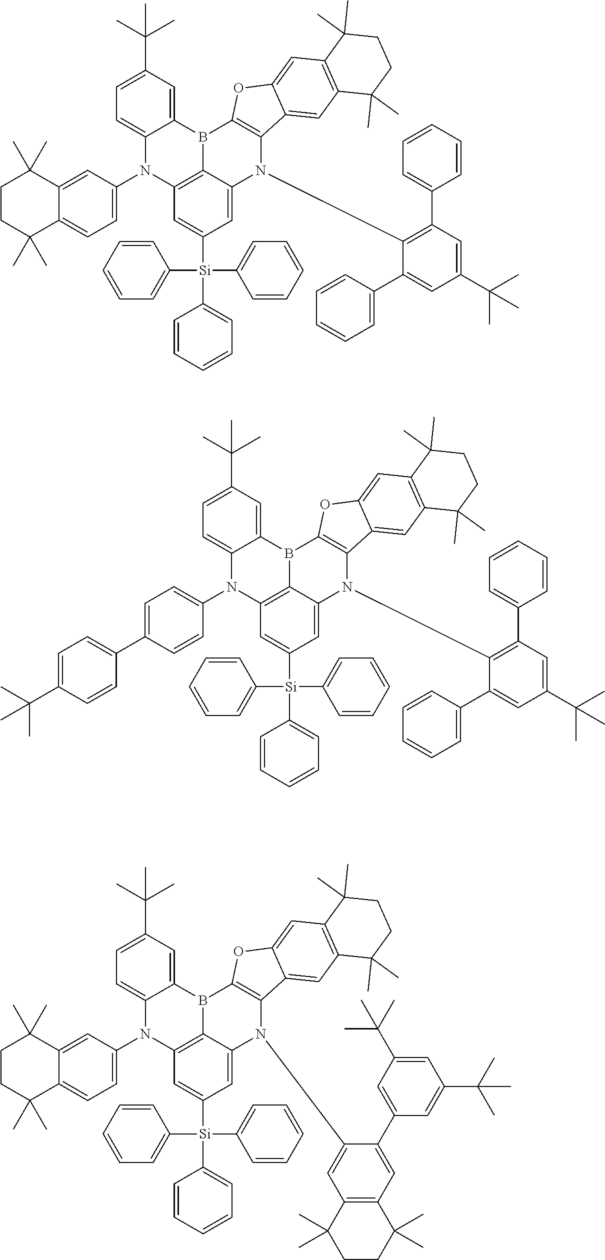

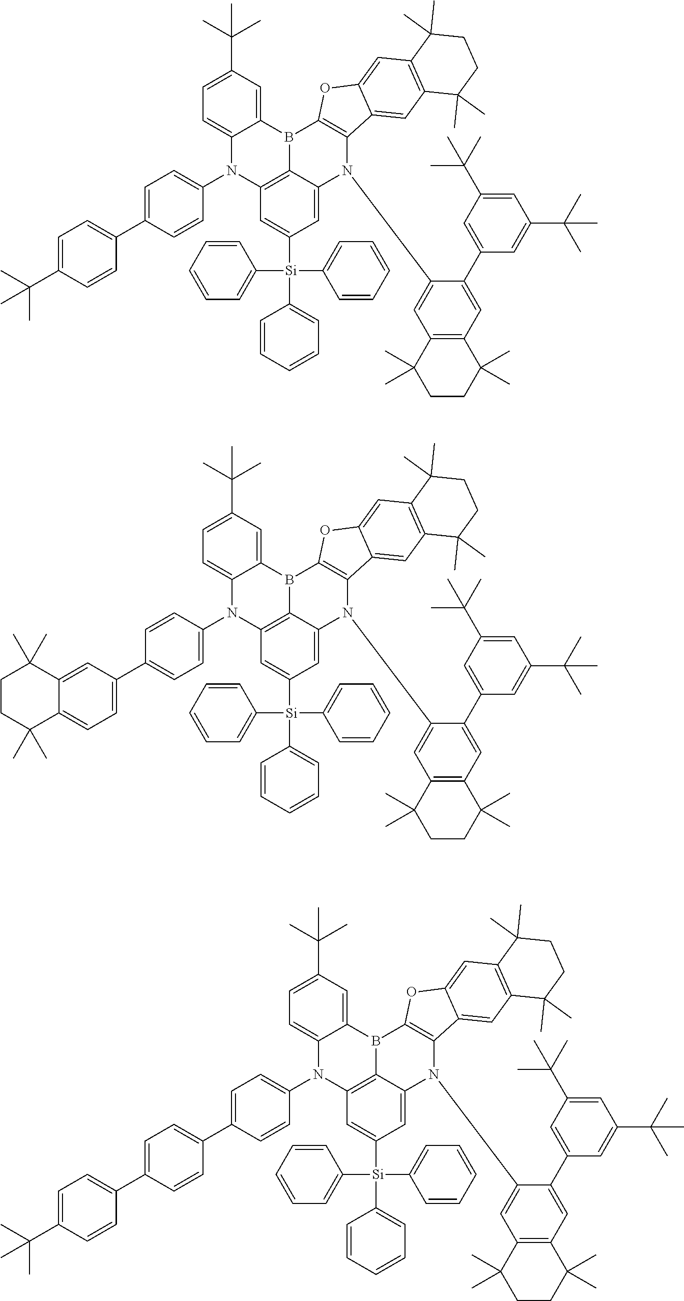

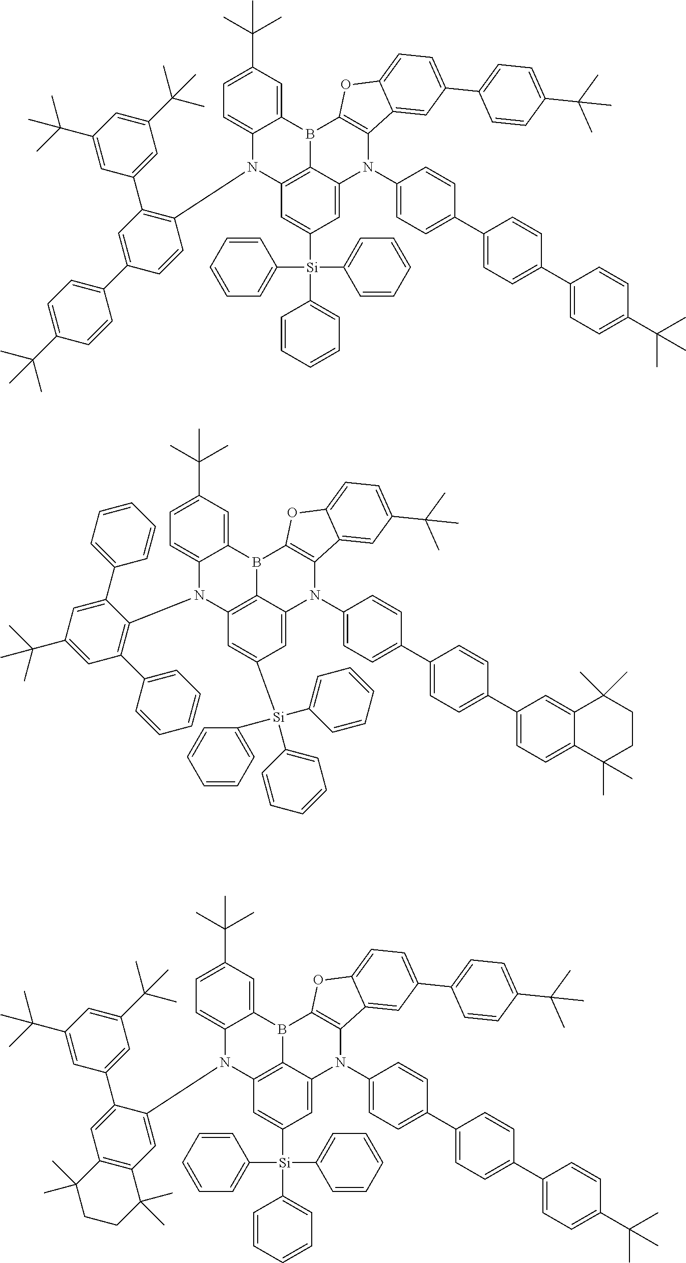

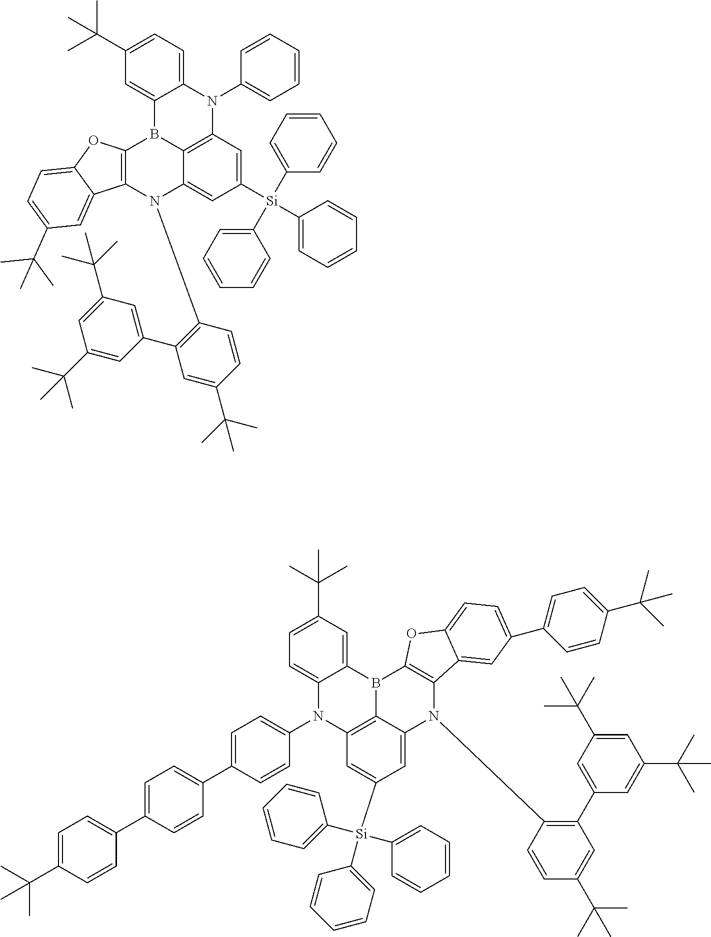 [SMILES: CC(C)(C)c1cc(-c2cc(C(C)(C)C)ccc2N2c3cc([Si](c4ccccc4)(c4ccccc4)c4ccccc4)cc4c3B(c3cc(C(C)(C)C)ccc3N4c3ccccc3)c3oc4ccc(C(C)(C)C)cc4c32)cc(C(C)(C)C)c1 ; CC(C)(C)c1ccc(-c2ccc(-c3ccc(N4c5ccc(C(C)(C)C)cc5B5c6oc7ccc(-c8ccc(C(C)(C)C)cc8)cc7c6N(c6ccc(C(C)(C)C)cc6-c6cc(C(C)(C)C)cc(C(C)(C)C)c6)c6cc([Si](c7ccccc7)(c7ccccc7)c7ccccc7)cc4c65)cc3)cc2)cc1]

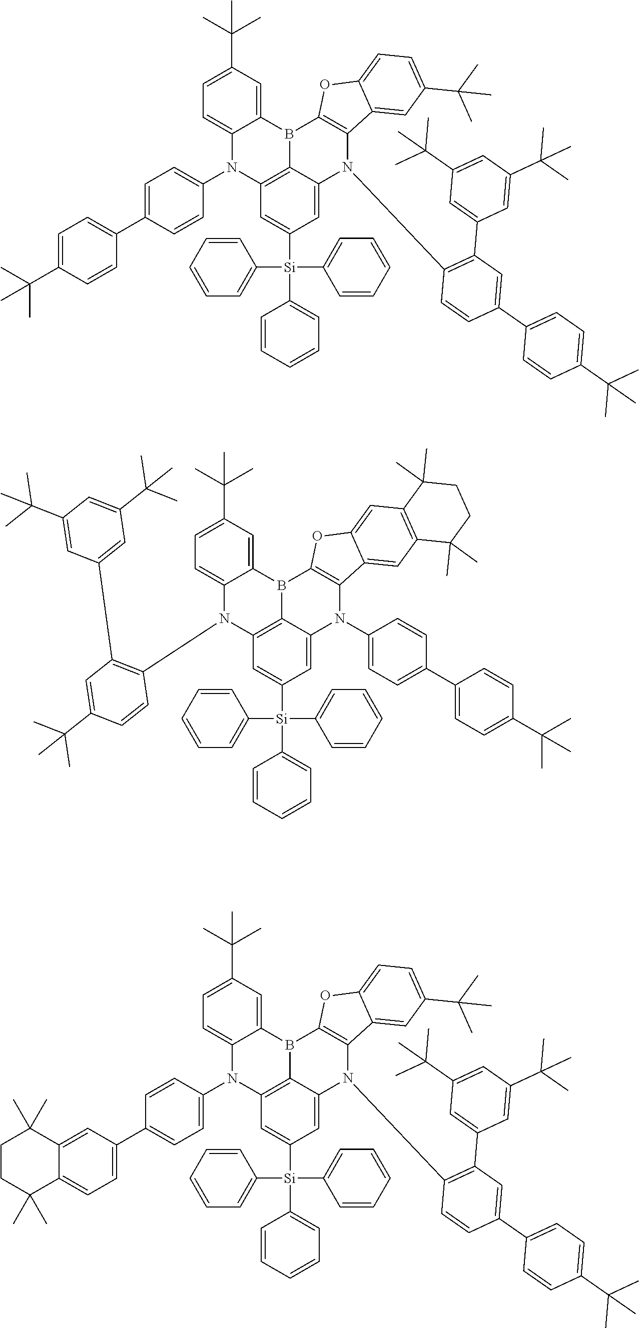

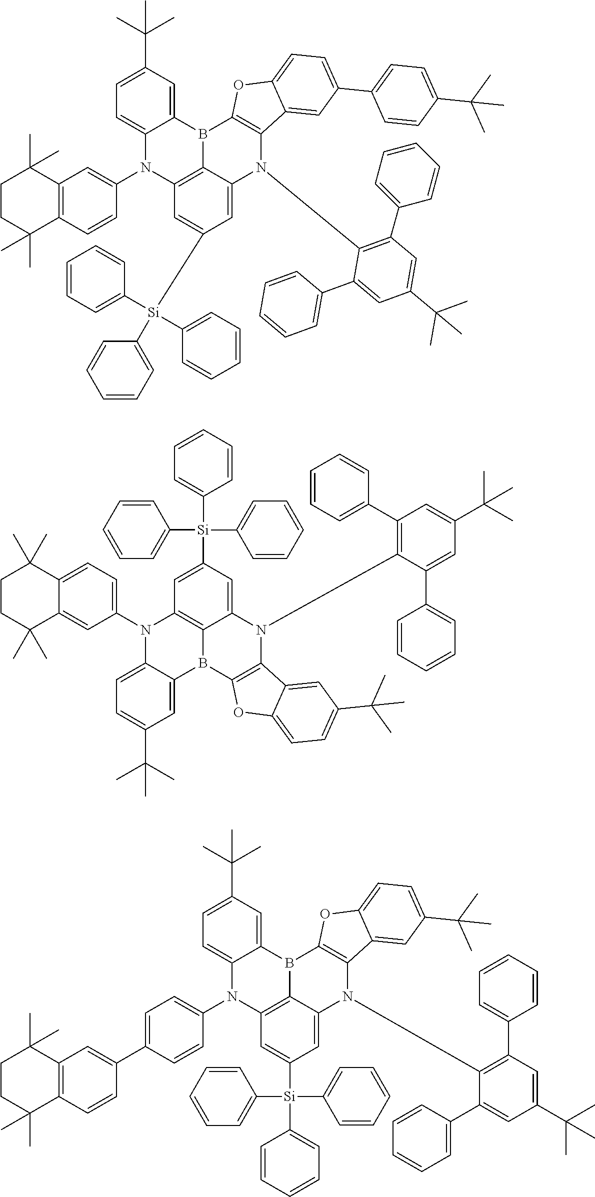 [SMILES: CC(C)(C)c1ccc(-c2ccc3oc4c(c3c2)N(c2c(-c3ccccc3)cc(C(C)(C)C)cc2-c2ccccc2)c2cc([Si](c3ccccc3)(c3ccccc3)c3ccccc3)cc3c2B4c2cc(C(C)(C)C)ccc2N3c2ccc3c(c2)C(C)(C)CCC3(C)C)cc1 ; CC(C)(C)c1ccc2c(c1)B1c3oc4ccc(C(C)(C)C)cc4c3N(c3c(-c4ccccc4)cc(C(C)(C)C)cc3-c3ccccc3)c3cc([Si](c4ccccc4)(c4ccccc4)c4ccccc4)cc(c31)N2c1ccc2c(c1)C(C)(C)CCC2(C)C ; CC(C)(C)c1ccc2c(c1)B1c3oc4ccc(C(C)(C)C)cc4c3N(c3c(-c4ccccc4)cc(C(C)(C)C)cc3-c3ccccc3)c3cc([Si](c4ccccc4)(c4ccccc4)c4ccccc4)cc(c31)N2c1ccc(-c2ccc3c(c2)C(C)(C)CCC3(C)C)cc1]

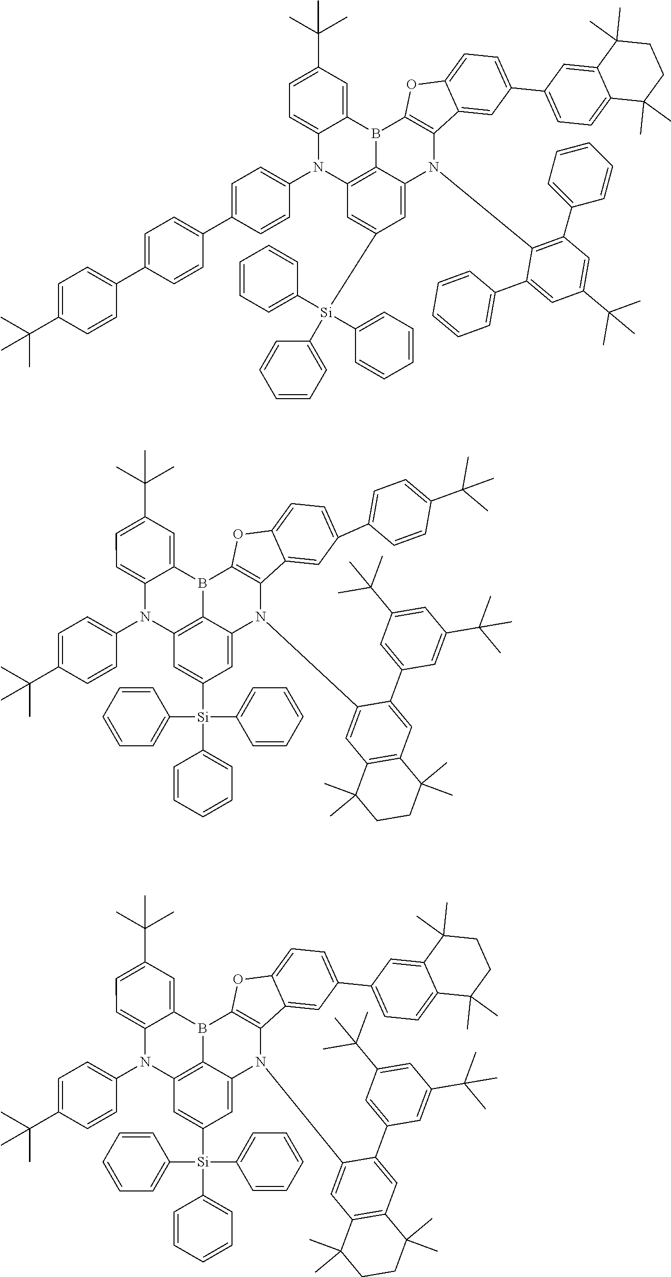

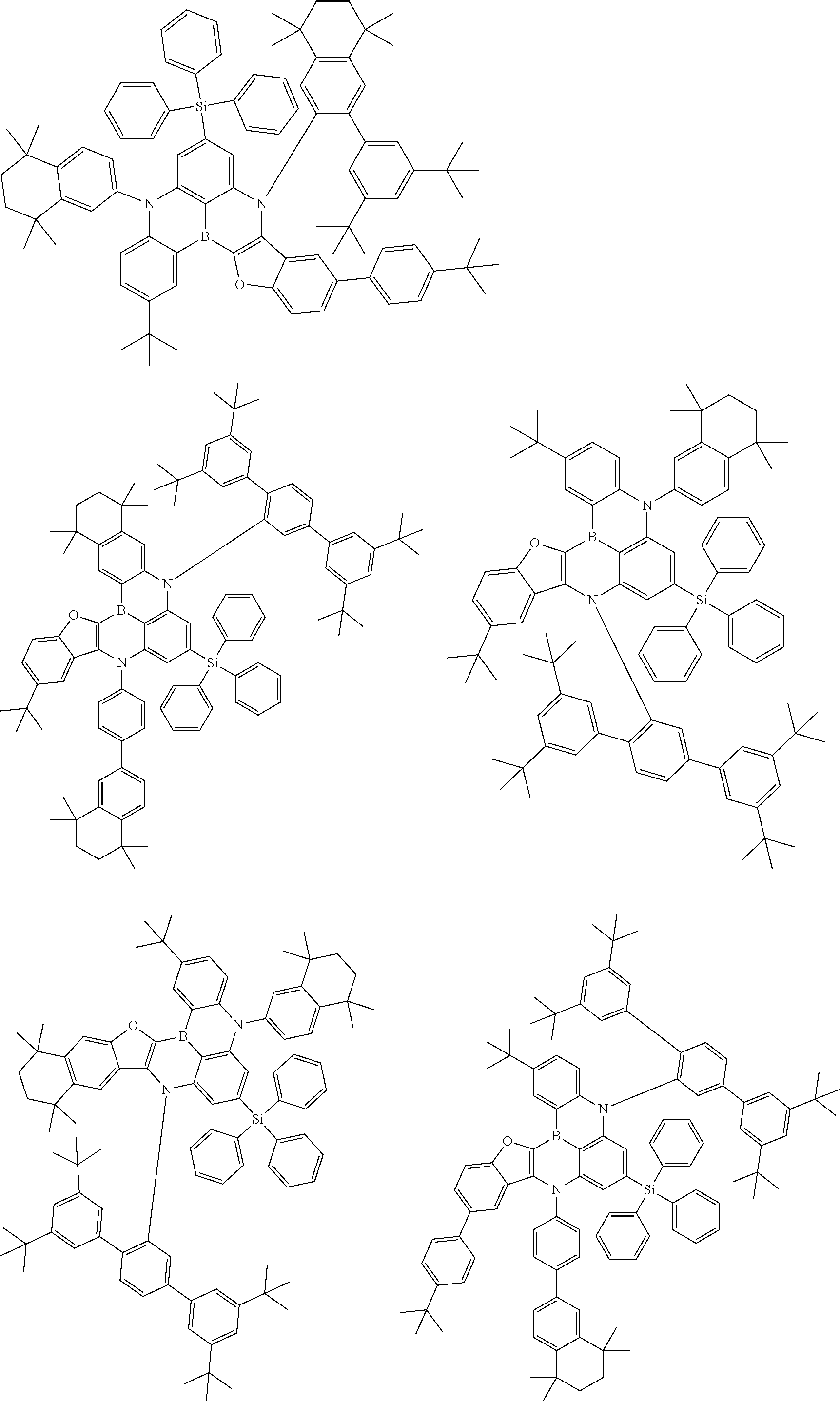

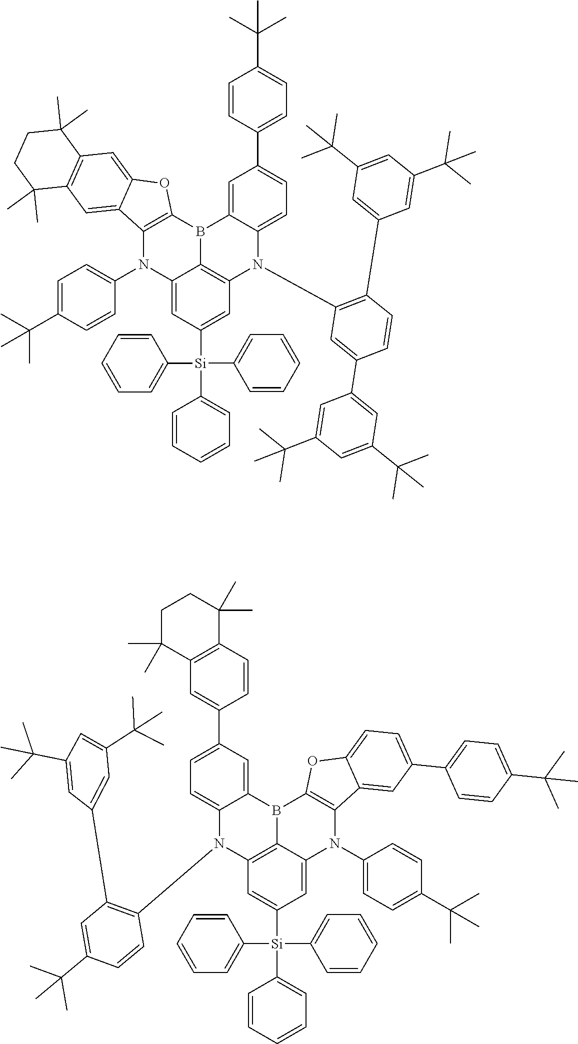

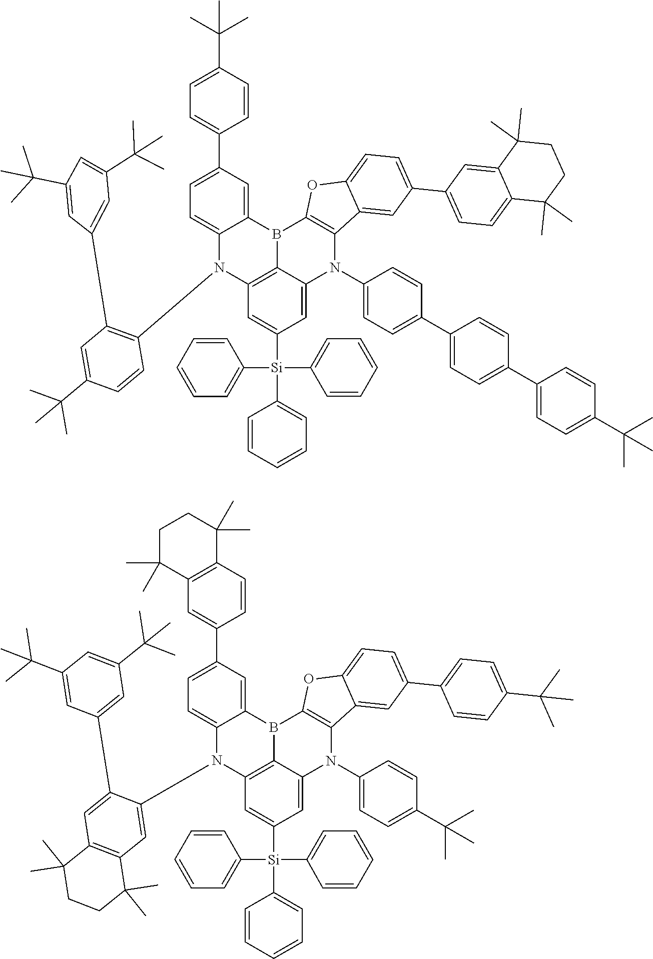

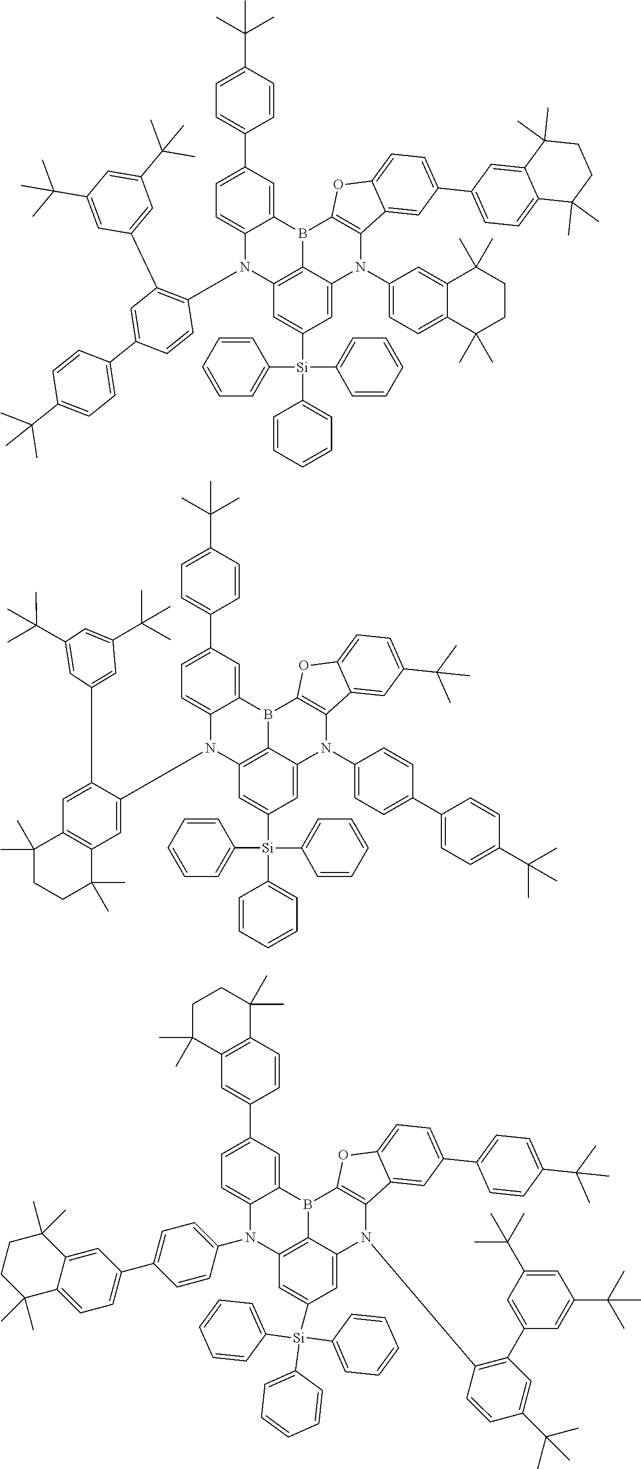

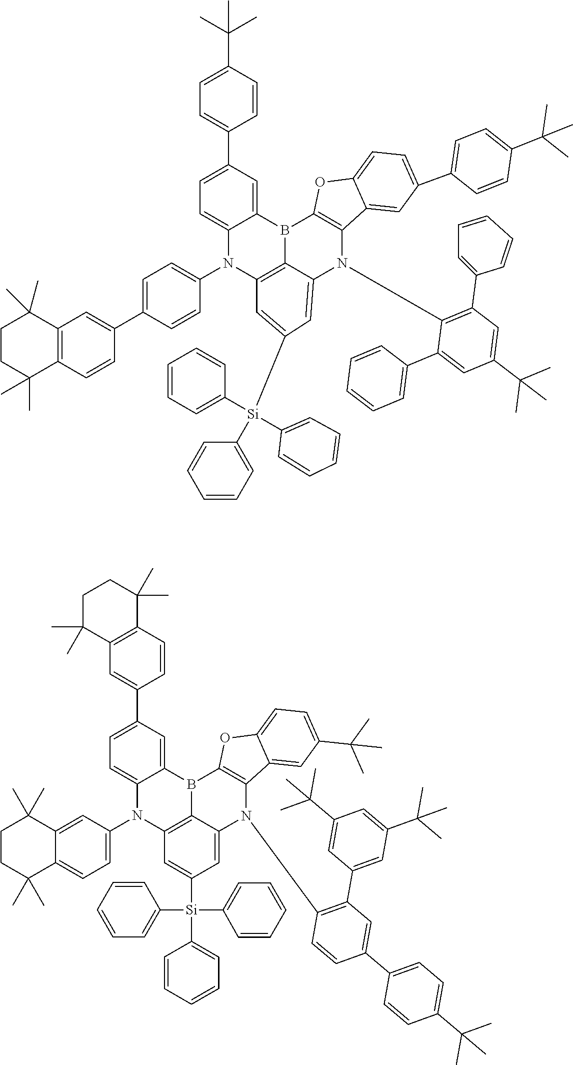 [SMILES: CC(C)(C)c1ccc(-c2ccc3c(c2)B2c4oc5ccc(-c6ccc(C(C)(C)C)cc6)cc5c4N(c4c(-c5ccccc5)cc(C(C)(C)C)cc4-c4ccccc4)c4cc([Si](c5ccccc5)(c5ccccc5)c5ccccc5)cc(c42)N3c2ccc(-c3ccc4c(c3)C(C)(C)CCC4(C)C)cc2)cc1 ; CC(C)(C)c1ccc(-c2ccc(N3c4cc([Si](c5ccccc5)(c5ccccc5)c5ccccc5)cc5c4B(c4cc(-c6ccc7c(c6)C(C)(C)CCC7(C)C)ccc4N5c4ccc5c(c4)C(C)(C)CCC5(C)C)c4oc5ccc(C(C)(C)C)cc5c43)c(-c3cc(C(C)(C)C)cc(C(C)(C)C)c3)c2)cc1]

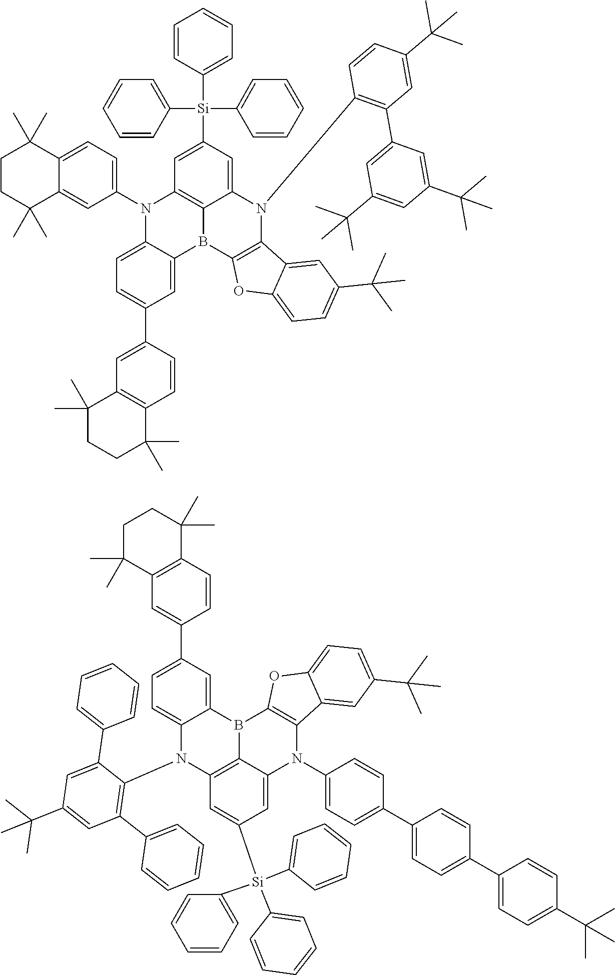

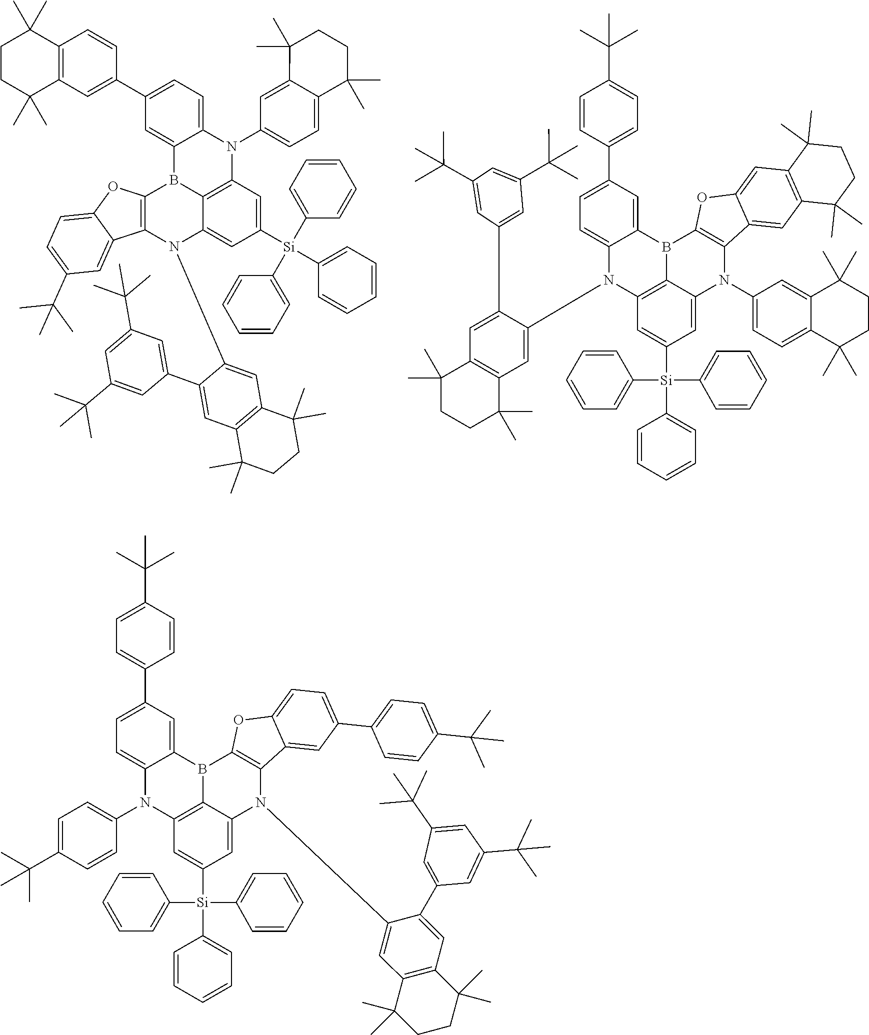

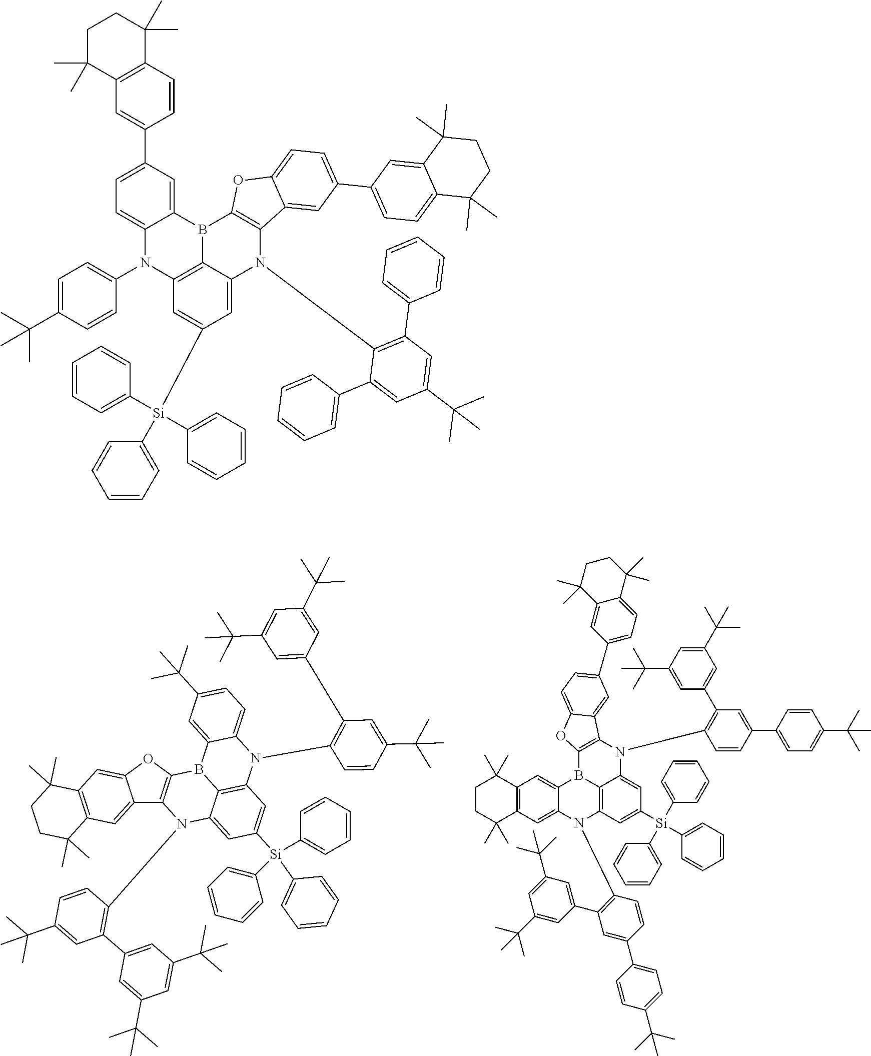

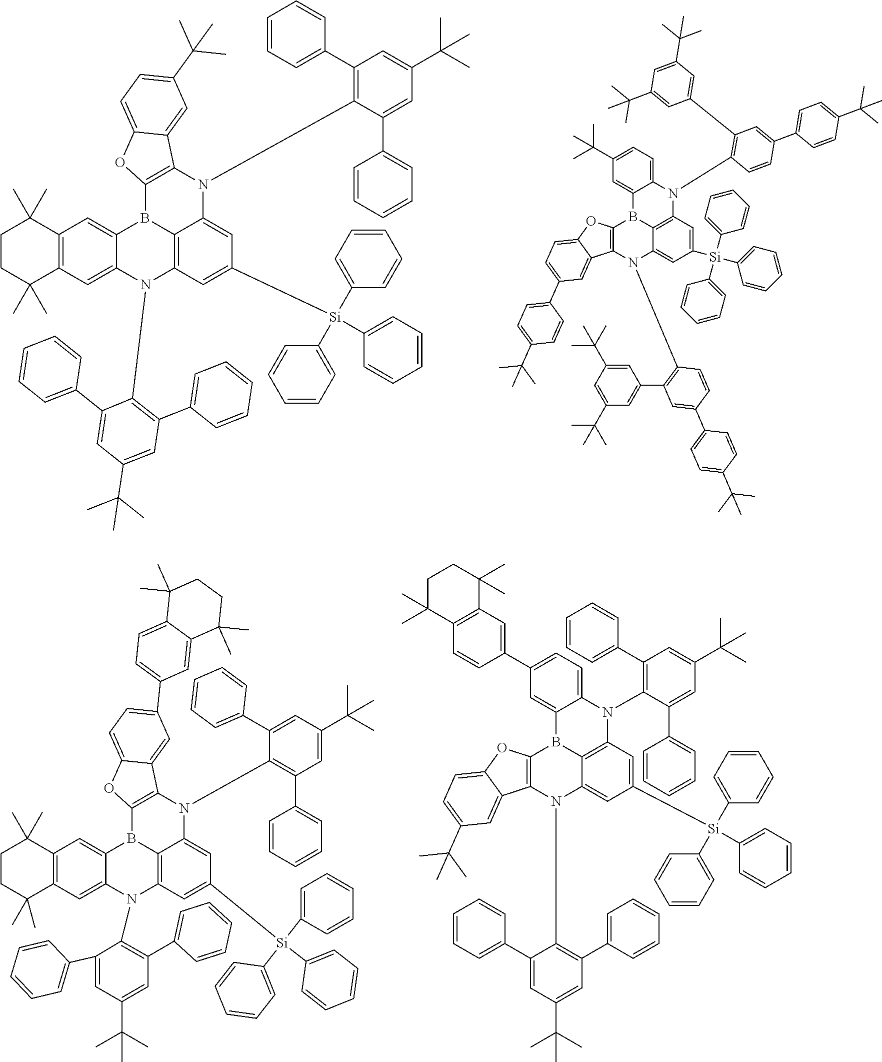

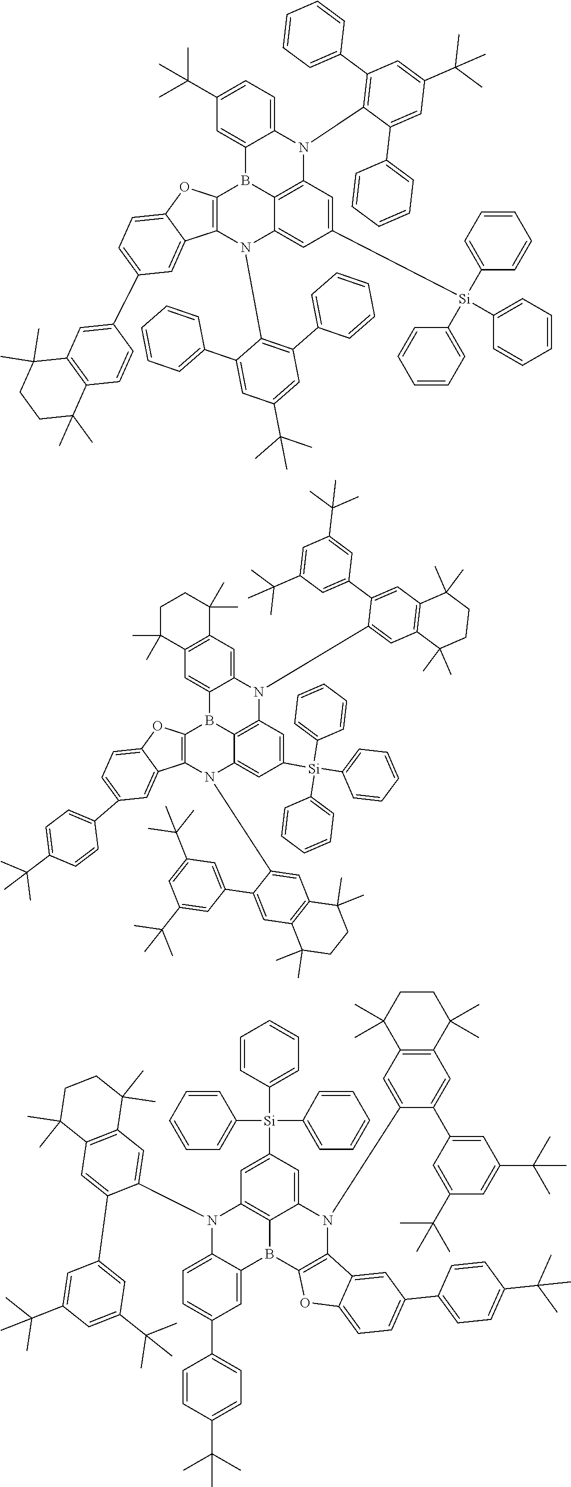

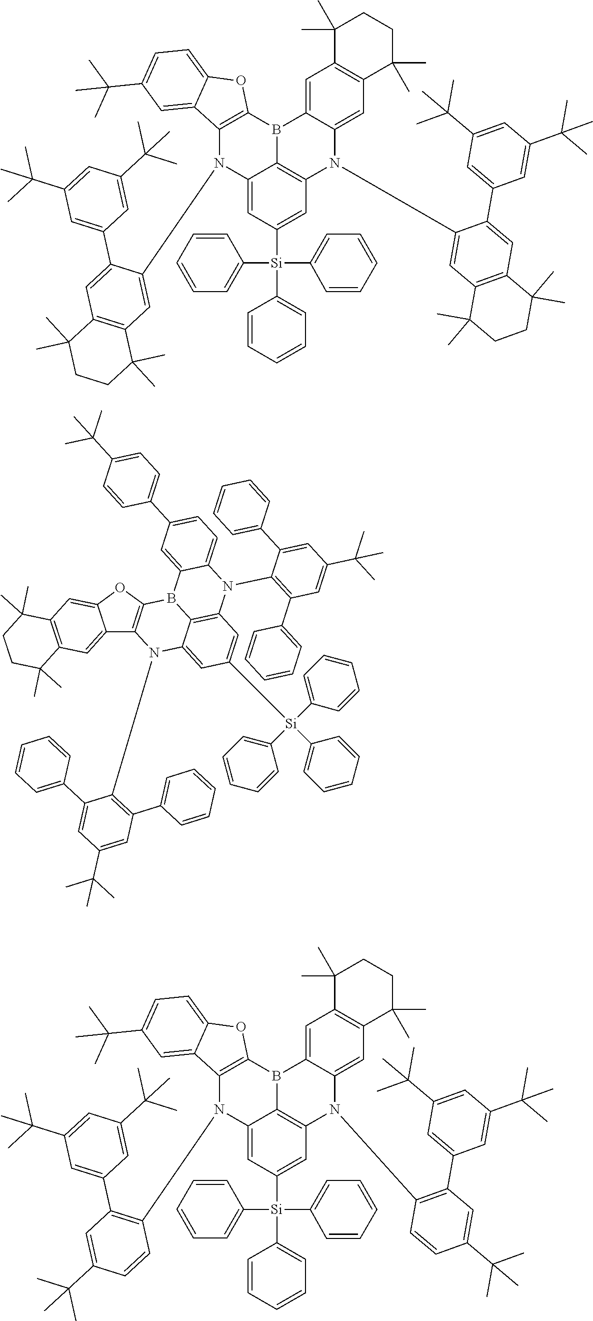

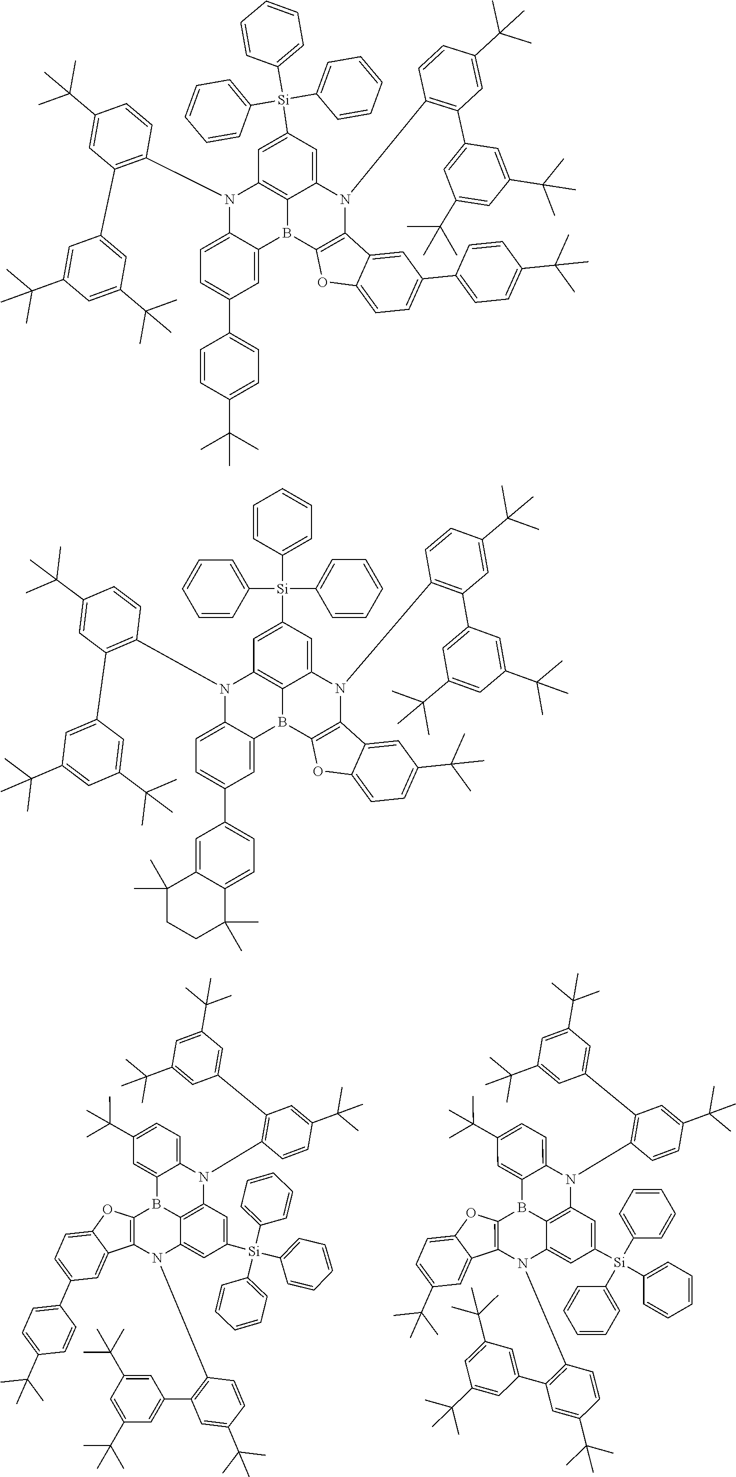

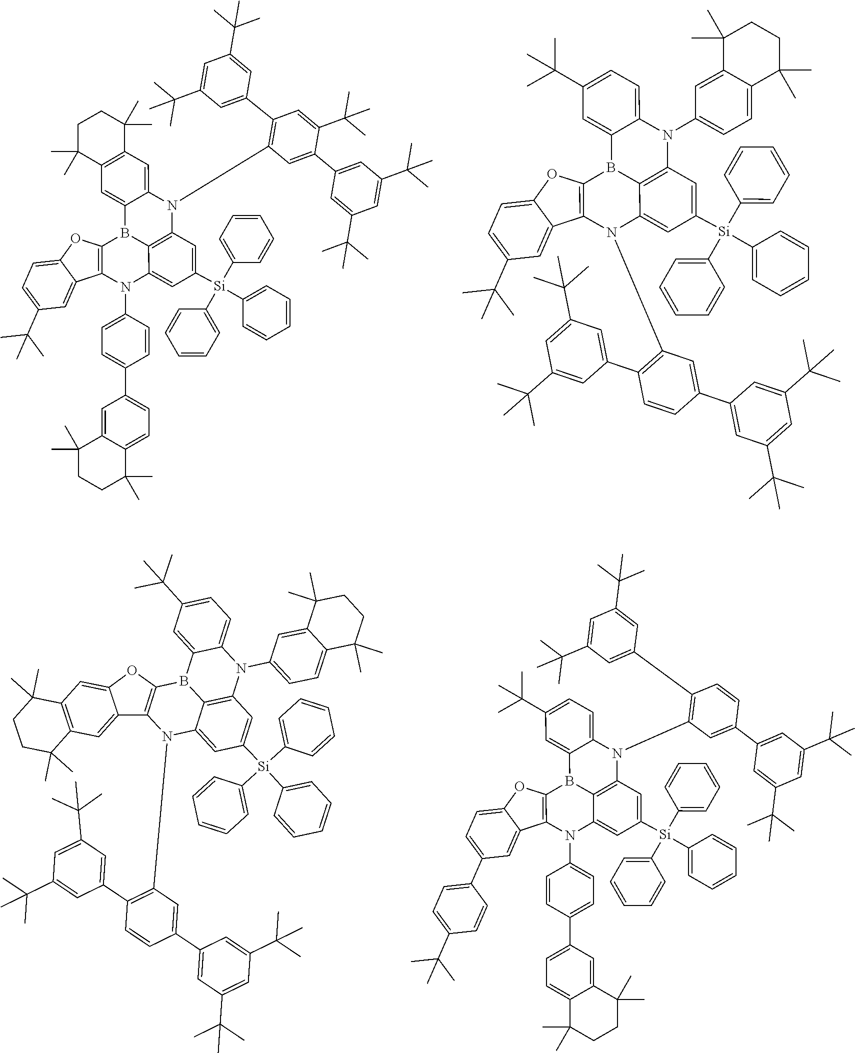

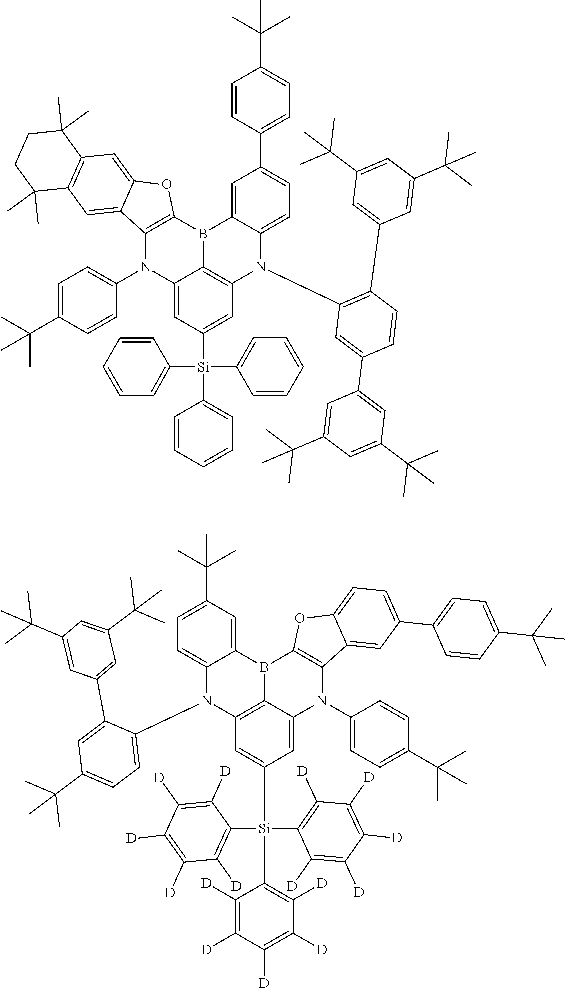

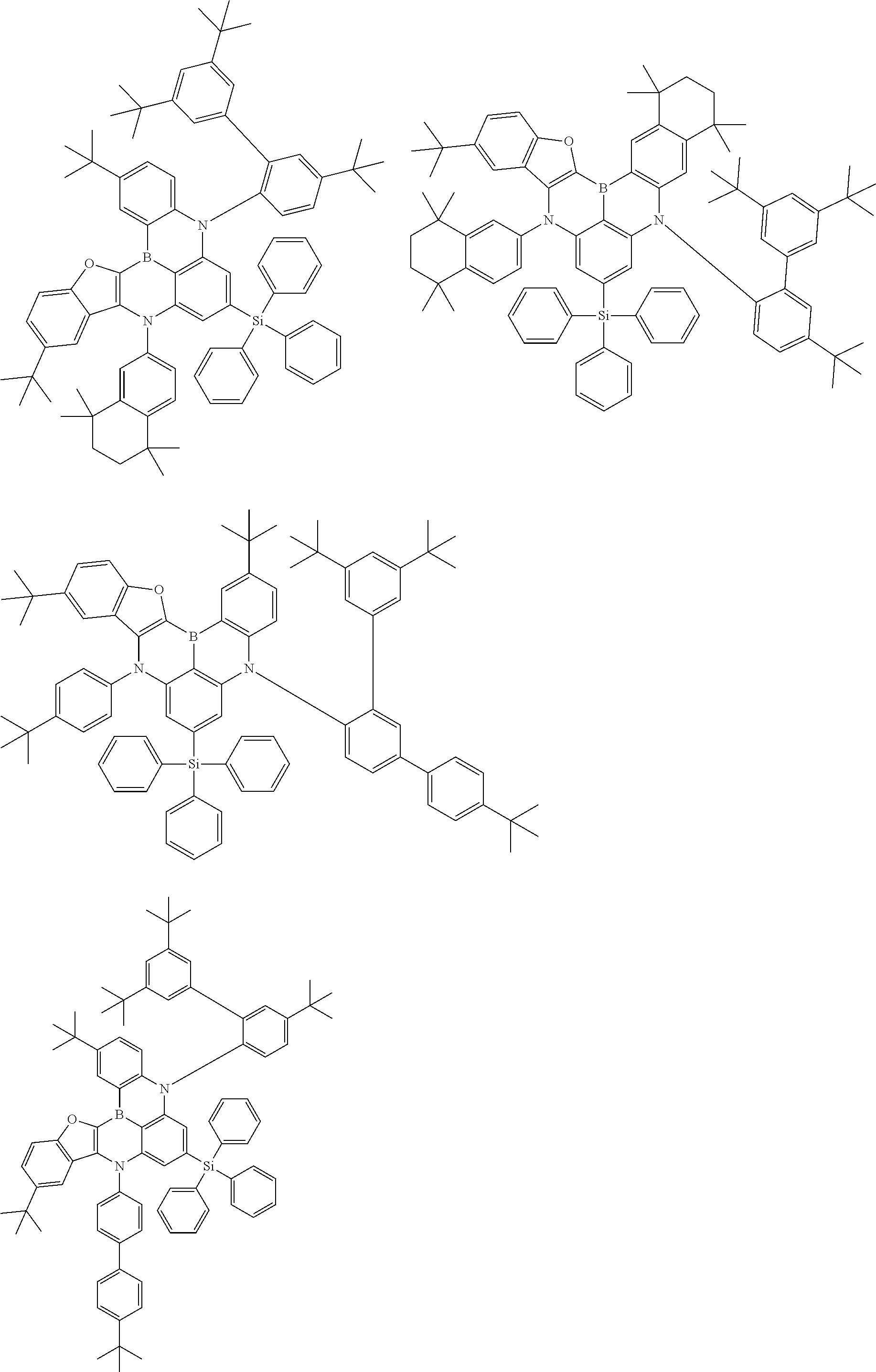

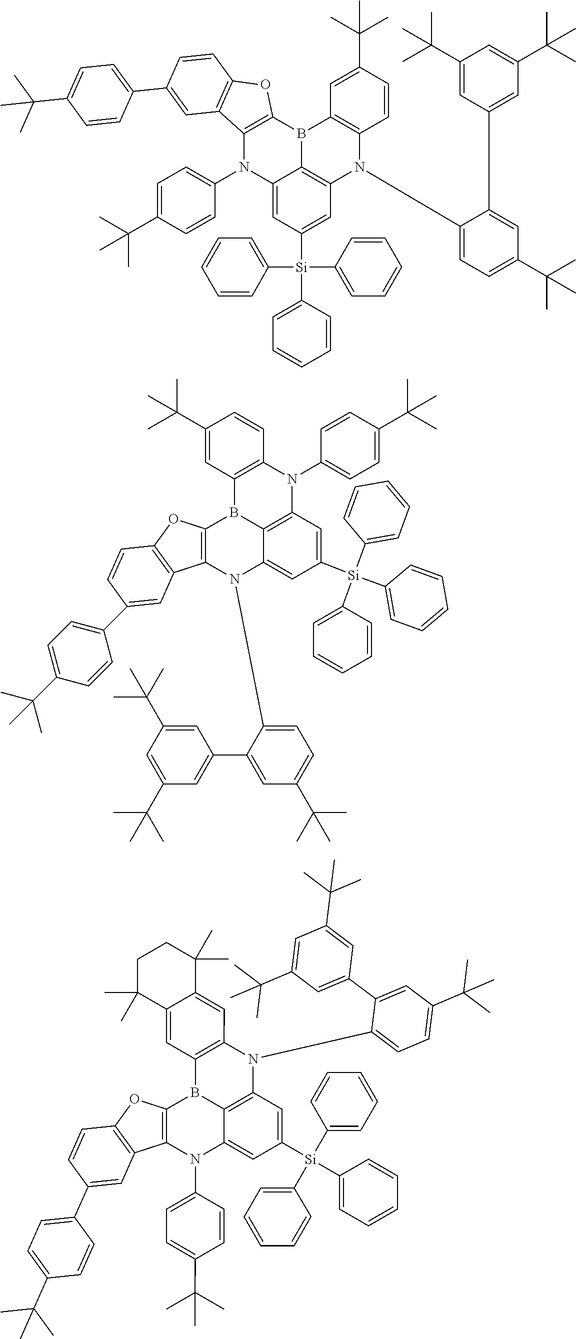

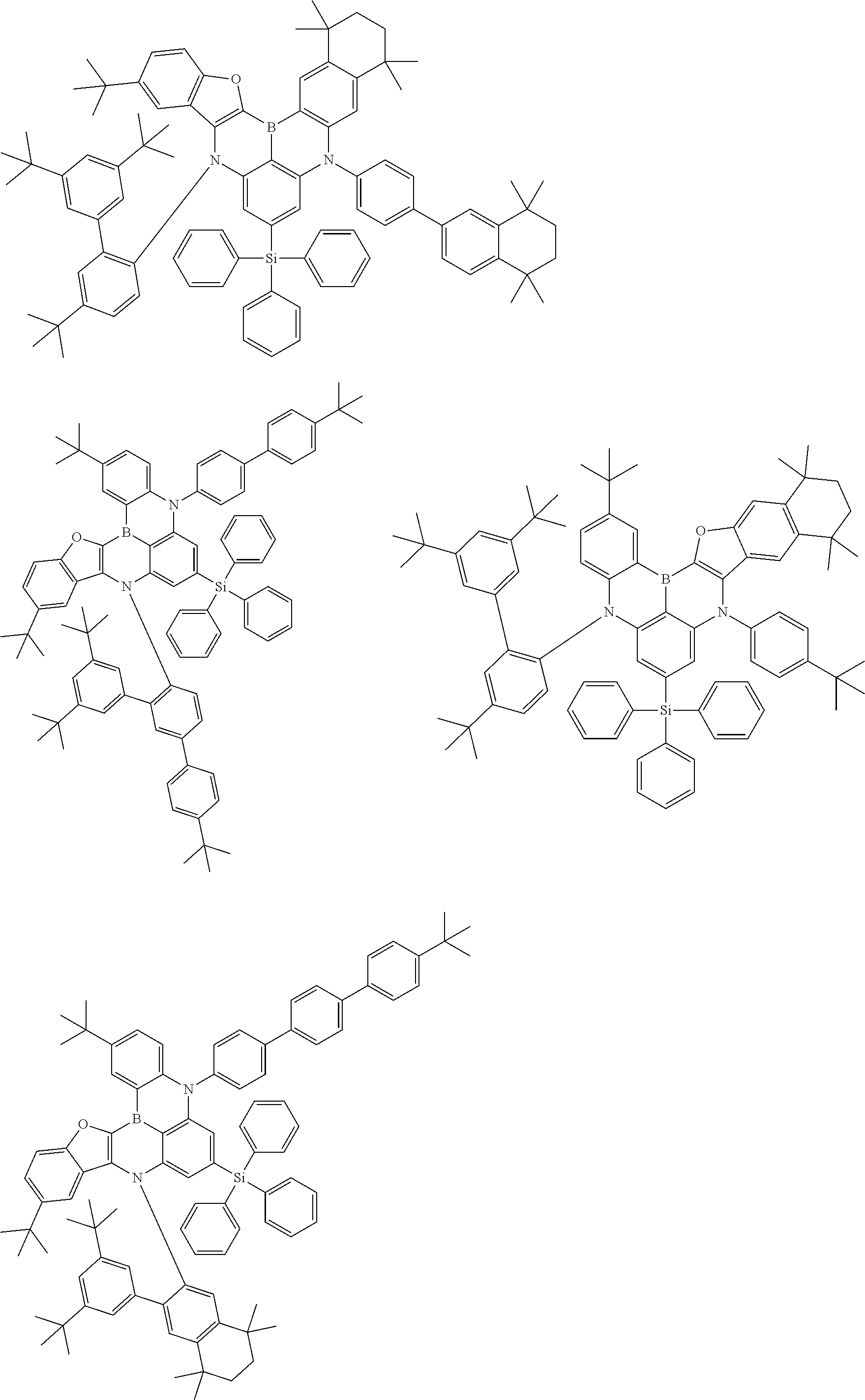

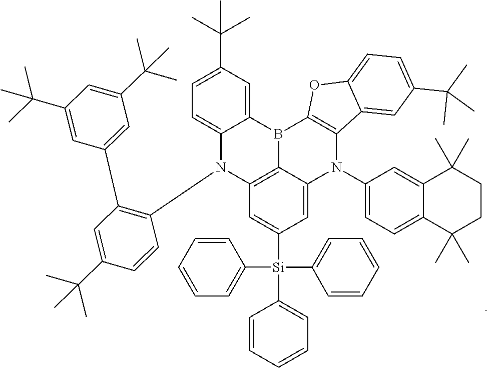 [SMILES: CC(C)(C)c1cc(-c2cc(C(C)(C)C)ccc2N2c3ccc(C(C)(C)C)cc3B3c4oc5ccc(C(C)(C)C)cc5c4N(c4ccc5c(c4)C(C)(C)CCC5(C)C)c4cc([Si](c5ccccc5)(c5ccccc5)c5ccccc5)cc2c43)cc(C(C)(C)C)c1]

9. An organic electroluminescent device, characterized by comprising an anode, a hole transport region, a luminescent layer, an electron transport region, and a cathode, which are sequentially arranged on a substrate plate, wherein the luminescent layer comprises a host material and a dopant material, and the dopant material comprises one or more polycyclic compounds according to claim 1.

10. The organic electroluminescent device according to claim 9, characterized in that the host material is selected from structures represented by the following general formula: 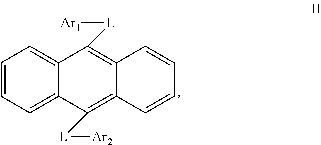
wherein
L is selected from a single bond or phenylene;
Ar₁ is selected from phenyl or naphthyl;
Ar₂ represents one of the following groups: 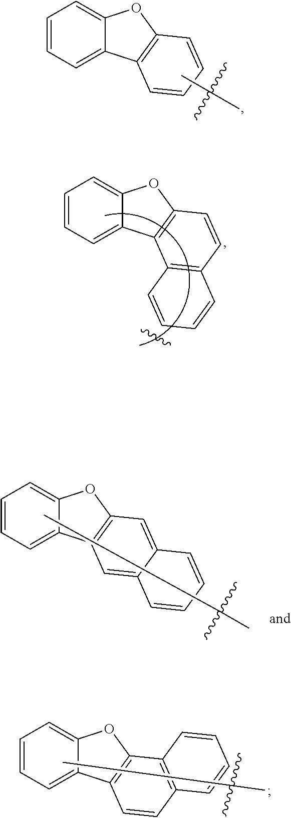
and
any hydrogen in Formula II can be replaced by deuterium, alkyl, or aryl.

11. The organic electroluminescent device according to claim 9, characterized in that the host material is selected from the following structures:

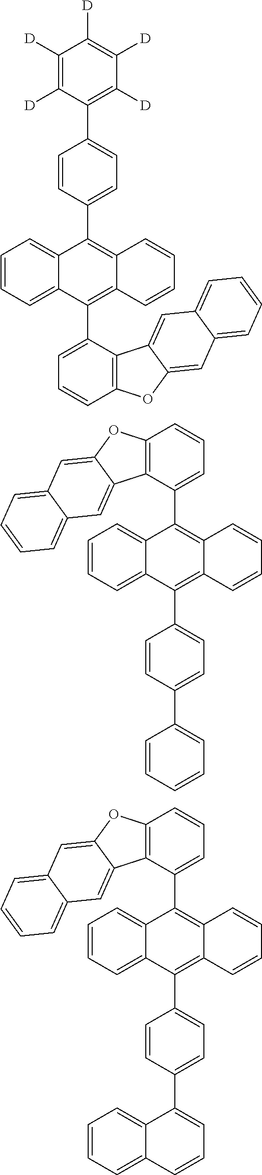

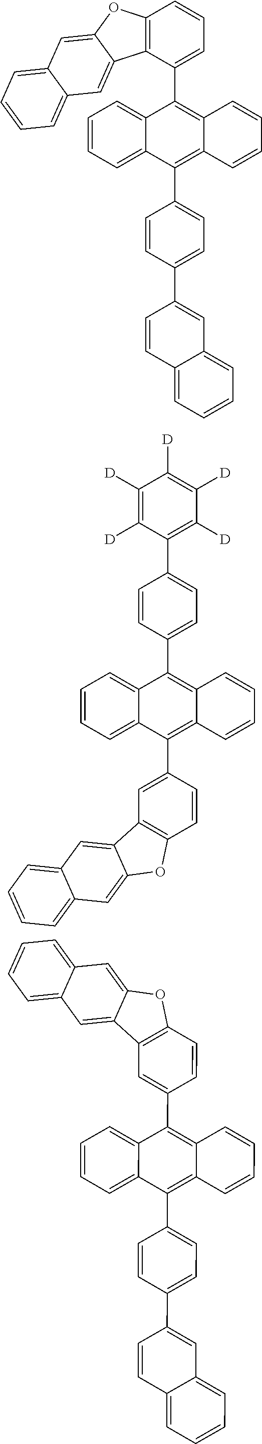

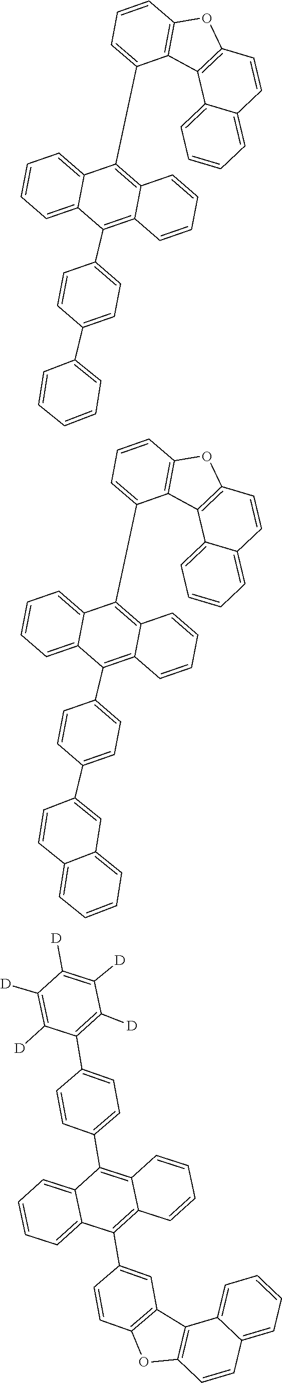

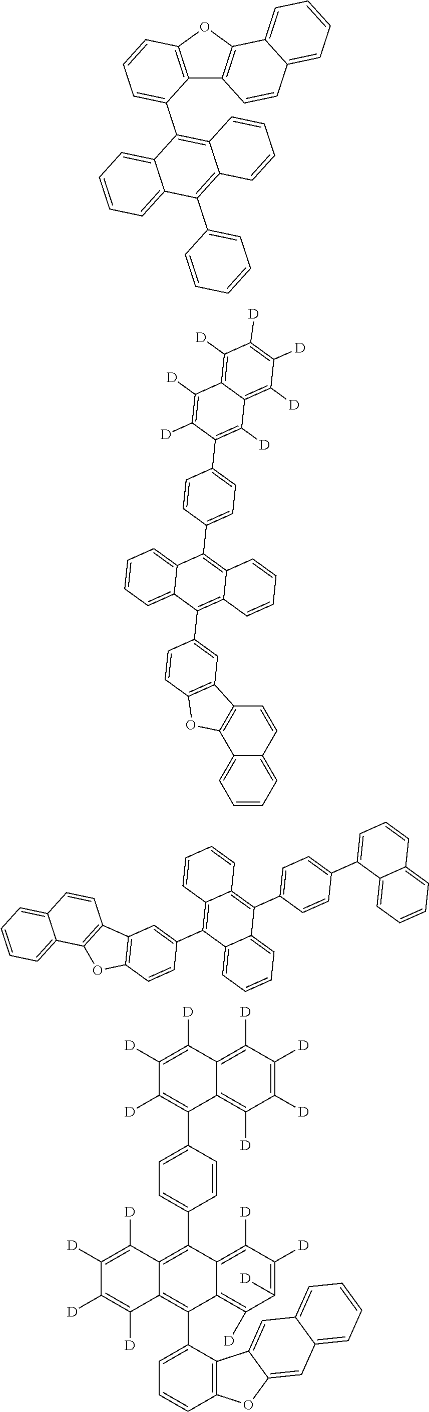

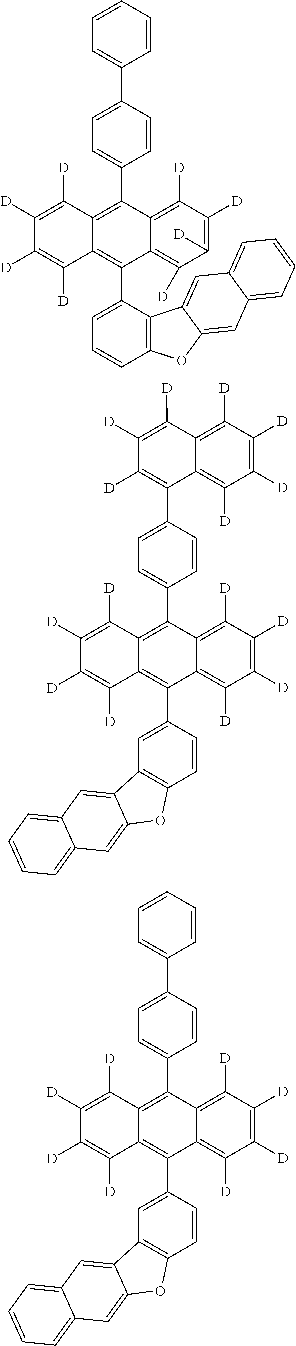

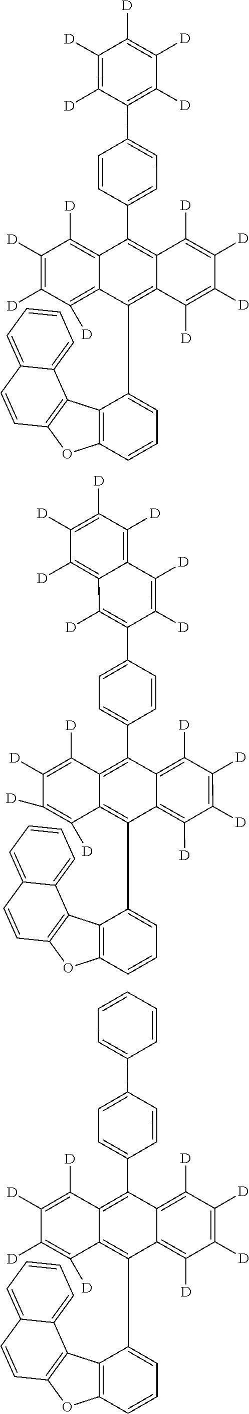

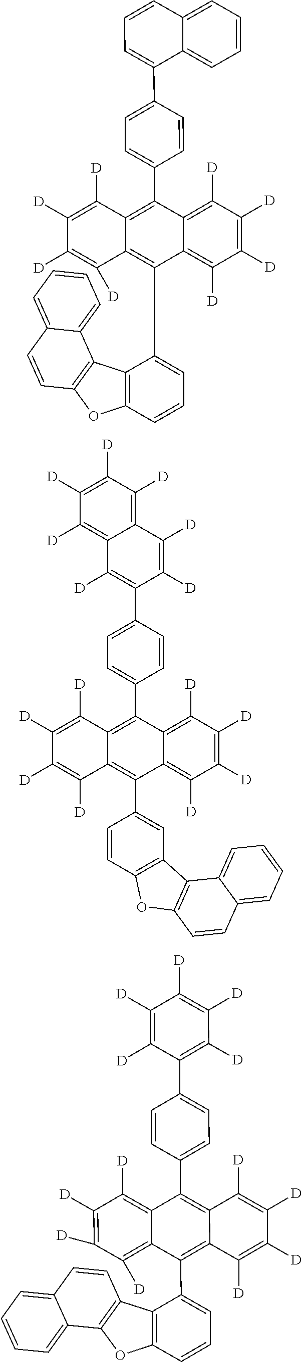

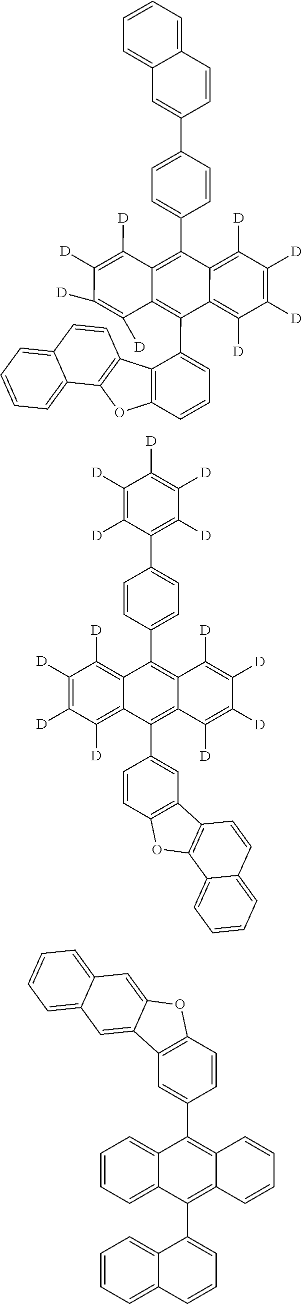

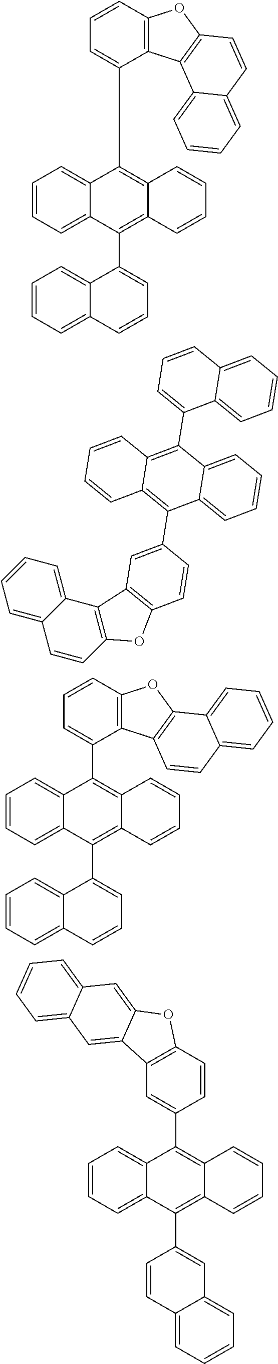

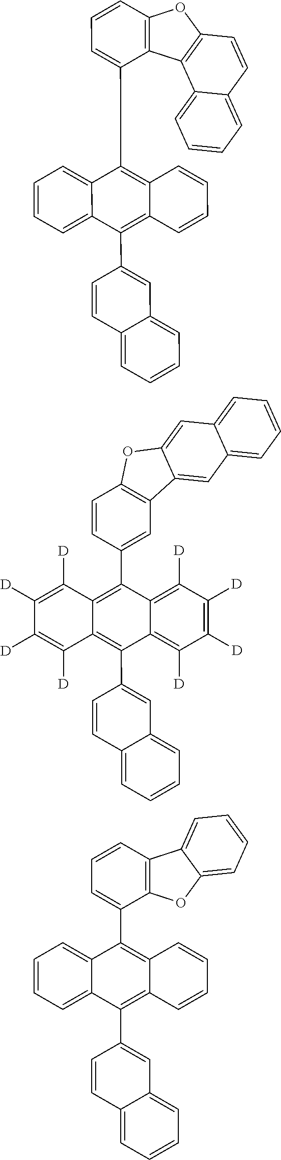

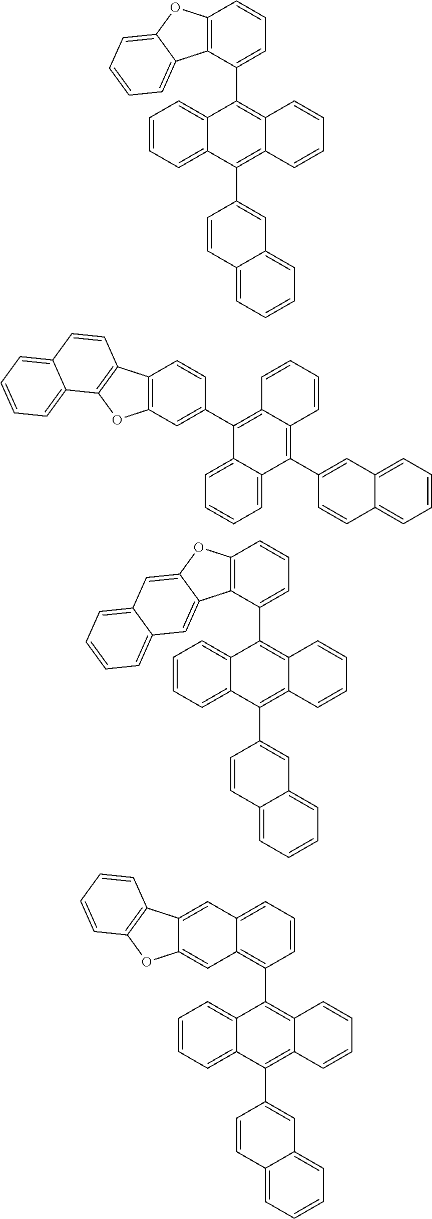

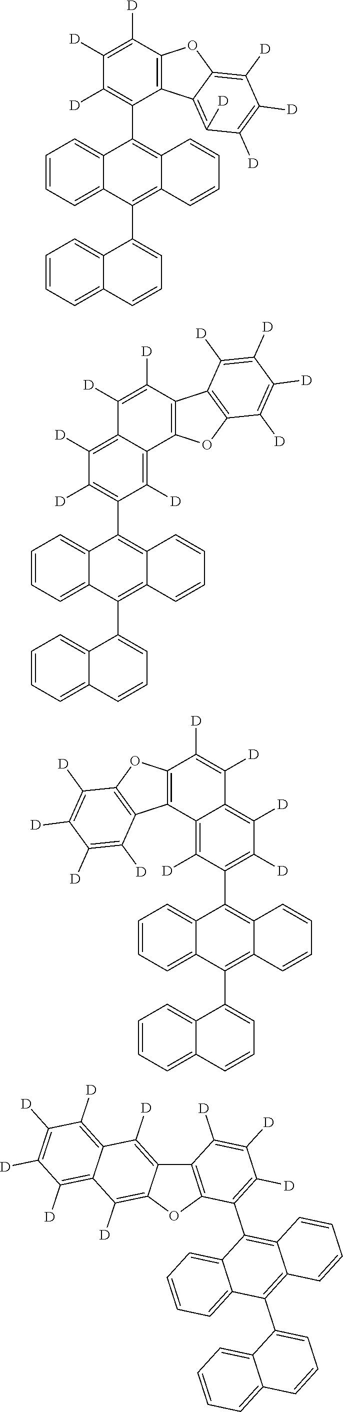

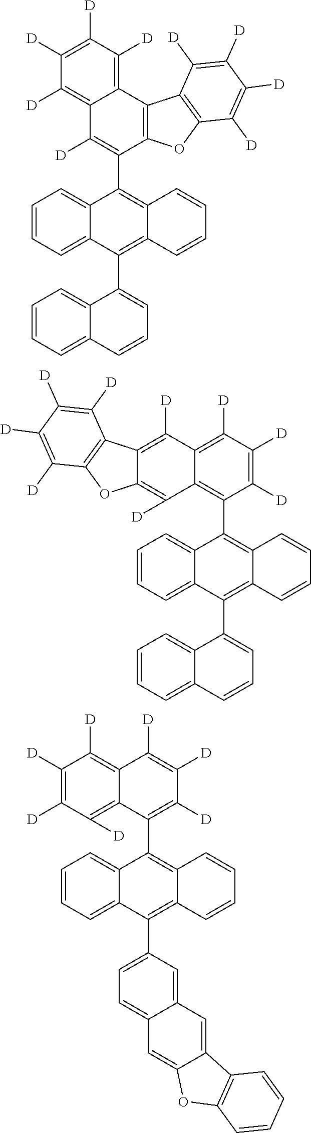

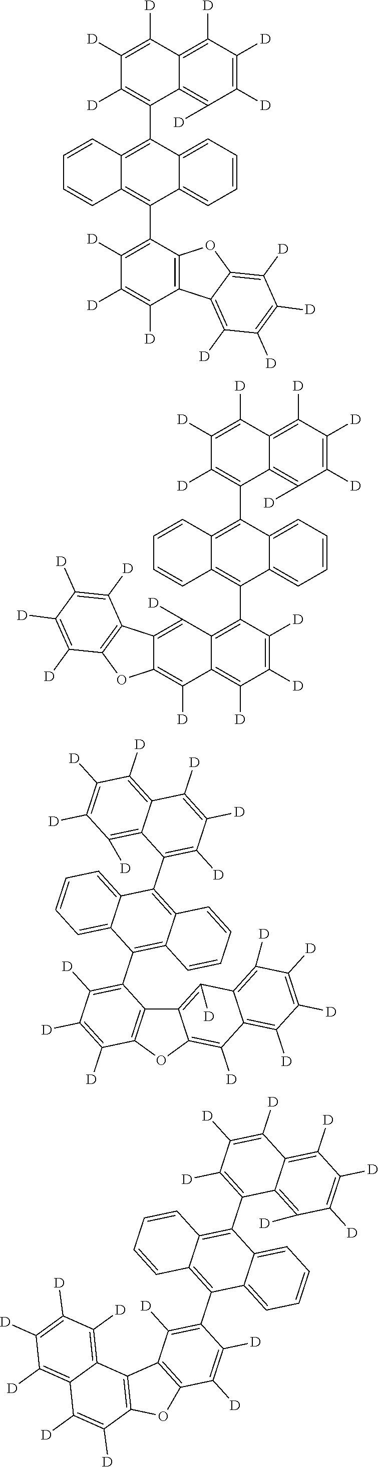

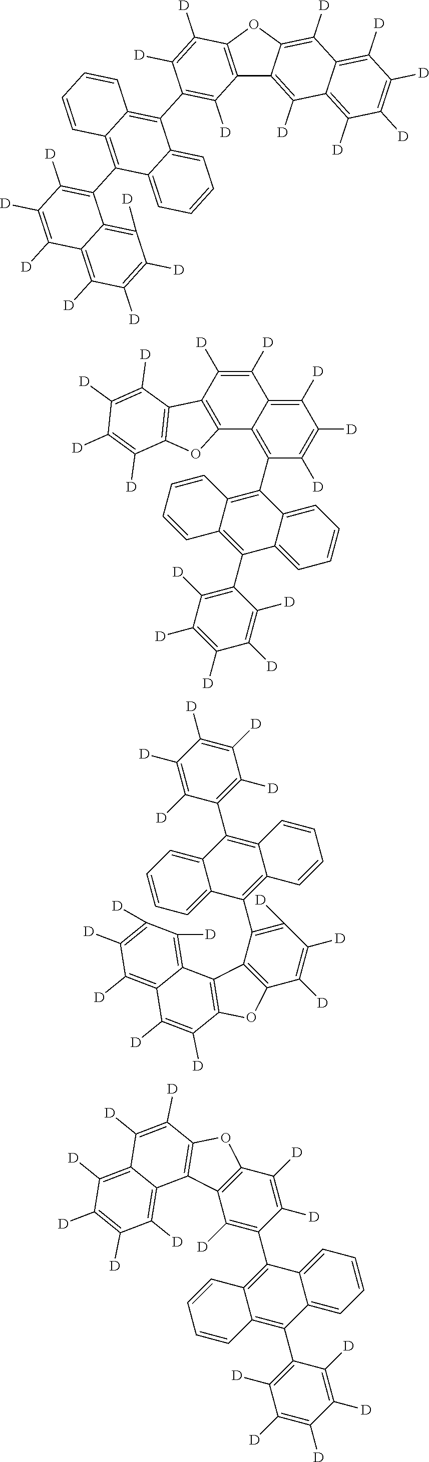

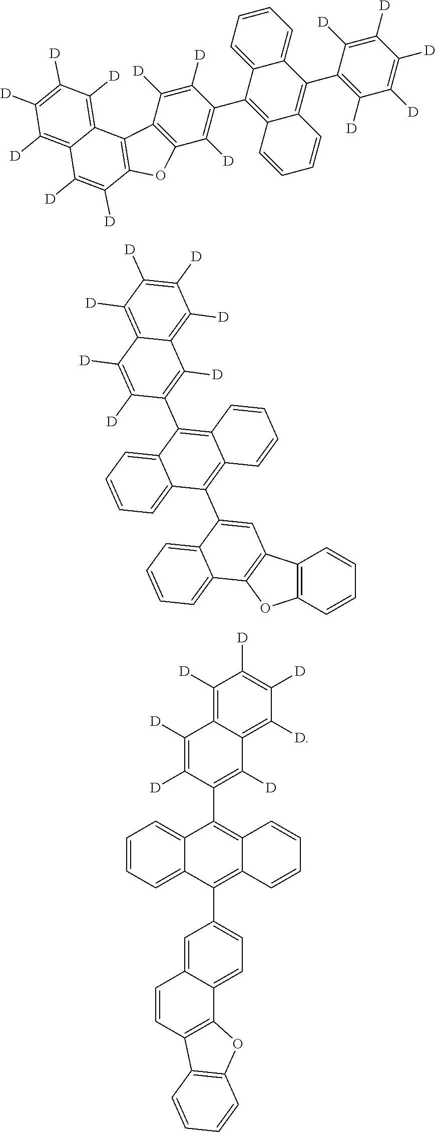

12. An organic electroluminescent device, characterized by comprising an anode, a hole transport region, a luminescent layer, an electron transport region, and a cathode, which are sequentially arranged on a substrate plate, wherein the luminescent layer comprises a host material and a dopant material, and the dopant material comprises one or more polycyclic compounds according to claim 2.

13. The organic electroluminescent device according to claim 12, characterized in that the host material is selected from structures represented by the following general formula: 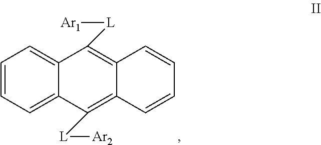
wherein
L is selected from a single bond or phenylene;
Ar₁ is selected from phenyl or naphthyl;
Ar₂ represents one of the following groups: 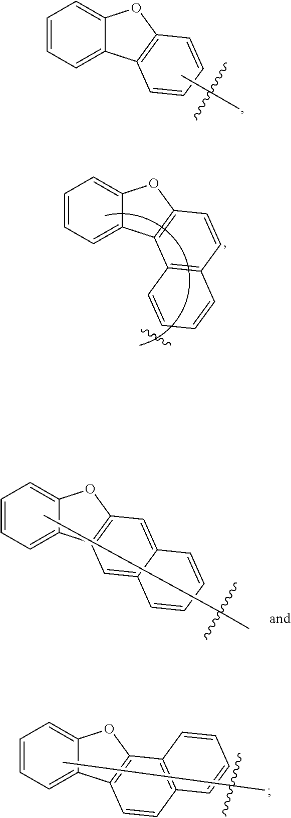
and
any hydrogen in Formula II can be replaced by deuterium, alkyl, or aryl.

14. The organic electroluminescent device according to claim 12, characterized in that the host material is selected from the following structures:

[chemical structure]

[chemical structure]

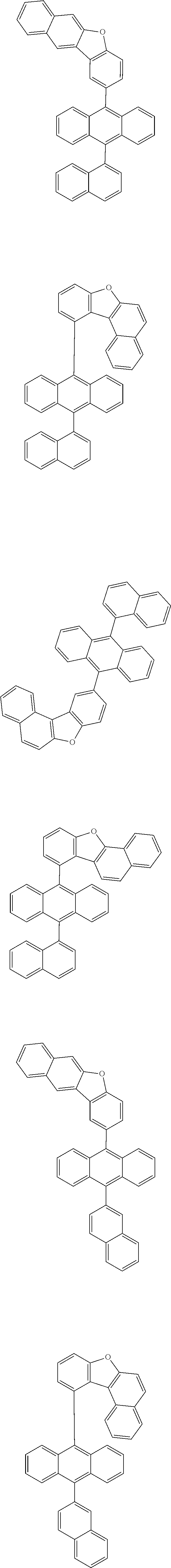 [SMILES: c1ccc2cc3c(cc2c1)oc1ccc(-c2c4ccccc4c(-c4cccc5ccccc45)c4ccccc24)cc13 ; c1ccc2c(-c3c4ccccc4c(-c4cccc5oc6ccc7ccccc7c6c45)c4ccccc34)cccc2c1 ; c1ccc2c(-c3c4ccccc4c(-c4ccc5oc6ccc7ccccc7c6c5c4)c4ccccc34)cccc2c1 ; c1ccc2c(-c3c4ccccc4c(-c4cccc5oc6c7ccccc7ccc6c45)c4ccccc34)cccc2c1 ; c1ccc2cc(-c3c4ccccc4c(-c4ccc5oc6cc7ccccc7cc6c5c4)c4ccccc34)ccc2c1 ; c1ccc2cc(-c3c4ccccc4c(-c4cccc5oc6ccc7ccccc7c6c45)c4ccccc34)ccc2c1]

[chemical structure]

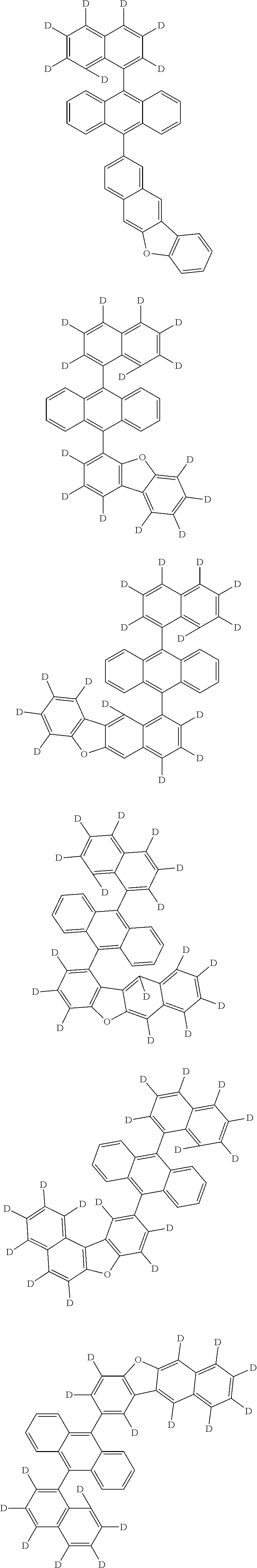

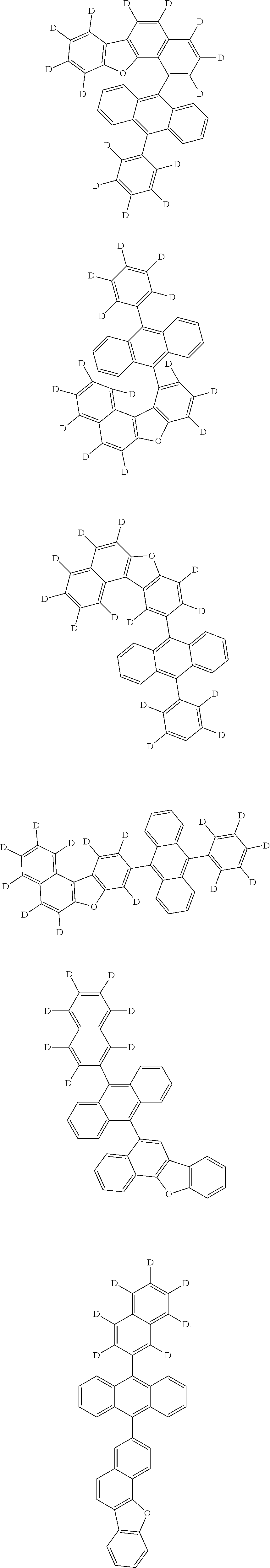

15. An organic electroluminescent device, characterized by comprising an anode, a hole transport region, a luminescent layer, an electron transport region, and a cathode, which are sequentially arranged on a substrate plate, wherein the luminescent layer comprises a host material and a dopant material, and the dopant material comprises one or more polycyclic compounds according to claim 3.

16. The organic electroluminescent device according to claim 15, characterized in that the host material is selected from structures represented by the following general formula: 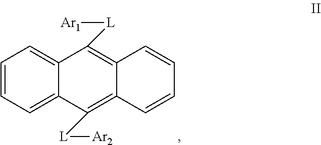
wherein
L is selected from a single bond or phenylene;
Ar₁ is selected from phenyl or naphthyl;
Ar₂ represents one of the following groups: 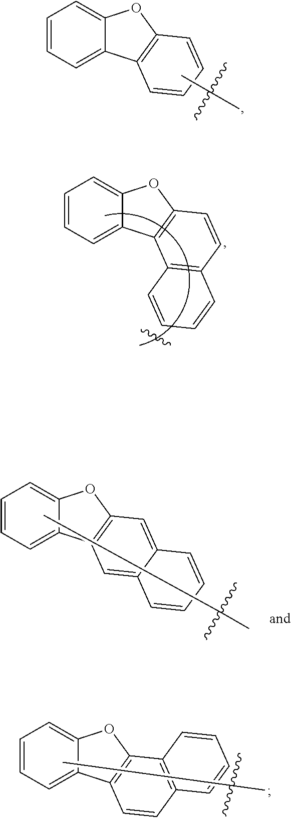
and
any hydrogen in Formula II can be replaced by deuterium, alkyl, or aryl.

17. The organic electroluminescent device according to claim 15, characterized in that the host material is selected from the following structures: 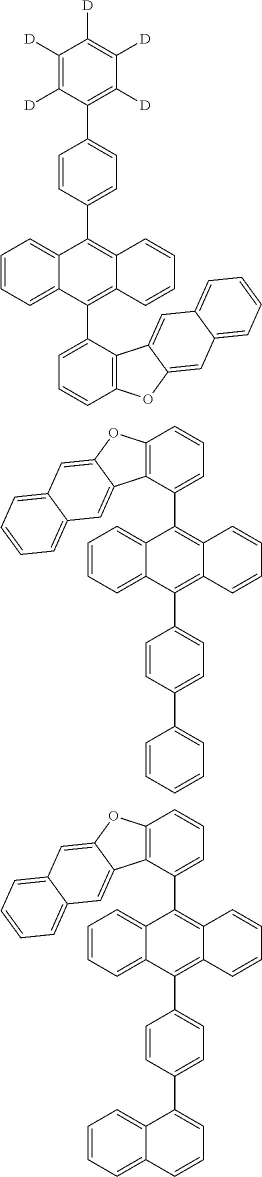 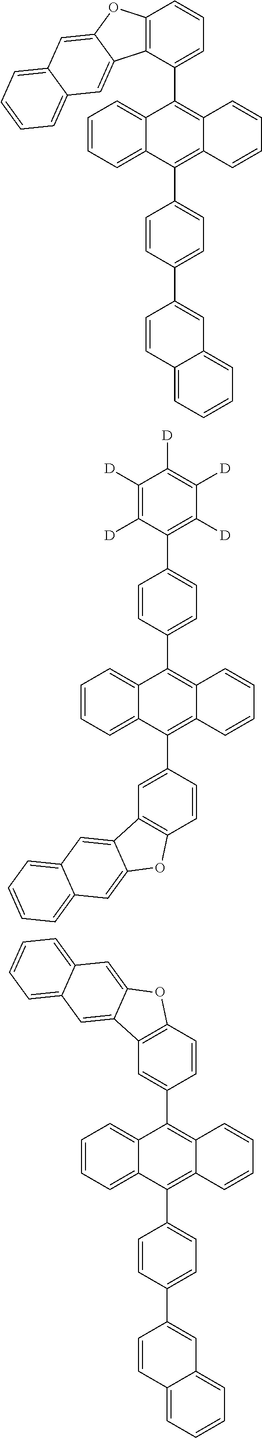 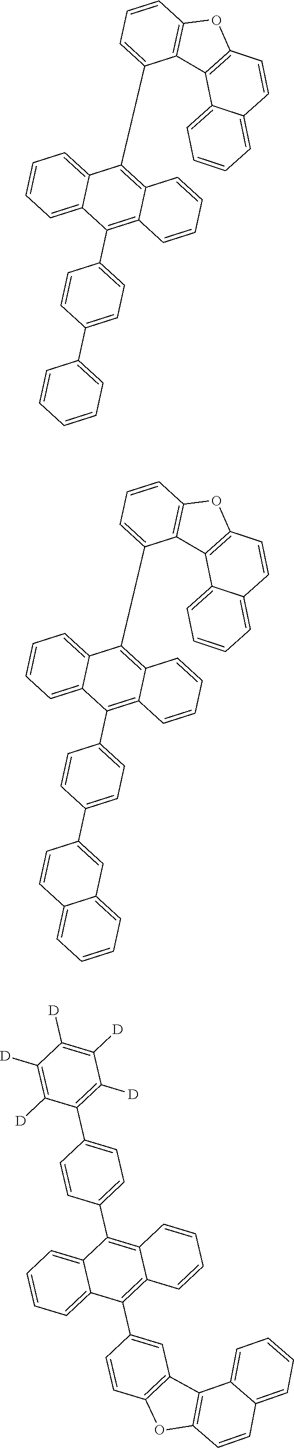 [SMILES: c1ccc(-c2ccc(-c3c4ccccc4c(-c4cccc5oc6ccc7ccccc7c6c45)c4ccccc34)cc2)cc1 ; c1ccc2cc(-c3ccc(-c4c5ccccc5c(-c5cccc6oc7ccc8ccccc8c7c56)c5ccccc45)cc3)ccc2c1 ; [2H]c1c([2H])c([2H])c(-c2ccc(-c3c4ccccc4c(-c4ccc5oc6ccc7ccccc7c6c5c4)c4ccccc34)cc2)c([2H])c1[2H]] 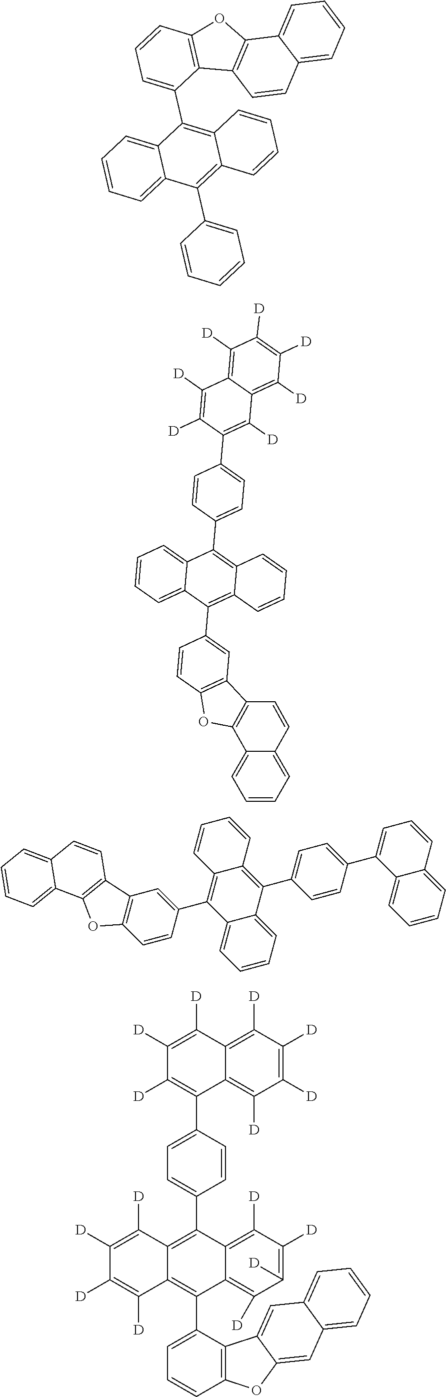 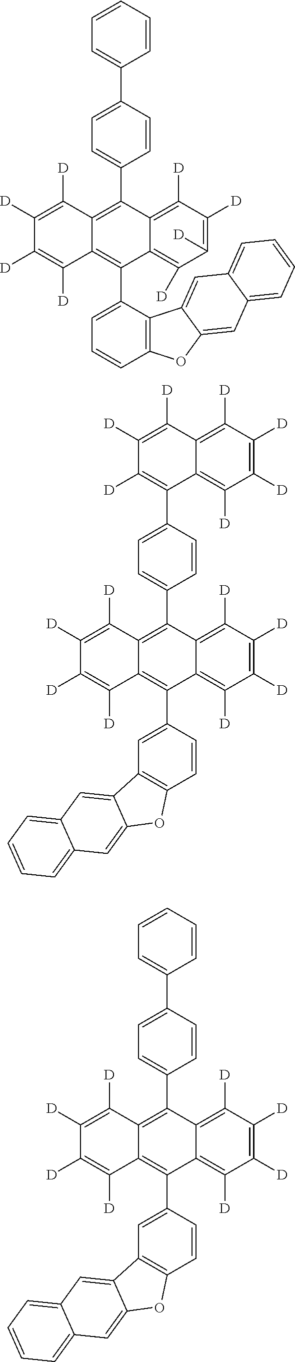 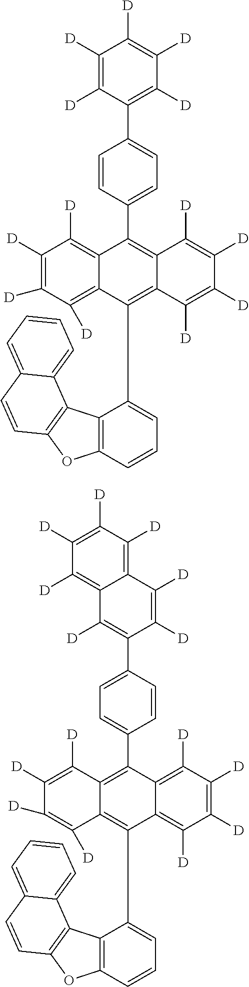 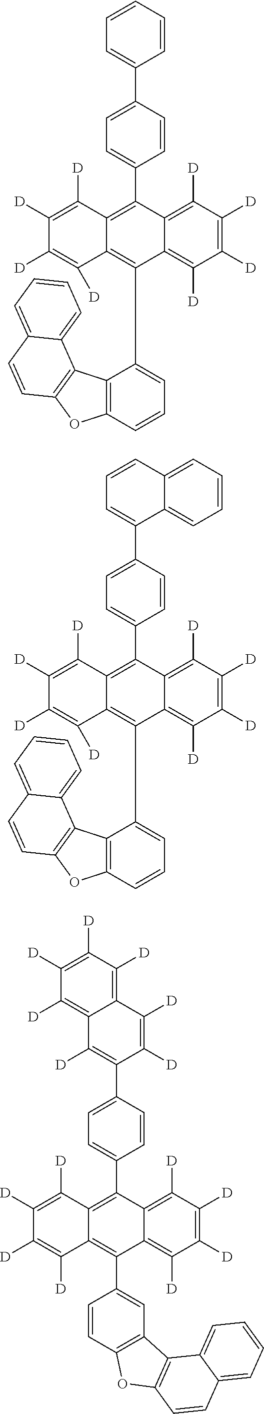 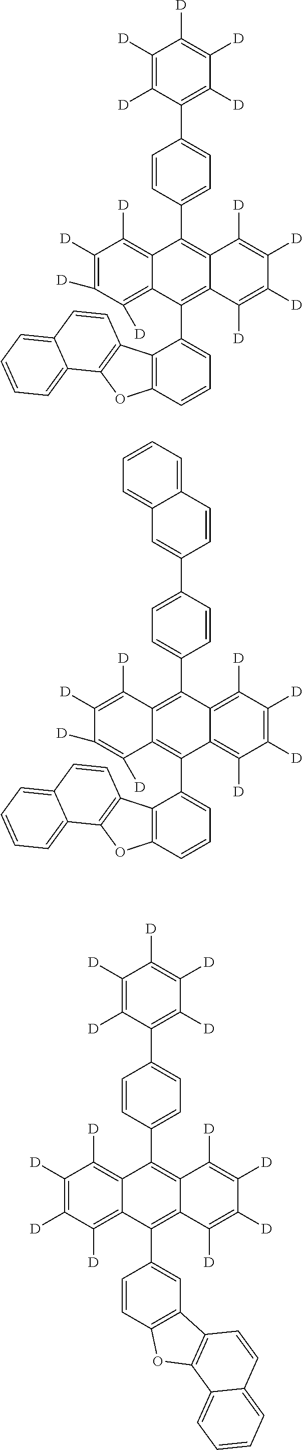 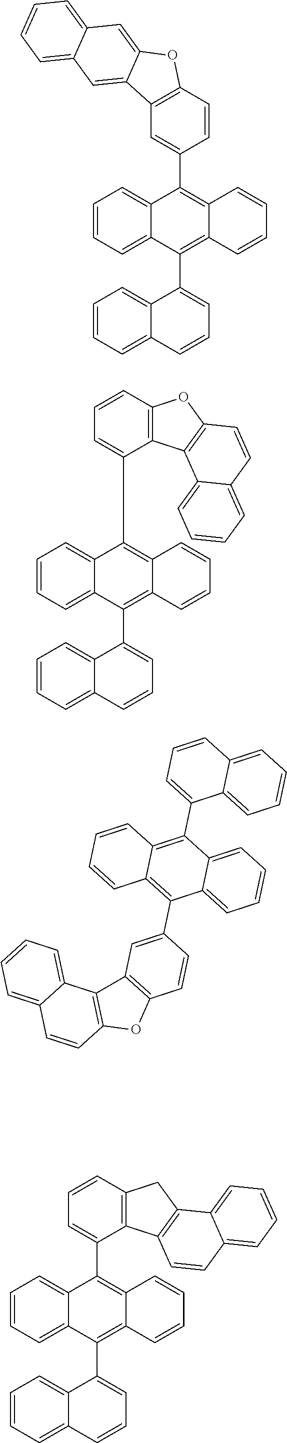 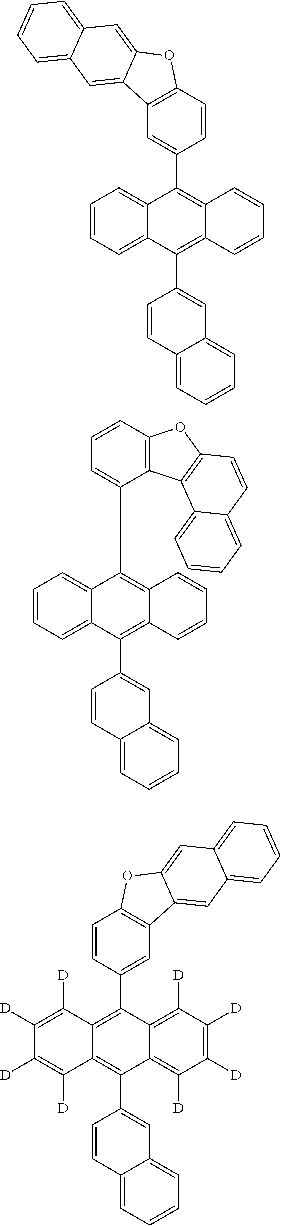 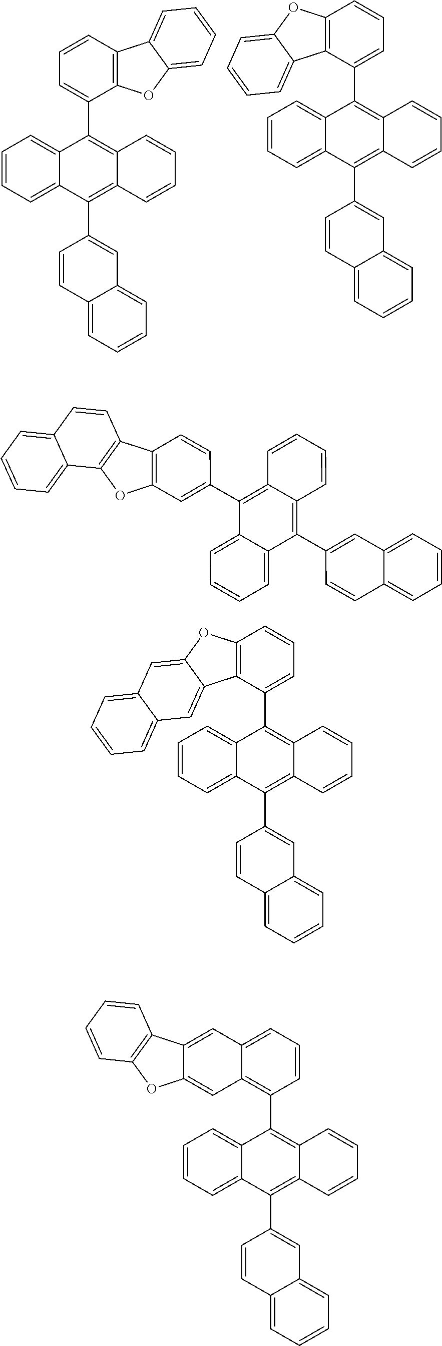 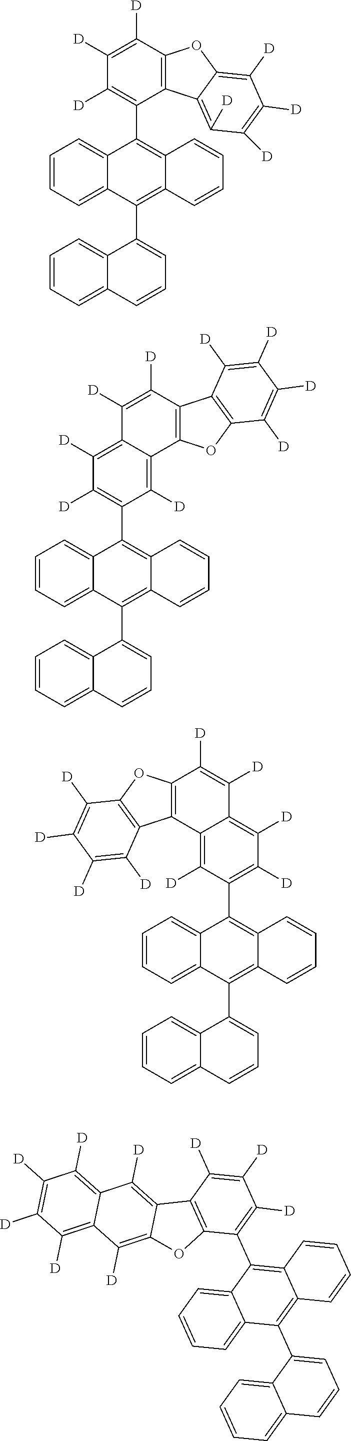 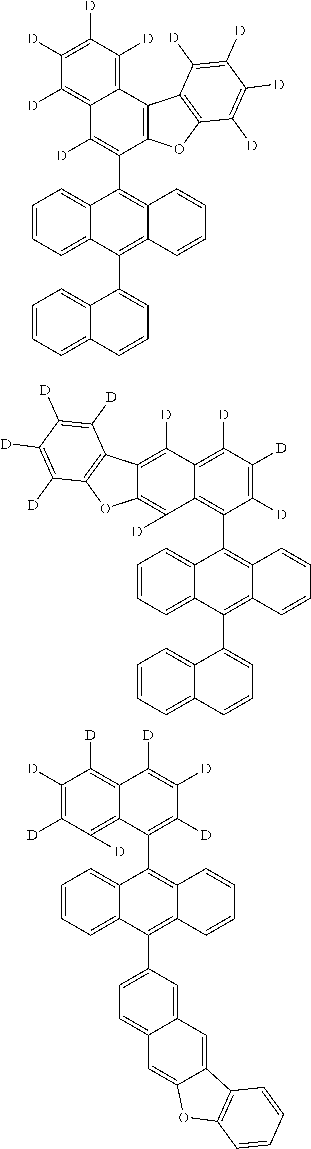 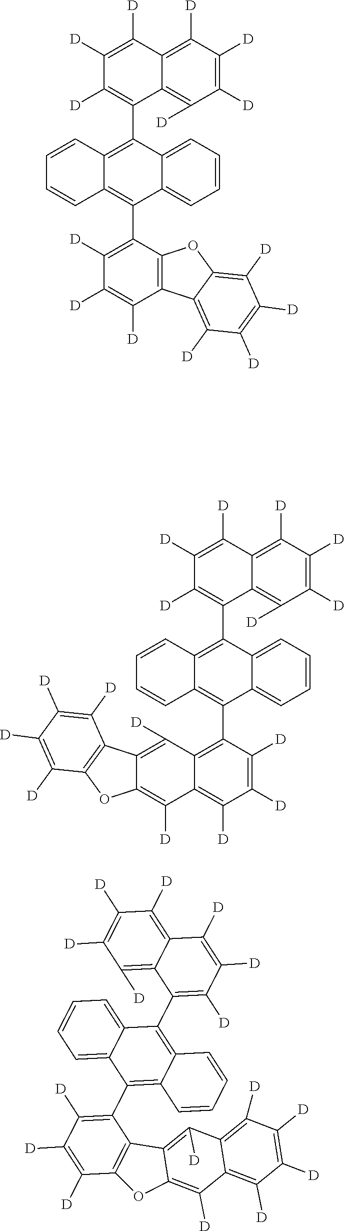 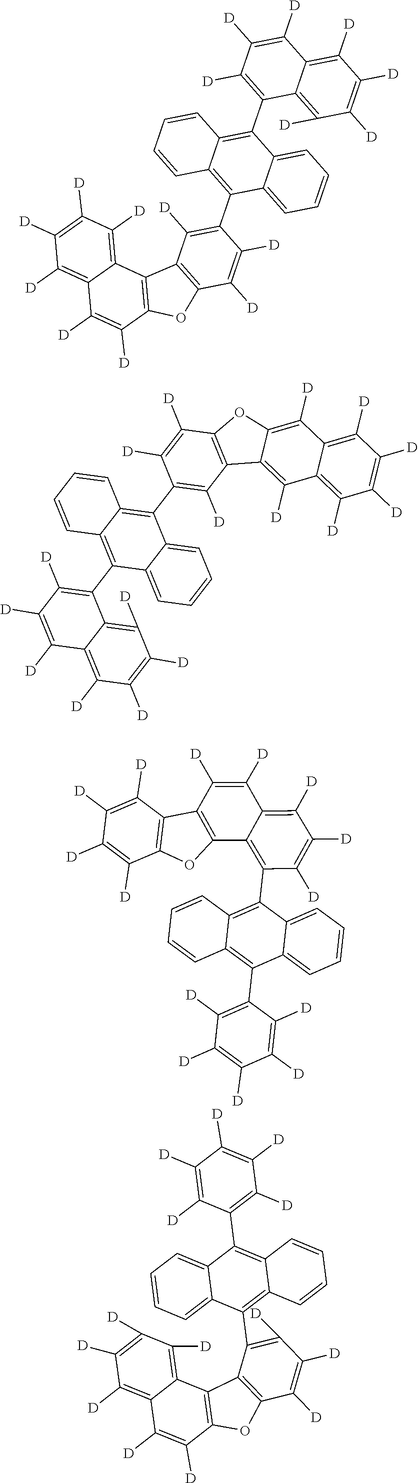 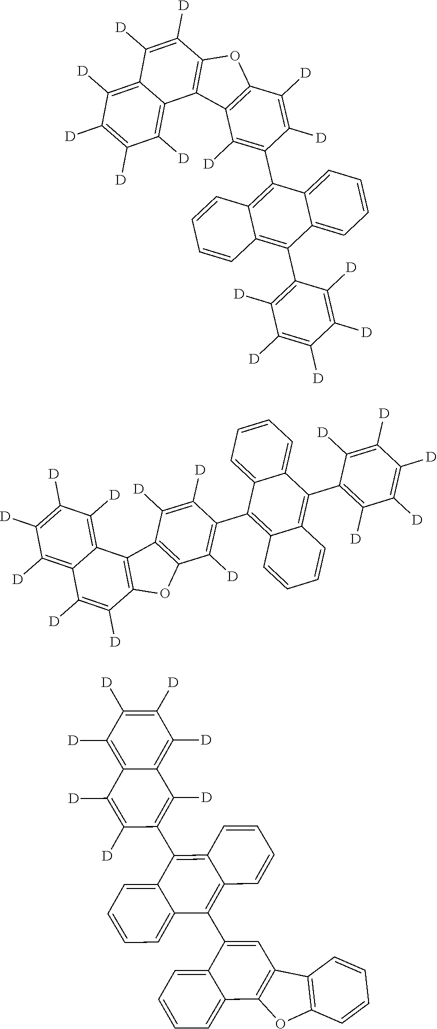 [chemical structure]
